(19) United States
(12) Patent Application Publication
(10) Pub. No.: US 2012/0193785 A1
(43) Pub. Date: Aug. 2, 2012

(54) Multichip Packages

(75) Inventors: Mou-Shiung Lin, Hsin-Chu (TW); Ping-Jung Yang, Hsinchu (TW); Hsin-Jung Lo, Jhonghe City (TW); Te-Sheng Liu, Jhubei City (TW); Jin-Yuan Lee, Hsin-Chu (TW)

(73) Assignee: Megica Corporation, Hsinchu (TW)

(21) Appl. No.: 13/358,496

(22) Filed: Jan. 25, 2012

Related U.S. Application Data
(60) Provisional application No. 61/438,635, filed on Feb. 1, 2011.

(51) Int. Cl. H01L 23/498

(52) U.S. Cl. 257/737; 257/E23.068

(57) ABSTRACT

Multichip packages or multichip modules may include stacked chips and through silicon/substrate vias (TSVs) formed using enclosure-first technology. Enclosure-first technology may include forming an isolation enclosure associated with a TSV early in the fabrication process, without actually forming the associated TSV. The TSV associated with the isolation enclosure is formed later in the fabrication process. The enclosure-first technology allows the isolation enclosures to be used as alignment marks for stacking additional chips. The stacked chips can be connected to each other or to an external circuit such that data input is provided through the bottom-most (or topmost) chip, data is output from the bottom-most (or topmost) chip. The multichip package may provide a serial data connection, and a parallel connection, to each of the stacked chips.

This application claims priority to U.S. Provisional Application No. 61/438,635, filed on Feb. 1, 2011, which is incorporated herein by reference.

### BACKGROUND OF THE DISCLOSURE

1. Field of the Disclosure

The disclosure relates to multichip packages, and more particularly, to multichip packages that include through substrate/silicon vias (TSVs) formed in stacked chips using enclosure-first technology and/or in stacked wafers, such as stacked Flash memory chips.

2. Brief Description of the Related Art

Semiconductor wafers are processed to produce IC (integrated circuit) chips having ever-increasing device density and shrinking feature geometries. Multiple conductive and insulating layers are required to enable the interconnection and isolation of the large number of semiconductor devices in different layers. Such large scale integration results in an increasing number of electrical connections between various layers and semiconductor devices. It also leads to an increasing number of leads to the resultant IC chip. These leads are exposed through a passivation layer of the IC chip, terminating in I/O pads that allow connections to external contact structures in a chip package.

Wafer-Level Packaging (WLP) commonly refers to the technology of packaging an IC chip at wafer level, instead of the traditional process of assembling the package of each individual unit after wafer dicing. WLP allows for the integration of wafer fabrication, packaging, test, and burn-in at the wafer level, before being singulated by dicing for final assembly into a chip carrier package, e.g., a ball grid array (BGA) package. The advantages offered by WLP include less size (reduced footprint and thickness), lesser weight, relatively easier assembly process, lower overall production costs, and improvement in electrical performance. WLP therefore streamlines the manufacturing process undergone by a device from silicon start to customer shipment. While WLP is a high throughput and low cost approach to IC chip packaging, it however invites significant challenges in manufacturability and structural reliability.

### SUMMARY OF THE DISCLOSURE

The present disclosure is directed to a multichip package or multichip module that includes stacked chips and through silicon/substrate vias (TSVs) formed using enclosure-first technology. The stacked chips can be connected to each other or to an external circuit such that data input is provided through the bottom-most (or topmost) chip, data is output from the bottom-most (or topmost) chip. The multichip package may provide a serial data connection, and a parallel connection, to each of the stacked chips.

In one example, a multichip package may include a first chip and a first patterned metal layer at a top side of a first silicon substrate of the first chip. The first patterned metal layer may be connected to a first metal contact point of the first chip at a bottom side of the first silicon substrate and through a first through-silicon via in the first silicon substrate. The multichip package may further include a second chip over the first chip and the first patterned metal layer, and a second patterned metal layer at a top side of a second silicon substrate of the second chip. The second patterned metal layer may be connected to a second metal contact point of the second chip at a bottom side of the second silicon substrate through a second through-silicon via in the second silicon substrate. The multichip package may further include a third chip over the first and second chips and the first and second patterned metal layers, and a third patterned metal layer at a top side of a third silicon substrate of the third chip. The third patterned metal layer may be connected to a third metal contact point of the third chip at a bottom side of the third silicon substrate through a third through-silicon via in the third silicon substrate. The first metal contact point may be connected to the third patterned metal layer through, in sequence, the first through-silicon via, the second through-silicon via, and the third through-silicon via. The third patterned metal layer may have the same pattern as the first patterned metal layer and may have a different pattern than the second patterned metal layer.

These, as well as other components, steps, features, benefits, and advantages of the present disclosure, will now become clear from a review of the following detailed description of illustrative embodiments, the accompanying drawings, and the claims.

### BRIEF DESCRIPTION OF THE DRAWINGS

The drawings disclose illustrative embodiments of the present disclosure. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same numeral appears in different drawings, it refers to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure.

FIGS. 1-16 illustrate cross-sectional views of multichip packages according to exemplary embodiments of the present disclosure.

FIG. 17 illustrates a view of a multichip package according to an exemplary embodiment of the present disclosure.

FIGS. 18-37 illustrate a process for forming a multichip package according to exemplary embodiments of the present disclosure.

FIGS. 38-39 illustrate cross-sectional views of multichip packages according to exemplary embodiments of the present disclosure.

FIGS. 40-65 illustrate a process for forming a multichip package according to exemplary embodiments of the present disclosure.

FIGS. 66-74 illustrate a process for forming a substrate which can be used in a multichip package according to an exemplary embodiment of the present disclosure.

FIGS. 75-85 illustrate a process for forming a multichip package using enclosure-first technology according to exemplary embodiments of the present disclosure.

FIG. 86 illustrates a schematic circuit diagram of a data storage device according to an exemplary embodiment of the present disclosure.

FIG. 86A illustrates an exemplary block arrangement of a memory chip.

FIG. 87 illustrates a schematic cross-sectional view of a multichip package according to an exemplary embodiment of the present disclosure.

FIG. 88 illustrates a top perspective view of the layout of the overlying interconnects 236a shown in FIG. 87.

FIG. 89 illustrates a top perspective view of the layout of the overlying interconnects 236b shown in FIG. 87.

FIG. 90 illustrates a top perspective view of the layout of the overlying interconnects 236c shown in FIG. 87.

FIG. 91 illustrates a top perspective view of the layout of the overlying interconnects 236d shown in FIG. 87.

FIG. 92 illustrates a schematic cross-sectional view of a multichip package according to an exemplary embodiment of the present disclosure.

FIG. 93 illustrates a top perspective view of the layout of the metal interconnects 239 shown in FIG. 92.

FIG. 94 illustrates a top perspective view of the layout of the overlying interconnects 237a shown in FIG. 92.

FIG. 95 illustrates a top perspective view of the layout of the overlying interconnects 237b shown in FIG. 92.

FIG. 96 illustrates a top perspective view of the layout of the overlying interconnects 237c shown in FIG. 92.

FIG. 97 illustrates a top perspective view of the layout of the overlying interconnects 236a shown in FIG. 87.

FIG. 98 illustrates a top perspective view of the layout of the overlying interconnects 236b shown in FIG. 87.

FIG. 99 illustrates a top perspective view of the layout of the overlying interconnects 236c shown in FIG. 87.

FIG. 100 illustrates a top perspective view of the layout of the overlying interconnects 236d shown in FIG. 87.

FIGS. 101A and 101B are top perspective views.

FIG. 102 illustrates a schematic cross-sectional view of a multichip package according to an exemplary embodiment of the present disclosure.

FIG. 103 illustrates a schematic cross-sectional view of a multichip package according to an exemplary embodiment of the present disclosure.

FIG. 104 illustrates a schematic diagram of a data storage device according to an exemplary embodiment of the present disclosure.

While certain embodiments are depicted in the drawings, one skilled in the art will appreciate that the embodiments depicted are illustrative and that variations of those shown, as well as other embodiments described herein, may be envisioned and practiced within the scope of the present disclosure.

### DETAILED DESCRIPTION OF THE INVENTION

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

The process of fabricating multichip packages described herein may include fabricating isolation enclosures and through silicon/substrate vias (TSVs) using enclosure-first technology. Enclosure-first technology may include forming an isolation enclosure associated with a TSV early in the fabrication process, without actually forming the associated TSV. The TSV associated with the isolation enclosure is formed later in the fabrication process. Deep trenches may be formed to provide TSV isolation, while shallow trenches may be formed for active device isolation. The enclosure-first technology may also allow the isolation enclosures to be used as alignment marks for additional wafers. The alignment marks facilitate stacking multiple wafers together in a multichip package.

The enclosure-first technology may also be applied to Flash wafer stacking, such as in solid state drive (SSD) using a single Flash chip design. The Flash wafers may be NAND flash or other types of Flash. The design may provide for data input from the bottom-most (or topmost) chip, data output from the topmost (or bottom-most) chip, a serial data connection, a parallel control and/or clock signal connection. The overlying metal layers at the backsides of the chips may include serial connections for connecting serial output ports of one chip to serial input ports of another chip. The overlying metal layers may have portions used as TSV etch stop for parallel connections and through-data connections.

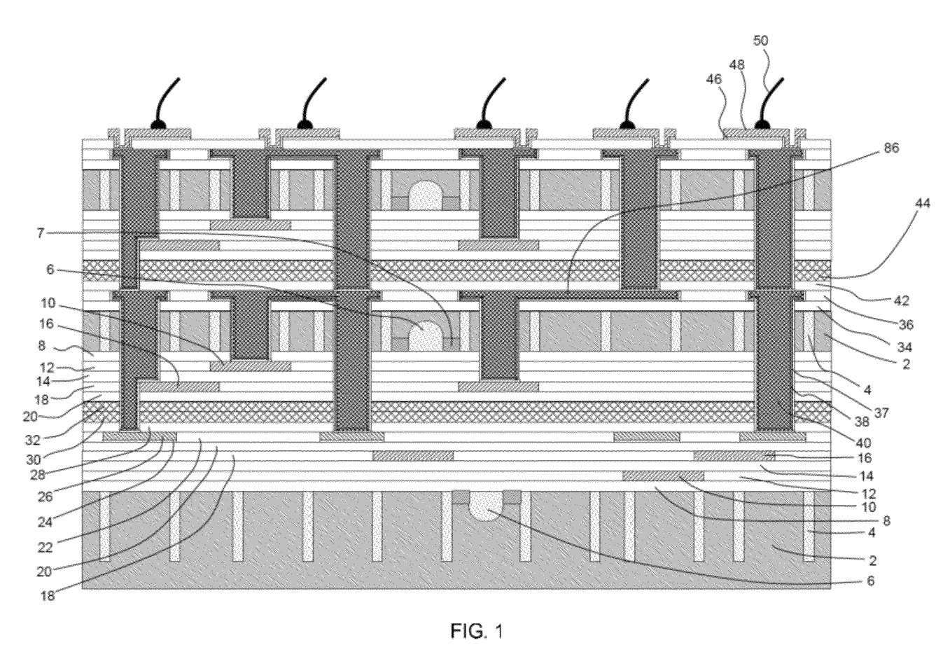

FIGS. 1-17 illustrate cross-sectional views of multichip packages according to exemplary embodiments of the present disclosure.

FIG. 1 illustrates a schematic cross-sectional view of a multichip package according to an exemplary embodiment of the present disclosure. The multichip package may include stacked chips, adhesive dielectric layers 30, 32 and 44, dielectric or insulating layers 34, 36 and 42, metal interconnects 86, metal traces composed of metal layers 46 and 48, and wirebonded wires 50 bonded onto the metal layer 48 of the metal traces. Each of the wirebonded wires 50 may include gold, copper, and/or aluminum. Each of metal interconnects or plugs 86 can be composed of a metal layer 40, a seed layer 38 on the bottoms and sidewalls of the metal layer 40, and an adhesion layer 37 at the bottoms and sidewalls of the metal layer 40. The adhesive dielectric layers 30, 32 and 44 are between the stacked chips. In one example, the stacked chips in the multichip package may be memory chips, such as NAND-Flash chips. Each of the stacked chips in the multichip package includes a semiconductor substrate 2, a deep-trench isolation (DTI) layer 4, a shallow-trench isolation (STI) layer 6, integrated circuit (IC) devices 7, dielectric layers 8, 12, 14 and 18, conductive layers 10 and 16, and a passivation layer 20.

The bottom one of the stacked chips may further include an insulating layer 22 on the passivation layer 20, a patterned metal layer composed of metal layers 24 and 26, and an insulating layer 28 on the insulating layer 22 and the patterned metal layer. The metal layer 24 is at the bottom of the metal layer 26 but not at the sidewalls of the metal layer 26. In one example, the metal layer 24 may include an adhesion layer, such as titanium, titanium nitride, a titanium-tungsten alloy, tantalum, tantalum nitride, chromium, nickel or nickel vanadium, having a suitable thickness, such as between 1 nanometer and 0.5 micrometers or between 10 nanometers and 0.8 micrometers, formed on the passivation layer 20 by using a suitable process, such as sputtering process, and a seed layer, such as copper, a titanium-copper alloy, gold, nickel or silver, having a suitable thickness, such as between 10 nanometers and 0.5 micrometers, formed on the adhesion layer by using a suitable process, such as sputtering process, and the metal layer 26 can be a layer of copper, gold, nickel or silver with a suitable thickness, such as between 2 and 30 micrometers or between 5 and 20 micrometers, formed on the seed layer by using a suitable process, such as electroplating process. Alternatively, the metal layer 24 can be an adhesion layer, such as titanium nitride, formed on the passivation layer 20 by using a suitable process, such as sputtering process, and the metal layer 26 can be an aluminum-containing layer, such as aluminum or an aluminum-copper alloy, formed on the adhesion layer 24 by using a suitable process, such as sputtering process.

The semiconductor substrate 2 of each of the stacked chips in the multichip package may be a silicon substrate having a suitable thickness, such as between 1 and 100 micrometers, between 1 and 50 micrometers, between 1 and 20 micrometers, between 1 and 10 micrometers, between 1 and 5 micrometers, or between 2 and 5 micrometers. Alternatively, the semiconductor substrate 2 of each stacked chips in the multichip package may be a substrate including Gallium arsenide (GaAs), Indium phosphide (InP), silicon-germanium (SiGe) or other silicon based variants and having a suitable thickness, such as between 1 and 100 micrometers, between 1 and 50 micrometers, between 1 and 20 micrometers, between 1 and 10 micrometers, between 1 and 5 micrometers, or between 2 and 5 micrometers.

The deep trench isolation (DTI) layer 4 of each of the stacked chips in the multichip package may also be referred to as a deep-trench insulating layer or deep-trench insulators. The DTI layer 4 may include silicon oxide and/or silicon nitride. The DTI layer 4 may have a suitable width, such as between 0.1 and 20 micrometers, between 0.1 and 10 micrometers, between 0.1 and 5 micrometers, between 0.1 and 2 micrometers, or between 0.1 and 1 micrometers. The DTI layer 4 may have a suitable depth, such as between 1 and 100 micrometers, between 1 and 50 micrometers, between 1 and 20 micrometers, between 1 and 10 micrometers, between 1 and 5 micrometers, or between 2 and 5 micrometers. The DTI layer 4 may be for positioning of through silicon/substrate vias (TSVs). The DTI layer 4 may include one or more backside alignment marks (not shown in FIG. 1) for forming the metal interconnects 86 and multiple isolation enclosures (shown in FIG. 1) enclosing the metal interconnects 86 in the TSVs. The shallow trench isolation (STI) layer 6 of each of the stacked chips in the multichip package may also be referred to as a shallow-trench insulating layer or shallow-trench insulators. The STI layer 6 may be for positioning of a semiconductor integrated circuit. The STI layer 6 may include silicon oxide or a combination of silicon oxide and silicon nitride. The STI layer 6 may have a suitable depth, such as between 0.02 and 1 micrometers or between 0.05 and 0.5 micrometers. The STI layer 6 may have a suitable width, such as between 0.02 and 100 micrometers, or between 0.05 and 10 micrometers.

The IC devices 7 of each of the stacked chips in the multichip package may be N-type metal-oxide-semiconductor (NMOS) transistors, P-type metal-oxide-semiconductor (PMOS) transistors, complementary metal-oxide-semiconductor (CMOS) logic circuits, P—N diodes, capacitors, resistors, inductors, programmable logic devices (PLDs), field-programmable gate arrays (FPGAs), analog devices, and/or memories, such as NAND-Flash memories, NOR-Flash memories, static random access memories (SRAMs), dynamic random access memories (DRAMs), synchronous dynamic random access memories (SDRAMs), ferroelectric random access memories (FeRAMs), magneto resistive random access memories, phase-change random access memories (PRAMs), electrically erasable programmable read-only memories (EEPROMs), or erasable programmable read only memories (EPROMs).

The dielectric layer 8 of each of the stacked chips in the multichip package may include one or more of phosphosilicate glass (PSG), borophosphosilicate glass (BPSG), silicon dioxide (SiO₂), silicon nitride (Si₃N₄), silicon carbon-nitride, silicon oxynitride, or low-k dielectric material, such as fluorosilicate glass (FSG), and/or black-diamond. The dielectric layer 8 may be formed or deposited using a suitable process.

The conductive layer 10 of each of the stacked chips in the multichip package may include one or more of aluminum-copper (Al—Cu), tungsten (W), copper, carbon nanotubes, and/or adhesion/barrier metal, such as titanium (Ti), titanium nitride (TiN), tantalum (Ta), tantalum nitride (TaN), and/or Titanium-Tungsten (TiW). The conductive layer 10 may have a suitable thickness, such as between 10 nanometers and 2 micrometers or between 10 nanometers and 1 micrometer. The conductive layer 10 may be formed or deposited using a suitable process. The dielectric layer 12 of each stacked chips in the multichip package may include one or more of silicon dioxide (SiO₂), silicon nitride (Si₃N₄), silicon carbon-nitride, silicon oxynitride, and/or a low-k dielectric material, such as fluorosilicate glass (FSG). The dielectric layer 12 may be formed or deposited using a suitable process. The dielectric layers 14 and 18 of each stacked chips in the multichip package may include one or more of silicon dioxide (SiO₂), silicon nitride (Si₃N₄), silicon carbon-nitride, silicon oxynitride, and/or a low-k dielectric material, such as fluorosilicate glass (FSG), and/or black-diamond. The dielectric constant of the low-k dielectric material may be between 1.8 and 3. The dielectric layers 14 and 18 may be formed or deposited using a suitable process.

The conductive layer 16 of each of the stacked chips in the multichip package may include one or more of aluminum-copper (Al—Cu), tungsten (W), copper, carbon nanotubes, and/or adhesion/barrier metal, such as titanium (Ti), titanium nitride (TiN), tantalum (Ta), tantalum nitride (TaN), or titanium-tungsten (TiW). The conductive layer 16 may have a suitable thickness, such as between 10 nanometers and 2 micrometers or between 10 nanometers and 1 micrometer. The conductive layer 16 may be formed or deposited using a suitable process. The passivation layer 20 of each stacked chips in the multichip package can be an insulating inorganic layer, and the insulating inorganic layer may include one or more of silicon-nitride, silicon-oxide, and/or silicon oxynitride. The passivation layer 20 may be formed or deposited using a suitable process. The insulating layer 22 may be on the passivation layer 20. The insulating layer 22 may include one or more of silicon dioxide (SiO₂), silicon nitride (Si₃N₄), silicon carbon-nitride, silicon oxynitride, polyimide, epoxy, benzocyclobutene (BCB), polybenzoxazole (PBO), Poly(p-phenylene oxide) (PPO), silosane, and/or SU-8. The insulating layer 22 may have a suitable thickness, such as between 0.3 and 30 micrometers. The insulating layer 22 may be formed or deposited using a suitable process.

The insulating layer 28 may include one or more of silicon dioxide (SiO₂), silicon nitride (Si₃N₄), silicon carbon-nitride, silicon oxynitride, polyimide, epoxy, benzocyclobutene (BCB), and/or polybenzoxazole (PBO). The insulating layer 28 may have a suitable thickness, such as between 0.3 and 10 micrometers, between 0.3 and 5 micrometers, between 0.3 and 3 micrometers, between 0.3 and 2 micrometers, or between 0.3 and 1 micrometers. The insulating layer 28 may be formed or deposited using a suitable process. The adhesive dielectric layers 30, 32 and 44 may include one or more of activated silicon oxide, activated silicon oxynitride, silicon nitride, BCB, polyimide, epoxy and/or PBO. The adhesive dielectric layers 30, 32 and 44 may have a suitable thickness, such as between 1 and 100 nanometers, between 0.1 and 10 micrometers, between 0.1 and 5 micrometers, and/or between 0.1 and 1 micrometers. The adhesive dielectric layers 30, 32 and 44 may be formed or deposited using a suitable process.

The dielectric or insulating layers 34 and 36 may include one or more of silicon dioxide (SiO₂), silicon nitride (Si₃N₄), silicon carbon-nitride, silicon oxynitride, polyimide, epoxy, and/or polybenzoxazole (PBO). The dielectric or insulating layers 34 and 36 may have a suitable thickness, such as between 0.3 and 10 micrometers, or between 0.3 and 5 micrometers. The dielectric or insulating layers 34 and 36 may be formed or deposited using a suitable process. The metal layers 37 and 46 may include one or more of titanium (Ti), titanium nitride (TiN), titanium tungsten (TiW), tantalum (Ta), tantalum nitride (TaN), chromium (Cr), nickel (Ni), and/or nickel vanadium (Ni—V). The metal layers 37 and 46 may have a suitable thickness, such as between 1 nanometer and 0.5 micrometers. The metal layers 37 and 46 may be formed or deposited using a suitable process.

The seed layer 38 may be a metal layer including one or more of copper, silver and/or gold and having a suitable thickness, such as between 10 nanometers and 0.8 micrometers. The seed layer 38 may be formed or deposited using a suitable process. The metal layer 40 may be for interconnection or pad relocation. The metal layer 40 may include one or more of copper, silver, and/or gold. For example, the metal layer 40 can be a copper plug. The metal layer 40 may have a suitable thickness, such as between 0.5 and 20 micrometers, between 0.5 and 10 micrometers, or between 1 and 5 micrometers. The metal layer 40 may be formed or deposited using a suitable process, such as electroplating process. The dielectric or insulating layer 42 may include one or more of silicon dioxide (SiO₂), silicon nitride (Si₃N₄), silicon carbon-nitride, silicon oxynitride, polyimide, epoxy, benzocyclobutene (BCB), and/or polybenzoxazole (PBO). The dielectric or insulating layer 42 has a suitable thickness, such as between 0.3 and 10 micrometers, between 0.3 and 5 micrometers, between 0.3 and 3 micrometers, between 0.3 and 2 micrometers, or between 0.3 and 1 micrometers. The dielectric or insulating layer 42 may be formed or deposited using a suitable process.

The metal layer 48 may include wire bondable metal such as one or more of aluminum-copper (Al—Cu), nickel/gold (Ni/Au), nickel/palladium (Ni/Pd), copper/nickel/gold (Cu/Ni/Au) and/or copper/nickel/palladium (Cu/Ni/Pd). The conduction layer may have a suitable thickness, such as between 0.5 and 10 micrometers. The metal layer 48 may also include a seed layer, such as a layer including copper and/or gold. The seed layer may have a thickness between 0.01 and 1 micrometers. The metal layer 48 and any associated seed layer may be formed or deposited using a suitable process. The wirebonded wires 50 may include one or more of gold, copper, and/or aluminum. The wirebonded wires 50 may be formed using a suitable process, such as wirebonding process. The metal interconnects 86 over the semiconductor substrate 2 may have a suitable thickness, such as between 0.1 and 20 micrometers, between 0.1 and 10 micrometers, between 0.1 and 5 micrometers, or between 0.1 and 1 micrometers. The metal interconnects 86 may be formed using a suitable process, such as damascene process including an electroplating process.

The stacked chips of FIG. 1 may have the same die size. Alternatively, the die sizes of the stacked chips may vary. The stacked chips may be memory chips, such as NAND memory, Flash memory, DRAM, and/or SRAM. The quantity of the stacked chips may be any suitable quantity, such as 4, 8, 16, or more. The stacked chips may have a suitable thickness, such as between 1 and 100 micrometers, between 1 and 50 micrometers, between 1 and 20 micrometers, or between 1 and 10 micrometers. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin. The multichip package may include damascene metal traces and/or embossing metal traces. The multichip package may also include bonding wire for leading out to input/output, signal, and/or power/ground pin.

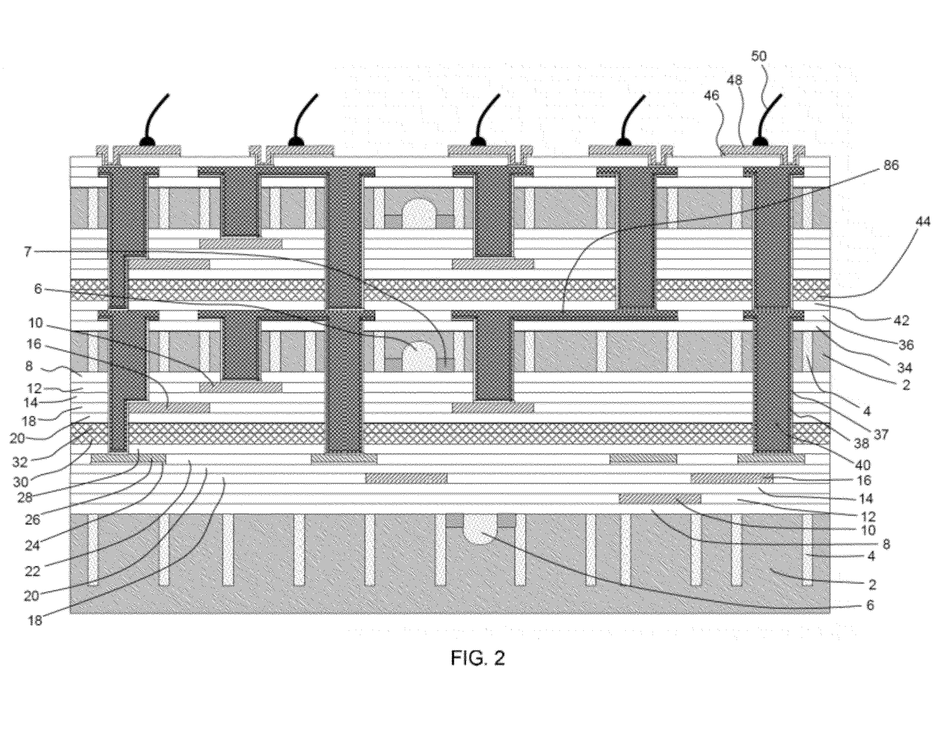

FIG. 2 illustrates a cross-sectional view of a multichip package according to an exemplary embodiment of the present disclosure. The stacked integrated circuit chips of FIG. 2 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin. The multichip package may include damascene metal traces and/or embossing metal traces. The multichip package may also include bonding wire for leading out to input/output, signal, and/or power/ground pin.

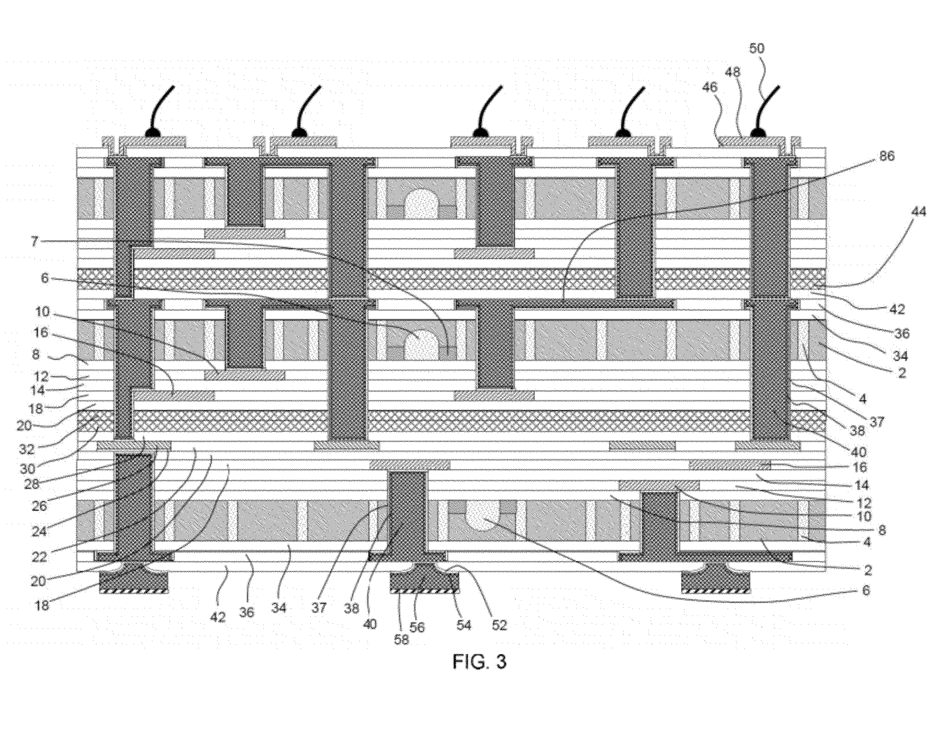

FIG. 3 illustrates a cross-sectional view of a multichip package according to an exemplary embodiment of the present disclosure. In addition to previously discussed elements and/or layers, the multichip package of FIG. 3 includes adhesion/barrier layer 52, seed layer 54, metal pad 56, and metal layer 58.

The adhesion/barrier layer 52 may include one or more of titanium (Ti), titanium nitride (TiN), titanium tungsten (TiW), tantalum (Ta), tantalum nitride (TaN), chromium (Cr), nickel (Ni), and/or nickel vanadium (Ni—V). The adhesion/barrier layer 52 may have a suitable thickness, such as between 1 nanometer and 0.5 micrometers. The adhesion/barrier layer 52 may be formed or deposited using a suitable process. The seed layer 54 may include one or more of copper, silver and/or gold. The seed layer 54 may have a suitable thickness, such as between 10 nanometers and 0.8 micrometers. The seed layer 54 may be formed or deposited using a suitable process. The metal pad 56 may include one or more of copper, silver, and/or gold. The metal pad 56 may have a suitable width, such as between 20 and 400 micrometers or between 50 and 100 micrometers. The metal pad 56 may have a suitable thickness, such as between 10 and 100 micrometers or between 20 and 60 micrometers. The metal pad 56 may be formed using a suitable process. The metal layer 58 may be on top of the metal pad 56. The metal layer 58 may include one or more of gold, nickel/gold (Ni/Au), palladium and/or nickel/palladium (Ni/Pd). The metal layer 58 may have a suitable thickness, such as between 0.5 and 5 micrometers or between 0.5 and 2 micrometers. The metal layer 58 may be formed or deposited using a suitable process.

The stacked integrated circuit chips of FIG. 3 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package may also include bonding wire for leading out to input/output, signal, and/or power/ground pin. The bonding wire may connect to the pads on one side of the stacked IC chips. The multichip package may also include metal pads on another side of the stacked IC chips for solder bonding or electrical contact. Alternatively, one or more metal pads may be replaced with one or more solder bumps (not shown).

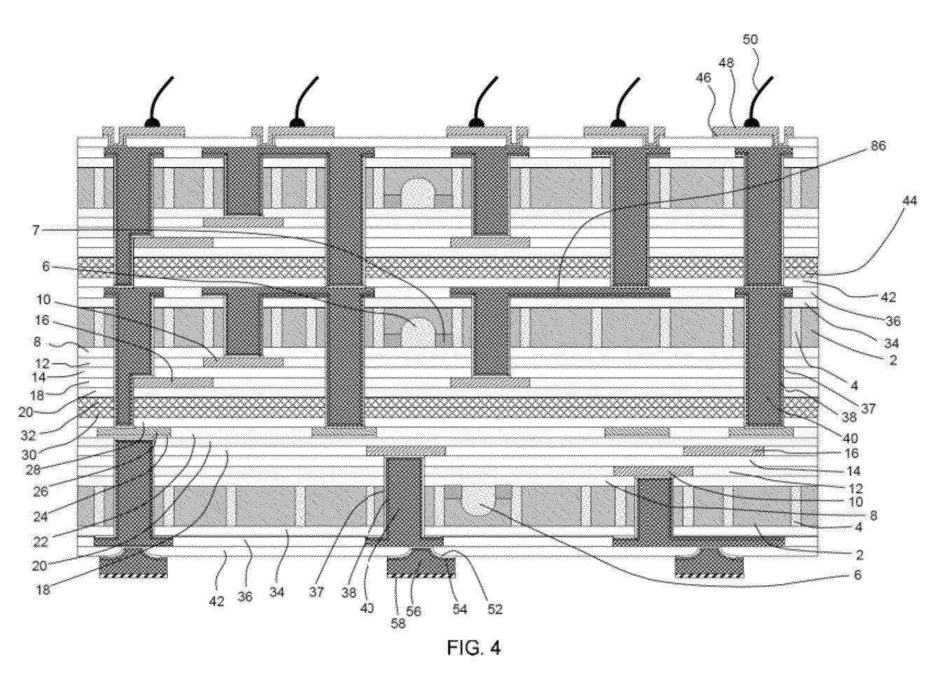

FIG. 4 illustrates a cross-sectional view of a multichip package according to an exemplary embodiment of the present disclosure. The stacked integrated circuit chips of FIG. 4 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package may also include bonding wire for leading out to input/output, signal, and/or power/ground pin. The bonding wire may connect to the pads on one side of the stacked IC chips. The multichip package may also include metal pads on another side of the stacked IC chips for solder bonding or electrical contact. Alternatively, one or more metal pads may be replaced with one or more solder bumps (not shown).

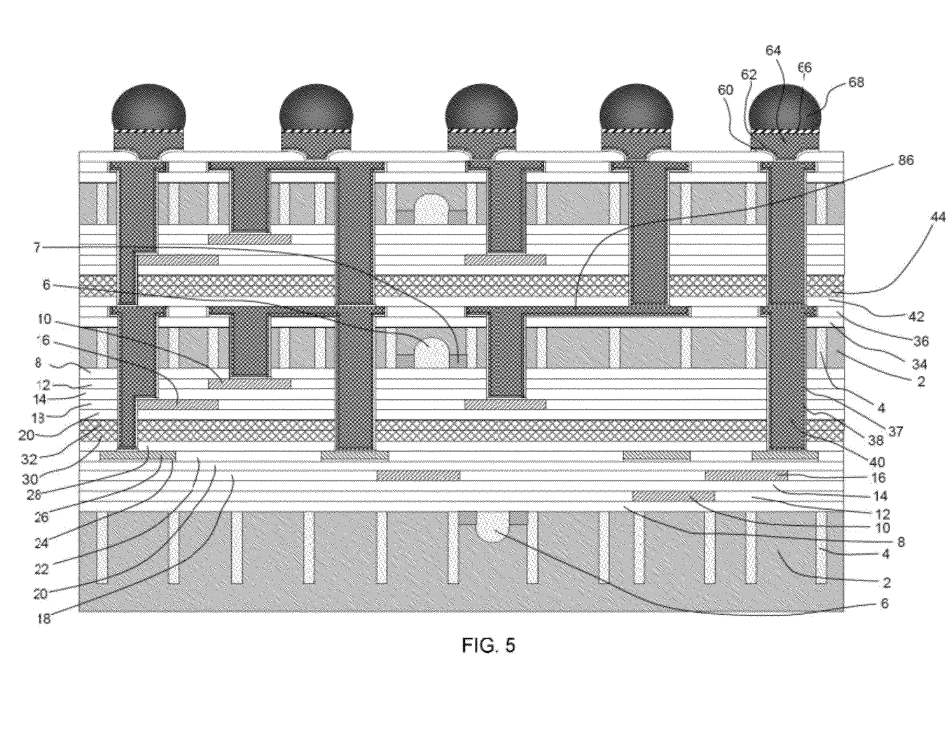

FIG. 5 illustrates a cross-sectional view of a multichip package according to an exemplary embodiment of the present disclosure. In addition to previously discussed elements and/or layers, the multichip package of FIG. 5 includes adhesion/barrier layer 60, seed layer 62, under-bump metal (UBM) 64, barrier layer 66, and solder bump 68.

The adhesion/barrier layer 60 may include one or more of titanium (Ti), titanium nitride (TiN), titanium tungsten (TiW), tantalum (Ta), tantalum nitride (TaN), chromium (Cr), nickel (Ni), and/or nickel vanadium (Ni—V). The adhesion/barrier layer 60 may have a suitable thickness, such as between 1 nanometer and 0.5 micrometers. The adhesion/barrier layer 60 may be formed or deposited using a suitable process. The seed layer 62 may include one or more of copper, silver and/or gold. The seed layer 62 may have a suitable thickness, such as between 10 nanometers and 0.8 micrometers. The seed layer 62 may be formed or deposited using a suitable process. The barrier layer 66 may include one or more of nickel, nickel/gold (Ni/Au), and/or nickel-vanadium (Ni—V). The barrier layer 66 may have a thickness between 0.5 and 10 micrometers, between 0.5 and 5 micrometers, or between 0.5 and 3 micrometers. The barrier layer 66 may be formed or deposited using a suitable process. The solder bump 68 may include one or more of tin-silver (Sn—Ag), tin-silver-copper (Sn—Ag—Cu), tin-gold (Sn—Au) and/or tin-lead (Sn—Pb). The solder bump 68 may have a suitable width, such as between 10 micrometers and 200 micrometers or between 50 micrometers and 100 micrometers. The solder bump 68 may have a suitable bump height, such as between 5 and 200 micrometers or between 10 and 100 micrometers. The solder bump 68 may be formed using a suitable process.

The stacked integrated circuit chips of FIG. 5 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package of FIG. 5 may include solder bumps 68 for leading out input/output, signal, and/or power/ground pin.

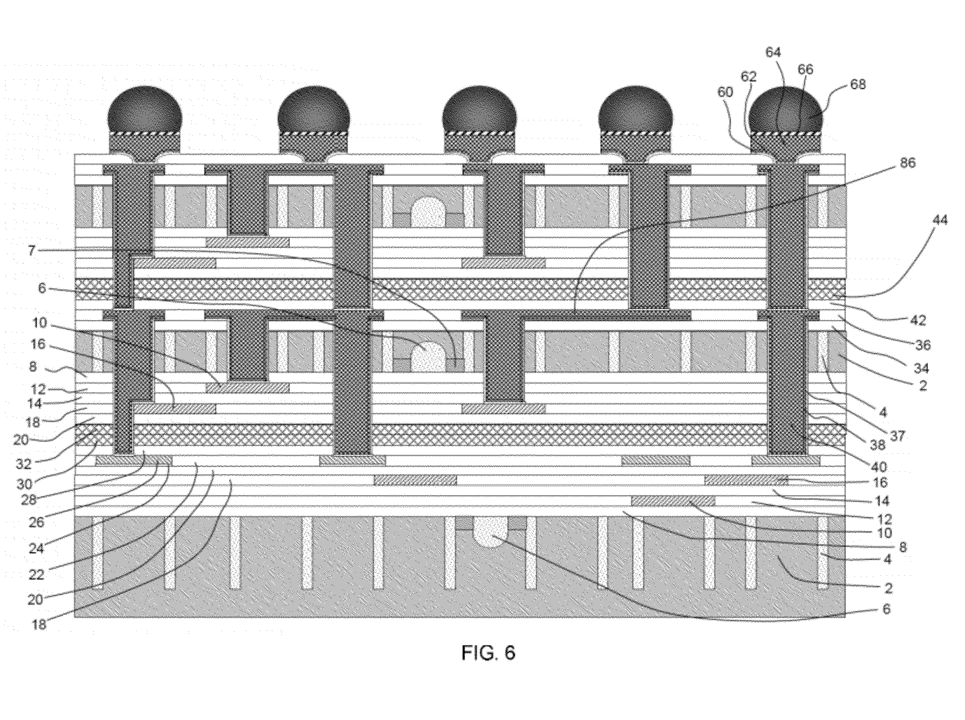

FIG. 6 illustrates a cross-sectional view of a multichip package according to an exemplary embodiment of the present disclosure. The stacked integrated circuit chips of FIG. 6 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package of FIG. 6 may include solder bumps 68 for leading out input/output, signal, and/or power/ground pin.

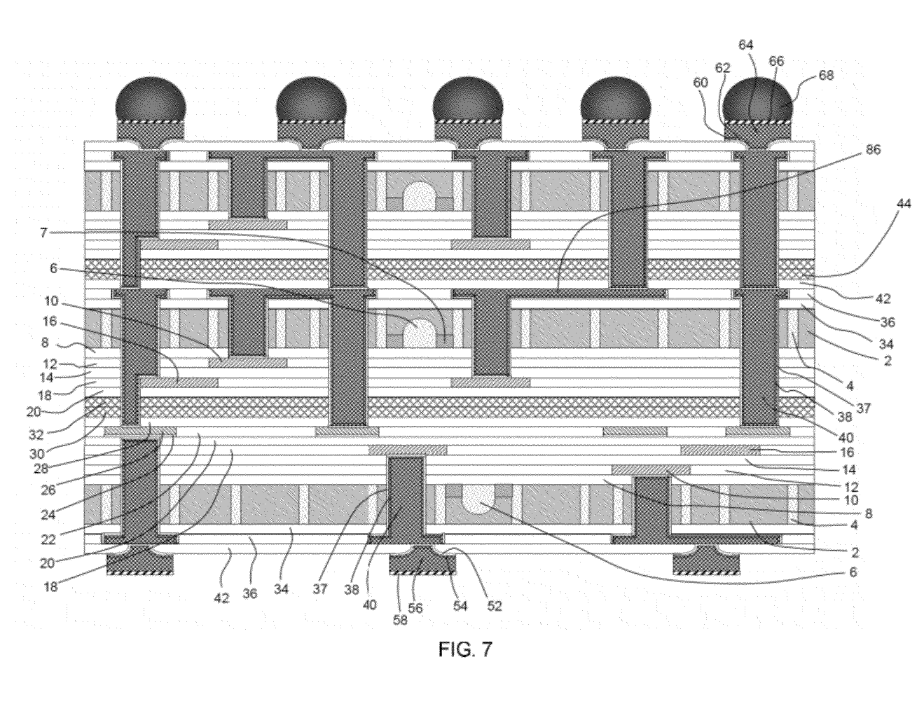

FIG. 7 illustrates a cross-sectional view of a multichip package according to an exemplary embodiment of the present disclosure. The stacked integrated circuit chips of FIG. 7 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package may include solder bumps 68 for leading out input/output, signal, and/or power/ground pin. The multichip package may also include metal pads on another side of the stacked IC chips for solder bonding or electrical contact. One or more of the metal pads may be replaced by one or more solder bumps (not shown).

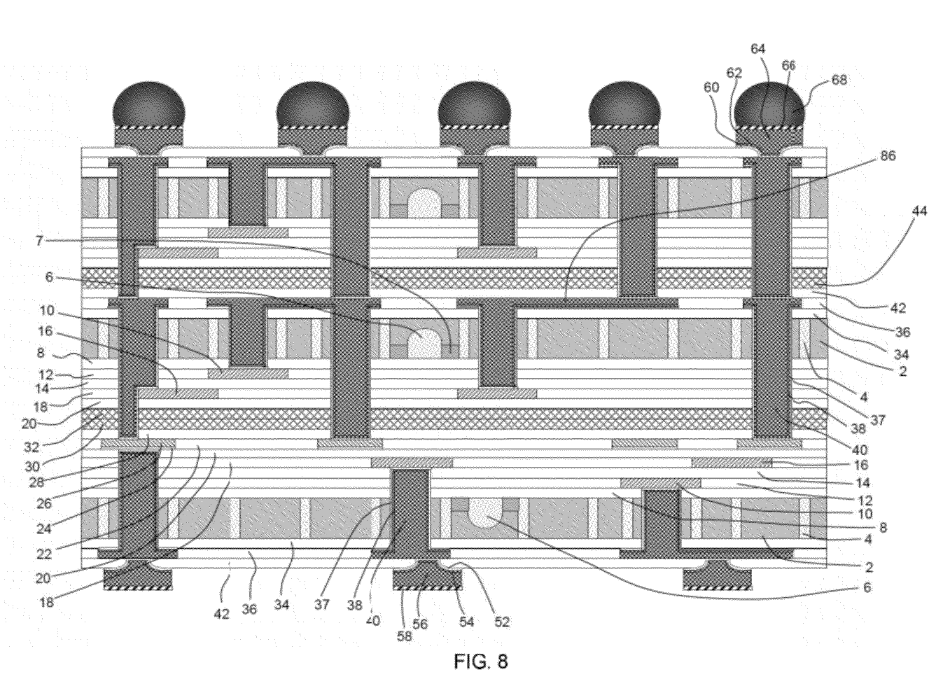

FIG. 8 illustrates a cross-sectional view of a multichip package according to an exemplary embodiment of the present disclosure. The stacked integrated circuit chips of FIG. 8 may have the same die size. Alternatively, the die sizes of the IC chips may vary. The stacked IC chips may be memory chips, such as NAND memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Alternatively, or in addition, the stacked IC chips may be FPGA. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin or a chip-select pin. The multichip package may include damascene metal traces and/or embossing metal traces. The multichip package may include solder bumps 68 for leading out input/output, signal, and/or power/ground pin. The multichip package may also include metal pads on another side of the stacked IC chips for solder bonding or electrical contact. One or more of the metal pads may be replaced by one or more solder bumps (not shown).

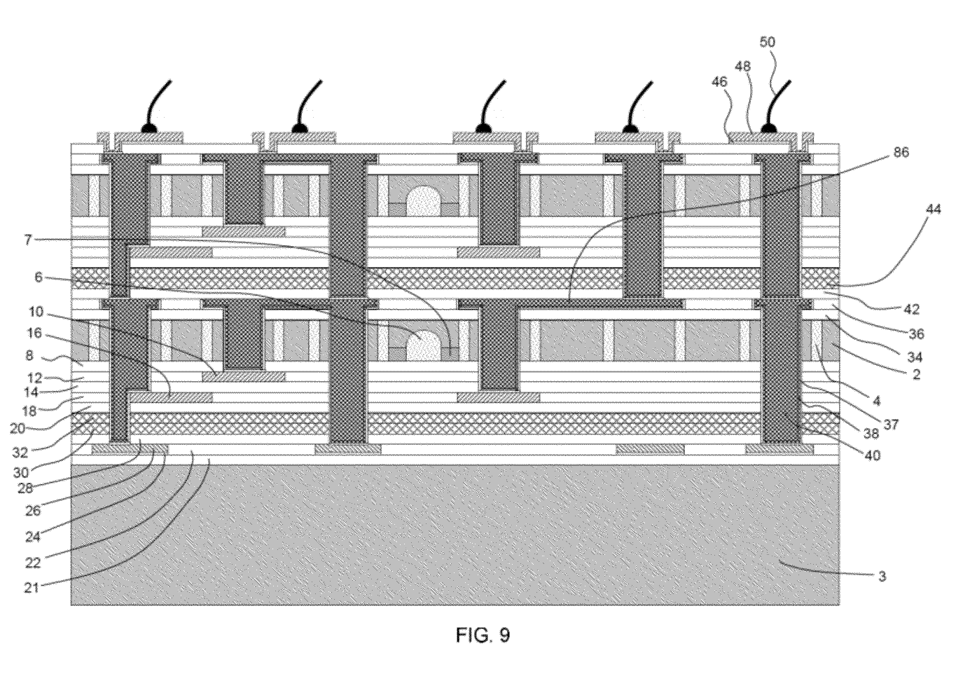

FIG. 9 illustrates a cross-sectional view of a multichip package according to an exemplary embodiment of the present disclosure. In addition to previously discussed elements and/or layers, the multichip package of FIG. 9 includes a substrate 3, and a dielectric layer 21.

The substrate 3 may include one or more of silicon, glass, ceramic, aluminum, copper, and/or organic polymer. The substrate 3 may have a thickness between 1 and 500 micrometers, between 1 and 100 micrometers, or between 1 and 500 micrometers. The substrate 3 may be a wafer. The dielectric layer 21 may one or more of include silicon dioxide (SiO₂), silicon nitride (Si₃N₄), silicon carbon-nitride, silicon oxynitride, polyimide, epoxy, benzocyclobutene (BCB), polybenzoxazole (PBO), Poly(p-phenylene oxide) (PPO), silosane, and/or SU-8. The dielectric layer 21 may be formed or deposited using a suitable process.

In contrast to the multichip package illustrated in FIG. 1, the multichip package illustrated in FIG. 9 does not include an active device in the supporting substrate 3.

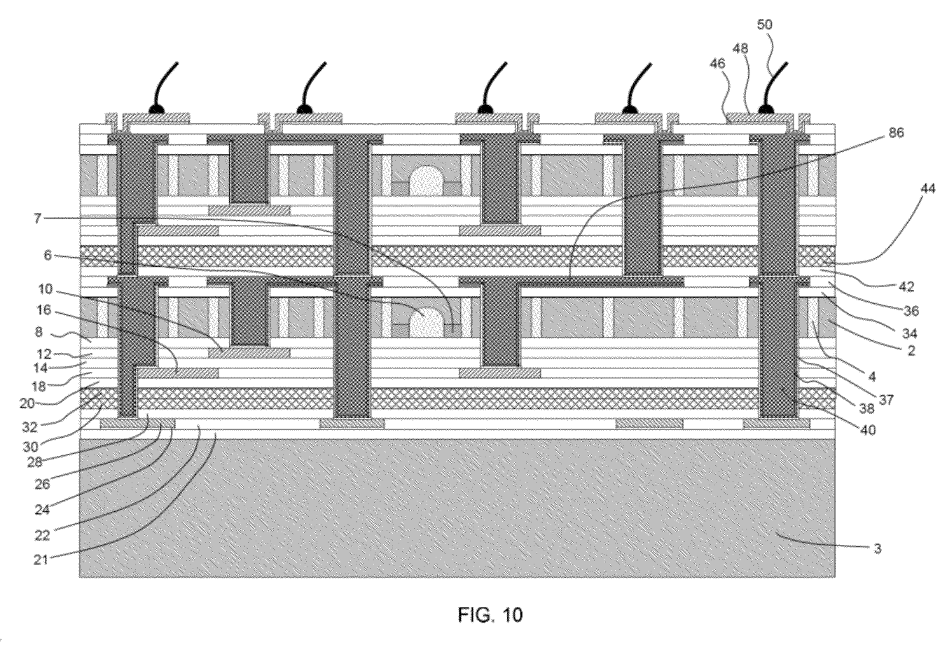

FIG. 10 illustrates a cross-sectional view of a multichip package according to an exemplary embodiment of the present disclosure. In contrast to the multichip package illustrated in FIG. 2, the multichip package illustrated in FIG. 10 does not include an active device in the supporting substrate 3.

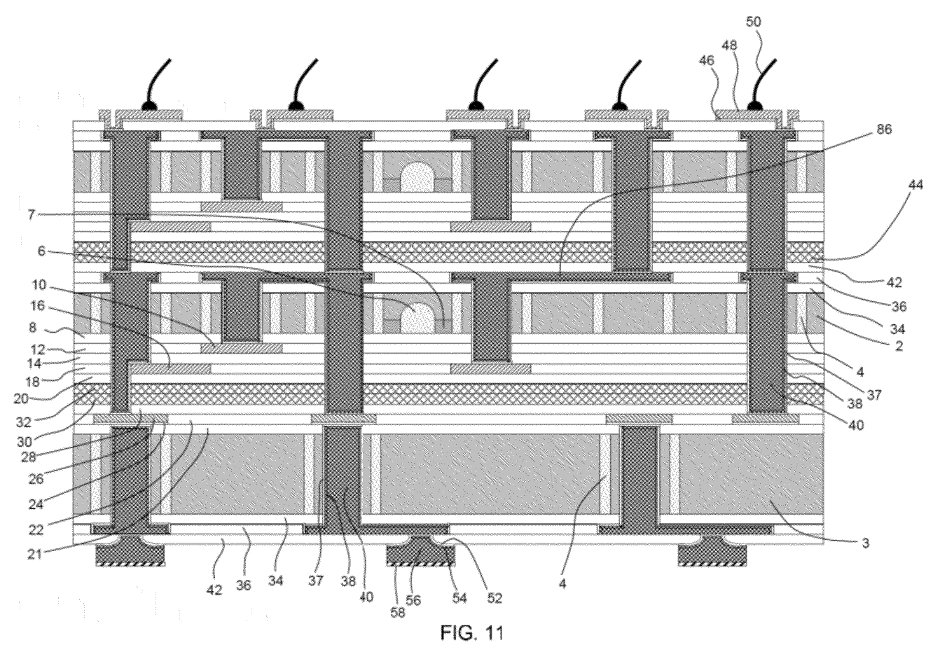

FIG. 11 illustrates a cross-sectional view of a multichip package according to an exemplary embodiment of the present disclosure. In contrast to the multichip package illustrated in FIG. 3, the multichip package illustrated in FIG. 11 does not include an active device in the supporting substrate 3.

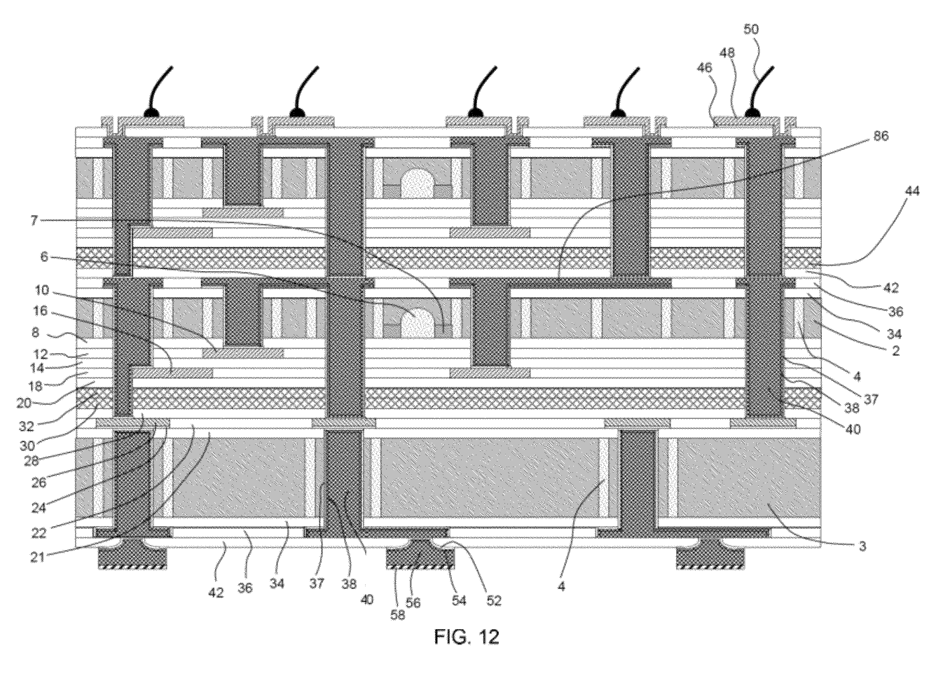

FIG. 12 illustrates a cross-sectional view of a multichip package according to an exemplary embodiment of the present disclosure. In contrast to the multichip package illustrated in FIG. 4, the multichip package illustrated in FIG. 12 does not include an active device in the supporting substrate 3.

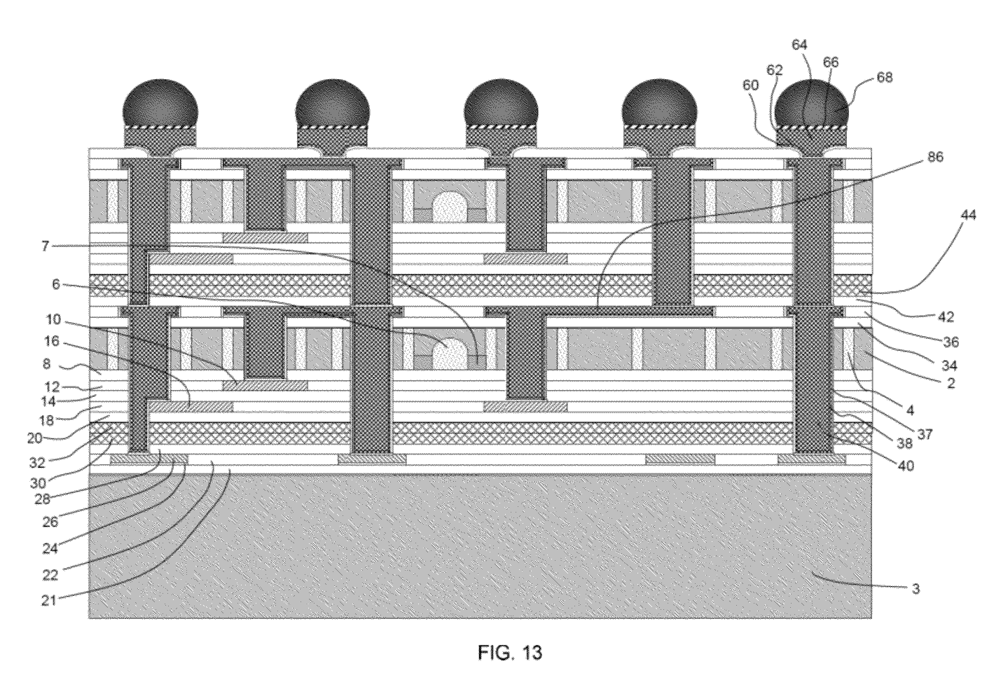

FIG. 13 illustrates a cross-sectional view of a multichip package according to an exemplary embodiment of the present disclosure. In contrast to the multichip package illustrated in FIG. 5, the multichip package illustrated in FIG. 13 does not include an active device in the supporting substrate 3.

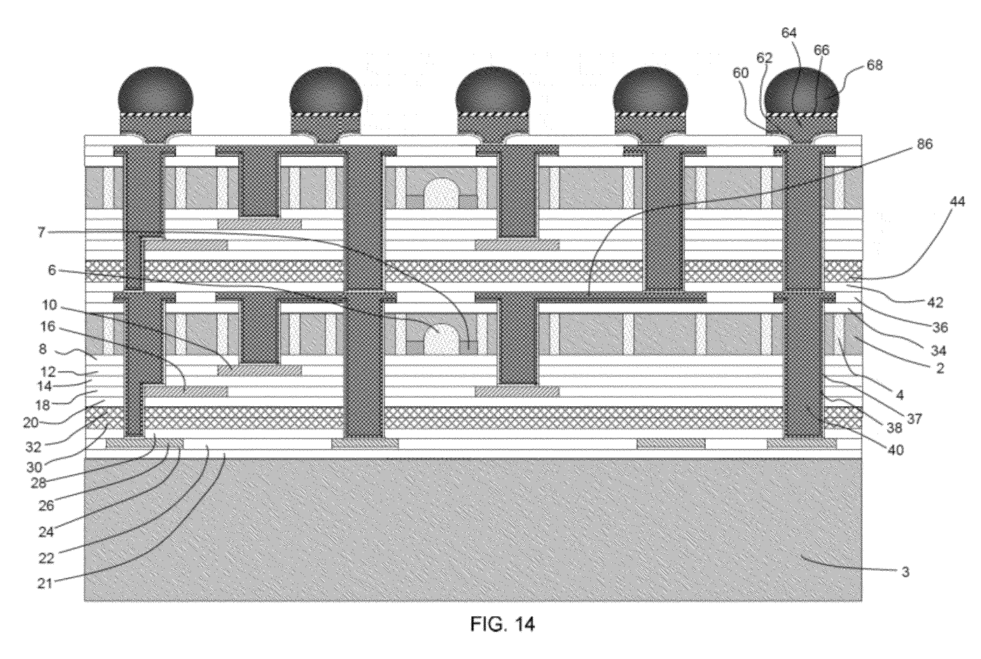

FIG. 14 illustrates a cross-sectional view of a multichip package according to an exemplary embodiment of the present disclosure. In contrast to the multichip package illustrated in FIG. 6, the multichip package illustrated in FIG. 14 does not include an active device in the supporting substrate 3.

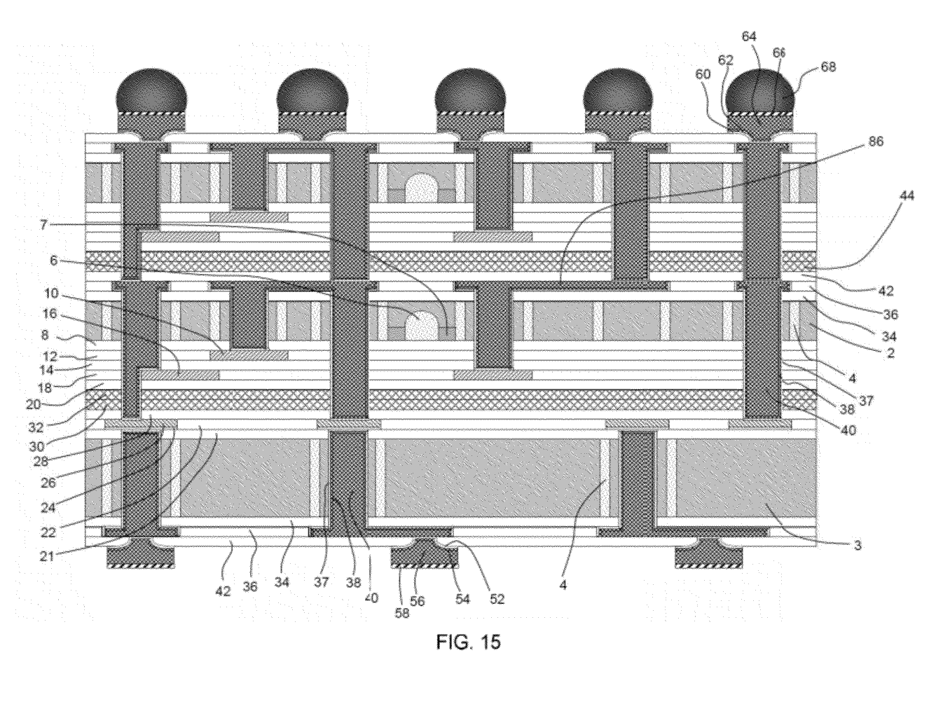

FIG. 15 illustrates a cross-sectional view of a multichip package according to an exemplary embodiment of the present disclosure. In contrast to the multichip package illustrated in FIG. 7, the multichip package illustrated in FIG. 15 does not include an active device in the supporting substrate 3.

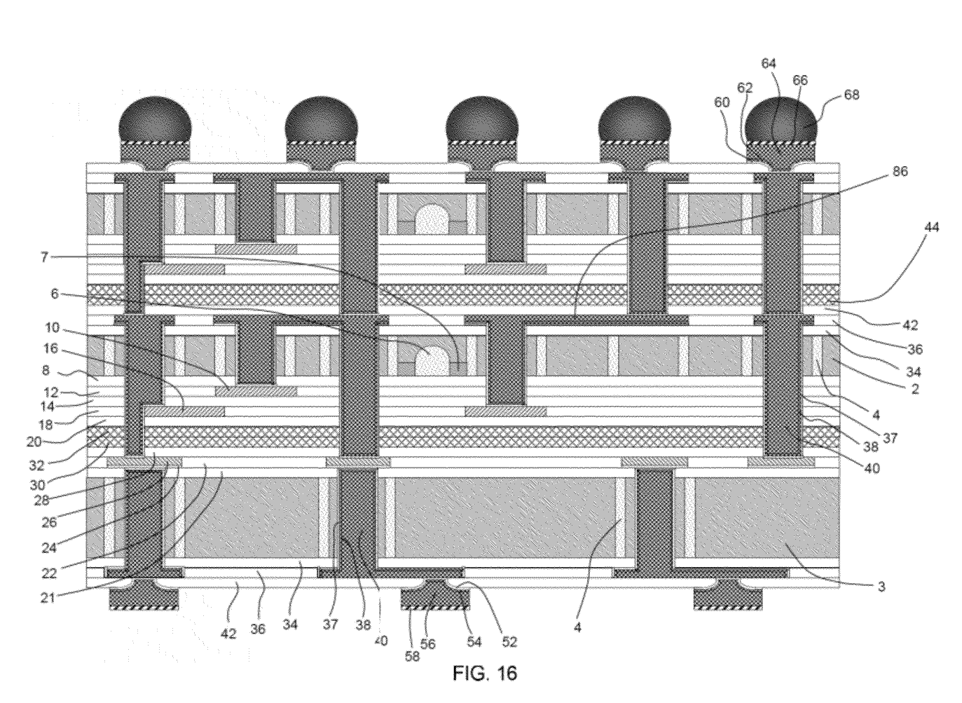

FIG. 16 illustrates a cross-sectional view of a multichip package according to an exemplary embodiment of the present disclosure. In contrast to the multichip package illustrated in FIG. 8, the multichip package illustrated in FIG. 16 does not include an active device in the supporting substrate 3.

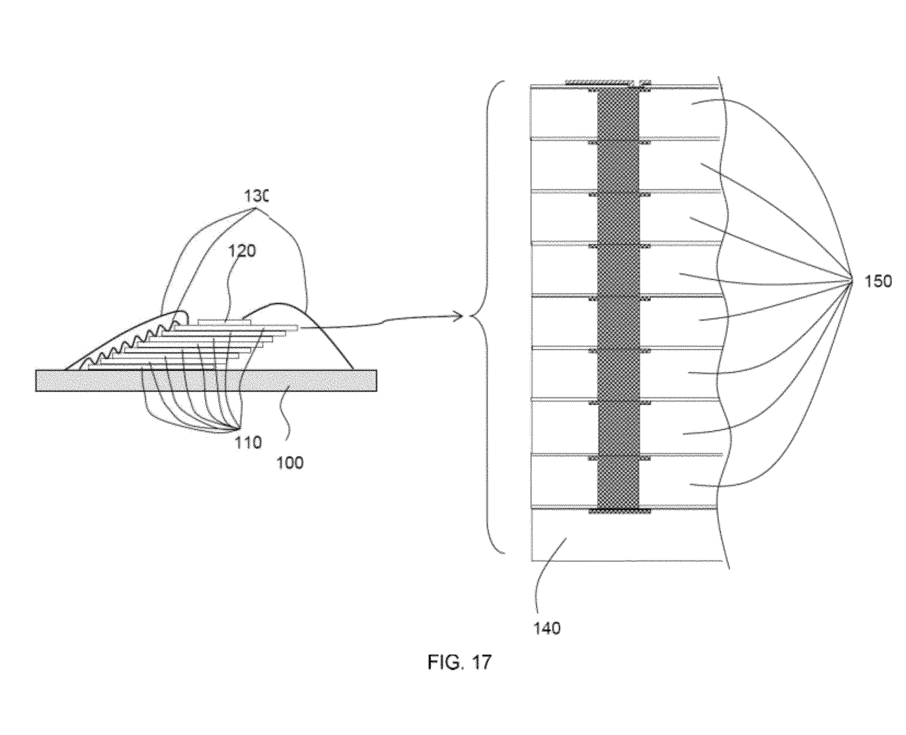

FIG. 17 illustrates a view of a multichip package according to an exemplary embodiment of the present disclosure. FIG. 17 includes a substrate 100, a set of memory dies or chips 110, an integrated circuit 120, a bonding wire 130, and a carrier substrate 140.

The substrate 100 may be a laminated substrate, a printed circuit board (PCB) substrate, and/or a ceramic substrate. The substrate 100 may include one or more of bismaleimide-triazine (BT) resin, FR-4, epoxy, and/or glass fiber. The substrate 100 may have a thickness between 0.1 and 2 mm. The substrate 100 may include copper traces and wire bondable pads. The set of memory dies or chips 110 may include 4, 8, 16, 32, or more dies. There may be through silicon/substrate via (TSV) in the set of memory dies 110. The TSVs may provide an input/output, signal, and/or power/ground connection to the memory dies or chips. The TSVs may be connected to any metal layer of a die or chip. The set of memory dies or chips 110 may include one or more of NAND-Flash, Nor-Flash, DRAM, Ferroelectric RAM (FeRAM), Magneto resistive RAM (MRAM), Phase-change memory (PRAM), EEPROM, EPROM and/or SRAM. The integrated circuit 120 may include one or more of a NAND Flash controller, a Nor Flash controller, a DRAM controller, a FeRAM controller, an MRAM controller, and/or a PRAM controller. The bonding wire 130 may include one or more of gold, copper, and/or aluminum. The carrier substrate 140 may be for TSV stacked dies.

FIG. 17 illustrates multiple stack chip units and a control chip. Each stack unit may include multiple chips with TSV interconnects.

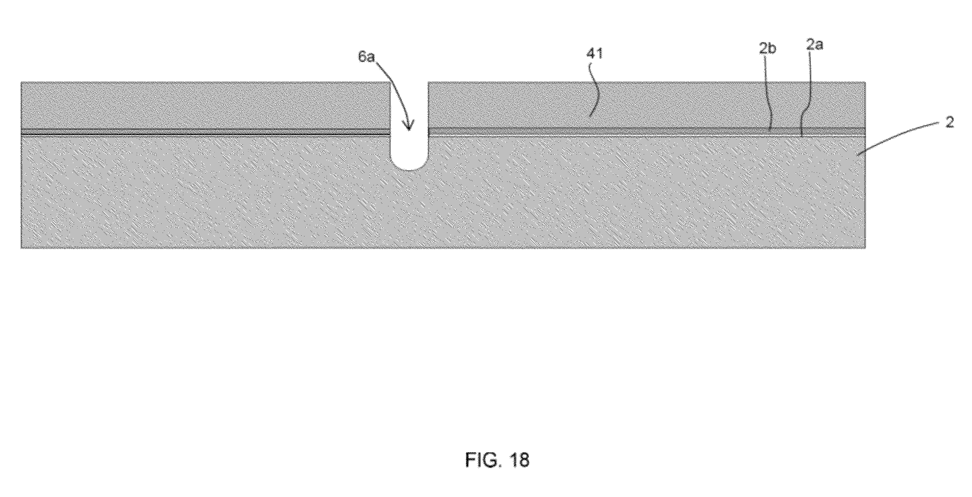

FIGS. 18-37 illustrate a process for forming a multichip package according to exemplary embodiments of the present disclosure, such as the multichip package illustrated in FIG. 9. FIGS. 18-22 illustrate a process for forming a deep-trench isolation (DTI) layer 4 and a shallow-trench isolation (STI) layer 6 in a semiconductor substrate 2, which can be applied to all embodiments of the present disclosure for forming the same.

Referring to FIG. 18, a process of forming multiple shallow trenches 6a (one of which is shown) is illustrated. A pad oxide layer 2a having a suitable thickness, such as between 1 and 20 nanometers, is formed on a semiconductor substrate 2 in a wafer level, using a suitable process. Then a silicon nitride layer 2b having a suitable thickness, such as between 10 and 200 nanometers, is formed on the pad oxide layer 2a, using a suitable process. The silicon nitride layer 2b is coated with a photoresist layer 41, such as by spin coating. The photoresist layer 41 may be patterned using lithographic technology of mask exposure and development. The photoresist layer 41 may be used to define the shallow trenches 6a. The shallow trenches 6a are formed by removing the exposed silicon nitride 2b and pad oxide 2a by a suitable process, such as by using reactive ion dry etching and etching silicon using reactive ion dry etching. The shallow trenches 6a may have a suitable depth, such as between 0.02 and 1 micrometer or between 0.05 and 0.5 micrometers.

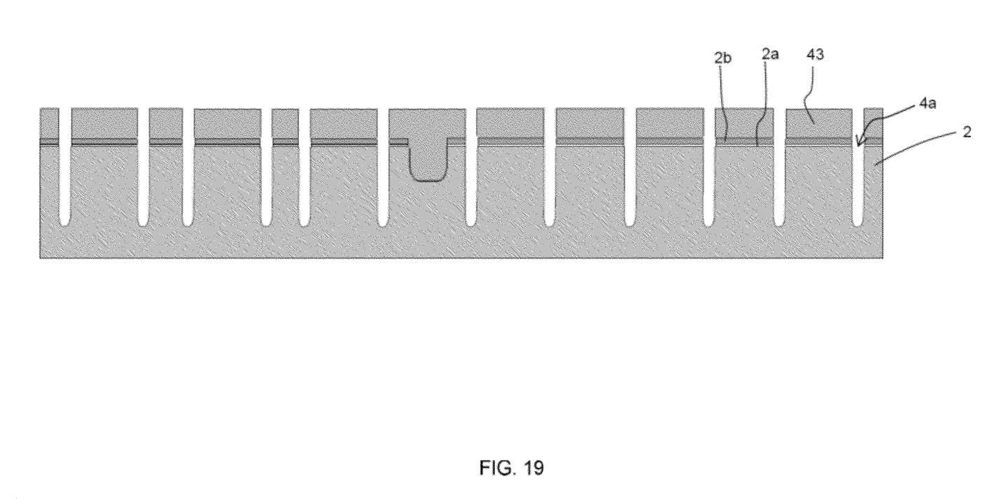

Next, referring to FIG. 19, a process of forming multiple deep trenches 4a is illustrated. The photoresist layer 41 of FIG. 18 is removed by using a wet chemical, such as hydrogen peroxide (H₂O₂) and/or sulfuric acid (H₂SO₄) and/or oxygen (O₂) plasma ashing. A photoresist layer 43 is then coated on the silicon nitride layer 2b, such as by using spin coating. The photoresist layer 43 may be patterned using lithographic technology of mask exposure and development. The photoresist layer 43 may be used to define the deep trenches 4a. The deep trenches 4a are formed by removing the exposed silicon nitride 2b and pad oxide 2a by a suitable process, such as by using reactive ion dry etching and etching silicon using reactive ion dry etching.

The deep trenches 4a may have a suitable width, such as between 0.1 and 20 micrometers, between 0.1 and 10 micrometers, between 0.1 and 5 micrometers, between 0.1 and 2 micrometers, or between 0.1 and 1 micrometers. The deep trenches 4a may have a suitable depth, such as between 1 and 100 micrometers, between 1 and 50 micrometers, between 1 and 20 micrometers, between 1 and 10 micrometers, between 1 and 5 micrometers, or between 2 and 5 micrometers.

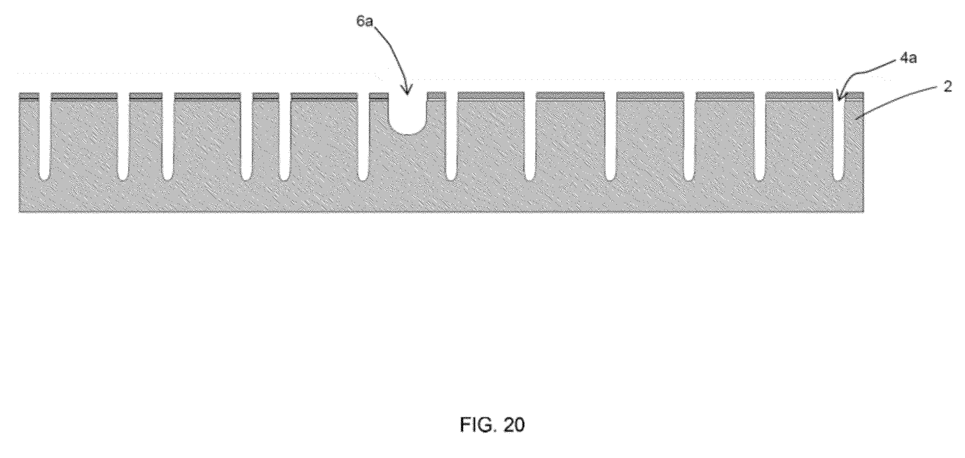

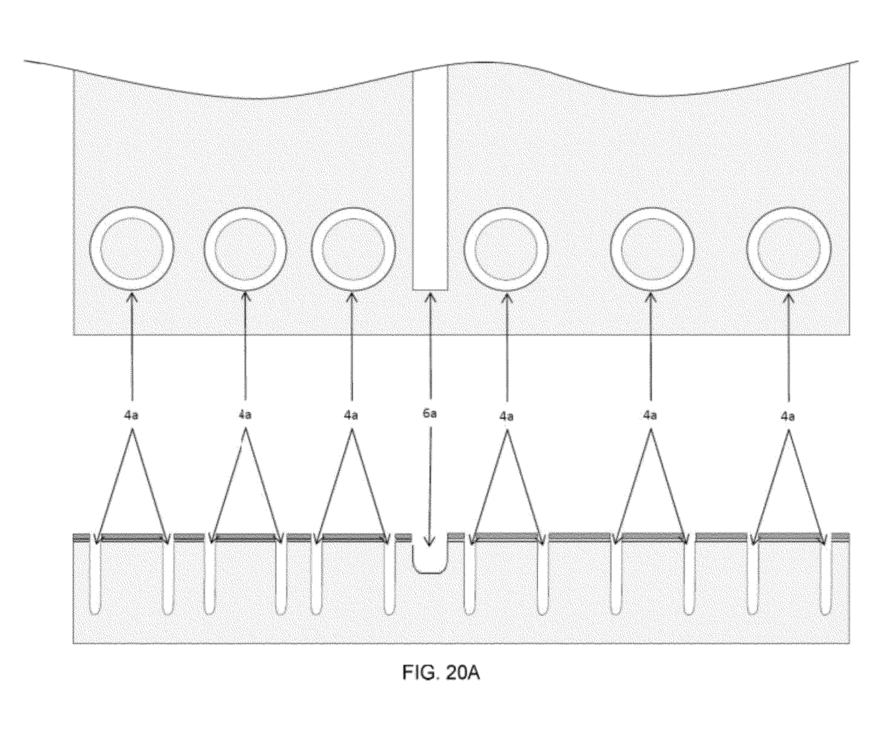

FIG. 20 illustrates a cross section view of the shallow trenches 6a and the deep trenches 4a, after removing the photoresist layer 43 of FIG. 19 by using a wet chemical, such as hydrogen peroxide (H₂O₂) and/or sulfuric acid (H₂SO₄) and/or oxygen (O₂) plasma ashing.

FIG. 20A illustrates a top view of the semiconductor substrate 2 with the shallow trenches 6a and the deep trenches 4a. FIG. 20A illustrates the locations of the deep trenches 4a and shallow trenches 6a in both the top view relative to the cross-sectional view of FIG. 20.

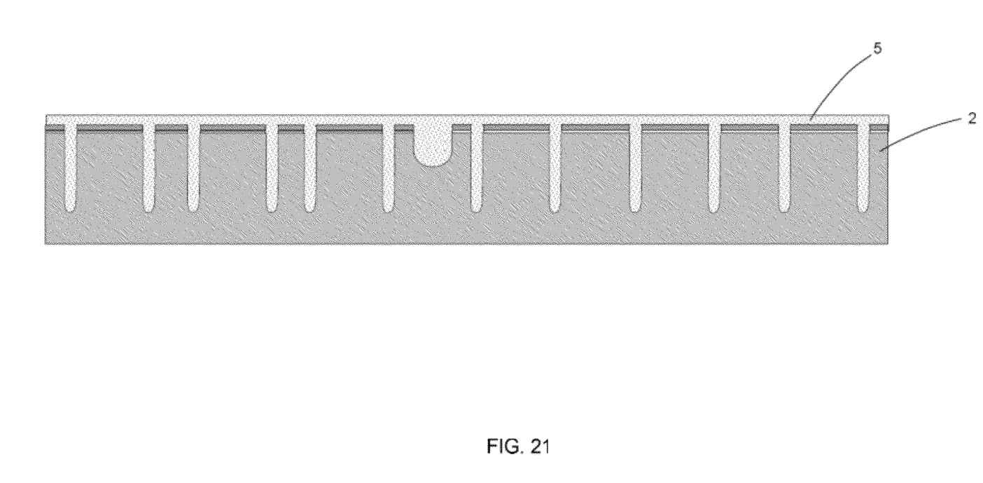

Next, referring to FIG. 21, a process of oxide refilling the shallow trenches 6a and the deep trenches 4a is illustrated. A lining oxide (not shown) is formed on the sidewalls of the shallow trenches 6a and the deep trenches 4a using a suitable process. The lining oxide may have a suitable thickness, such as between 1 and 20 nanometers. A lining silicon nitride (not shown) may be deposited using a suitable process. Alternatively, the lining silicon nitride may be optional. The silicon nitride may have a suitable thickness, such as between 2 and 100 nanometers. The refilling dielectric layer 5 may be deposited, using a suitable process. The refilling dielectric layer 5 may be silicon oxide or a combination of silicon nitride and silicon oxide. The refilling dielectric layer 5 may have a suitable thickness, such as between 0.2 and 5 micrometers or between 0.5 and 2 micrometers.

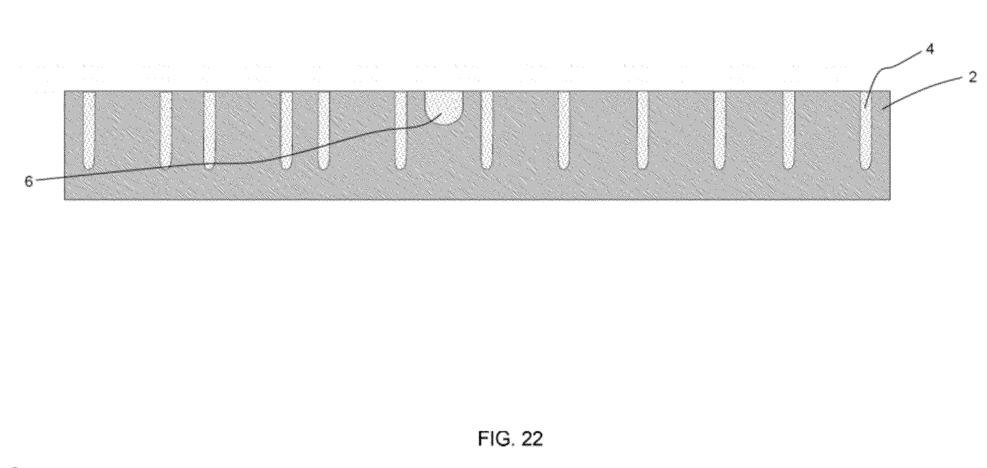

Next, referring to FIG. 22, a cross section view of the semiconductor substrate 2 is illustrated after a chemical-mechanical planarization (CMP) process has been performed, and after the silicon nitride 2b has been removed. The CMP process may remove excess oxide and planarize the surface of the semiconductor substrate 2. The silicon nitride 2b may be removed using a wet chemical such as hydrogen peroxide (H₂O₂) and phosphoric acid (H₃PO₄). The pad oxide 2a may be removed using a wet chemical containing hydrogen fluoride (HF).

The deep trench isolation layer 4 may be used for a through substrate via. The deep trench isolation layer 4 may include one or more of silicon oxide and/or silicon nitride. The deep trench isolation layer 4 may have a suitable width, such as between 0.1 and 20 micrometers, between 0.1 and 10 micrometers, between 0.1 and 5 micrometers, between 0.1 and 2 micrometers, or between 0.1 and 1 micrometers. The shallow trench isolation (STI) layer 6 may include one or more of silicon oxide and/or silicon nitride. The STI layer 6 may have a suitable depth, such as between 0.02 and 1 micrometers, or between 0.05 and 0.5 micrometers. The STI layer 6 may have a suitable width, such as between 0.02 and 100 micrometers or between 0.05 and 10 micrometers.

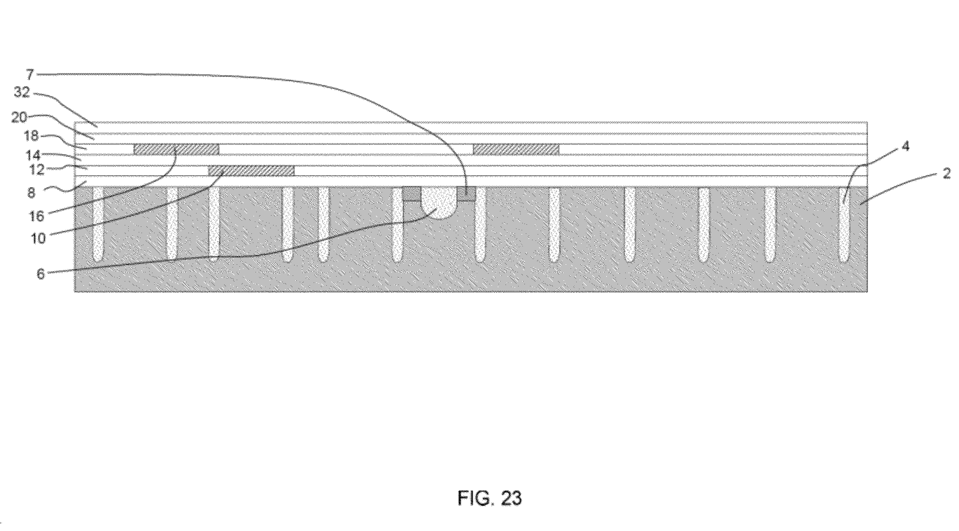

Next, referring to FIG. 23, a cross section view of the wafer substrate 2 is illustrated where the IC devices 7, a metal contact (not shown), the conductive layers 10 and 16, the dielectric layers 8, 12, 14 and 18, metal vias (not shown), the passivation layer 20, and adhesive dielectric layer 32 are formed using suitable processes. The IC devices 7 may include one or more of an N-type metal-oxide-semiconductor (NMOS) transistor, a P-type metal-oxide-semiconductor (PMOS) transistor, an NPN transistor, a PNP transistor, and/or a diode. The dielectric layer 8 may be formed using a suitable process, such as by depositing. The conductive layers 10, 16 may be formed by a suitable process, such as an electroplating process. The dielectric layers 12, 14, 18 may be formed using a suitable process, such as depositing. The passivation layer 20 may be formed by a suitable process, such as depositing. The adhesive dielectric layer 32 may include silicon oxide which may be activated by plasma treatment. The finished semiconductor wafer 2 may include multiple semiconductor chips or dies.

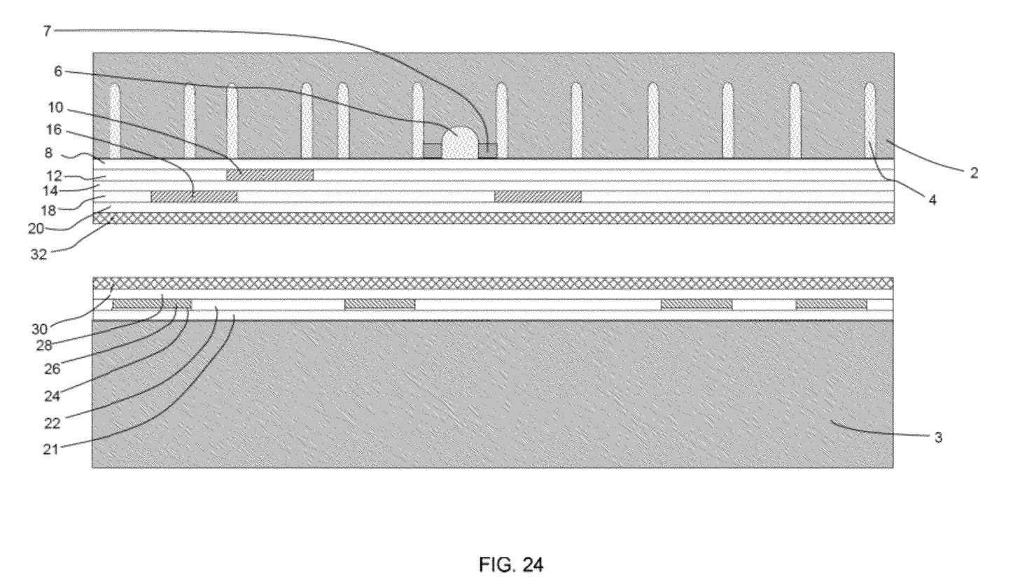

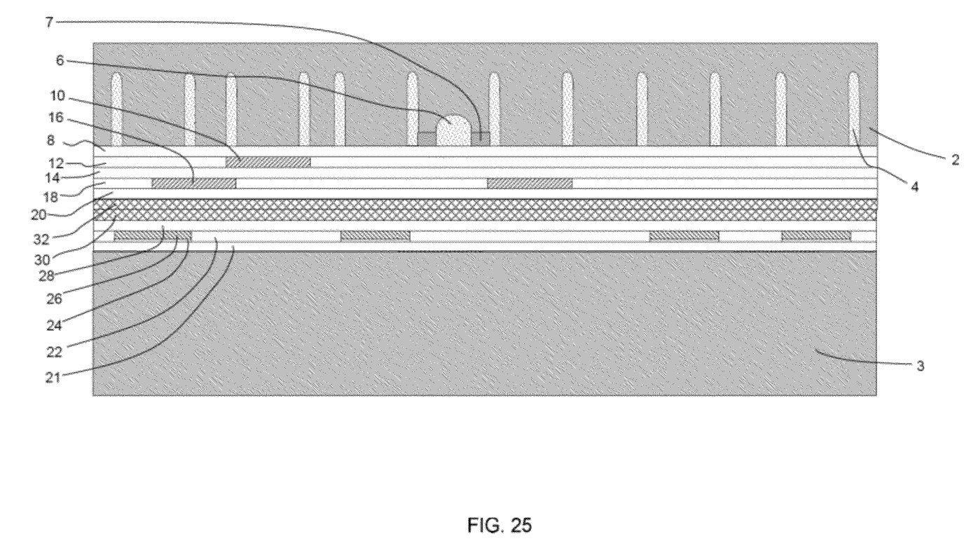

Next, referring to FIG. 24 and FIG. 25, a process of bonding two together two wafers by thermal compress is illustrated. For example, the wafer 2 from FIG. 23 may be inverted and bonded to wafer 3. Adhesive dielectrics 30, 32 may be used as bonding interface layers. The materials of the adhesive dielectrics 30, 32 may include oxide on oxide, polyimide on polyimide, polyimide on silicon nitride, polyimide on oxide, silicon nitride on polyimide, oxide on polyimide, epoxy on silicon nitride, epoxy on oxide, silicon nitride on epoxy, BCB on BCB, epoxy on epoxy, silicon oxynitride on silicon oxynitride, oxide on silicon oxynitride, and/or silicon oxynitride on oxide. Alternatively or in addition, adhesive dielectric 32 may include a passivation layer.

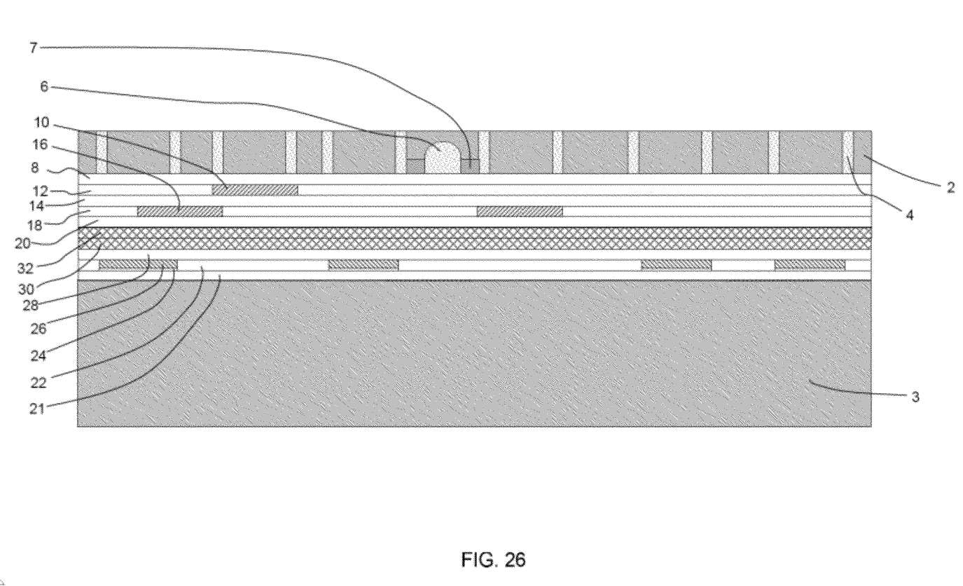

Next, referring to FIG. 26, a wafer thinning process is illustrated. The upper wafer (substrate 2) may be thinned from the backside (the side opposite to the active device site) to expose the deep trench isolation layer 4. The thinning process may be performed by mechanical grinding, polishing, chemical-mechanical-polishing, plasmas dry etching, chemical wet etching and/or a combination thereof. After the wafer thinning process, substrate 2 may have a thickness between 1 and 100 micrometers, between 1 and 50 micrometers, between 1 and 20 micrometers, or between 1 and 10 micrometers.

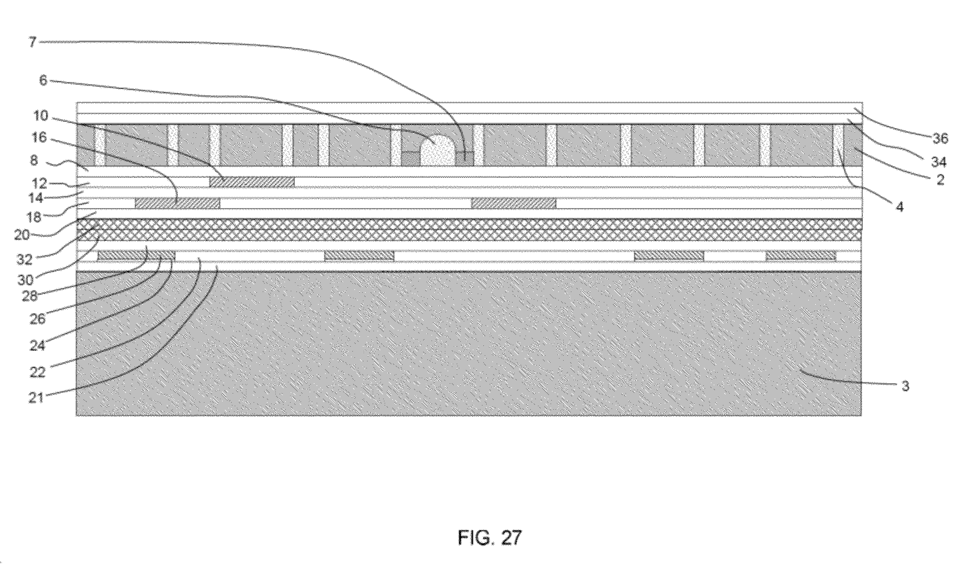

Next, referring to FIG. 27, a process of depositing backside dielectric layers 34, 36 on substrate 2 is illustrated. As previously discussed, the dielectric layers 34, 36 may include one or more of silicon dioxide (SiO₂), silicon nitride (Si₃N₄), silicon carbon-nitride, silicon oxynitride, polyimide, epoxy, and/or polybenzoxazole (PBO). The dielectric layers 34, 36 may be deposited using a suitable process, such as chemical vapor deposition (CVD), spin-coating, screen printing and/or lamination.

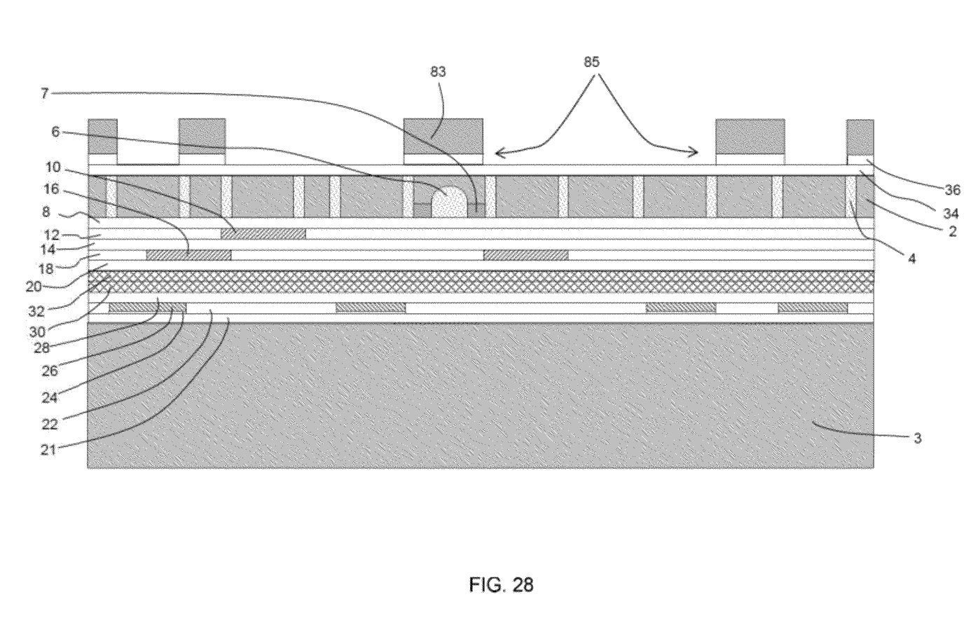

Next, referring to FIG. 28, one or more openings 85 in the backside dielectric layer 36 are formed, such as for metal interconnect trace formed by a damascene process. For example, a photo resist layer 83 may be formed on top of backside dielectric layer 36 using a suitable process, such as spin coating. The photo resist layer 83 may be patterned using lithographic technology of mask exposure and development. The one or more openings 85 in the backside dielectric layer 36 may be formed using reactive ion dry etching. The etching may stop on backside dielectric layer 34, such that the backside dielectric layer 34 is not etched. The photo resist layer 83 may be removed after the formation of opening 85.

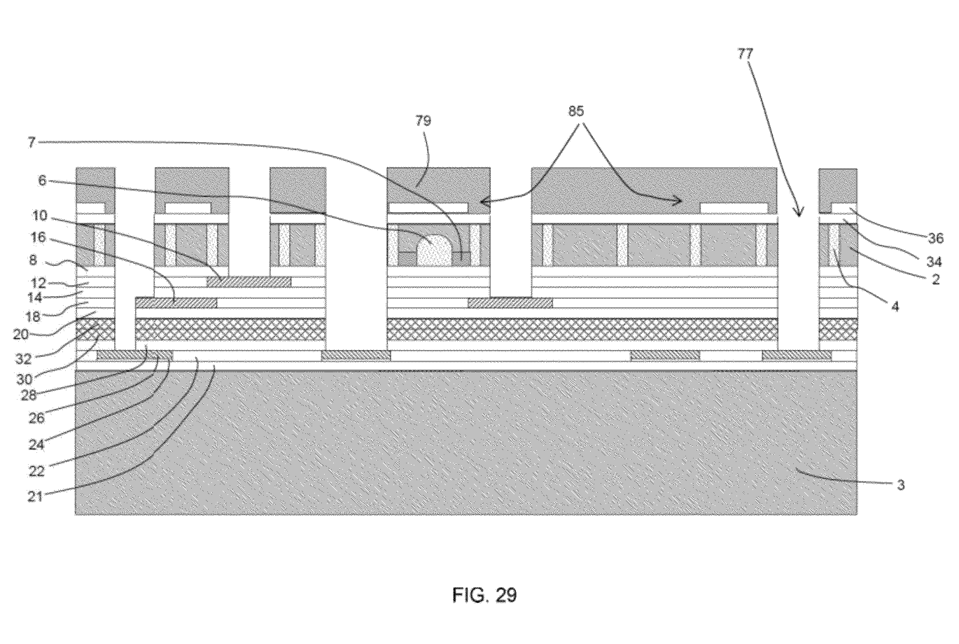

Next, referring to FIG. 29, one or more through vias 77 are formed. For example, a photo resist layer 79 may be coated on the backside dielectric layers 34, 36 using a suitable process, such as spin coating. The photo resist layer 79 may be patterned using lithographic technology of mask exposure and development. The through via 77 may be formed using reactive ion dry etching. The reactive ion dry etching may stop at a metal pad, such as the metal pad formed by the post passivation conduction layer 26. The photo resist layer 79 may be removed (process not shown on the FIG.) after the forming the one or more through vias 77.

Through via 77 may have a suitable width and/or diameter, such as between 0.5 and 100 micrometers, between 0.5 and 50 micrometers, between 0.5 and 30 micrometers, between 0.5 and 20 micrometers, between 0.5 and 10 micrometers, between 0.5 and 5 micrometers, or between 1 and 3 micrometers. The through via 77 may have a suitable pitch (width plus space), such as between 1 and 300 micrometers, between 1 and 200 micrometers, between 1 and 100 micrometers, between 1 and 60 micrometers, between 1 and 40 micrometers, between 1 and 20 micrometers, between 1 and 10 micrometers, and/or between 2 and 6 micrometers.

The photo resist layer 79 may be a through-hole photo resist. The photo resist layer 79 may include positive or negative type resist. The photo resist layer 79 may be deposited by spin coating, screen printing, or laminated, and may be defined by litho-exposure and development. The thickness of the photo resist layer 79 may be between 3 and 50 micrometers.

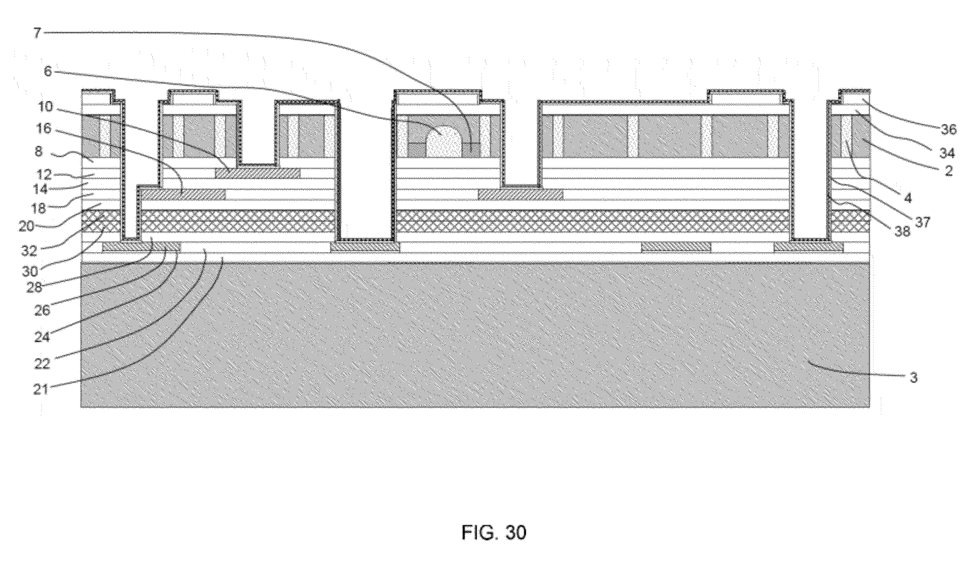

Next, referring to FIG. 30, the adhesion/barrier layer 37 and seed layer 38 are formed. The adhesion/barrier layer and/or the seed layer 38 may be deposited using a suitable process, such as physical vapor deposition (PVD) or chemical vapor deposition (CVD). The PVD technology may include sputtering and/or evaporation.

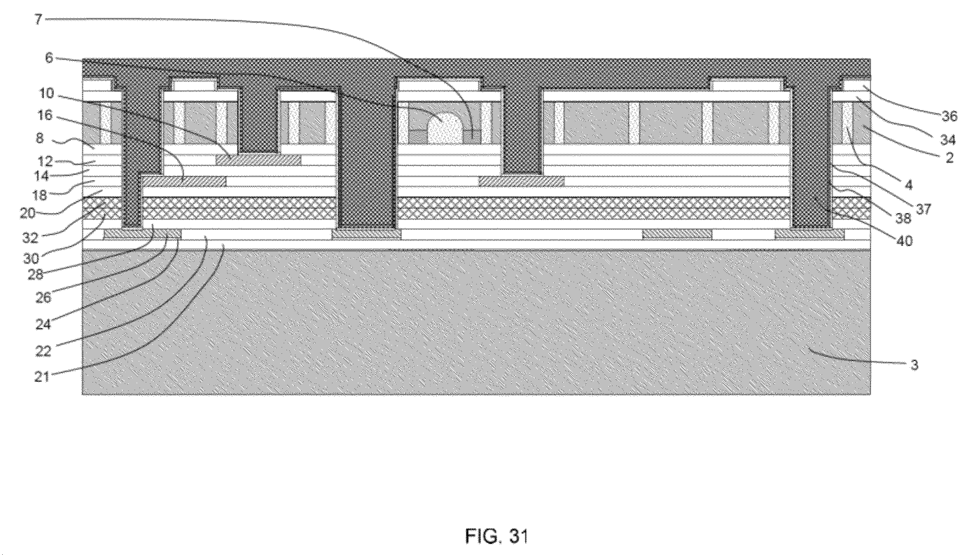

Next, referring to FIG. 31, conduction layer 40 is formed. The conduction layer 40 may be deposited using a suitable process, such as electroplating, electroless plating, or CVD. The conduction layer 40 may fill the etched openings of the one or more through silicon vias 77 and the opening 85.

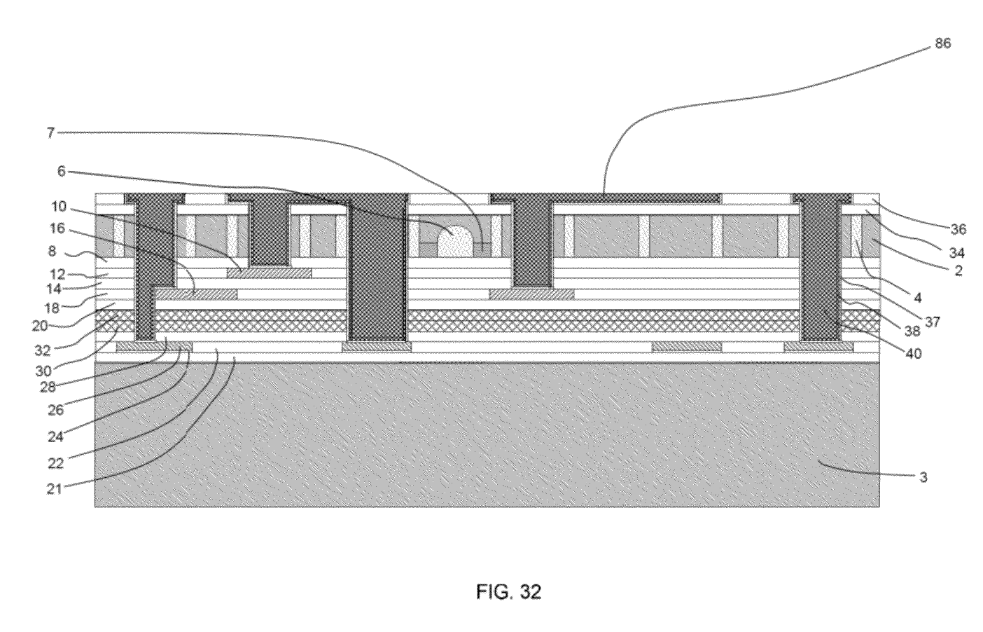

Next, referring to FIG. 32, the undesired portion of conduction layer 40 is removed, such as the portion of the conduction layer 40 that extends beyond the top of the backside dielectric layer 36. The undesired portion of conduction layer 40 may be removed using a chemical-mechanical-polish.

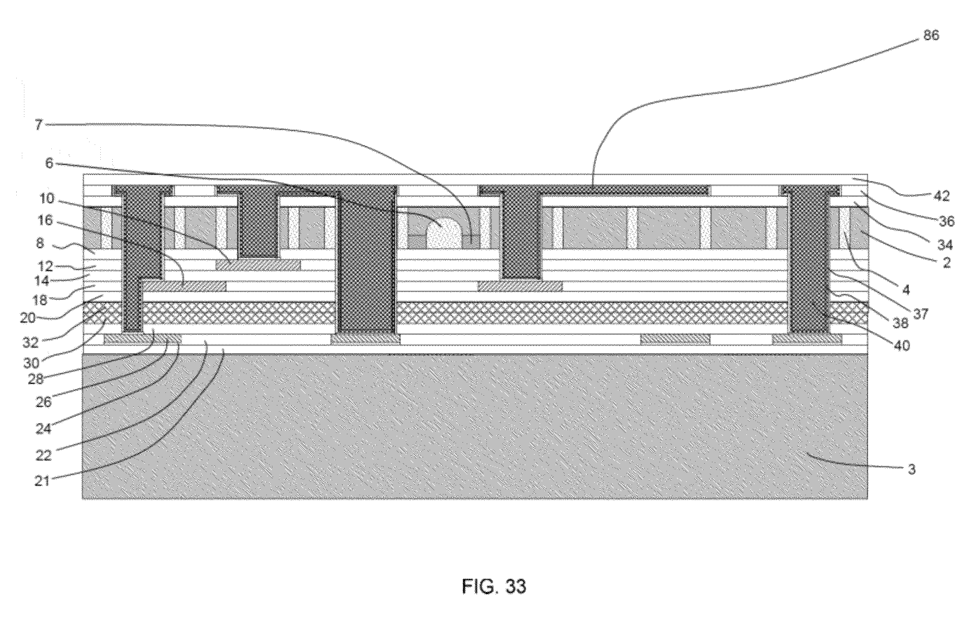

Next, referring to FIG. 33, dielectric layer 42 is formed. The dielectric layer 42 may include one or more of silicon dioxide (SiO₂), silicon nitride (Si₃N₄), silicon carbon-nitride, silicon oxynitride, polyimide, epoxy, PBO, and/or BCB. The dielectric layer 42 may be deposited using a suitable process, such as CVD, spin-coating, lamination or screen printing.

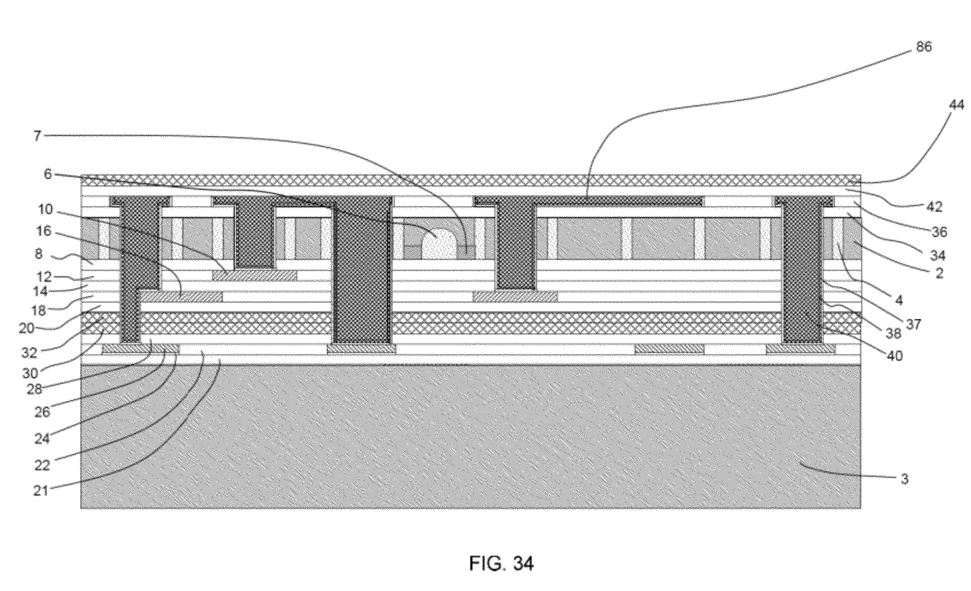

Next, referring to FIG. 34, adhesive dielectric layer 44 is formed or deposited using a suitable process. As previously discussed, the adhesive dielectric layer 44 may include one or more of activated silicon oxide, activated silicon oxynitride, activated silicon nitride, BCB, polyimide, epoxy and/or PBO. The adhesive dielectric layer may be deposited by using a suitable process, such as CVD, spin-coating, lamination or screen printing. For example, the material of dielectric layer 44 may be activated silicon oxide where the silicon oxide is activated by plasma treatment.

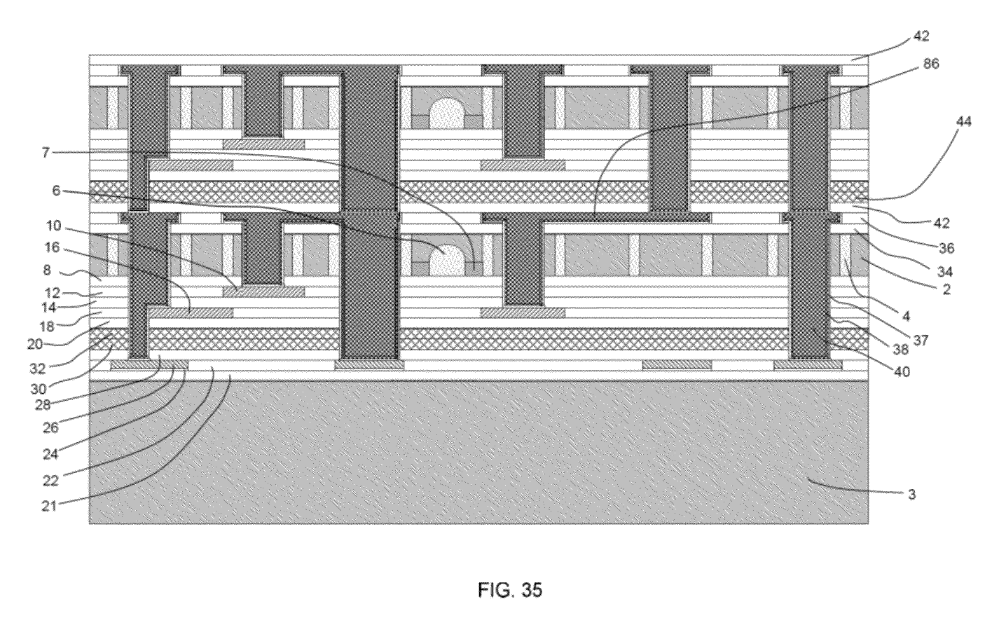

Next, referring to FIG. 35, the process illustrated in FIGS. 24-32 is repeated to bond an additional semiconductor wafer. The additional semiconductor wafer may include multiple semiconductor chips or dies. The process illustrated in FIGS. 24-32 may be repeated any number of times to continue to add additional wafers.

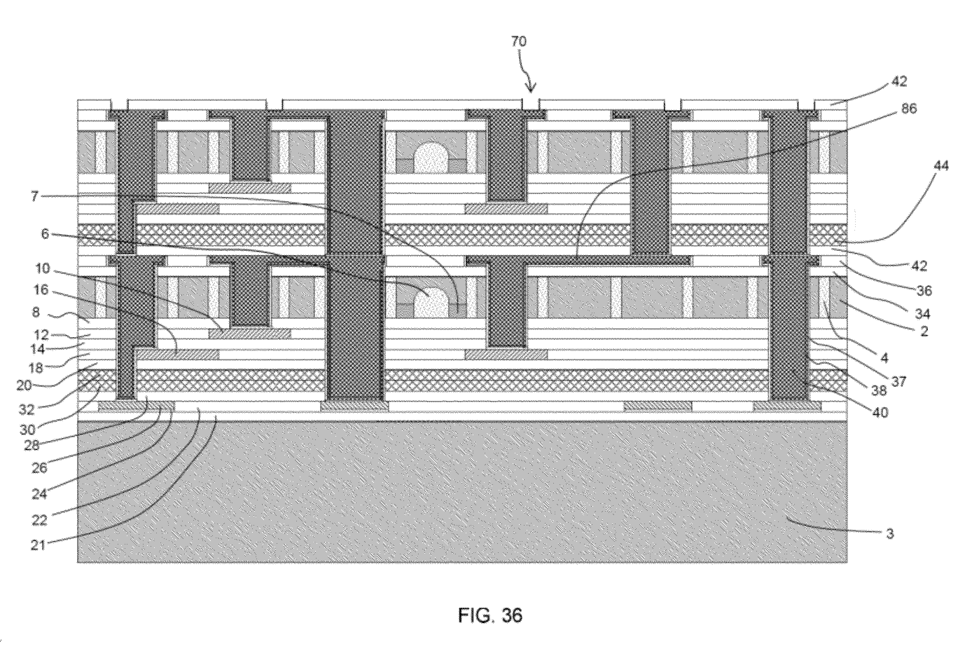

Next, referring to FIG. 36, one or more openings 70 are formed in the top dielectric layer 42. The opening 70 may be formed using an IC process of lithographic and etching.

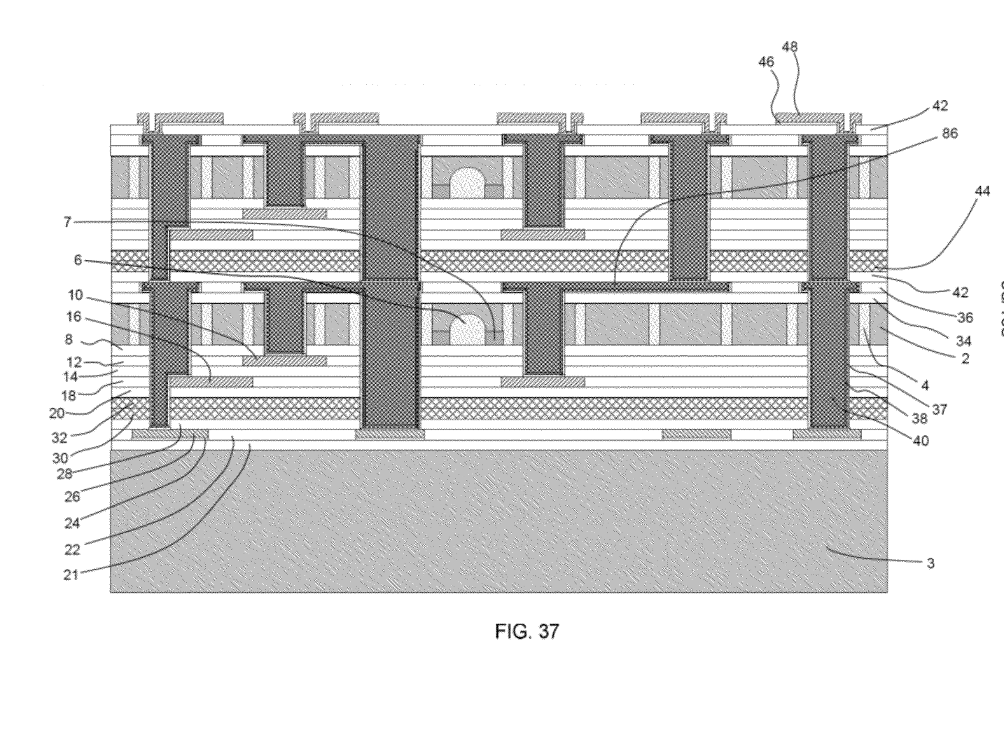

Next, referring to FIG. 37, the wire bondable conduction layer 48 is formed on top of dielectric layer 42. The conduction layer 48 may be formed using a suitable IC process, such as sputtering, lithographic and etching process when the conduction layer 48 includes a suitable alloy, such as aluminum alloy. Alternatively or in addition, the conduction layer 48 may be formed using a suitable IC process, such as sputtering, lithographic and electroplating, when the conduction layer 48 includes nickel/gold (Ni/Au) or nickel/palladium (Ni/Pd).

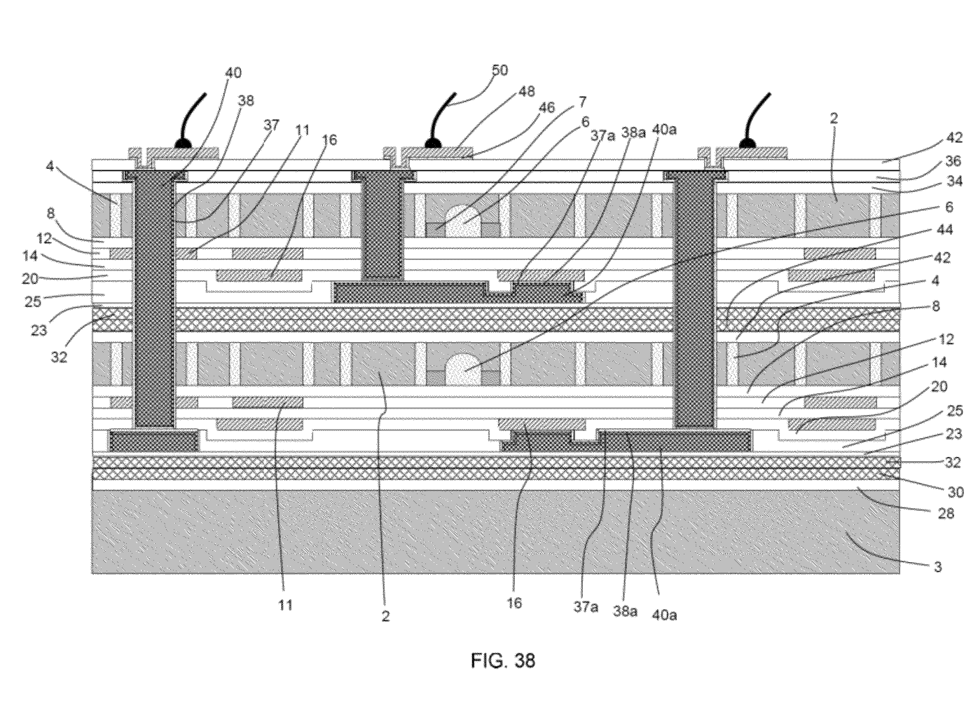

FIG. 38 illustrates a cross-sectional view of a multichip package according to an exemplary embodiment of the present disclosure. In addition to previously discussed elements and/or layers, the multichip package of FIG. 38 includes the interconnection layer 11, the dielectric layer 23, the dielectric layer 25, the adhesion/barrier layer 37a, the seed layer 38a, and the conduction layer 40a.

The interconnection layer 11 of an IC chip may be etched through by dry etching. The material of the interconnection layer may include one or more of aluminum-copper (Al—Cu), tungsten, copper, carbon nanotubes, and/or adhesion/barrier metal, such as titanium (Ti), titanium nitride (TiN), tantalum (Ta), tantalum nitride (TaN), and/or Titanium-Tungsten (TiW). The interconnection layer 11 may have a suitable thickness, such as between 10 nanometers and 2 micrometers. The dielectric layer 23 may provide protection for the passivation metal layer. The dielectric layer 23 may include one or more of silicon dioxide (SiO₂), silicon nitride (Si₃N₄), silicon carbon-nitride, silicon oxynitride, and/or silicon carbon oxynitride (Si—C—O—N). The dielectric layer 23 may have a suitable thickness, such as between 10 nanometers and 1 micron. The dielectric layer 25 may provide insulation of post passivation metal line or trace. The dielectric layer 25 may include one or more of silicon dioxide (SiO₂), silicon nitride (Si₃N₄), silicon carbon-nitride, silicon oxynitride, silicon carbon oxynitride, polyimide, epoxy, benzocyclobutene (BCB), polybenzoxazole (PBO), PPO, silosane, and/or SU-8. The dielectric layer 25 may have a thickness between 1 and 15 micrometers. The dielectric layers 23, 25 may be formed or deposited using a suitable process.

The adhesion/barrier layer 37a may include one or more of titanium (Ti), titanium nitride (TiN), titanium tungsten (TiW), tantalum (Ta), tantalum nitride (TaN), chromium (Cr), nickel (Ni), and/or nickel vanadium (Ni—V). The adhesion/barrier layer 37a may have a suitable thickness, such as between 1 nanometer and 0.5 micrometers. The seed layer 38a may include one or more of copper, gold, and/or silver. The seed layer 38a may have a suitable thickness, such as between 1 nanometer and 0.05 micrometers. The conduction layer 40a may provide interconnection or pad relocation. The conduction layer 40a may include one or more of copper, silver, aluminum, and/or gold. For example, the conduction layer 40a comprises a copper layer, an aluminum layer, or a gold layer. The conduction layer 40a may have a suitable thickness, such as between 0.1 and 20 micrometers, between 0.1 and 10 micrometers, between 0.1 and 5 micrometers, between 0.1 and 1 micrometers, or between 1 and 5 micrometers. The adhesion barrier layer 37a, seed layer 38a, and conduction layer 40a may be formed or deposited using a suitable process.

The stacked integrated circuit chips of FIG. 38 may have the same die size. Alternatively, the die sizes of the IC chips may vary. The stacked IC chips may be memory chips, such as NAND flash memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin. The multichip package may include damascene metal traces and/or embossing metal traces. The multichip package may also include bonding wire for leading out to input/output, signal, and/or power/ground pin. The multichip package may include a through silicon/substrate via (TSV) direct through two or more of the stacked IC chips.

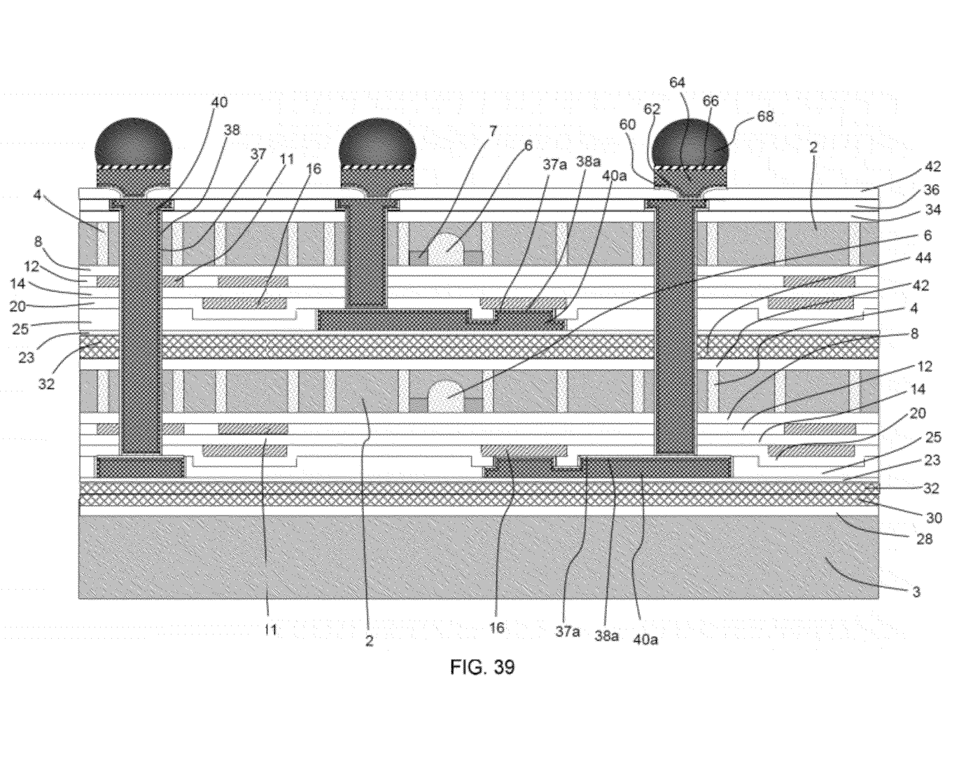

FIG. 39 illustrates a cross-sectional view of a multichip package according to an exemplary embodiment of the present disclosure. The stacked integrated circuit chips of FIG. 39 may have the same die size. Alternatively, the die sizes of the IC chips may vary. The stacked IC chips may be memory chips, such as NAND flash memory, Flash memory, DRAM, and/or SRAM. The quantity of the stacked memory chips may be any suitable quantity, such as 4, 8, 16, or more. The stacked die may have a suitable thickness, such as between 1 and 100 micrometers, between 1 and 50 micrometers, between 1 and 20 micrometers, or between 1 and 10 micrometers. Through silicon/substrate vias (TSVs) may provide an input/output, signal, and/or power/ground connection to the stacked chips. The TSVs may be connected to any metal layer of an IC chip. In one example, there may be butted connect of TSV. The multichip package may include metal traces which lead out to an independent signal pin. The independent signal may be a chip-enable pin. The multichip package may include damascene metal traces and/or embossing metal traces. The multichip package may also include bonding wire for leading out to input/output, signal, and/or power/ground pin. The multichip package may include a through silicon/substrate via (TSV) direct through two or more of the stacked IC chips.

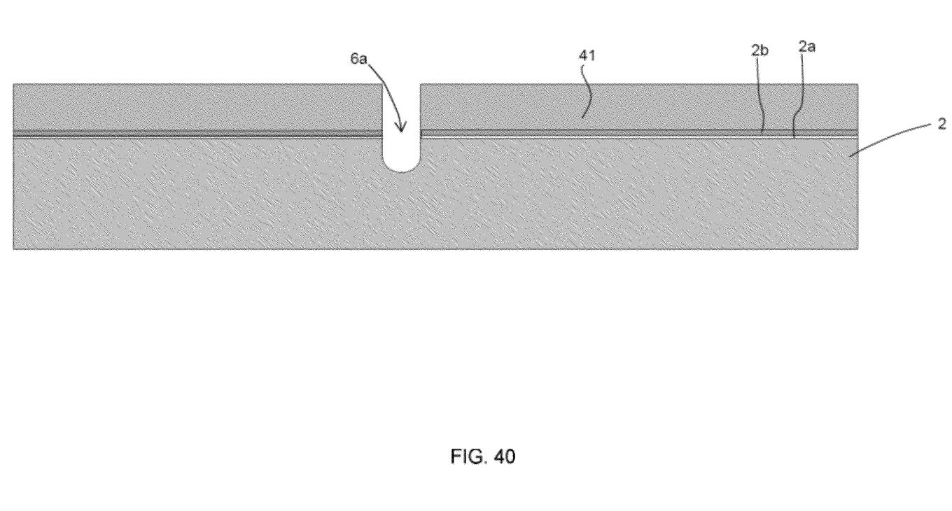

FIGS. 40-65 illustrate a process for forming the multichip package illustrated in FIG. 38. Variations of the process illustrated in FIGS. 40-65 may be used to form the multichip package illustrated in FIG. 39, or other multichip packages. Please note that FIGS. 40-44 illustrate a process for forming a deep-trench isolation (DTI) layer 4 and a shallow-trench isolation (STI) layer 6 in a semiconductor substrate 2, which can be applied to all embodiments of the present disclosure for forming the same.

Referring to FIG. 40, a process of forming shallow trenches 6a (one of them is shown) in the semiconductor substrate 2 in a wafer level is illustrated. A pad oxide layer 2a having a suitable thickness, such as between 1 and 20 nanometers, is formed on a wafer substrate 2 using a suitable process. Then a silicon nitride layer 2b having a suitable thickness, such as between 10 and 200 nanometers, is formed on the pad oxide layer 2a using a suitable process. The silicon nitride layer 2b is coated with a photo resist layer 41 using a suitable process, such as spin coating. The photo resist layer 41 may be patterned using lithographic technology of mask exposure and development. The shallow trench 6a is formed by removing the exposed silicon nitride 2b and pad oxide 2a by a suitable process, such as by using reactive ion dry etching and etching silicon using reactive ion dry etching.

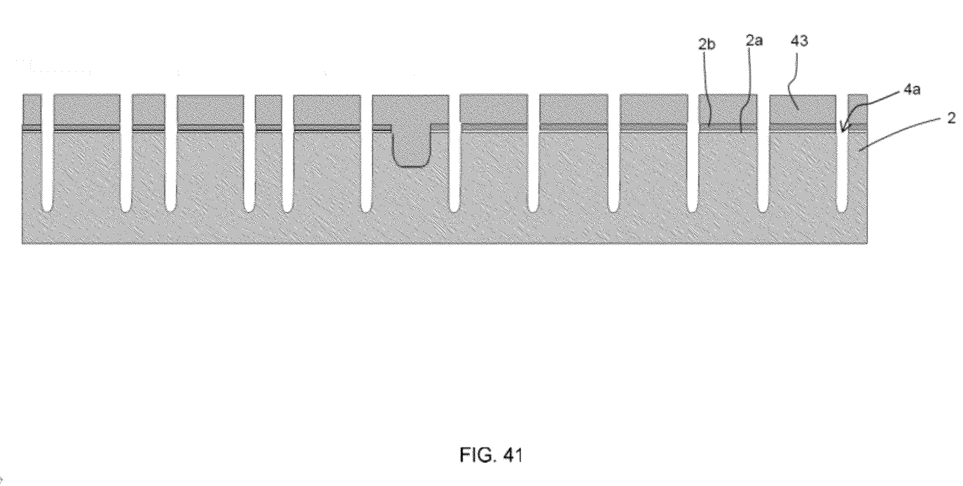

Next, referring to FIG. 41, a process of forming a deep trench 4a in the wafer substrate 2 is illustrated. The photo resist layer 41 of FIG. 18 is removed by using a wet chemical, such as hydrogen peroxide (H₂O₂) and/or sulfuric acid (H₂SO₄) and/or oxygen (O₂) plasma ashing. A photo resist layer 43 is then coated on the silicon nitride layer 2b using a suitable process, such as spin coating. The photo resist layer 43 may be patterned using lithographic technology of mask exposure and development. The deep trench 4a is formed by removing the exposed silicon nitride 2b and pad oxide 2a by a suitable process, such as by using reactive ion dry etching and etching silicon using reactive ion dry etching.

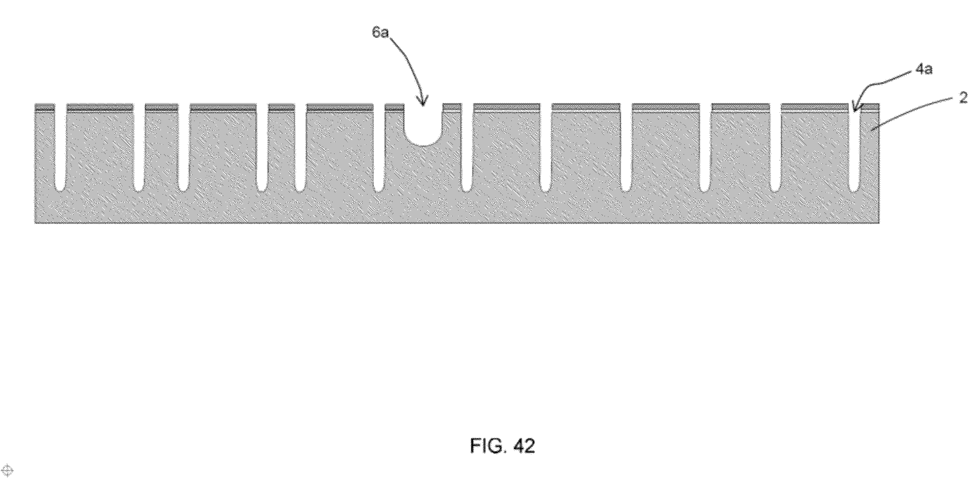

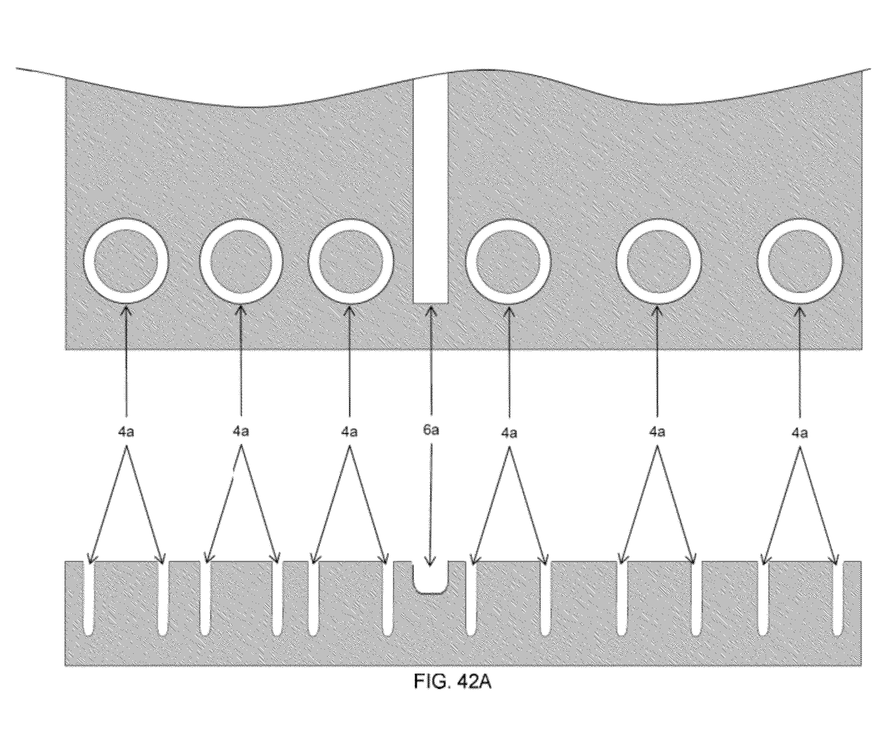

FIG. 42 shows a cross section view of the shallow trench 6a and the deep trench 4a, after removing the photo resist layer 43 of FIG. 41 by using a wet chemical, such as hydrogen peroxide (H₂O₂) and/or sulfuric acid (H₂SO₄) and/or oxygen (O₂) plasma ashing.

FIG. 42A show a top view of the wafer substrate 2 after forming the shallow trench 6a and the deep trench 4a. FIG. 42a illustrates the locations of the deep trenches 4a and shallow trench 6a in both the top view relative to the cross-sectional view of FIG. 42.

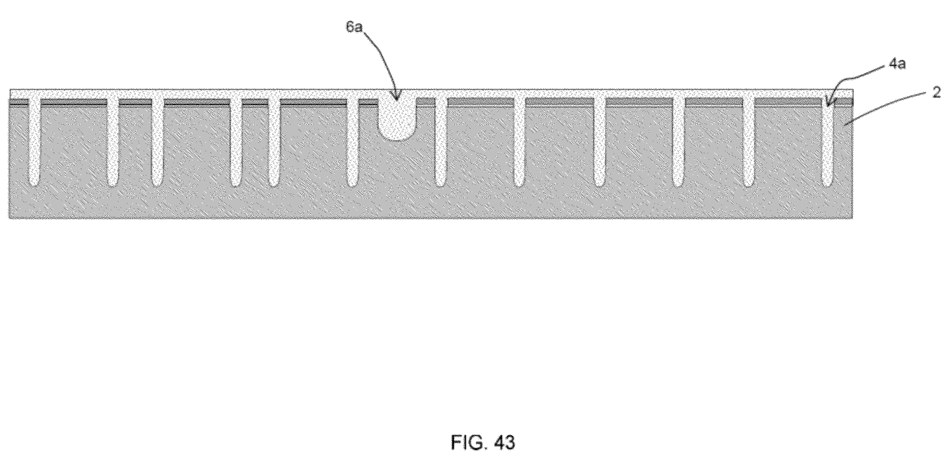

Next, referring to FIG. 43, a process of oxide refilling the shallow trench 6a and the deep trench 4a is illustrated. A lining oxide (not shown) is formed on the sidewall of the shallow trench 6a and the deep trench 4a using a suitable process. The lining oxide may have a suitable thickness, such as between 1 and 20 nanometers. A lining silicon nitride (not shown) may be deposited. Alternatively, the lining silicon nitride may be optional. The silicon nitride may have a suitable thickness, such as between 2 and 100 nanometers. The refilling dielectric layer may be deposited. The refilling dielectric layer may be silicon oxide or a combination of silicon nitride and silicon oxide. The refilling dielectric layer may have a suitable thickness, such as between 0.2 and 5 micrometers or between 0.5 and 2 micrometers.

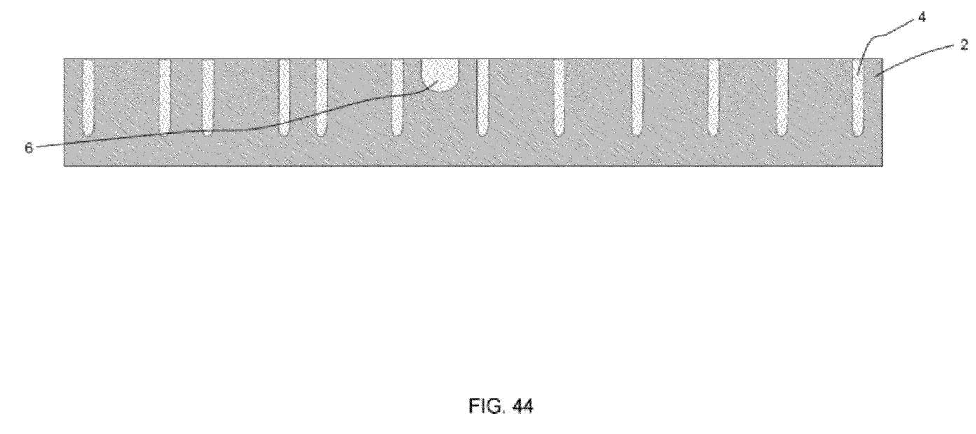

Next, referring to FIG. 44, a cross section view of the semiconductor substrate 2 in a wafer level is illustrated after a chemical-mechanical planarization (CMP) process has been performed, and after the silicon nitride has been removed. The CMP process may remove excess oxide and planarize the surface of the semiconductor substrate 2. The silicon nitride may be removed using a wet chemical such as hydrogen peroxide (H₂O₂) and phosphoric acid (H₃PO₄). The pad oxide may be removed using a wet chemical containing hydrogen fluoride (HF).

The deep trench isolation layer 4 may be for a through substrate via. The deep trench isolation layer 4 may include one or more of silicon oxide and/or silicon nitride. The deep trench isolation layer 4 may have a suitable width, such as between 0.1 and 20 micrometers, between 0.1 and 10 micrometers, between 0.1 and 5 micrometers, between 0.1 and 2 micrometers, or between 0.1 and 1 micrometers. The shallow trench isolation (STI) layer 6 may include one or more of silicon oxide and/or silicon nitride. The STI layer 6 may have a suitable depth, such as between 0.02 and 1 micrometers, or between 0.05 and 0.5 micrometers. The STI layer 6 may have a suitable width, such as between 0.02 and 100 micrometers or between 0.05 and 10 micrometers.

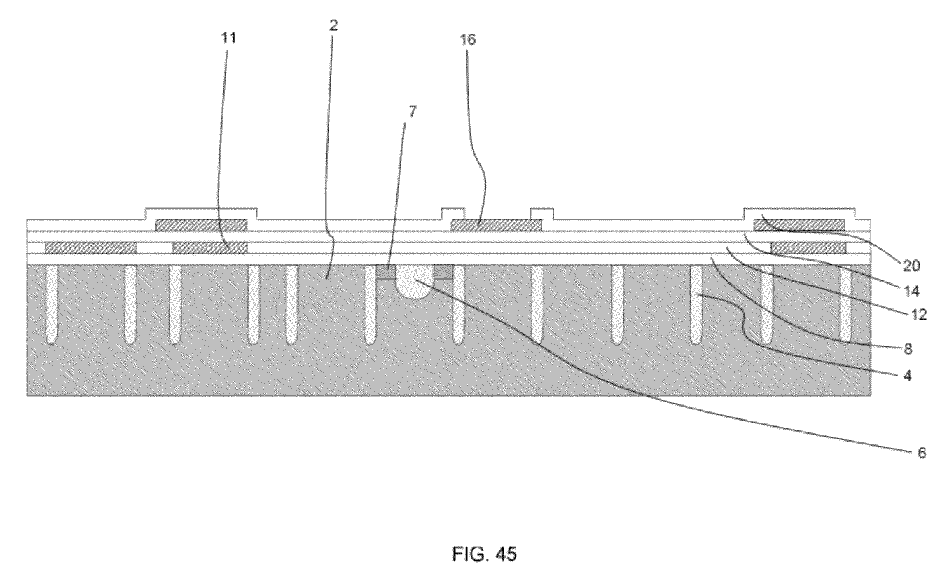

Next, referring to FIG. 45, a cross section view of a wafer 2 is illustrated where IC (integrated circuit) devices 7, a pre-metal dielectric layer 8, a metal contact (not shown), metal layers 11, 16, inter-metal dielectric layers 12, 14, 18, metal vias (not shown), passivation layer 20, and passivation opening are formed using suitable processes. The active device may include one or more of an N-type metal-oxide-semiconductor (NMOS) logic, a P-type metal-oxide-semiconductor (PMOS) logic, an NPN transistor, a PNP transistor, and/or a diode. The pre-metal dielectric layer 8 may be formed using a suitable process, such as by depositing. The metal layers 11, 16 may be formed by a suitable process, such as an electroplating process. The inter-metal dielectric layers 12, 14, 18 may be formed using a suitable process, such as depositing. The passivation layer 20 may be formed by a suitable process, such as depositing. The adhesive dielectric may include silicon oxide. The silicon oxide may be activated by plasma treatment. The finished semiconductor wafer 2 comprises multiple semiconductor chips or dies.

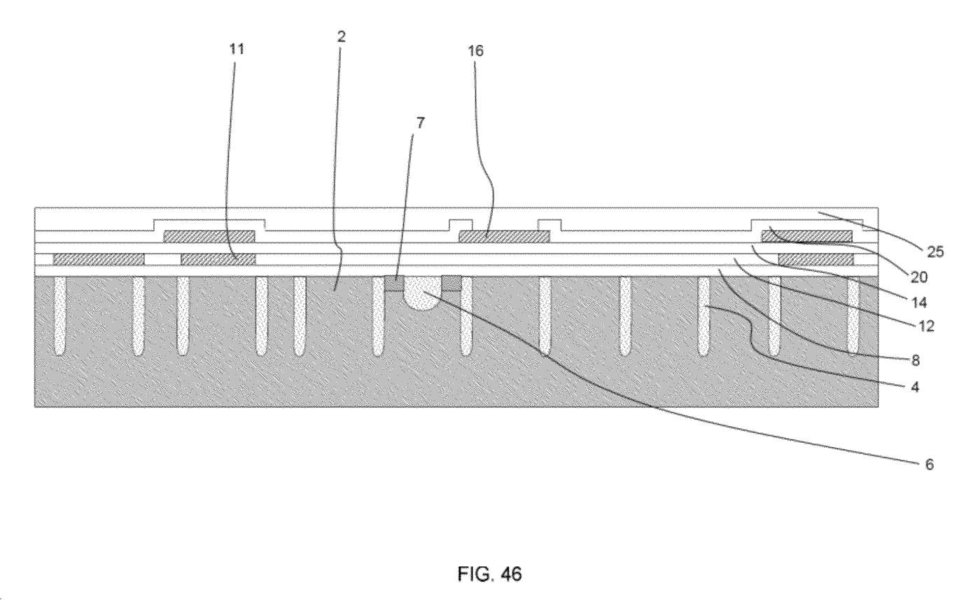

Next, referring to FIG. 46, dielectric layer 25 is formed. The dielectric layer 25 may include one or more of silicon dioxide (SiO₂), silicon nitride (Si₃N₄), silicon carbon-nitride, silicon oxynitride, polyimide, epoxy, PBO, and/or BCB. The dielectric layer 25 may be deposited using a suitable process, such as CVD for inorganic, and/or spin-coating (for organic). The dielectric layer 25 may be planarized by using a polishing process, such as CMP.

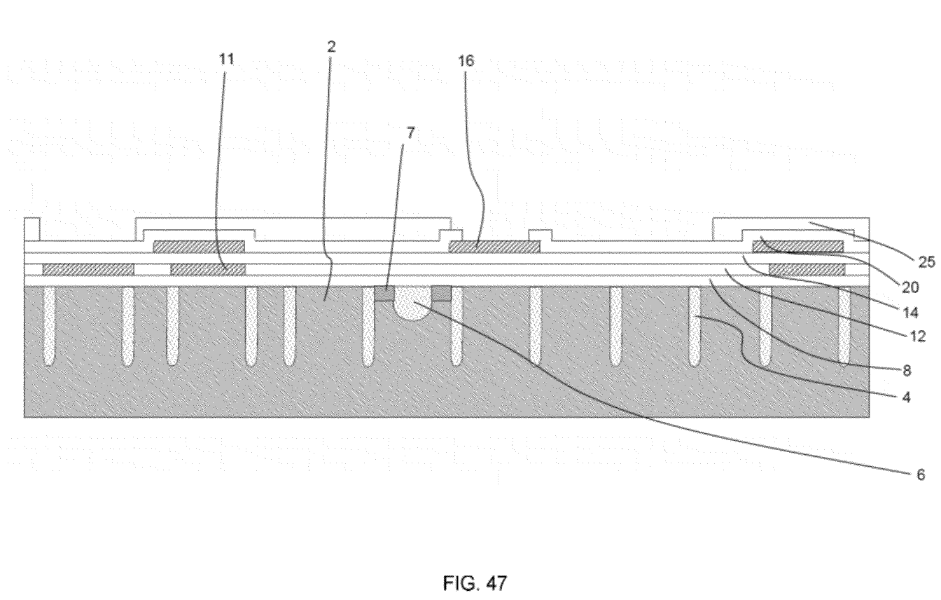

Next, referring to FIG. 47, openings in the dielectric layer 25 are formed for metal interconnect line or trace. For example, a photo resist layer may be formed on top of dielectric layer 25. The photo resist layer may be patterned using lithographic technology of mask exposure and development. The opening in the dielectric layer 25 may be formed using reactive ion dry etching. The dry etching may stop on dielectric layer 25, such that the passivation layer 20 is not etched. The photo resist layer may be removed after the formation of the openings.

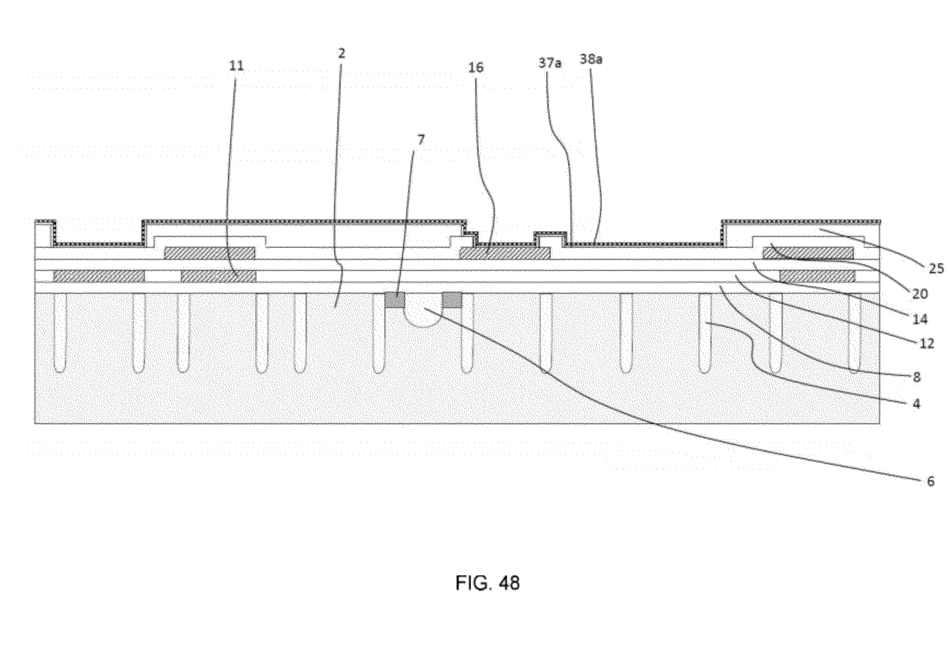

Next, referring to FIG. 48, the adhesion/barrier layer 37a and seed layer 38a are formed. The adhesion/barrier layer 37a and/or the seed layer 38a may be deposited using a suitable process, such as physical vapor deposition (PVD) or chemical vapor deposition (CVD). The PVD technology may include sputtering and evaporation.

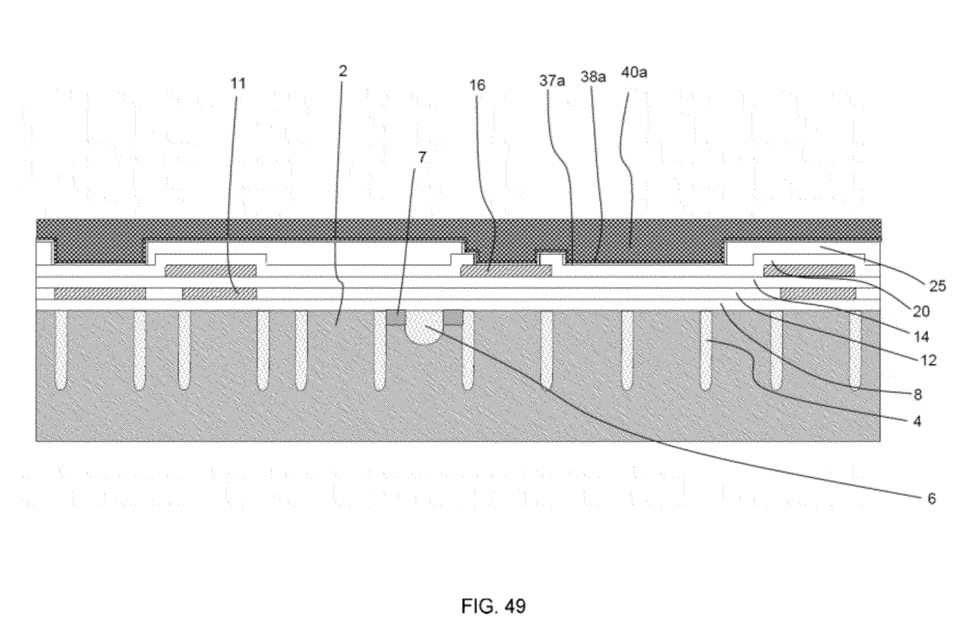

Next, referring to FIG. 49, conduction layer 40a is formed. The conduction layer 40a may be deposited using a suitable process, such as electroplating, electroless plating, or CVD.

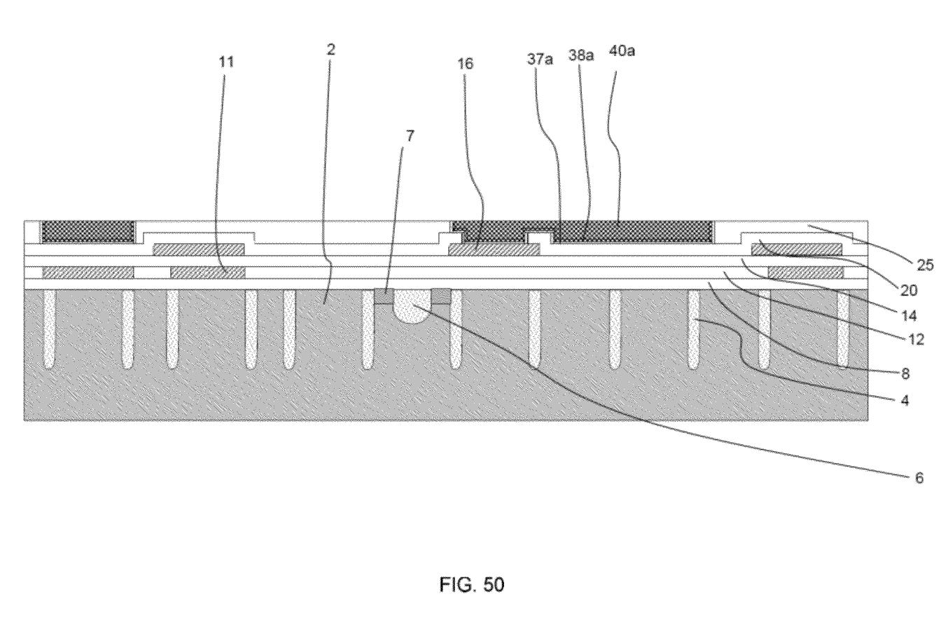

Next, referring to FIG. 50, the undesired portion of conduction layer 40a is removed, such as the portion of the conduction layer 40a that extends beyond the top of the dielectric layer 25. The undesired portion of conduction layer 40a may be removed using a chemical-mechanical-polish. The damascene process is completed through the process steps from FIG. 47 to FIG. 50.

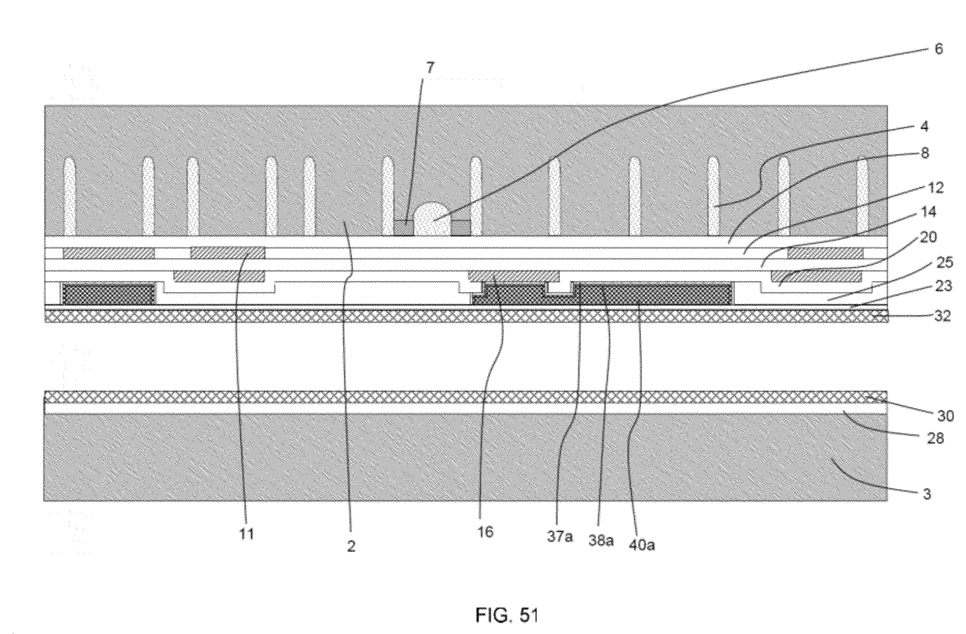

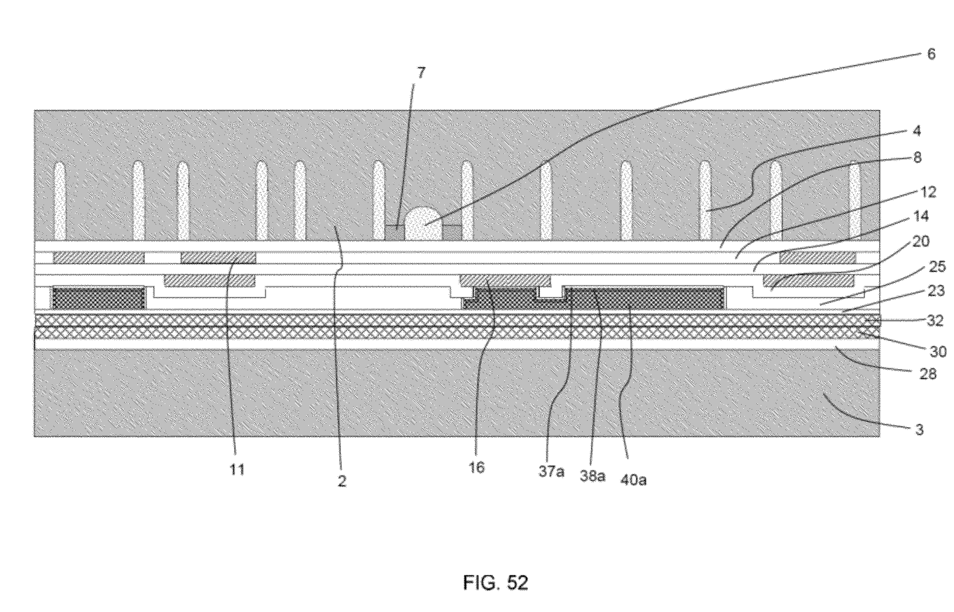

Next, referring to FIG. 51 and FIG. 52, a process of bonding two together two wafers by thermal compress is illustrated. For example, the substrate 2 of FIG. 50 may be inverted and bonded to the substrate 3 by thermal compress. Adhesive dielectric 30, 32 may be bonding interface layers. Adhesive dielectric 30, 32 may include oxide on oxide, polyimide on polyimide, polyimide on silicon nitride, polyimide on oxide, silicon nitride on polyimide, oxide on polyimide, epoxy on silicon nitride, epoxy on oxide, silicon nitride on epoxy, BCB on BCB, epoxy on epoxy, silicon oxynitride on silicon oxynitride, oxide on silicon oxynitride, and/or silicon oxynitride on oxide.

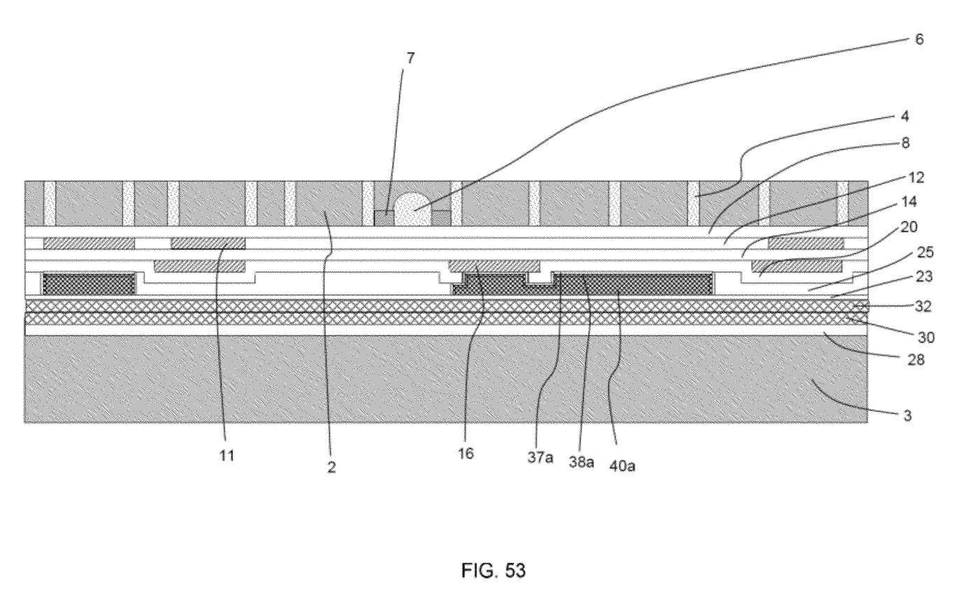

Next, referring to FIG. 53, a wafer thinning process is illustrated. The upper wafer (substrate 2) may be thinned from the backside (the side opposite to the active device site) to expose the deep trench isolation layer 4. The thinning process may be performed by mechanical grinding, polishing, chemical-mechanical-polishing, plasmas dry etching, chemical wet etching and/or a combination thereof. After the wafer thinning process, substrate 2 may have a thickness between 1 and 100 micrometers, between 1 and 50 micrometers, between 1 and 20 micrometers, or between 1 and 10 micrometers.

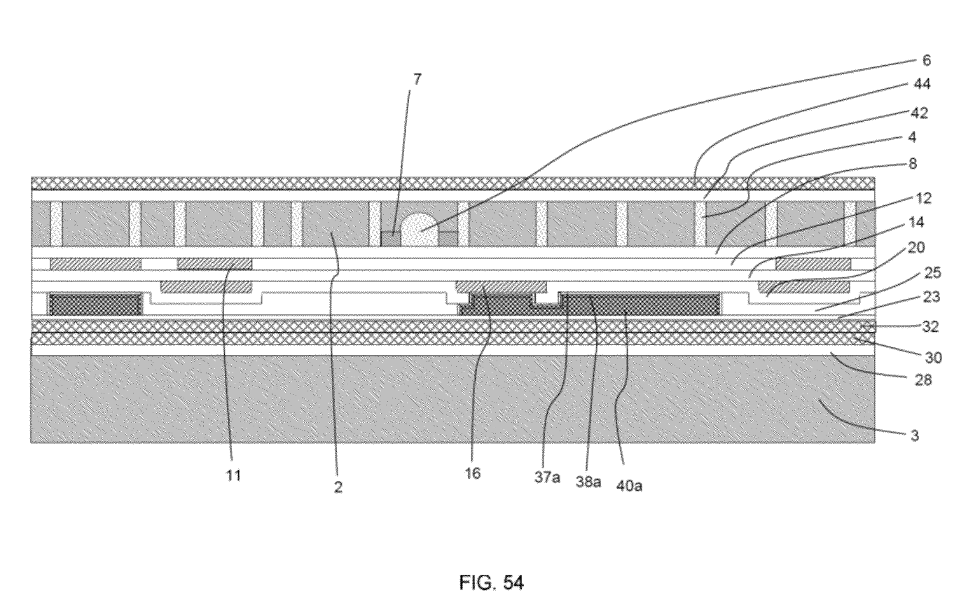

Next, referring to FIG. 54, dielectric layer 42 and adhesive dielectric layer 44 are formed. The dielectric layer 42 may include one or more of silicon dioxide (SiO₂), silicon nitride (Si₃N₄), silicon carbon-nitride, silicon oxynitride, polyimide, epoxy, PBO, and/or BCB. The dielectric layer 42 may be deposited using a suitable process, such as CVD, spin-coating, lamination or screen printing. As previously discussed, the adhesive dielectric layer 44 may include one or more of activated silicon oxide, activated silicon oxynitride, activated silicon nitride, BCB, polyimide, epoxy and/or PBO. The adhesive dielectric layer 44 may be deposited by using a suitable process, such as CVD, spin-coating, lamination or screen printing. For example, the material of dielectric layer 44 may be activated silicon oxide where the silicon oxide is activated by plasma treatment.

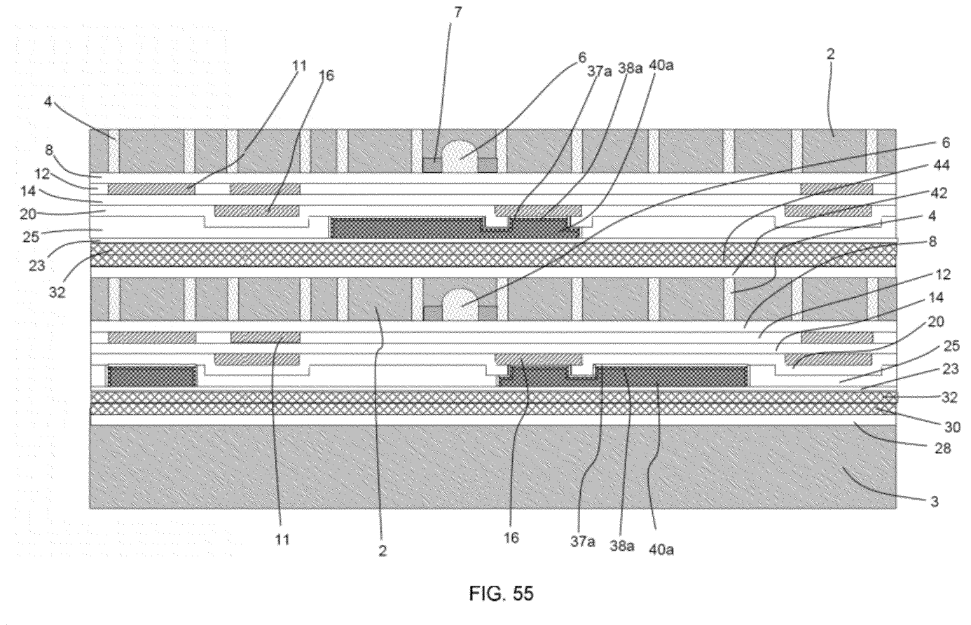

Next, referring to FIG. 55, the process illustrated in FIGS. 51-54 is repeated to bond an additional semiconductor wafer. The additional semiconductor wafer may include multiple semiconductor chips or dies. The process illustrated in FIGS. 51-54 may be repeated any number of times to continue to add additional wafers.

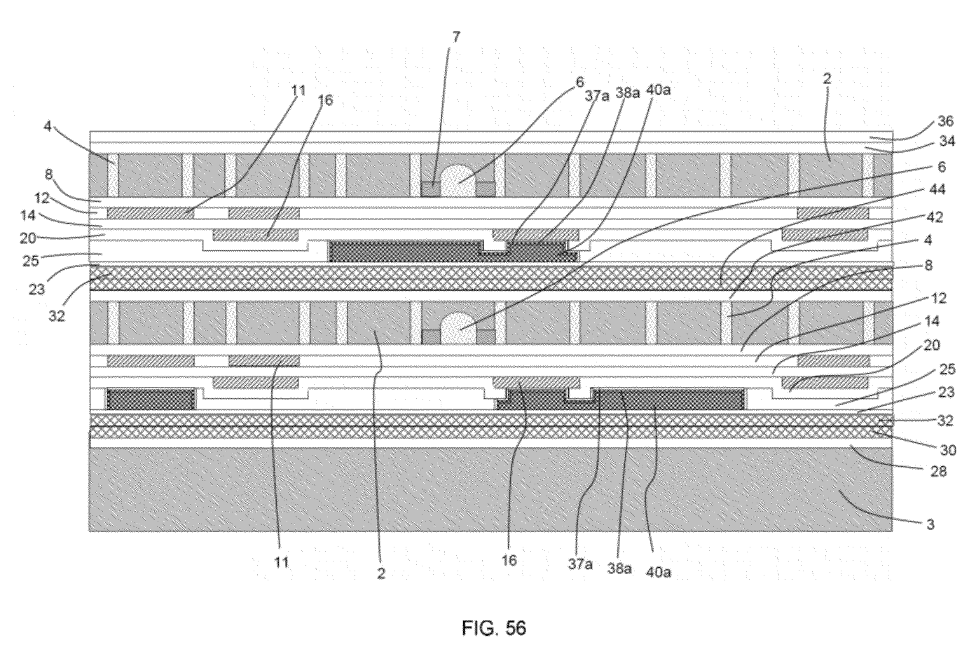

Next, referring to FIG. 56, a process of depositing backside dielectric layers 34, 36 is illustrated. As previously discussed, the dielectric layers 34, 36 may include one or more of silicon dioxide (SiO₂), silicon nitride (Si₃N₄), silicon carbon-nitride, silicon oxynitride, polyimide, epoxy, and/or polybenzoxazole (PBO). The dielectric layers 34, 36 may be deposited using a suitable process, such as chemical vapor deposition (CVD), spin-coating, screen printing and/or lamination.

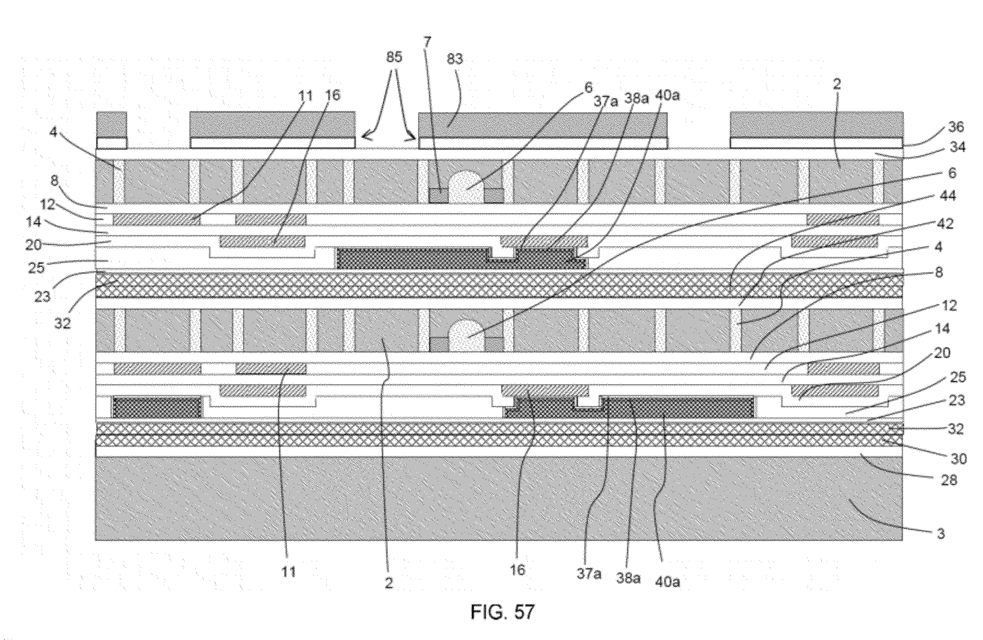

Next, referring to FIG. 57, one or more openings 85 in the backside dielectric layer 36 are formed, such as for metal interconnect trace formation. For example, a photo resist layer 83 may be formed on top of backside dielectric layer 36 using a suitable process, such as spin coating. The photo resist layer 83 may be patterned using lithographic technology of mask exposure and development. The one or more openings 85 in the backside dielectric layer 36 may be formed using reactive ion dry etching. The dry etching may stop at backside dielectric layer 34, such that the backside dielectric layer 34 is not etched. The photo resist layer 83 may be removed after the formation of the one or more openings 85. The photo resist layer 83 may be used to define metal interconnection amongst TSV.

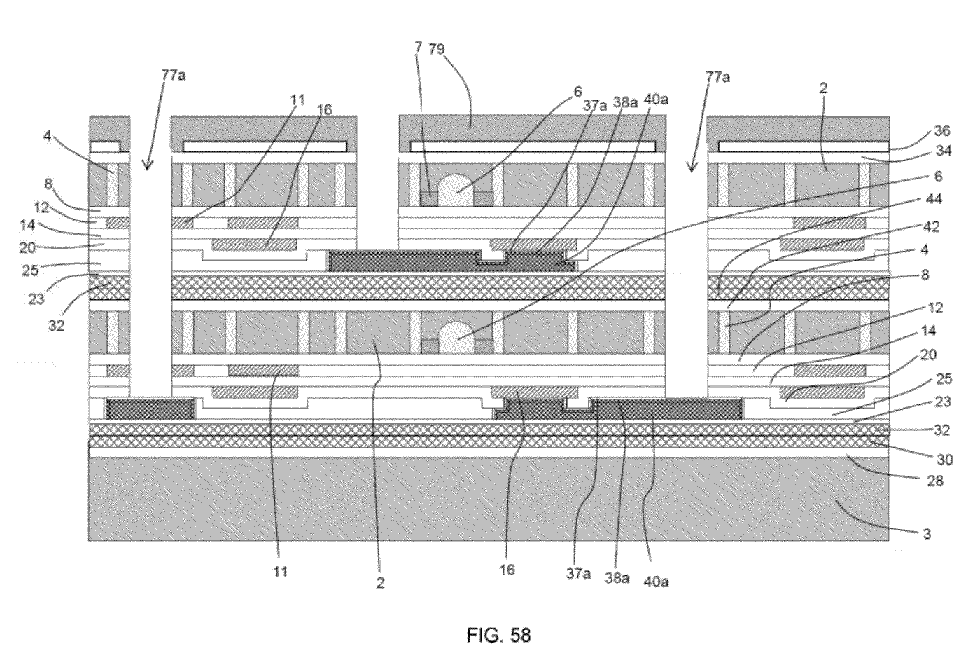

Next, referring to FIG. 58, one or more through vias 77a are formed. For example, a photo resist layer 79 may be coated on the backside dielectric layers 34, 36 using a suitable process, such as spin coating. The photo resist layer 79 may be patterned using lithographic technology of mask exposure and development. The one or more through vias 77a may be formed using reactive ion dry etching. The reactive ion dry etching may stop at a metal pad, such as the metal pad formed by the post passivation conduction layer 26. The one or more through vias 77a may pass through more than one wafer and the one or more through vias 77a may pass through the metal layer 11.

The through via 77a may have a suitable width and/or diameter, such as between 0.5 and 100 micrometers, between 0.5 and 50 micrometers, between 0.5 and 30 micrometers, between 0.5 and 20 micrometers, between 0.5 and 10 micrometers, between 0.5 and 5 micrometers, or between 1 and 3 micrometers.

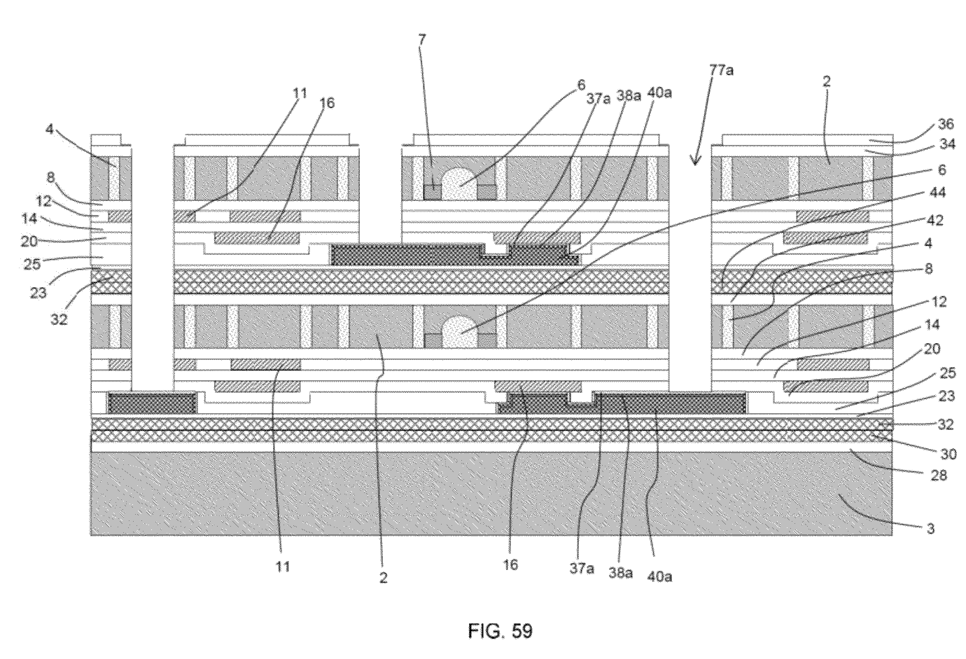

Next, referring to FIG. 59, the photo resist layer 79 may be removed after the formation of the through via 77a using a suitable process, such as by etching.

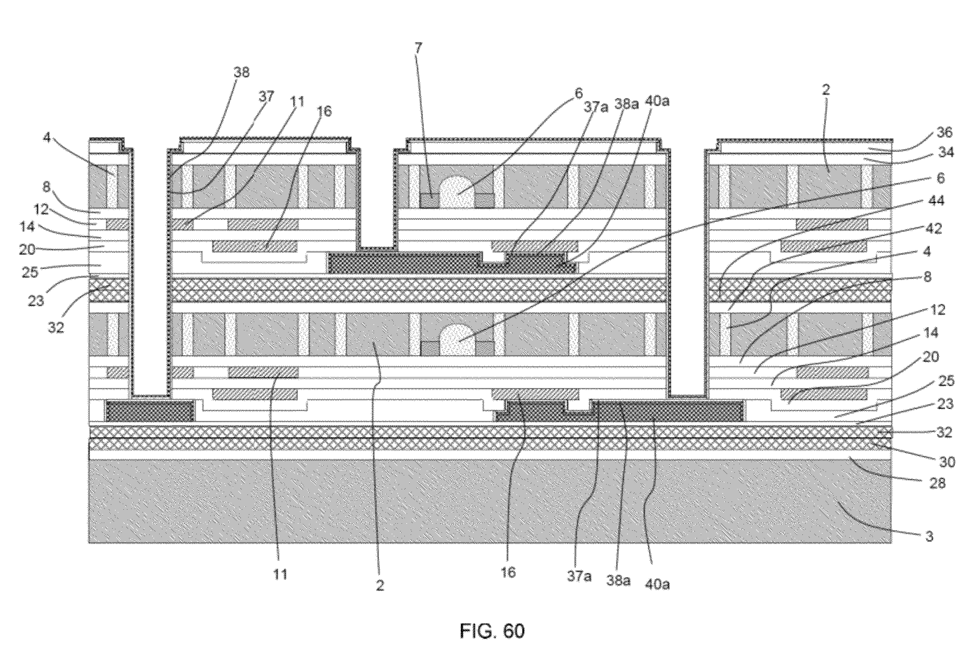

Next, referring to FIG. 60, the adhesion/barrier layer 37 and seed layer 38 are formed. The adhesion/barrier layer 37 and/or the seed layer 38 may be deposited using a suitable process, such as physical vapor deposition (PVD) or chemical vapor deposition (CVD). The PVD technology may include sputtering and evaporation.

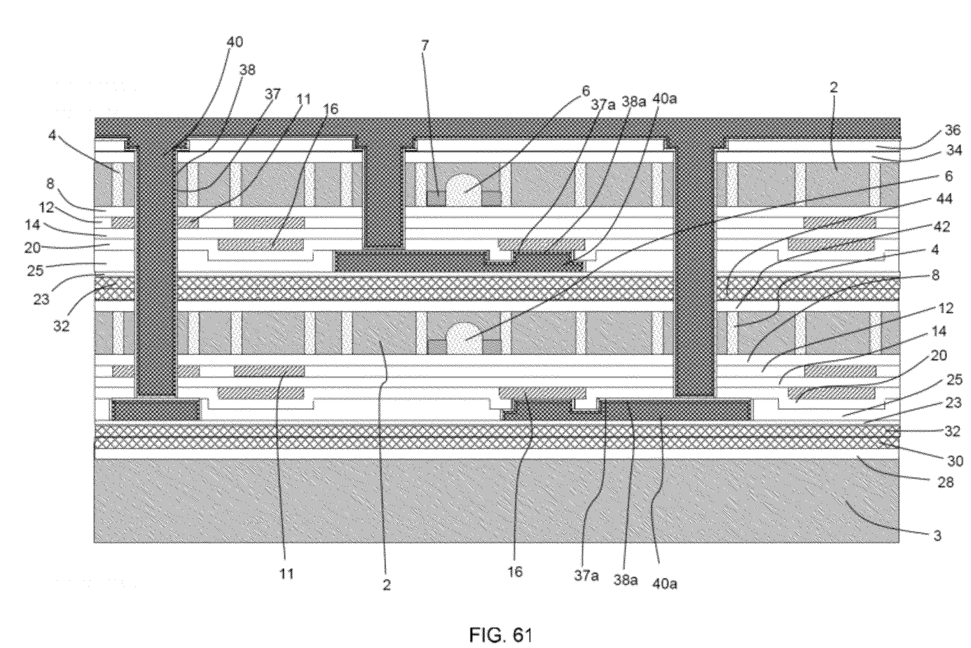

Next, referring to FIG. 61, conduction layer 40 is formed. The conduction layer 40 may be deposited using a suitable process, such as electroplating, electroless plating, or CVD.

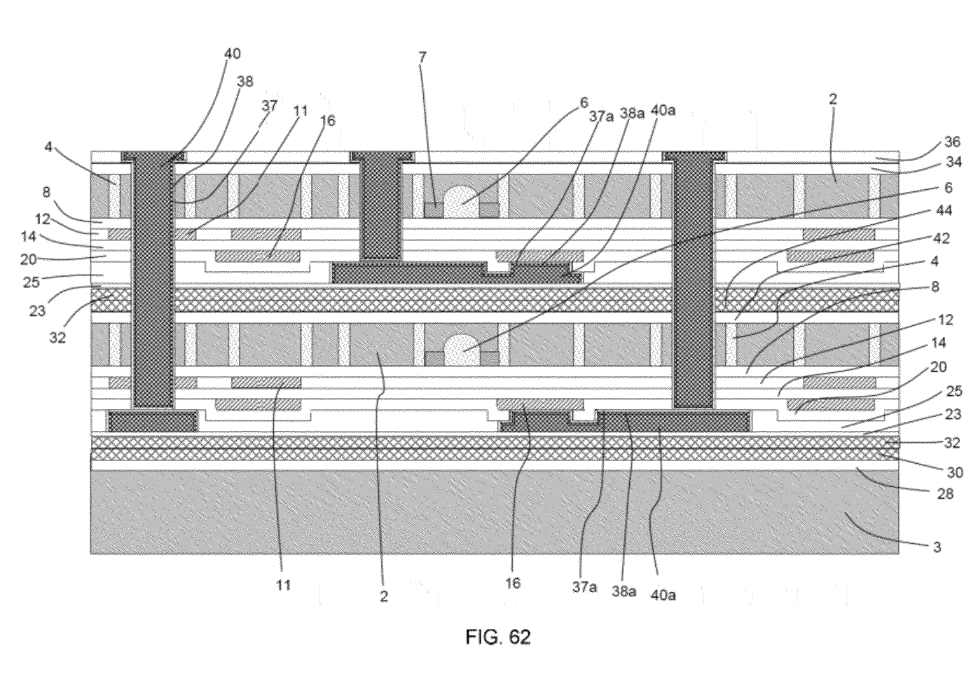

Next, referring to FIG. 62, the undesired portion of conduction layer 40, such as the excess portion of conduction layer 40, is removed, such as the portion of the conduction layer 40 that extends beyond the top of the backside dielectric layer 36. The undesired portion of conduction layer 40 may be removed using a chemical-mechanical-polish.

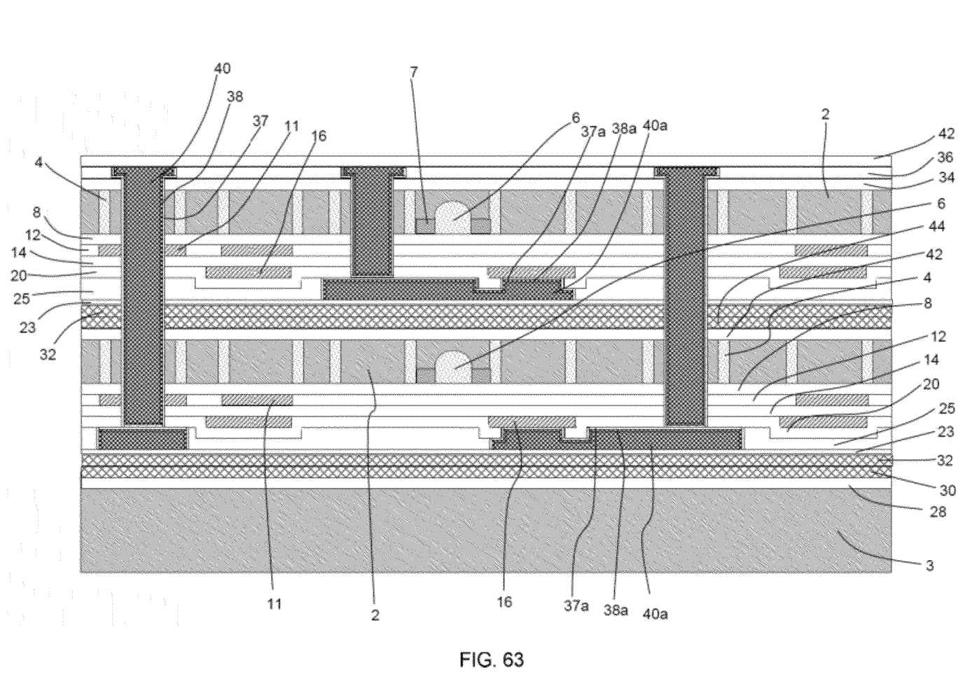

Next, referring to FIG. 63, dielectric layer 42 is formed. The dielectric layer 42 may include one or more of silicon dioxide (SiO₂), silicon nitride (Si₃N₄), silicon carbon-nitride, silicon oxynitride, polyimide, epoxy, PBO, and/or BCB. The dielectric layer 42 may be deposited using a suitable process, such as CVD, spin-coating, lamination or screen printing.

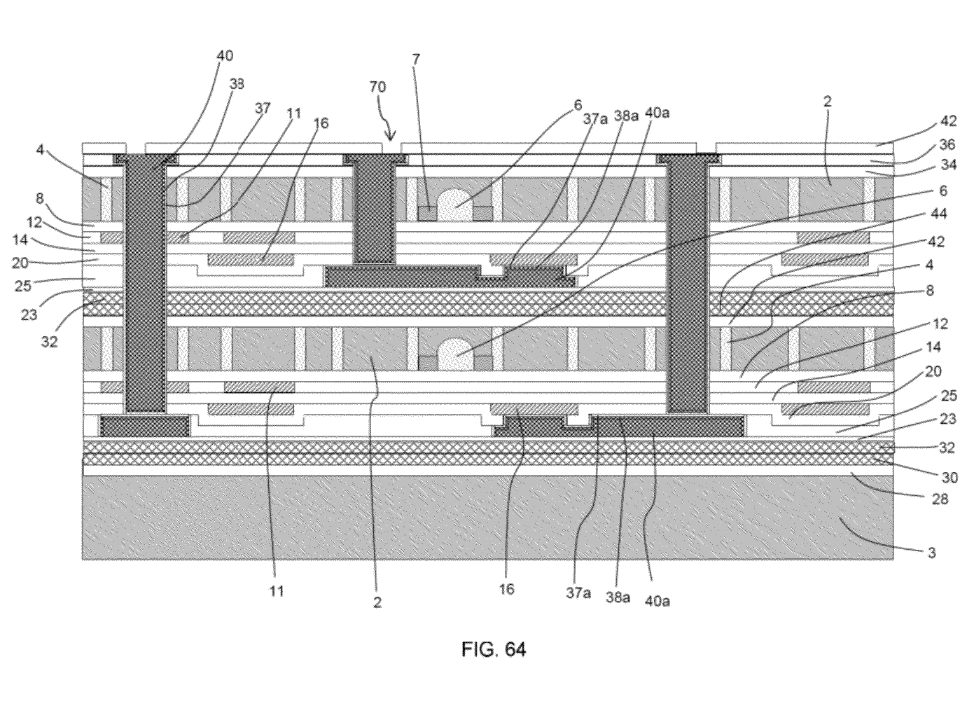

Next, referring to FIG. 64, one or more openings 70 are formed in the top dielectric layer 42. The one or more openings 70 may be formed using an IC process of lithographic and etching.

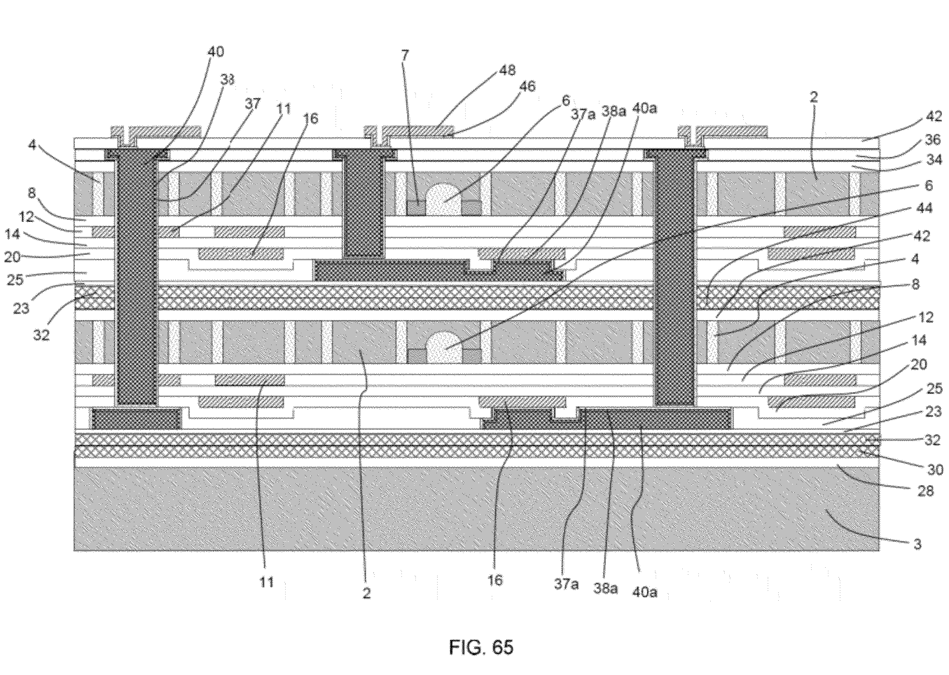

Next, referring to FIG. 65, the wire bondable conduction layer 48 is formed on top of dielectric layer 42. The conduction layer 48 may be formed using a suitable IC process, such as sputtering, lithographic and etching process when the conduction layer 48 includes a suitable alloy, such as aluminum alloy. Alternatively or in addition, the conduction layer 48 may be formed using a suitable IC process, such as sputtering, lithographic and electroplating, when the conduction layer 48 includes nickel/gold (Ni/Au) or nickel/palladium (Ni/Pd).

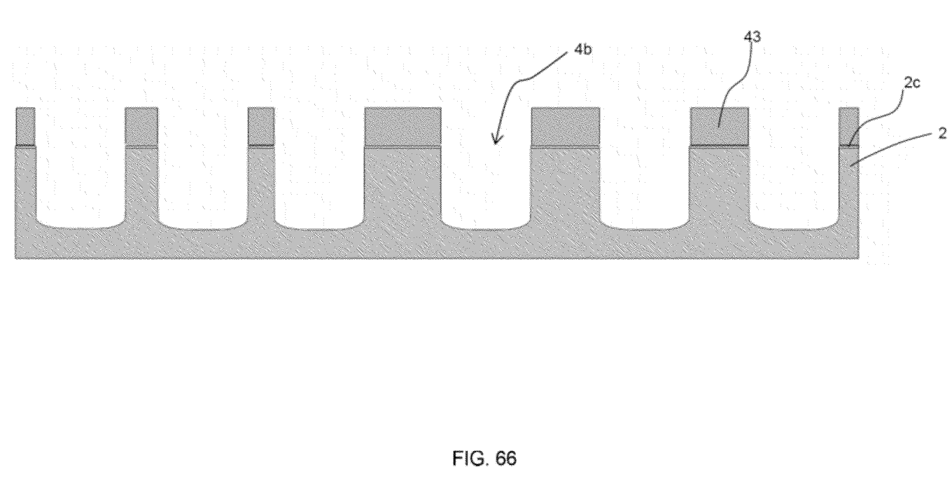

FIGS. 66-74 illustrate a process for forming a deep-trench isolation (DTI) layer and a shallow-trench isolation (STI) layer in a semiconductor substrate according to an exemplary embodiment of the present disclosure. For example, FIGS. 66-74 illustrate a process for forming a semiconductor substrate which may be used in place of, or in conjunction with, the semiconductor substrate 2 illustrated in FIG. 22.

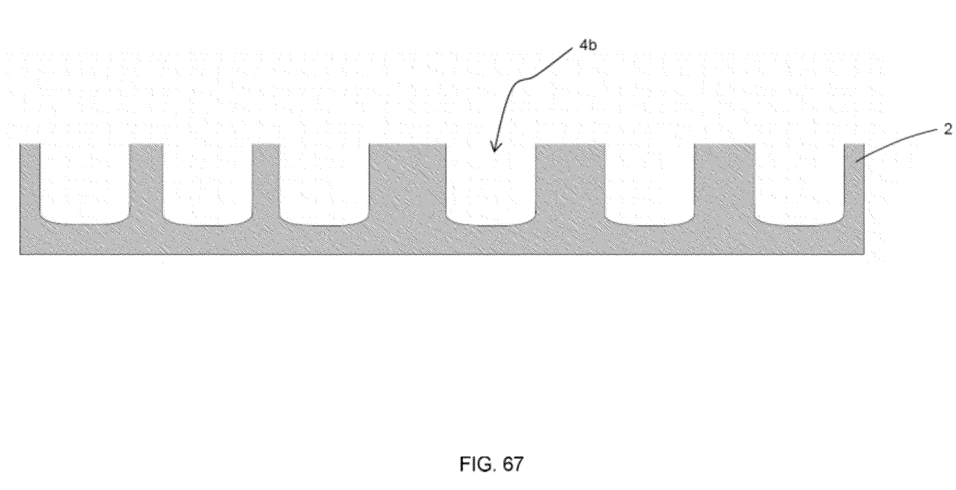

Referring to FIGS. 66 and 67, multiple deep trenches 4b are formed in the substrate 2 by forming a pad oxide 2c, such as silicon oxide, having a thickness between 5 and 35 nanometers on a top surface of the substrate 2, next forming a photoresist layer 43 on the pad oxide 2c using a suitable process, such as spin coating, next using a photolithographic technology including exposure and development, patterning the photoresist layer 43 to form multiple openings in the photoresist layer 43 exposing the pad oxide 2c, next removing the pad oxide 2c and the substrate 2 under the openings in the photoresist layer 43 using a suitable process, such as plasma dry etching, next removing the photoresist layer 43 using a wet chemical, and then removing the pad oxide 2c using a wet chemical.

The deep trenches 4b may have a suitable width, such as between 0.1 and 20 micrometers, between 0.1 and 10 micrometers, between 0.1 and 5 micrometers, between 0.1 and 2 micrometers, or between 0.1 and 1 micrometers. The deep trench 4b may have a suitable depth, such as between 1 and 100 micrometers, between 1 and 50 micrometers, between 1 and 20 micrometers, between 1 and 10 micrometers, between 1 and 5 micrometers, or between 2 and 5 micrometers. A pitch between the neighboring two of the deep trenches 4b may be between 1 and 300 micrometers, between 1 and 200 micrometers, between 1 and 100 micrometers, between 1 and 60 micrometers, between 1 and 40 micrometers, between 1 and 20 micrometers, between 1 and 10 micrometers, or between 2 and 6 micrometers.

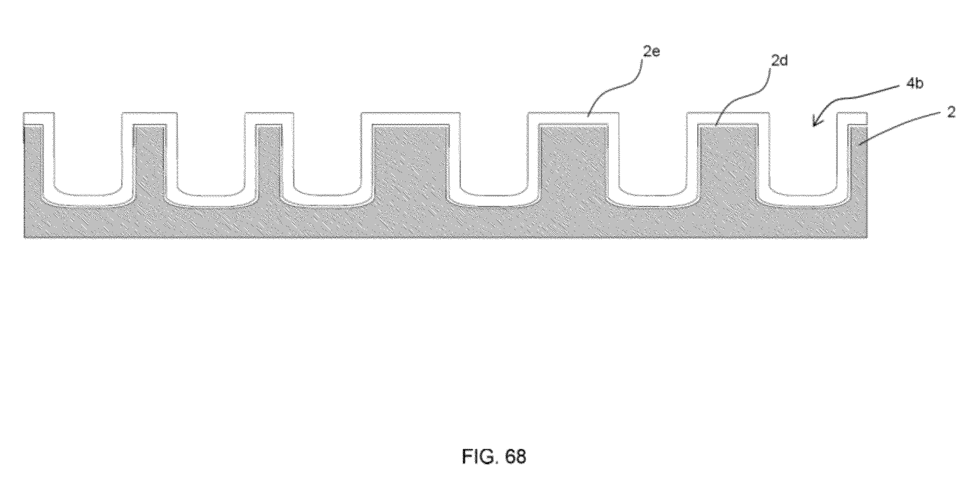

Next, referring to FIG. 68, a lining oxide 2d is formed on the top surface of the substrate 2 and sidewalls and bottoms of the deep trenches 4b by using a suitable process, such as thermal oxidation, and a silicon nitride layer 2e is formed on the lining oxide 2d by using a suitable process, such as CVD. The lining oxide 2d may have a suitable thickness, such as between 1 and 35 nanometers. The silicon nitride layer 2e may have a suitable thickness, such as between 50 and 200 nanometers.

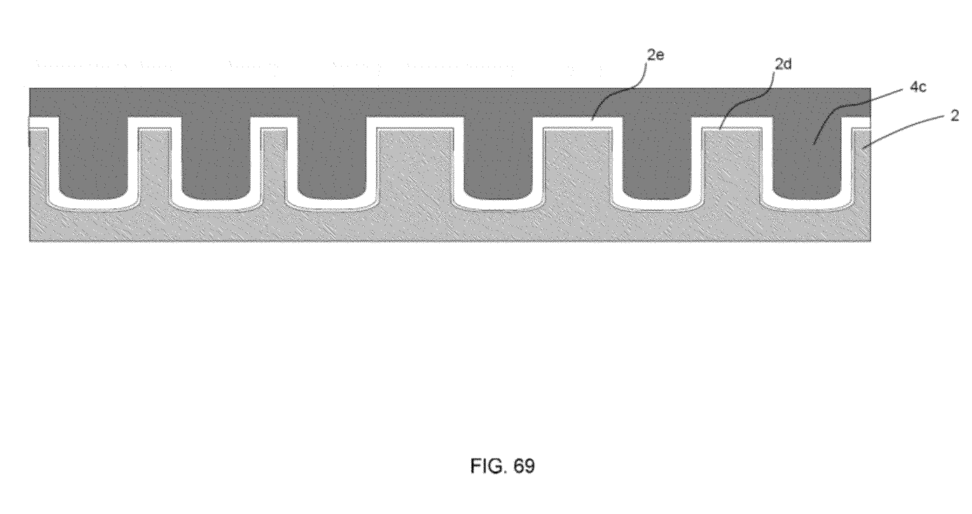

Next, referring to FIG. 69, a poly-silicon layer 4c is formed on the silicon nitride layer 2e and in the deep trenches 4b using a suitable process, such as CVD.

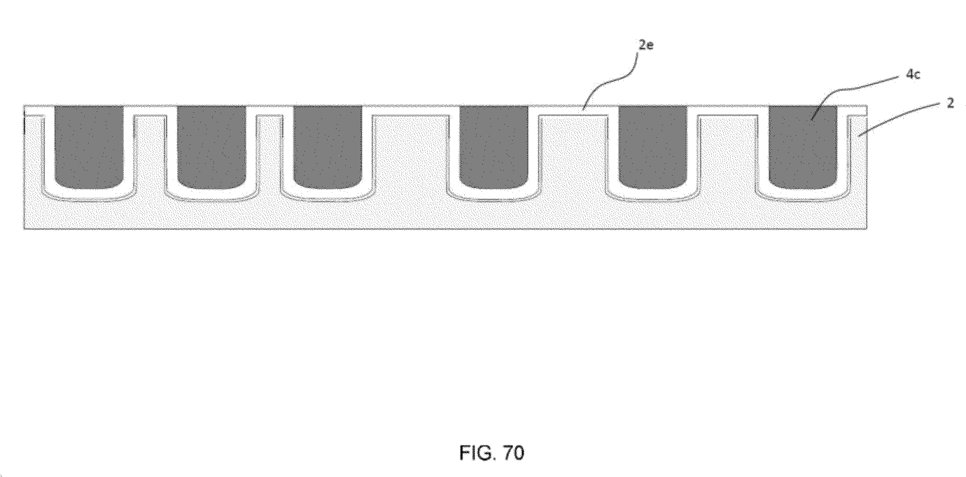

Next, referring to FIG. 70, the poly-silicon layer 4c can be ground or polished by a suitable process, such as CMP, until the silicon nitride layer 2e is exposed.

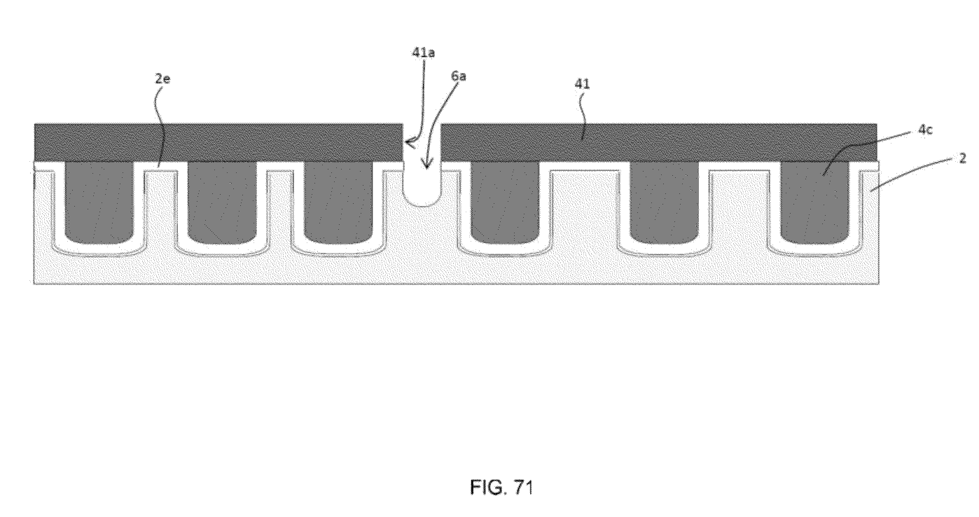

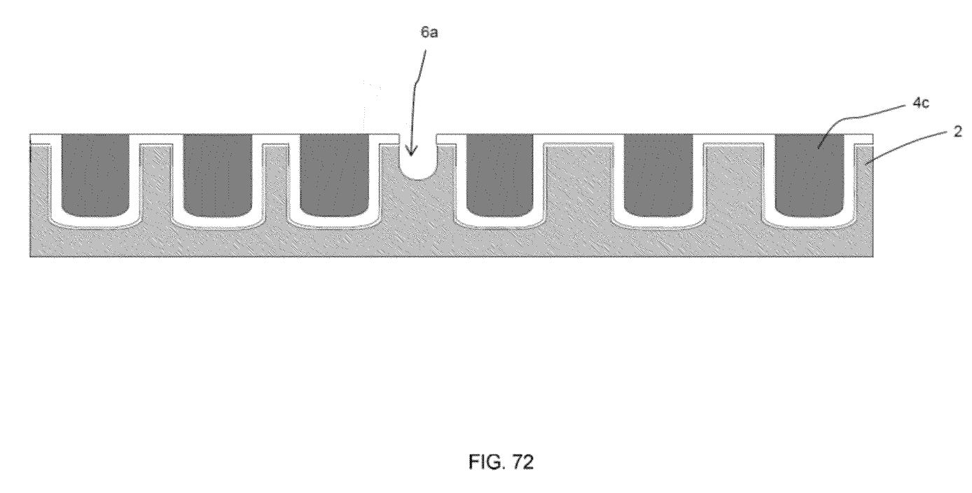

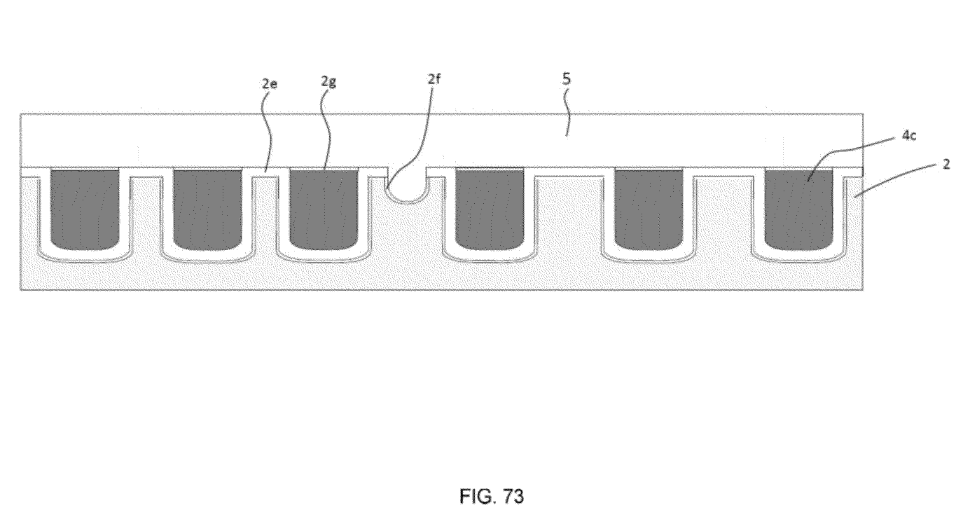

Next, referring to FIGS. 71 and 72, shallow trenches 6a (one of them is shown) are formed in the substrate 2 by forming a photoresist layer 41 on the silicon nitride layer 2e and the poly-silicon layer 4c using a suitable process, such as spin coating, next using a photolithographic technology including exposure and development processes, patterning the photoresist layer 41 to form openings 41a (one of them is shown) in the photoresist layer 41 exposing the silicon nitride layer 2e, next removing the silicon nitride layer 2e, the lining oxide 2d and the substrate 2 under the openings 41a using a suitable process, such as plasma dry etching, and then removing the photoresist layer 41 using a wet chemical.

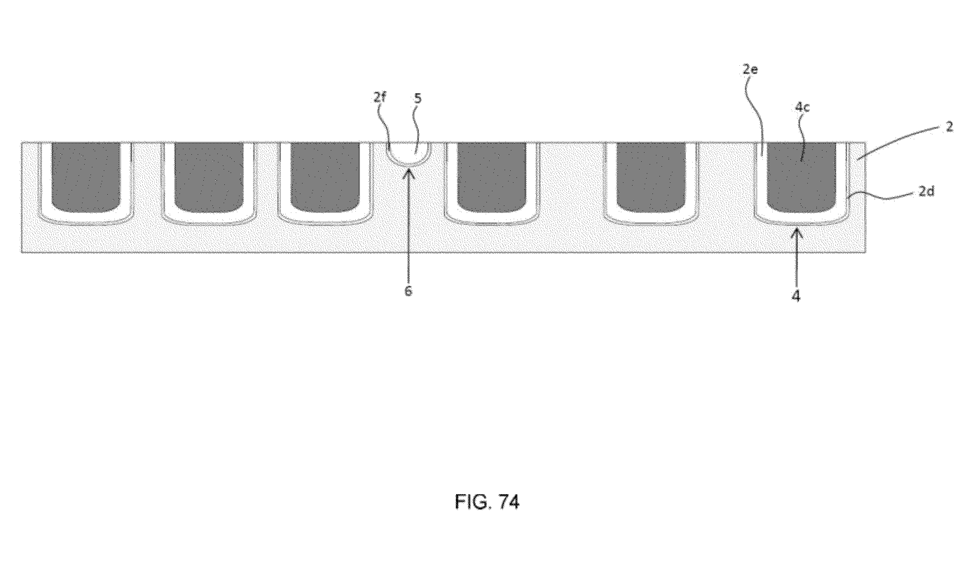

Next, referring to FIG. 73, a process of oxide refilling the shallow trenches 6a is illustrated. A lining oxide 2f is formed on sidewalls and bottoms of the shallow trenches 6a, and an oxide layer 2g is formed on a top surface of the poly-silicon layer 4c. The lining oxide 2f may have a suitable thickness, such as between 1 and 20 nanometers. The lining oxide may be deposited using a suitable process, such as thermal oxidation. Next, a dielectric layer 5 may be formed in the shallow trenches 6a and on the silicon nitride layer 2e, the lining oxide 2f and the oxide layer 2g by using a suitable process, such as CVD. The dielectric layer 5 may be a silicon-oxide layer or a composite including a silicon-nitride layer at the bottom of the composite and a silicon-oxide layer on the silicon-nitride layer. The dielectric layer 5 on the silicon nitride layer 2e may have a suitable thickness, such as between 0.2 and 5 micrometers or between 0.5 and 2 micrometers.

Next, referring to FIG. 74, using a grinding or polishing process, such as chemical-mechanical-polishing (CMP) process, mechanical polishing process, mechanical grinding process or a process including mechanical polishing and chemical etching, the dielectric layer 5 outside the shallow trenches 6a is removed until the silicon nitride layer 2e is exposed. Next, the silicon nitride layer 2e over the top surface of the substrate 2 is removed by using wet chemical. Next, the lining oxide 2d on the top surface of the substrate 2 and the oxide layer 2g on the top surface of the poly-silicon layer 4c are removed by using wet chemical. Thereby, a deep-trench isolation (DTI) layer 4 formed in the deep trenches 4b, and a shallow-trench isolation (STI) layer 6 formed in the shallow trenches 6a may have different materials. The deep-trench isolation (DTI) layer 4 can be composed of the lining oxide 2d on the sidewalls and bottoms of the deep trenches 4b, the silicon nitride layer 2e at the sidewalls and bottoms of the deep trenches 4b, and the poly-silicon layer 4c in the deep trenches 4b. The shallow-trench isolation (STI) layer 6 can be composed of the lining oxide 2f on the sidewalls and bottoms of the shallow trenches 6a, and the dielectric layer 5 in the shallow trenches 6a.

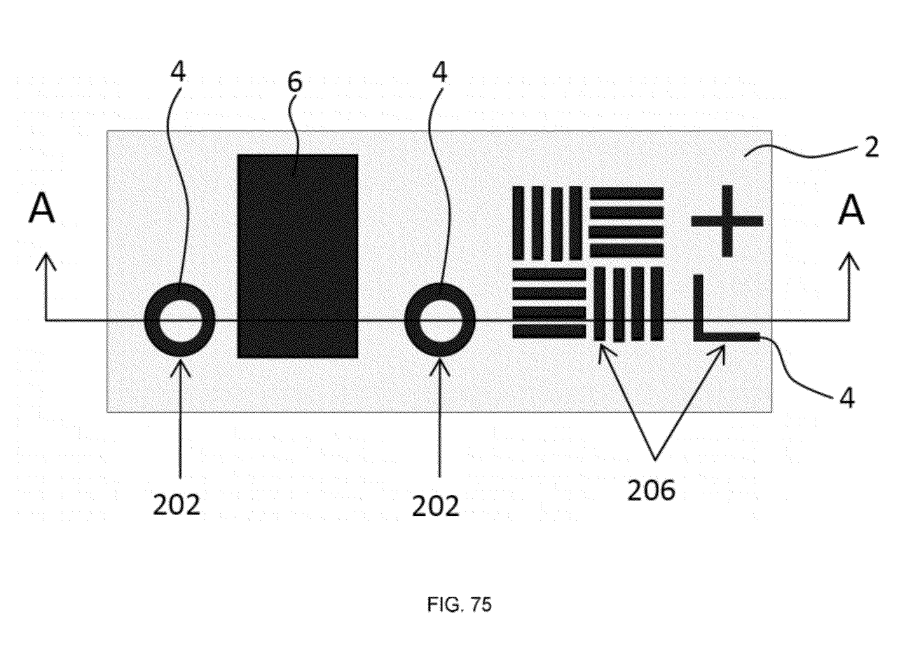

FIGS. 75-85 illustrate a process for forming a multichip package using enclosure-first technology according to exemplary embodiments of the present disclosure.

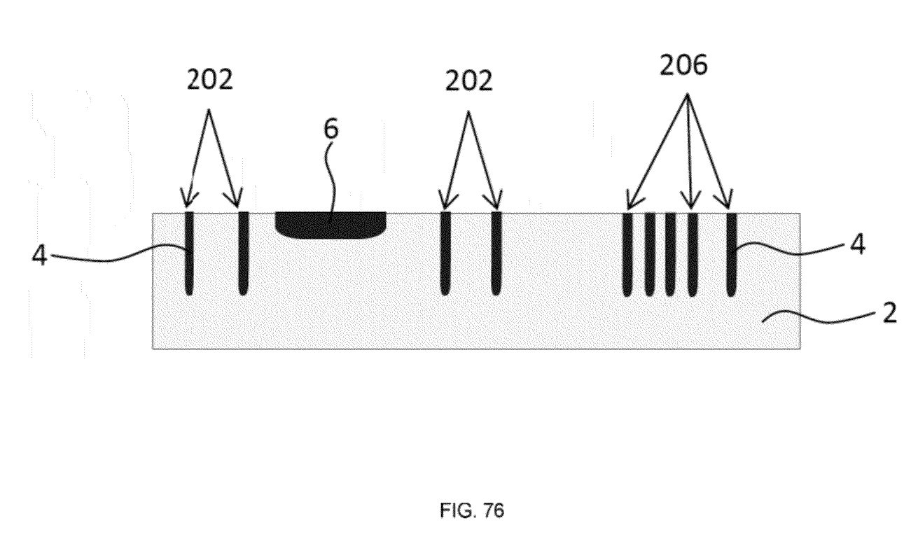

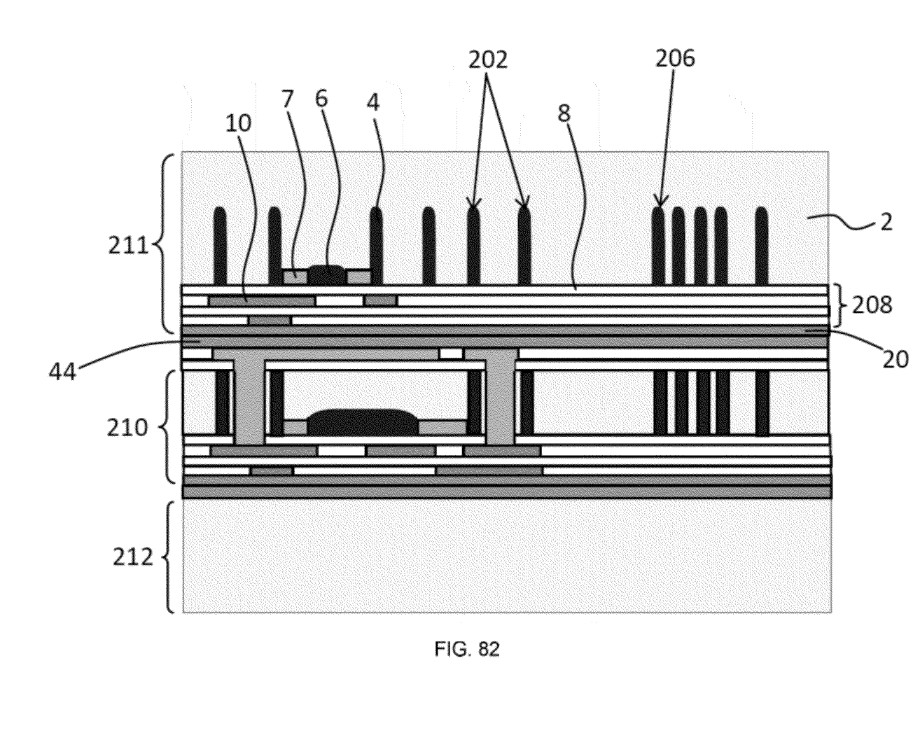

FIG. 75 illustrates a top view of a semiconductor substrate 2 in a wafer level. The semiconductor substrate 2 has the above-mentioned shallow-trench isolation (STI) layer 6, in the above-mentioned shallow trenches, for isolating multiple active-device regions or isolating an active-device region and a passive-device region, and the above-mentioned deep-trench isolation (DTI) layer 4, in the above-mentioned deep trenches, acting as isolation enclosures 202 enclosing through silicon/substrate vias (TSVs) and as backside alignment marks 206 for aligning another semiconductor wafer 211 with the semiconductor substrate 2 when the semiconductor wafer 211 is mounted on the backside of the semiconductor substrate 2, as shown in FIG. 82, for example. The STI layer 6 and DTI layer 4 may be formed by forming shallow and deep trenches in the semiconductor substrate 2 and then filling the shallow and deep trenches with oxides (such as silicon oxide) and/or nitrides (such as silicon nitride or silicon oxynitride), which can be referred to as the process illustrated in FIGS. 40-44, FIGS. 66-74, or FIGS. 18-20, 20A, 21 and 22. In one example, the material of the deep-trench isolation layer 4 may be an inorganic dielectric, such as silicon oxide, silicon nitride, or a combination of silicon oxide and silicon nitride, and the material of the shallow-trench isolation layer 6 may be an inorganic dielectric, such as silicon oxide, silicon nitride, or a combination of silicon oxide and silicon nitride. FIG. 76 illustrates an A-A cross section view of FIG. 75.

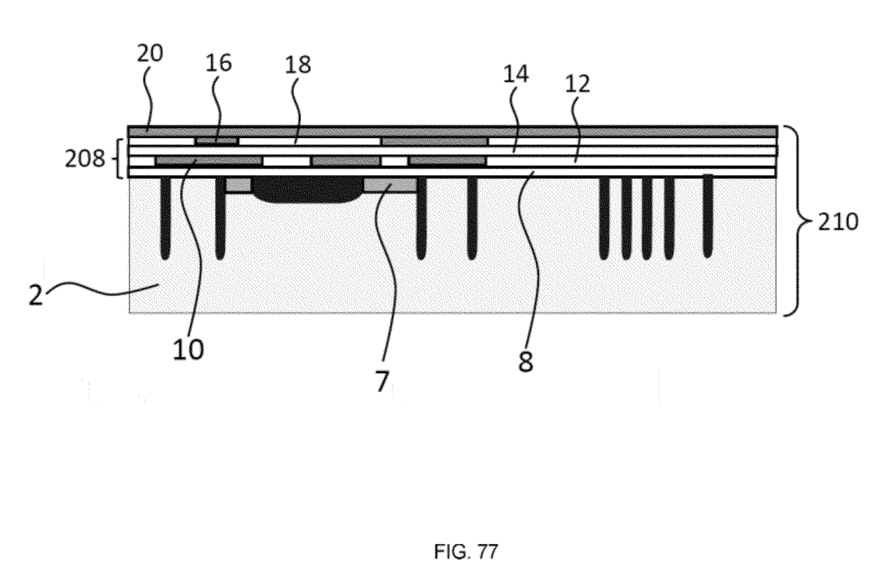

Referring to FIG. 77, after the steps illustrated in FIGS. 75 and 76, IC (integrated circuit) devices 7, an IC scheme 208 and a passivation layer 20 are formed over the semiconductor substrate 2. Thereby, the semiconductor substrate 2, the DTI layer 4, the STI layer 6, the IC devices 7, the IC scheme 208 and the passivation layer 20 compose a semiconductor wafer 210. FIG. 77 illustrates a cross section view of the semiconductor wafer 210 including the substrate 2, the isolation layers 4 and 6 in the substrate 2, the IC devices 7 in or on the substrate 2, the IC scheme 208 on the substrate 2, and the passivation layer 20 over the IC scheme 208 and the IC devices 7.

The semiconductor substrate 2 of the wafer 210 may be a silicon substrate or a substrate including Gallium arsenide (GaAs), Indium phosphide (InP), or silicon-germanium (SiGe). The IC devices 7 may be NMOS transistors, PMOS transistors, CMOS logic circuits, P—N diodes, capacitors, resistors, inductors, programmable logic devices (PLDs), field-programmable gate arrays (FPGAs), analog devices, and/or memories, such as NAND-Flash memories, Nor-Flash memories, static random access memories (SRAMs), dynamic random access memories (DRAMs), synchronous dynamic random access memories (SDRAMs), ferroelectric random access memories (FeRAMs), magneto resistive random access memories, phase-change random access memories (PRAMs), electrically erasable programmable read-only memories (EEPROMs), or erasable programmable read only memory (EPROMs).

The IC scheme 208, for example, may include multiple dielectric layers 8, 12, 14 and 18, and a circuit structure including conductive layers 10 and 16. Each of the dielectric layers 8, 12, 14 and 18 may include one or more of phosphosilicate glass (PSG), borophosphosilicate glass (BPSG), silicon oxide, silicon nitride, silicon oxynitride, silicon oxycarbonitride (SiOCN), silicon carbon nitride (SiCN), or low-k dielectric material having a dielectric constant smaller than 3.0 or between 1.8 and 3.0, and may have a suitable thickness, such as between 0.1 and 0.6 micrometers or between 50 nanometers and 1 micrometer. Each of the conductive layers 10 and 16, for example, can be a metal layer including aluminum, titanium, tantalum, electroplated copper or tungsten and having a suitable thickness, such as between 10 nanometers and 2 micrometers or between 0.1 and 1 micrometers. In one example, the conductive layer 10 may include a first electroplated copper layer having a suitable thickness, such as between 0.1 and 1 micrometers, on the dielectric layer 8 and in the dielectric layer 12, a first seed layer, such as copper or a titanium-copper alloy, on sidewalls and bottoms of the first electroplated copper layer, and a first adhesion layer, such as titanium nitride, a titanium-tungsten alloy or tantalum nitride, at the sidewalls and bottoms of the first electroplated copper layer, and the conductive layer 16 may include a second electroplated copper layer having a suitable thickness, such as between 0.1 and 1 micrometers, over the first electroplated copper layer, on the dielectric layer 14 and in the dielectric layer 18, a second seed layer, such as copper or a titanium-copper alloy, on sidewalls and bottoms of the second electroplated copper layer, and a second adhesion layer, such as titanium nitride, a titanium-tungsten alloy or tantalum nitride, at the sidewalls and bottoms of the second electroplated copper layer. Alternatively, each of the conductive layers 10 and 16 may include carbon nanotube and/or graphene and may have a suitable thickness, such as between 0.1 and 2 nanometers.

The passivation layer 20 may be an insulating or separating layer, such as silicon oxide, silicon nitride, silicon oxynitride, silicon carbon nitride or silicon oxycarbonitride, having a suitable thickness, such as between 0.3 and 1.5 micrometers. Alternatively, the passivation layer 20 may be an insulating inorganic layer including an oxide layer, such as silicon oxide, with a suitable thickness, such as between 0.3 and 1.5 micrometers, and an insulating nitride layer, such as silicon nitride or silicon oxynitride, with a suitable thickness, such as between 0.3 and 1.5 micrometers, over or under the oxide layer.

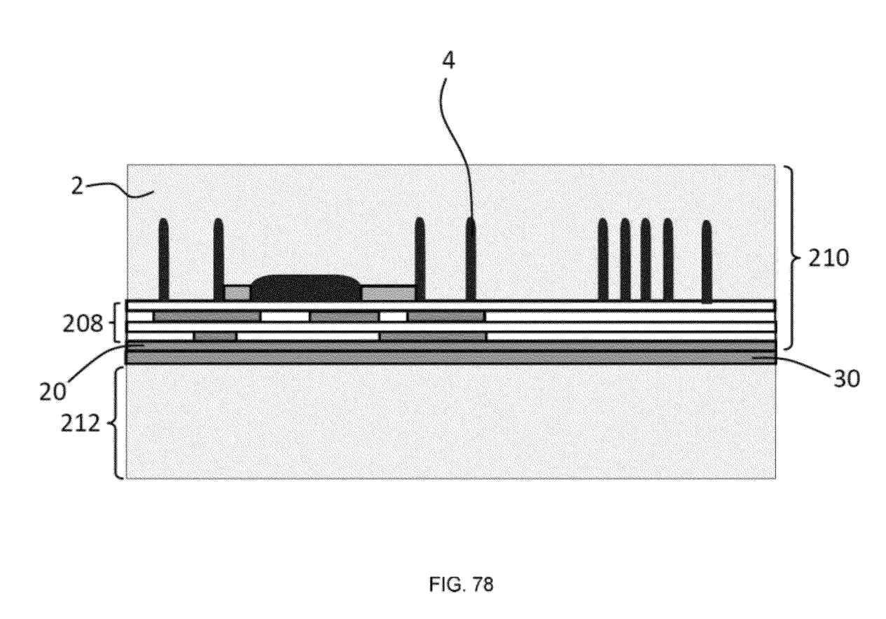

Next, referring to FIG. 78, the first semiconductor wafer 210 shown in FIG. 77 can be flipped (faced down) and bonded onto a supporting substrate 212, e.g., by the following steps. First, an adhesive layer 30, such as polymer layer, can be formed on a top surface of the supporting substrate 212 by using a suitable process, such as spin coating process, lamination process, spraying process, dispensing process, or screen printing process. Next, the adhesive layer 30 can be optionally pre-cured or baked. Next, the first semiconductor wafer 210 shown in FIG. 77 can be flipped placed over the supporting substrate 212 with the adhesive layer 30 between the first semiconductor wafer 210 and the supporting substrate 212. Next, the adhesive layer 30 can be cured again in a temperature between 180 degrees centigrade and 350 degrees centigrade with a mechanical or thermal pressure on the adhesive layer 30. Thereby, the first semiconductor wafer 210 can be joined with the supporting substrate 212 using the adhesive layer 30, and the adhesive layer 30 may have a suitable thickness, such as between 1 and 100 micrometers, between 1 and 15 micrometers, between 0.1 and 10 micrometers, between 0.1 and 5 micrometers, or between 0.1 and 1 micrometers. The passivation layer 20 of the first semiconductor wafer 210 can face the supporting substrate 212.

Alternatively, the adhesive layer 30 can be replaced with a silicon-oxide layer formed on the top surface of the supporting substrate 212, and the first semiconductor wafer 210 can be joined with the supporting substrate 212, e.g., by bonding a silicon-oxide layer of the passivation layer 20 of the first semiconductor wafer 210 onto the silicon-oxide layer 30.

The supporting substrate 212 may be a silicon wafer or substrate, a glass wafer or substrate, or a ceramic wafer or substrate. Alternatively, the supporting substrate 212 may be a semiconductor wafer including the semiconductor substrate 2, the DTI layer 4, the STI layer 6, the IC devices 7, the IC scheme 208 and the passivation layer 20, as mentioned above in the wafer 210, and having a same layout of the DTI layer 4 as that of the DTI layer 4 of the wafer 210, a different layout of the DTI layer 4 from that of the DTI layer 4 of the wafer 210, a same layout of the conductive layer 10 or 16 as that of the conductive layer 10 or 16 of the wafer 210, or a different layout of the conductive layer 10 or 16 from that of the conductive layer 10 or 16 of the wafer 210. Alternatively, the supporting substrate 212 and the wafer 210 may be same wafers having a same die marking and/or having a same layout of the DTI layer 4. In one embodiment, the supporting substrate 212 may have a top surface with a profile that is substantially same as that of a top surface of the first semiconductor wafer 210, that is, when the first semiconductor wafer 210 is a round wafer, the supporting substrate 212 can be a round wafer having a same diameter as that of the round wafer 210.

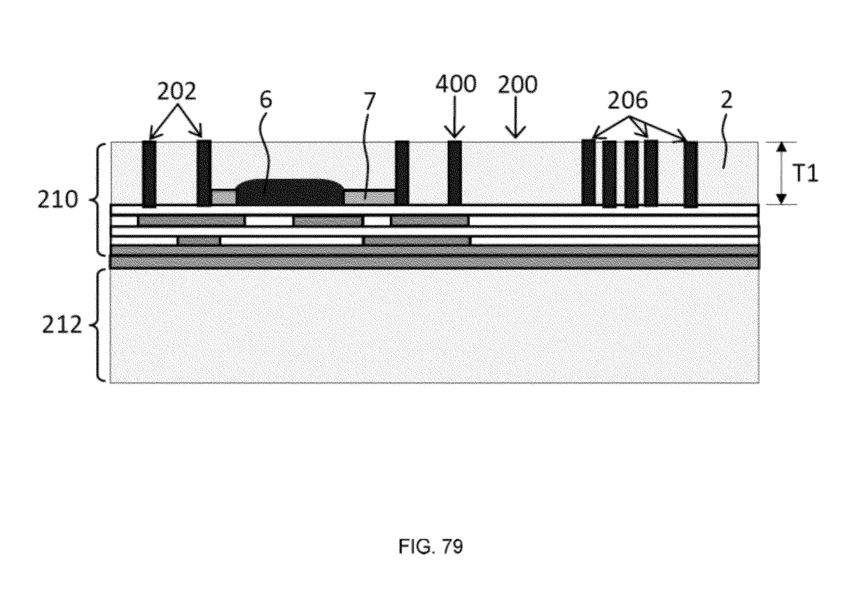

Next, referring to FIG. 79, the backside of the semiconductor substrate 2 of the semiconductor wafer 210 can be ground or polished by a suitable process, such as chemical-mechanical-polishing (CMP) process, mechanical polishing process, mechanical grinding process or a process including mechanical polishing and chemical etching, until the DTI layer 4 in the semiconductor substrate 2 of the wafer 210 has an exposed bottom surface 400, over which there is no portion of the semiconductor substrates 2 of the wafer 210.

Accordingly, the semiconductor substrate 2 of the wafer 210 can be thinned to a suitable thickness T1, such as between 1 and 100 micrometers, between 1 and 50 micrometers, between 1 and 20 micrometers, between 1 and 10 micrometers, between 1 and 5 micrometers, or between 2 and 5 micrometers. The ground or polished surface 200 of the substrate 2 of the wafer 210 may be substantially coplanar with the exposed bottom surface 400 of the DTI layer 4 of the wafer 210, and the DTI layer 4 of the wafer 210 may have a same thickness as the thickness T1 of the semiconductor substrate 2 of the wafer 210. Filled oxides and/or nitrides at the bottom end 400 of the DTI layer 4 of the wafer 210 may be exposed. The DTI layer 4 of the wafer 210 may be used as the backside alignment marks 206 for forming metal interconnects 86 and used as the isolation enclosures 202 for enclosing through silicon/substrate vias (TSVs) 77 in the wafer 210 as discussed below.

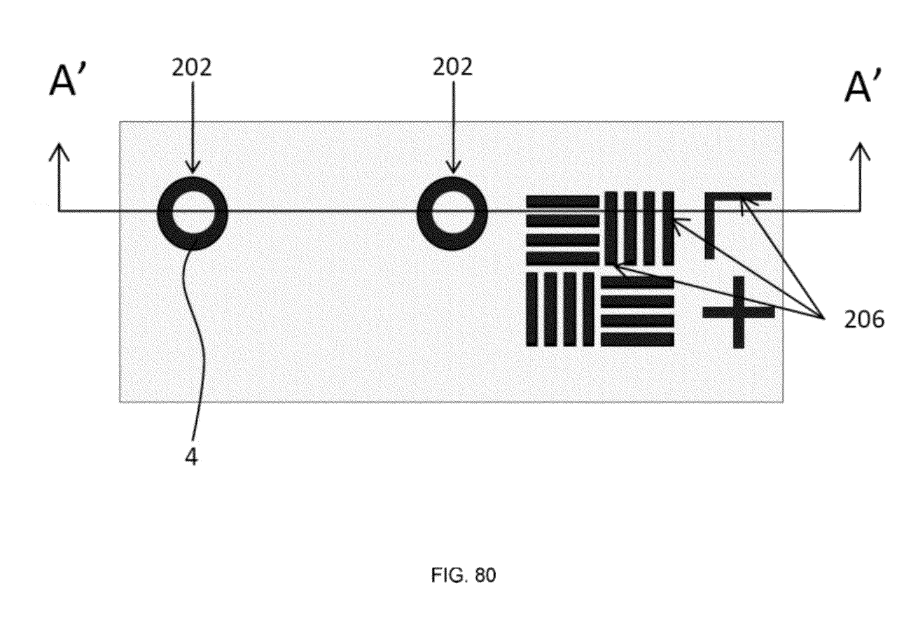

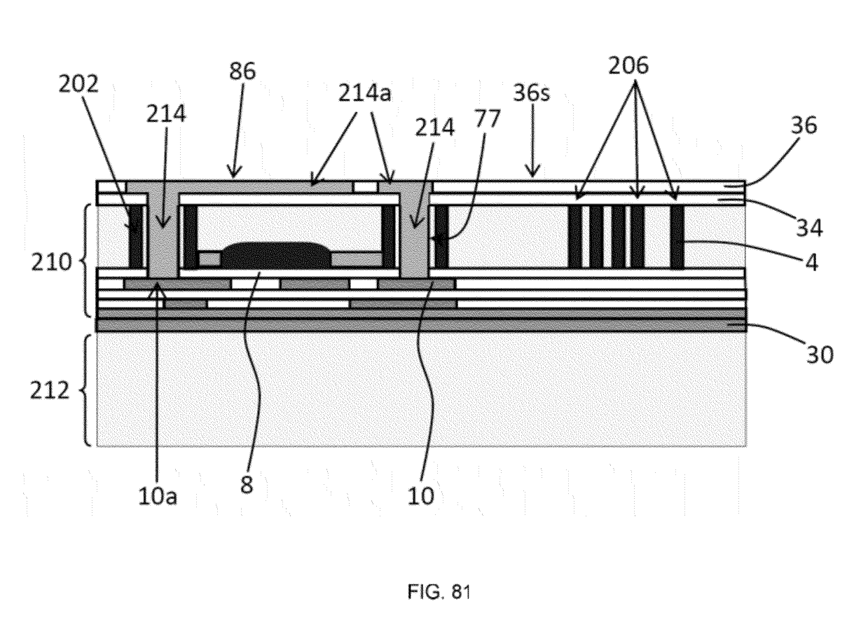

FIG. 80 illustrates a top view, from the backside of the first wafer 210, after thinning the substrate 2 of the wafer 210 and exposing the DTI layer 4 of the wafer 210 as discussed in FIG. 79 above. The DTI layer 206 may be used as backside alignment marks, such as in the process discussed in FIGS. 81-85 below. FIG. 80 illustrates exemplary alignment marks, however other markings or notations may also be formed using the processes disclosed herein. FIG. 79 illustrates an A′-A′ cross section view of FIG. 80.

Next, referring to FIG. 81, a process of forming the metal interconnects 86 is illustrated as below. First, a dielectric or insulating layer 34 can be formed on the ground or polished surface 200 of the substrate 2 of the wafer 210 and on the exposed bottom surface 400 of the DTI layer 4 of the wafer 210. The dielectric layer 34 may be a silicon-containing layer, such as silicon nitride, silicon oxide, silicon oxynitride or silicon carbon nitride, having a suitable thickness, such as between 0.1 and 1.5 micrometers, between 0.2 and 2 micrometers, between 0.3 and 5 micrometers or between 0.3 and 10 micrometers.

Next, a dielectric or insulating layer 36 can be formed on the dielectric layer 34. The dielectric layer 36 can be a silicon-containing layer, such as silicon nitride, silicon oxide, silicon oxynitride or silicon carbon nitride, having a suitable thickness, such as between 0.1 and 1.5 micrometers, between 0.2 and 2 micrometers, between 0.3 and 5 micrometers or between 0.3 and 10 micrometers.

Next, using the alignment marks 206 of the wafer 210 to align a photo mask with the wafer 210 with accuracy, multiple trenches can be formed, in a desired position, in the dielectric layer 36 based on the pattern of the photo mask and expose the dielectric layer 34 by an etching process.

Next, using the alignment marks 206 of the wafer 210 to align a photo mask with the wafer 210 with accuracy, multiple TSVs 77 can be formed, in a desired position, in the wafer 210 based on the pattern of the photo mask and expose contact points 10a of the conductive layer 10 of the wafer 210 by an etching process. The TSVs 77 may pass through the dielectric layer 34 under the trenches in the dielectric layer 36, through portions of the substrate 2 enclosed by the isolation enclosures 202 of the wafer 210, and through the dielectric layer 8 of the wafer 210. By means of the alignment marks 206 of the wafer 210, each of the isolation enclosures 202 of the wafer 210 may have a reduced inner diameter, such as between 0.1 and 10 micrometers, between 0.1 and 5 micrometers, between 0.1 and 2 micrometers or between 0.1 and 1 micrometers, accommodating the TSVs 77, and the semiconductor wafer 210 has much space spared for forming much more TSVs in the semiconductor substrate 2 or forming more above-mentioned IC devices 7 in and on the semiconductor substrate 2. Besides, the pitch between the neighboring two of the TSVs 77 can be dramatically reduced, such as between 1 and 20 micrometers, between 1 and 10 micrometers or between 2 and 6 micrometers.

Next, an adhesion layer can be formed on the contact points 10a, on sidewalls of the TSVs 77, on sidewalls and bottoms of the trenches in the dielectric layer 36, and on a top surface of the dielectric layer 36 by using a suitable process, such as sputtering process. The adhesion layer can be a metal layer, such as titanium, a titanium-tungsten alloy, titanium nitride, chromium, tantalum or tantalum nitride, having a suitable thickness, such as between 10 nanometers and 0.8 micrometers.

Next, a seed layer can be formed on the adhesion layer, at the sidewalls of the TSVs 77, at the sidewalls and bottoms of the trenches in the dielectric layer 36, and over the top surface of the dielectric layer 36 by using a suitable process, such as sputtering process. The seed layer can be a metal layer, such as copper, a titanium-copper alloy, gold or nickel, having a suitable thickness, such as between 10 nanometers and 0.8 micrometers.

Next, a conduction layer can be formed on the seed layer, in the TSVs 77, in the trenches in the dielectric layer 36, and over the top surface of the dielectric layer 36 by using a suitable process, such as electroplating process. The conduction layer can be a metal layer, such as copper, gold or nickel.

Next, the adhesion, seed and conduction layers are ground or polished by using a suitable process, such as chemical-mechanical-polishing (CMP) process, mechanical polishing process, mechanical grinding process or a process including mechanical polishing and chemical etching, until the dielectric layer 36 has an exposed top surface 36s, over which there are no portions of the adhesion, seed and conduction layers, and the adhesion, seed and conduction layers outside the trenches in the dielectric layer 36 are removed. Thereby, the adhesion, seed and conduction layers in the TSVs 77 and in the trenches in the dielectric layer 36 compose the metal interconnects 86. Each of the metal interconnects 86 can be divided into one or more TSV interconnects 214 in one or more of the TSVs 77, and an overlying interconnect 214a (such as metal trace) over the semiconductor wafer 210, over the TSV interconnect(s) 214 and in one of the trenches in the dielectric layer 36. Each of the overlying interconnects 214a may have a top surface substantially coplanar with the exposed top surface 36s of the dielectric layer 36 and may have a suitable thickness, such as between 0.1 and 5 micrometers, between 0.1 and 1 micrometers, between 0.2 and 1.5 micrometers, between 0.5 and 2 micrometers, between 0.3 and 5 micrometers or between 0.3 and 10 micrometers. The dielectric layer 34 may be used as an insulating layer between the overlying interconnects 214a and the semiconductor substrate 2 of the semiconductor wafer 210. The TSV interconnects 214 in the TSVs 77 can contact the contact points 10a of the semiconductor wafer 210 and can be enclosed by the isolation enclosures 202 of the semiconductor wafer 210. The TSV interconnects 214 can connect the overlying interconnects 214a to the contact points 10a of the semiconductor wafer 210.

In one example, the metal interconnects 86 may include a titanium-containing layer (that is the adhesion layer), such as titanium, a titanium-tungsten alloy or titanium nitride, having a thickness between 10 nanometers and 0.8 micrometers on the contact points 10a, on the sidewalls of the TSVs 77, and on the sidewalls and bottoms of the trenches in the dielectric layer 36, a copper-containing layer (that is the seed layer), such as copper or a titanium-copper alloy, having a thickness between 10 nanometers and 0.8 micrometers on the titanium-containing layer, at the sidewalls of the TSVs 77, and at the sidewalls and bottoms of the trenches in the dielectric layer 36, and an electroplated copper layer (that is the conduction layer) on the copper-containing layer, in the TSVs 77, and in the trenches in the dielectric layer 36. The electroplated copper layer in the trenches in the dielectric layer 36 may have a suitable thickness, such as between 0.1 and 5 micrometers, between 0.1 and 1 micrometer, between 0.2 and 1.5 micrometers, between 0.5 and 2 micrometers, between 0.3 and 5 micrometers or between 0.3 and 10 micrometers. Alternatively, the titanium-containing layer can be replaced with a tantalum-containing layer, such as tantalum or tantalum nitride.

Next, referring to FIG. 82, a second semiconductor wafer 211 can be flipped (faced down) and bonded over the backside of the semiconductor substrate 2 of the first semiconductor wafer 210, e.g., by the following steps. First, an insulating layer 44 can be formed by forming a silicon-containing layer, such as silicon nitride, silicon oxynitride or silicon carbon nitride, having a suitable thickness, such as between 0.3 and 1.5 micrometers or between 0.01 and 0.5 micrometers, on the exposed top surface 36s of the dielectric layer 36 and on the top surfaces of the overlying interconnects 214a, and then forming an adhesive layer, such as polymer layer, on the silicon-containing layer. Next, the adhesive layer of the insulating layer 44 can be optionally pre-cured or baked. Next, using the alignment marks 206 of the wafer 210 to align the second wafer 211 with the first wafer 210 with accuracy, the second semiconductor wafer 211 can be flipped placed over the backside of the substrate 2 of the first semiconductor wafer 210 with the adhesive layer of the insulating layer 44 between the wafers 210 and 211. Next, the adhesive layer of the insulating layer 44 can be cured again in a temperature between 180 degrees centigrade and 350 degrees centigrade with a mechanical or thermal pressure on the adhesive layer. Thereby, the second semiconductor wafer 211 can be bonded over the first semiconductor wafer 210 using the adhesive layer of the insulating layer 44, and the adhesive layer of the insulating layer 44 may have a suitable thickness, such as between 1 and 100 micrometers, between 1 and 15 micrometers, between 0.1 and 10 micrometers, between 0.1 and 5 micrometers or between 0.1 and 1 micrometers. The passivation layer 20 of the second semiconductor wafer 211 can face the backside of the substrate 2 of the first semiconductor wafer 210.

The semiconductor wafer 211 may include the semiconductor substrate 2, the STI layer 6, the DTI layer 4, the IC devices 7, the IC scheme 208 and the passivation layer 20, as mentioned above in the semiconductor wafer 210. The semiconductor wafer 211 may have a same layout of the DTI layer 4 as that of the DTI layer 4 of the semiconductor wafer 210, a different layout of the DTI layer 4 from that of the DTI layer 4 of the semiconductor wafer 210, a same layout of the conductive layer 10 or 16 as that of the conductive layer 10 or 16 of the semiconductor wafer 210, or a different layout of the conductive layer 10 or 16 from that of the conductive layer 10 or 16 of the semiconductor wafer 210. Alternatively, the semiconductor wafers 210 and 211 may be same wafers having a same die marking and/or having a same layout of the DTI layer 4.

In one embodiment, the semiconductor wafer 211 may have a top surface with a profile that is substantially same as that of a top surface of the semiconductor wafer 210, that is, when the semiconductor wafer 210 is a round wafer, the semiconductor wafer 211 can be a round wafer having a same diameter as that of the round wafer 210.

Alternatively, the adhesive layer of the insulating layer 44 can be a silicon-oxide layer formed on the above-mentioned silicon-containing layer of the insulating layer 44, and using the alignment marks 206 of the wafer 210 to align the second wafer 211 with the first wafer 210 with accuracy, the second wafer 211 can be bonded over the first wafer 210, e.g., by bonding a silicon-oxide layer of the passivation layer 20 of the second wafer 211 onto the silicon-oxide layer of the insulating layer 44.

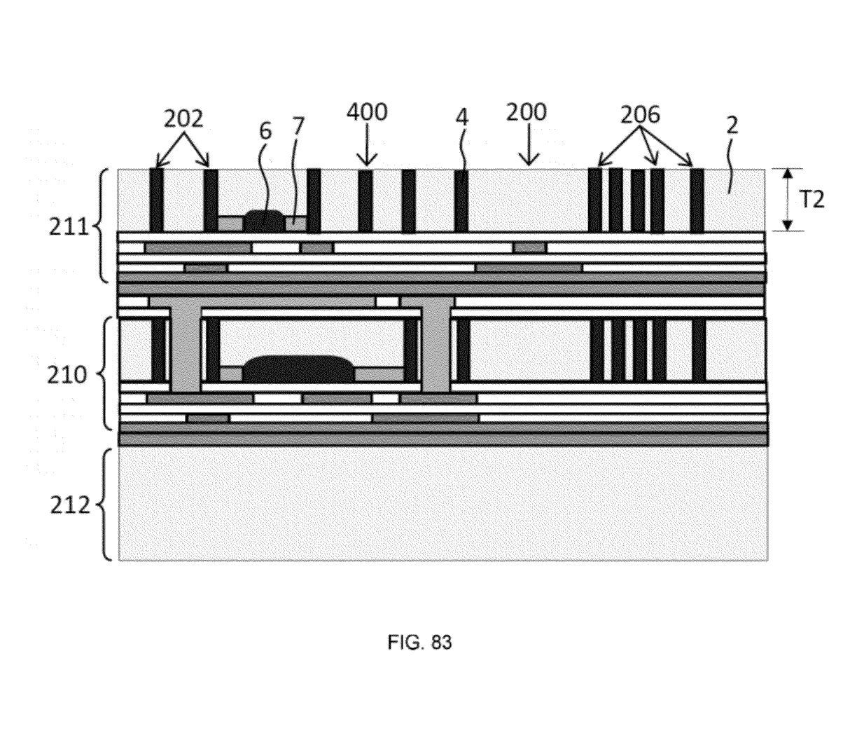

Next, referring to FIG. 83, the backside of the semiconductor substrate 2 of the semiconductor wafer 211 can be ground or polished by a suitable process, such as chemical-mechanical-polishing (CMP) process, mechanical polishing process, mechanical grinding process or a process including mechanical polishing and chemical etching, until the DTI layer 4 in the semiconductor substrate 2 of the wafer 211 has an exposed bottom surface 400, over which there is no portion of the semiconductor substrates 2 of the wafer 211.

Accordingly, the semiconductor substrate 2 of the wafer 211 can be thinned to a suitable thickness T2, such as between 1 and 100 micrometers, between 1 and 50 micrometers, between 1 and 20 micrometers, between 1 and 10 micrometers, between 1 and 5 micrometers, or between 2 and 5 micrometers. The ground or polished surface 200 of the substrate 2 of the wafer 211 may be substantially coplanar with the exposed bottom surface 400 of the DTI layer 4 of the wafer 211, and the DTI layer 4 of the wafer 211 may have a same thickness as the thickness T2 of the semiconductor substrate 2 of the wafer 211. Filled oxides and/or nitrides at the bottom end 400 of the DTI layer 4 of the wafer 211 may be exposed. The DTI layer 4 of the wafer 211 may be used as the backside alignment marks 206 for forming metal interconnects 86a and used as the isolation enclosures 202 for enclosing through silicon/substrate vias (TSVs) 77a, 77b and 77c passing through the substrate 2 of the wafer 211 as discussed below.

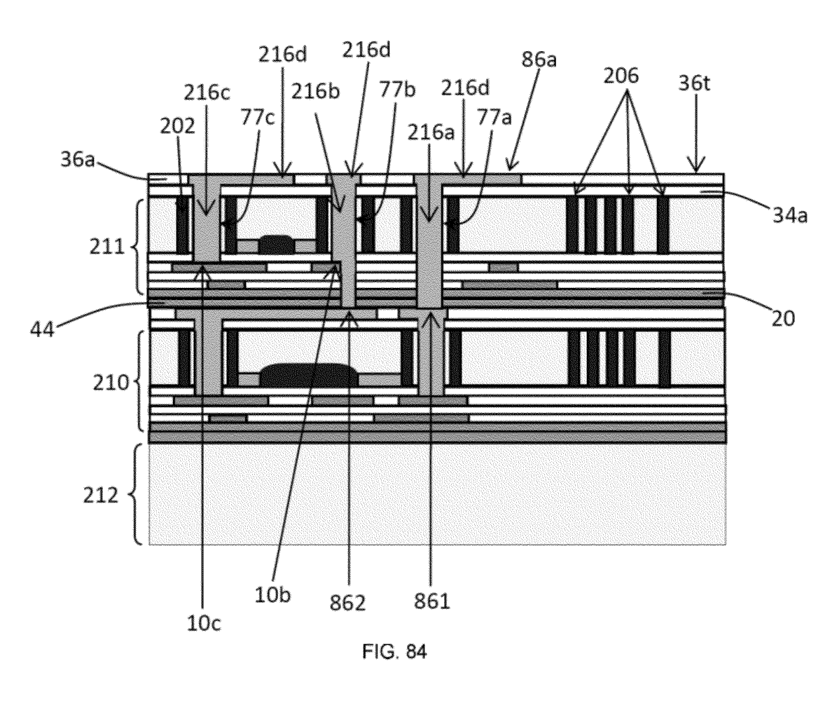

Next, referring to FIG. 84, a process of forming the metal interconnects 86a is illustrated as below. First, a dielectric or insulating layer 34a can be formed on the ground or polished surface 200 of the substrate 2 of the wafer 211 and on the exposed bottom surface 400 of the DTI layer 4 of the wafer 211. The dielectric layer 34a may be a silicon-containing layer, such as silicon nitride, silicon oxide, silicon oxynitride or silicon carbon nitride, having a suitable thickness, such as between 0.1 and 1.5 micrometers, between 0.2 and 2 micrometers, between 0.3 and 5 micrometers or between 0.3 and 10 micrometers.

Next, a dielectric or insulating layer 36a can be formed on the dielectric layer 34a. The dielectric layer 36a can be a silicon-containing layer, such as silicon nitride, silicon oxide, silicon oxynitride or silicon carbon nitride, having a suitable thickness, such as between 0.1 and 1.5 micrometers, between 0.2 and 2 micrometers, between 0.3 and 5 micrometers or between 0.3 and 10 micrometers.

Next, using the alignment marks 206 of the wafer 211 to align a photo mask with the wafer 211 with accuracy, multiple trenches can be formed, in a desired position, in the dielectric layer 36a based on the pattern of the photo mask and expose the dielectric layer 34a by an etching process.

Next, using the alignment marks 206 of the wafer 211 to align a photo mask with the wafer 211 with accuracy, multiple TSVs 77a, 77b and 77c can be formed, in a desired position, in and through the wafer 211 based on the pattern of the photo mask and expose multiple contact points 10b and 10c of the conductive layer 10 of the wafer 211 and multiple contact points 861 and 862 of the overlying interconnects 214a by a suitable process, such as etching process. The TSVs 77a (one of them is shown) may pass through the dielectric layer 34a under some of the trenches in the dielectric layer 36a, through portions of the substrate 2 enclosed by some of the isolation enclosures 202 of the wafer 211, through the dielectric layers 8, 12, 14 and 18 of the wafer 211, through the passivation layer 20 of the wafer 211, and through the insulating layer 44 to expose the contact points 861 (one of them is shown) of some of the overlying interconnects 214a. The TSVs 77b (one of them is shown) may pass through the dielectric layer 34a under some of the trenches in the dielectric layer 36a, through portions of the substrate 2 enclosed by some of the isolation enclosures 202 of the wafer 211, through the dielectric layers 8, 12, 14 and 18 of the wafer 211, through the passivation layer 20 of the wafer 211, and through the insulating layer 44 to expose the contact points 10b (one of them is shown) of the conductive layer 10 of the wafer 211 and the contact points 862 (one of them is shown) of some of the overlying interconnects 214a. The TSVs 77c (one of them is shown) may pass through the dielectric layer 34a under some of the trenches in the dielectric layer 36a, through portions of the substrate 2 enclosed by some of the isolation enclosures 202 of the wafer 211, and through the dielectric layer 8 of the wafer 211 to expose the contact points 10c (one of them is shown) of the conductive layer 10 of the wafer 211.

By means of the alignment marks 206 of the wafer 211, each of the isolation enclosures 202 of the wafer 211 may have a reduced inner diameter, such as between 0.1 and 10 micrometers, between 0.1 and 5 micrometers, between 0.1 and 2 micrometers or between 0.1 and 1 micrometers, accommodating the TSVs 77a, 77b and 77c, and the semiconductor wafer 211 has much space spared for forming much more TSVs in the semiconductor substrate 2 or forming more above-mentioned IC devices 7 in and on the semiconductor substrate 2. Besides, the pitch between the neighboring two of the TSVs 77a, 77b and 77c can be dramatically reduced, such as between 1 and 20 micrometers, between 1 and 10 micrometers or between 2 and 6 micrometers.

Next, an adhesion layer can be formed on the contact points 10b, 10c, 861 and 862, on sidewalls of the TSVs 77a, 77b and 77c, on sidewalls and bottoms of the trenches in the dielectric layer 36a, and on a top surface of the dielectric layer 36a by using a suitable process, such as sputtering process. The adhesion layer can be a metal layer, such as titanium, a titanium-tungsten alloy, titanium nitride, chromium, tantalum or tantalum nitride, having a suitable thickness, such as between 10 nanometers and 0.8 micrometers.

Next, a seed layer can be formed on the adhesion layer, at the sidewalls of the TSVs 77a, 77b and 77c, at the sidewalls and bottoms of the trenches in the dielectric layer 36a, and over the top surface of the dielectric layer 36a by using a suitable process, such as sputtering process. The seed layer can be a metal layer, such as copper, a titanium-copper alloy, gold or nickel, having a suitable thickness, such as between 10 nanometers and 0.8 micrometers.

Next, a conduction layer can be formed on the seed layer, in the TSVs 77a, 77b and 77c, in the trenches in the dielectric layer 36a, and over the top surface of the dielectric layer 36a by using a suitable process, such as electroplating process. The conduction layer can be a metal layer, such as copper, gold or nickel.

Next, the adhesion, seed and conduction layers are ground or polished by using a suitable process, such as chemical-mechanical-polishing (CMP) process, mechanical polishing process, mechanical grinding process or a process including mechanical polishing and chemical etching, until the dielectric layer 36a has an exposed top surface 36t, over which there are no portions of the adhesion, seed and conduction layers, and the adhesion, seed and conduction layers outside the trenches in the dielectric layer 36a are removed. Thereby, the adhesion, seed and conduction layers in the TSVs 77a, 77b and 77c and in the trenches in the dielectric layer 36a compose the metal interconnects 86a. The metal interconnects 86a can be divided into TSV interconnects 216a, 216b and 216c in the TSVs 77a, 77b and 77c, and overlying interconnects 216d over the semiconductor wafer 211, over the TSV interconnects 216a, 216b and 216c, and in the trenches in the dielectric layer 36a. Each of the overlying interconnects 216d may have a top surface substantially coplanar with the exposed top surface 36t of the dielectric layer 36a and may have a suitable thickness, such as between 0.1 and 5 micrometers, between 0.1 and 1 micrometers, between 0.2 and 1.5 micrometers, between 0.5 and 2 micrometers, between 0.3 and 5 micrometers or between 0.3 and 10 micrometers. The dielectric layer 34a may be used as an insulating layer between the overlying interconnects 216d and the semiconductor substrate 2 of the semiconductor wafer 211. The TSV interconnects 216a (one of them is shown) in the TSVs 77a can contact the contact points 861 and can be enclosed by some of the isolation enclosures 202 of the wafer 211. The TSV interconnects 216a can connect some of the overlying interconnects 216d to the contact points 861. The TSV interconnects 216b (one of them is shown) in the TSVs 77b can contact the contact points 10b and 862 and can be enclosed by some of the isolation enclosures 202 of the wafer 211. The TSV interconnects 216b can connect some of the overlying interconnects 216d to the contact points 10b and to the contact points 862 and can connect the contact points 10b to contact points 862. The TSV interconnects 216c (one of them is shown) in the TSVs 77c can contact the contact points 10c and can be enclosed by some of the isolation enclosures 202 of the wafer 211. The TSV interconnects 216c can connect some of the overlying interconnects 216d to the contact points 10c.

In one example, the metal interconnects 86a may include a titanium-containing layer (that is the adhesion layer), such as titanium, a titanium-tungsten alloy or titanium nitride, having a thickness between 10 nanometers and 0.8 micrometers on the contact points 10b, 10c, 861 and 862, on the sidewalls of the TSVs 77a, 77b and 77c, and on the sidewalls and bottoms of the trenches in the dielectric layer 36a, a copper-containing layer (that is the seed layer), such as copper or a titanium-copper alloy, having a thickness between 10 nanometers and 0.8 micrometers on the titanium-containing layer, at the sidewalls of the TSVs 77a, 77b and 77c, and at the sidewalls and bottoms of the trenches in the dielectric layer 36a, and an electroplated copper layer (that is the conduction layer) on the copper-containing layer, in the TSVs 77a, 77b and 77c, and in the trenches in the dielectric layer 36a. The electroplated copper layer in the trenches in the dielectric layer 36a may have a suitable thickness, such as between 0.1 and 5 micrometers, between 0.1 and 1 micrometer, between 0.2 and 1.5 micrometers, between 0.5 and 2 micrometers, between 0.3 and 5 micrometers or between 0.3 and 10 micrometers. Alternatively, the titanium-containing layer can be replaced with a tantalum-containing layer, such as tantalum or tantalum nitride.

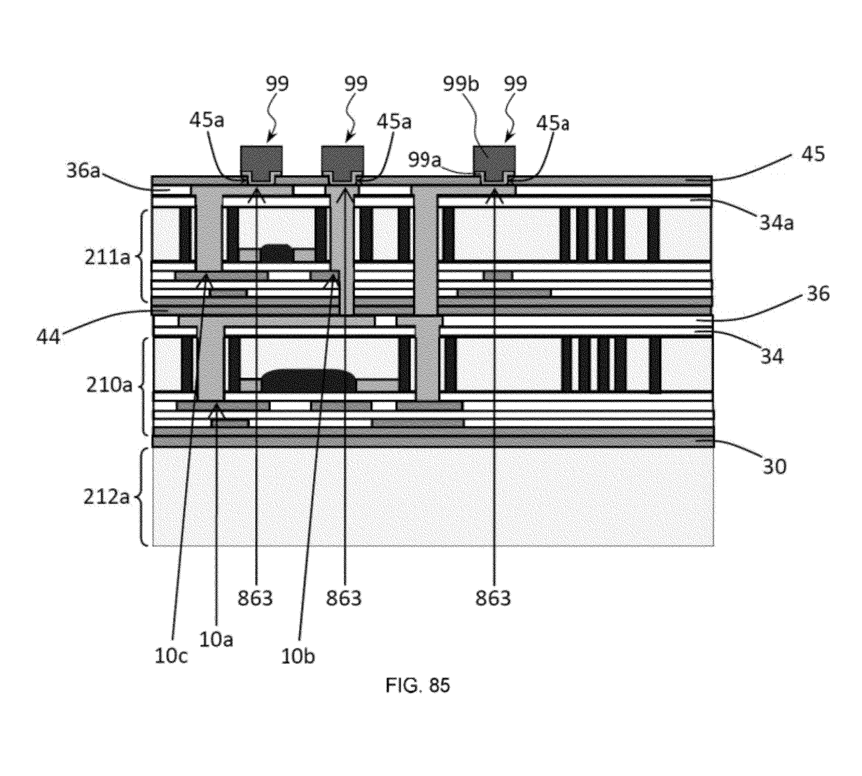

Next, referring to FIG. 85, an insulating layer 45 can be formed on the exposed top surface 36t of the dielectric layer 36a and on the top surfaces of the overlying interconnects 216d. In one example, the insulating layer 45 may include an oxide layer, such as silicon oxide, having a thickness between 0.2 and 1.5 micrometers on the exposed top surface 36t and on the top surfaces of the overlying interconnects 216d, and a nitride layer, such as silicon nitride or silicon oxynitride, having a thickness between 0.2 and 1.5 micrometers on the oxide layer. Alternatively, the insulating layer 45 may be composed of a silicon-containing layer, such as silicon nitride, silicon oxynitride or silicon oxide, having a thickness between 0.2 and 2 micrometers on the exposed top surface 36t and on the top surfaces of the overlying interconnects 216d, and a polymer layer, such as polyimide, benzocyclobutene (BCB), epoxy, polybenzoxazole (PBO) or Poly(p-phenylene oxide) (PPO), having a thickness greater than the thickness of the silicon-containing layer and between 2 and 30 micrometers on the silicon-containing layer. Multiple openings 45a in the insulating layer 45 are over multiple contact points 863 of the overlying interconnects 216d, and the contact points 863 are at bottoms of the openings 45a. The openings 45a expose the contact points 863, and each of the openings 45a may have a suitable width or diameter, such as between 0.3 and 5 micrometer, 0.5 and 10 micrometers or 10 and 100 micrometers.

Next, multiple metal pillars or bumps 99 can be formed on the contact points 863, on the insulating layer 45 and in the openings 45a by using a suitable process. Each of the metal pillars or bumps 99 may have a suitable height, such as between 5 and 300 micrometers, between 5 and 30 micrometers or between 10 and 100 micrometers, and may include a metal layer 99a and a metal layer 99b on the metal layer 99a. The metal layer 99a may be composed of an adhesion layer on the contact points 863, on the insulating layer 45 and in the openings 45a, and a seed layer on the adhesion layer. The adhesion layer may include or can be a titanium-containing layer, such as titanium, titanium nitride or a titanium-tungsten alloy, having a suitable thickness, such as between 1 nanometer and 0.5 micrometers or between 10 nanometers and 0.8 micrometers, on the contact points 863, on the insulating layer 45 and in the openings 45a. Alternatively, the adhesion layer may include or can be a tantalum-containing layer, such as tantalum or tantalum nitride, having a suitable thickness, such as between 1 nanometer and 0.5 micrometers or between 10 nanometers and 0.8 micrometers, on the contact points 863, on the insulating layer 45 and in the openings 45a. The seed layer may include or can be a layer of copper, a titanium-copper alloy, nickel or gold having a suitable thickness, such as between 10 nanometers and 0.8 micrometers, on the adhesion layer. The metal layer 99b may include or can be an electroplated copper layer with a suitable thickness, such as between 5 and 30 micrometers or between 10 and 100 micrometers, on the seed layer of copper or a titanium-copper alloy, for instance. Alternatively, the metal layer 99b may include or can be a nickel layer with a suitable thickness, such as between 5 and 30 micrometers, on the seed layer of nickel, copper or a titanium-copper alloy, for instance. Alternatively, the metal layer 99b may include or can be a gold layer with a suitable thickness, such as between 5 and 30 micrometers, on the seed layer of gold, for instance. Alternatively, the metal layer 99b may include an electroplated copper layer with a suitable thickness, such as between 1 and 10 micrometers or between 2 and 5 micrometers, on the seed layer of copper or a titanium-copper alloy, for instance, an electroplated or electroless plated nickel layer with a suitable thickness, such as between 0.1 and 2 micrometers or between 0.5 and 5 micrometers, on the electroplated copper layer, and a tin-containing layer, such as a tin-lead alloy, a tin-silver alloy, a tin-silver-copper alloy or a tin-gold alloy, with a suitable thickness, such as between 30 and 100 micrometers or between 50 and 300 micrometers, on the electroplated or electroless plated nickel layer. Alternatively, the metal layer 99b may include an electroplated copper layer with a suitable thickness, such as between 10 and 100 micrometers, on the seed layer of copper or a titanium-copper alloy, for instance, an electroplated or electroless plated nickel layer with a suitable thickness, such as between 0.1 and 1 micrometers or between 0.5 and 2 micrometers, on the electroplated copper layer, and an electroplated or electroless plated gold layer with a suitable thickness, such as between 0.1 and 1 micrometers or between 0.5 and 2 micrometers, on the electroplated or electroless plated nickel layer. Alternatively, the metal layer 99b may include an electroplated copper layer with a suitable thickness, such as between 1 and 10 micrometers or between 2 and 5 micrometers, on the seed layer of copper or a titanium-copper alloy, for instance, and a tin-containing layer, such as a tin-lead alloy, a tin-silver alloy, a tin-silver-copper alloy or a tin-gold alloy, with a suitable thickness, such as between 30 and 100 micrometers, on the electroplated copper layer.

After forming the metal pillars or bumps 99, a singulation process can be performed to cut the supporting substrate 212 shown in FIG. 84, the semiconductor wafers 210 and 211 shown in FIG. 84, the insulating layers 44 and 45, the dielectric layers 34, 34a, 36 and 36a, and the adhesive layer 30 into a plurality of the multichip package, shown in FIG. 85, including a chip 210a cut from the semiconductor wafer 210 shown in FIG. 84, a chip 211a cut from the semiconductor wafer 211 shown in FIG. 84, and a substrate 212a cut from the supporting substrate 212 shown in FIG. 84. The multichip package can be physically and electrically connected to an external circuit of the multichip package, such as mother board, printed circuit board, glass substrate, ceramic substrate or flexible substrate, using the metal pillars or bumps 99.

The stacked chips 210a and 211a may be memory chips, such as NAND-Flash memory chips, Flash memory chips, DRAM chips, SRAM chips, or SDRAM chips. The substrate 212a may be a silicon substrate, a glass substrate, or a ceramic substrate. Alternatively, if the supporting substrate 212 is a semiconductor wafer, the substrate 212a can be a memory chip, such as NAND-Flash memory chip, Flash memory chip, DRAM chip, SRAM chip or SDRAM chip, a central-processing-unit (CPU) chip, a graphics-processing-unit (GPU) chip, a digital-signal-processing (DSP) chip, a baseband chip, a wireless local area network (WLAN) chip, a logic chip, an analog chip, a global-positioning-system (GPS) chip, a “Bluetooth” chip, or a chip including one or more of a CPU circuit block, a GPU circuit block, a DSP circuit block, a memory circuit block (such as DRAM circuit block, SRAM circuit block, SDRAM circuit block, Flash memory circuit block, or NAND-Flash memory circuit block), a baseband circuit block, a Bluetooth circuit block, a GPS circuit block, a WLAN circuit block, and a modem circuit block, from the semiconductor wafer.

The semiconductor chip 210a, for example, may have a top surface with a profile that is substantially same as that of a top surface of the substrate 212a and that of a top surface of the semiconductor chip 211a. The semiconductor chip 210a may have a same length as that of the semiconductor chip 211a and that of the substrate 212a, and/or may have a same width as that of the semiconductor chip 211a and that of the substrate 212a. The semiconductor chip 210a, for example, may have a different layout of the DTI layer 4 from that of the DTI layer 4 of the semiconductor chip 211a, a different layout of the conductive layer 10 or 16 from that of the conductive layer 10 or 16 of the semiconductor chip 211a, or a same layout of the conductive layer 10 or 16 as that of the conductive layer 10 or 16 of the semiconductor chip 211a. Alternatively, the semiconductor chips 210a and 211a may be same chips having a same die marking and/or having a same layout of the DTI layer 4.

The overlying interconnects 216d, shown in FIG. 84, of the multichip package may be or include signal interconnects, power interconnects or ground interconnects. The TSV interconnect 216a, shown in FIG. 84, of the multichip package may be a signal interconnect, a power interconnect or a ground interconnect. The TSV interconnect 216b, shown in FIG. 84, of the multichip package may be a signal interconnect, a power interconnect or a ground interconnect. The TSV interconnect 216c, shown in FIG. 84, of the multichip package may be a signal interconnect, a power interconnect or a ground interconnect. The overlying interconnects 214a, shown in FIG. 81, of the multichip package may be or include signal interconnects, power interconnects or ground interconnects. The TSV interconnects 214, shown in FIG. 81, of the multichip package may be or include signal interconnects, power interconnects or ground interconnects.

A pitch between the neighboring two of the metal pillars or bumps 99 may be between 20 and 50 micrometers, between 30 and 100 micrometers, or between 100 and 300 micrometers. Some of the metal pillars or bumps 99 of the multichip package can be signal interconnects, power interconnects, or ground interconnects. For example, the middle one of the metal pillars or bumps 99 shown in FIG. 85 can be a power interconnect, for delivering power input from the above-mentioned external circuit of the multichip package, connected to one or more of the IC devices 7 of the chip 211a through, in sequence, the middle one of the overlying interconnects 216d shown in FIG. 84, the TSV interconnect 216b shown in FIG. 84, and the contact point 10b of the chip 211a, and connected to one or more of the IC devices 7 of the chip 210a through, in sequence, the middle one of the overlying interconnects 216d shown in FIG. 84, the TSV interconnect 216b shown in FIG. 84, the left one of the overlying interconnects 214a shown in FIG. 81, the left one of the TSV interconnects 214 shown in FIG. 81, and the left one of the contact points 10a of the chip 210a.

Alternatively, the middle one of the metal pillars or bumps 99 shown in FIG. 85 can be a ground interconnect, for delivering ground, connected to one or more of the IC devices 7 of the chip 211a through, in sequence, the middle one of the overlying interconnects 216d shown in FIG. 84, the TSV interconnect 216b shown in FIG. 84, and the contact point 10b of the chip 211a, and connected to one or more of the IC devices 7 of the chip 210a through, in sequence, the middle one of the overlying interconnects 216d shown in FIG. 84, the TSV interconnect 216b shown in FIG. 84, the left one of the overlying interconnects 214a shown in FIG. 81, the left one of the TSV interconnects 214 shown in FIG. 81, and the left one of the contact points 10a of the chip 210a.

Alternatively, the middle one of the metal pillars or bumps 99 shown in FIG. 85 can be a signal interconnect for transmitting signal, clock or data input from the above-mentioned external circuit of the multichip package to one of the IC devices 7 of the chip 211a through, in sequence, the middle one of the overlying interconnects 216d shown in FIG. 84, the TSV interconnect 216b shown in FIG. 84, and the contact point 10b of the chip 211a, and to one of the IC devices 7 of the chip 210a through, in sequence, the middle one of the overlying interconnects 216d shown in FIG. 84, the TSV interconnect 216b shown in FIG. 84, the left one of the overlying interconnects 214a shown in FIG. 81, the left one of the TSV interconnects 214 shown in FIG. 81, and the left one of the contact points 10a of the chip 210a.

Alternatively, the middle one of the metal pillars or bumps 99 shown in FIG. 85 can be a signal interconnect for transmitting signal, clock or data input from one of the IC devices 7 of the chip 211a to the above-mentioned external circuit of the multichip package through, in sequence, the contact point 10b of the chip 211a, the TSV interconnect 216b shown in FIG. 84, and the middle one of the overlying interconnects 216d shown in FIG. 84, or for transmitting signal, clock or data input from one of the IC devices 7 of the chip 210a to the above-mentioned external circuit of the multichip package through, in sequence, the left one of the contact points 10a of the chip 210a, the left one of the TSV interconnects 214 shown in FIG. 81, the left one of the overlying interconnects 214a shown in FIG. 81, the TSV interconnect 216b shown in FIG. 84, and the middle one of the overlying interconnects 216d shown in FIG. 84.

The contact point 10c of the chip 211a, which is connected to one of the IC devices 7 of the chip 211a, may be physically and electrically connected to the contact point 10b of the chip 211a, which is connected to another one of the IC devices 7 of the chip 211a, through, in sequence, the TSV interconnect 216c shown in FIG. 84, one of the overlying interconnects 216d shown in FIG. 84, and the TSV interconnect 216b shown in FIG. 84, and the contact point 10b of the chip 211a may be physically and electrically connected to the left one of the contact points 10a of the chip 210a, which is connected to one of the IC devices 7 of the chip 210a, through, in sequence, the TSV interconnect 216b shown in FIG. 84, one of the overlying interconnects 214a shown in FIG. 81, and the left one of the TSV interconnects 214 shown in FIG. 81. In this case, the path connecting the contact points 10b and 10c and the left one of the contact points 10a may be connected to one or more of the metal pillars or bumps 99 for access to the above-mentioned external circuit of the multichip package. Alternatively, the path connecting the contact points 10b and 10c and the left one of the contact points 10a may be not connected to any metal pillar or bump 99 for access to any external circuit of the multichip package.

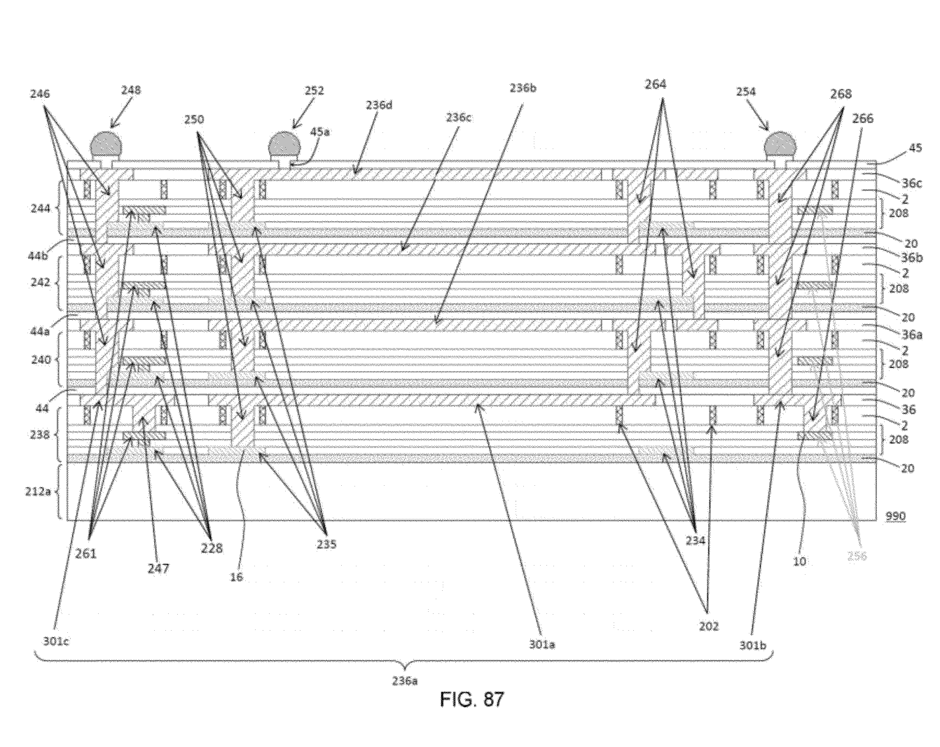

Alternatively, the multichip package can include more than two stacked chips, such as four stacked memory chips illustrated in FIG. 87, six stacked memory chips, eight stacked memory chips or sixteen stacked memory chips, over the substrate 212a by repeating the steps illustrated in FIGS. 82-84 by many times, that is, placing another semiconductor wafer over the topmost one of the stacked semiconductor wafers by the face-down fashion, as illustrated in FIG. 82, next grinding or polishing the backside of the semiconductor substrate of the another semiconductor wafer to expose DTI layer in the semiconductor substrate thereof, as illustrated in FIG. 83, and then forming metal interconnects in TSVs through the semiconductor substrate thereof and in trenches in a dielectric layer over the backside of the semiconductor substrate thereof, as illustrated in FIG. 84, by many times, and then by performing the steps illustrated in FIG. 85, that is, forming the insulating layer 45 over the topmost one of the stacked wafers and on the topmost one of the metal interconnects, next forming the metal pillars or bumps 99 on the topmost one of the metal interconnects, and then cutting the stacked wafers and the supporting substrate 212 into a plurality of the multichip package.

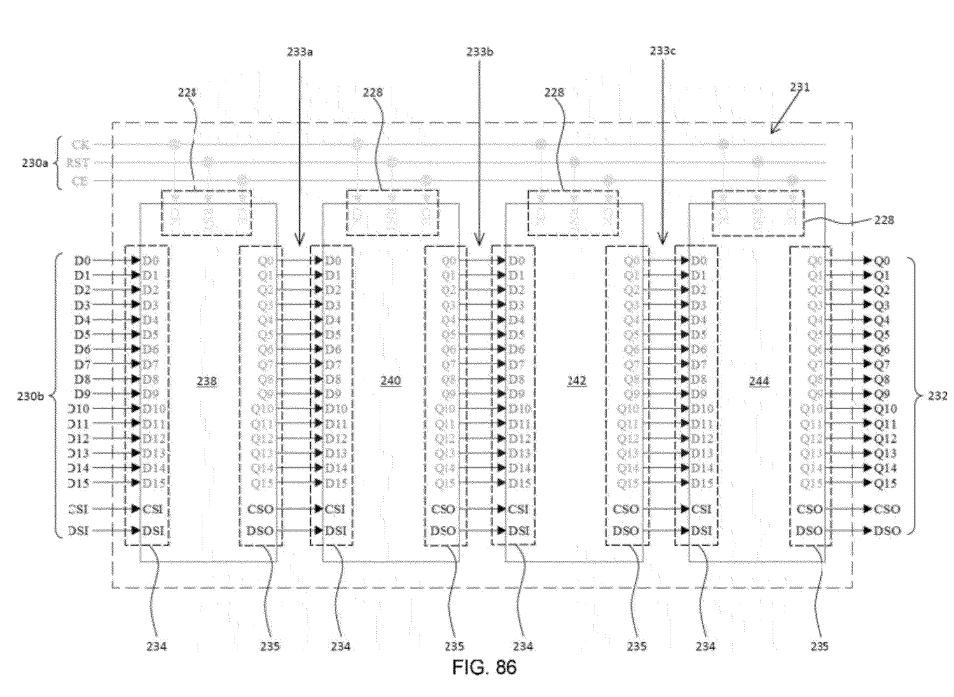

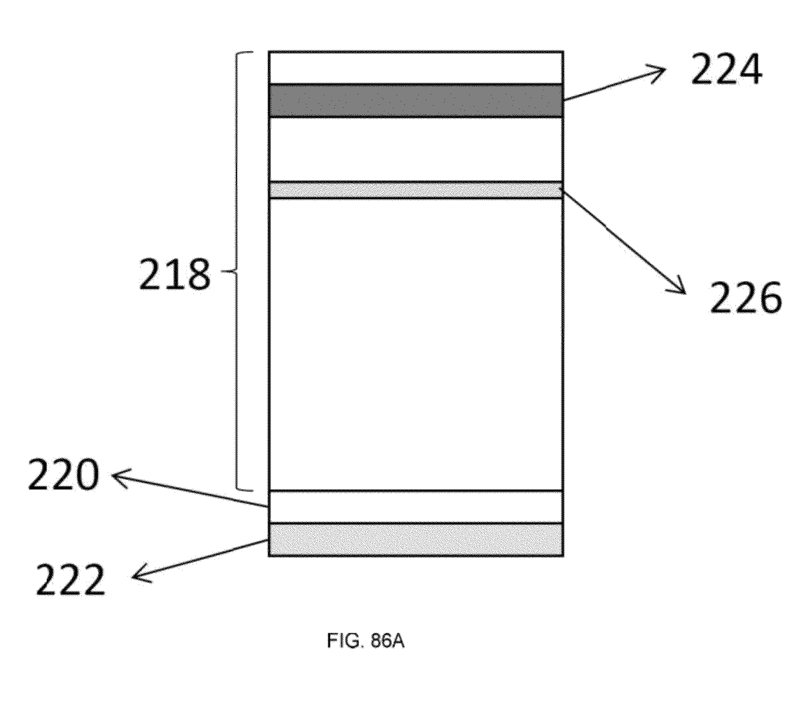

FIG. 86 illustrates a schematic circuit diagram of a data storage device according to an exemplary embodiment of the present disclosure. The data storage device, for example, can be a solid-state drive (SSD), an universal serial bus (USB) device, an embedded multi media device, or a mSATA (mini serial advanced technology attachment) SSD. The data storage device includes any suitable number of suitable semiconductor chips, such as four memory chips 238, 240, 242 and 244. Alternatively, the data storage device may include at least four, at least eight or at least twelve memory chips including the memory chips 238, 240, 242 and 244. The memory chips 238, 240, 242 and 244 can be non-volatile memory chips, such as phase-change memory (PCM) chips, ferroelectric memory chips, magnetoresistive memory chips, racetrack memory chips, electrically-erasable programmable read-only memory (EEPROM) chips, erasable programmable read-only memory (EPROM) chips, or flash memory chips (such as NAND-Flash memory chips or NOR-Flash memory chips). Each of the memory chips 238, 240, 242 and 244 includes serial input ports 234 (shown as sixteen data input ports D0-D15, CSI (command strobe input) and DSI (data strobe input)), serial output ports 235 (shown as sixteen data output ports Q0-Q15, CSO (command strobe output) and DSO (data strobe output)), and parallel common input ports 228 (shown as ports CK, RST and CE). In this case, each of the memory chips 238, 240, 242 and 244 may have a data width of by-sixteen bits, that is, including the sixteen data input ports D0-D15 and the sixteen data output ports Q0-Q15. Alternatively, each of the memory chips 238, 240, 242 and 244 may have a data width of by-one bit, that is, including only one data input port D0 and only one data output port Q0, or may have a data width of by-eight bits, that is, including the data input ports D0-D7 and the data output ports Q0-Q7.

In each of the memory chips 238, 240, 242 and 244, each input port 234 is paired with a corresponding output port 235. That is, each of the memory chips 238, 240, 242 and 244 contains the output ports Q0-Q15 and the input ports D0-D15 paired with the corresponding output ports Q0-Q15, respectively. Each of the memory chips 238, 240, 242 and 244 contains the output port CSO and the input port CSI paired with the output port CSO. Each of the memory chips 238, 240, 242 and 244 contains the output port DSO and the input port DSI paired with the output port DSO. Each of the memory chips 238, 240, 242 and 244 may include circuit paths, signal or data paths, between the input-output pairs 234 and 235, from the serial input ports 234 to the corresponding serial output ports 235, that is, the circuit path between the input-output pair D0 and Q0 can transmit a signal, memory data, from the input port D0 to the output port Q0, for example. Each of the memory chips 238, 240, 242 and 244 includes memory cells to store data, and each of the circuit paths enables access to specific memory cells. Data flows in the memory chips 238, 240, 242 and 244 can be transmitted from the serial input ports 234 of the memory chips 238, 240, 242 and 244 to the corresponding serial output ports 235 of the memory chips 238, 240, 242 and 244, respectively.

Via a parallel connection 231, input signals 230a (shown as clock signal (CK), reset signal (RST) and chip enable signal (CE)) can be coupled to respective input ports 228 of the memory chips 238, 240, 242 and 244. That is, signal CK can drive respective input CK of each of the memory chips 238, 240, 242 and 244, signal RST can drive respective input RST of each of the memory chips 238, 240, 242 and 244, and signal CE can drive respective input CE of each of the memory chips 238, 240, 242 and 244. The parallel connection 231 may include metal interconnects connected to the input ports 228 of the memory chips 238, 240, 242 and 244.

External serial input signals 230b (shown as signals D0-D15, CSI and DSI to the memory chip 238) for the data storage device can be coupled to respective serial input ports 234 of the memory chip 238. The serial output ports 235 of the memory chip 238 can be connected in series to the serial input ports 234 of the memory chip 240 through a serial connection 233a between the serial output ports 235 of the memory chip 238 and the serial input ports 234 of the memory chip 240. Signals or Data output from the serial output ports 235 of the memory chip 238 can be transmitted to the serial input ports 234 of the memory chip 240 through the serial connection 233a. The serial connection 233a may include metal interconnects connecting the serial output ports 235 of the memory chip 238 and the serial input ports 234 of the memory chip 240. The serial output ports 235 of the memory chip 240 can be connected in series to the serial input ports 234 of the memory chip 242 through a serial connection 233b between the serial output ports 235 of the memory chip 240 and the serial input ports 234 of the memory chip 242. Signals or Data output from the serial output ports 235 of the memory chip 240 can be transmitted to the serial input ports 234 of the memory chip 242 through the serial connection 233b. The serial connection 233b may include metal interconnects connecting the serial output ports 235 of the memory chip 240 and the serial input ports 234 of the memory chip 242. The serial output ports 235 of the memory chip 242 can be connected in series to the serial input ports 234 of the memory chip 244 through a serial connection 233c between the serial output ports 235 of the memory chip 242 and the serial input ports 234 of the memory chip 244. Signals or Data output from the serial output ports 235 of the memory chip 242 can be transmitted to the serial input ports 234 of the memory chip 244 through the serial connection 233c. The serial connection 233c may include metal interconnects connecting the serial output ports 235 of the memory chip 242 and the serial input ports 234 of the memory chip 244. The serial output ports 235 of the memory chip 244 can be coupled with serial output signals 232 (shown as signals Q0-15, CSO and DSO) of the data storage device.

The input signals 230a (e.g., signals CK, RST and CE) may be input from an external circuit of the data storage device or a memory controller of the data storage device to the parallel common input ports 228 of the memory chips 238, 240, 242 and 244. The input signals 230b (e.g., signals D0-D15, CSI and DSI) may be input from the external circuit of the data storage device or the memory controller of the data storage device to the serial input ports 234 of the memory chip 238. The signals 232 (e.g., signals Q0-Q15, CSO and DSO) of the data storage device may be output from the serial output ports 235 of the memory chip 244 to the external circuit of the data storage device, the memory controller of the data storage device, or inputs of another successive data storage device. In some embodiments, a larger data storage device may include multiple storage devices in which one or more memory controllers enable access to data stored in respective memory chips.

FIG. 86A illustrates a block arrangement of each of the memory chips 238, 240, 242 and 244, especially for NAND-Flash memory chip. The block arrangement includes a user addressable block 218, a reserved (spare) block 220 and a system block 222. The user addressable block 218 may have a bad block 224 detected and recorded in a functional testing process in a wafer level or a package level, and a bad block 226 detected and recorded in a normal operation after the data storage device is installed in a system. A bad block table recording the positions of the bad blocks 224 and 226 may be stored in the system block 222 such that a memory controller of the data storage device may perform bad-block management. The memory controller may have a design architecture providing a mechanism to select good bits in and the memory chips 238, 240, 242 and 244 and to abandon bad bits in the memory chips 238, 240, 242 and 244. Thus, yield loss may not be a concern with stacked memory chips.

FIG. 87 illustrates a schematic cross-sectional view of a multichip package 990. In one example, the data storage device as mentioned in FIG. 86 may include a circuit substrate (not shown), the multichip package 990 joining and connecting to the circuit substrate, a memory controller (not shown) joining the circuit substrate and connecting to the multichip package 990, one or more DRAM chips (not shown) joining the circuit substrate, etc. The circuit substrate, for example, may be a mother board, a printed circuit board (PCB), a ball-grid-array (BGA) substrate, or a glass substrate. The schematic circuit diagram illustrated in FIG. 86 can be applied to the multichip package 990. The enclosure-first technology may be applied to the multichip package 990.

The multichip package 990 includes the substrate 212a as mentioned in FIG. 85 and the memory chips 238, 240, 242 and 244, as mentioned in FIG. 86, that are stacked over the substrate 212a. In the multichip package 990, the memory chips 238, 240, 242 and 244 are faced down. The multichip package 990 further includes multiple overlying interconnects 236a between the memory chips 238 and 240, multiple overlying interconnects 236b between the memory chips 240 and 242, multiple overlying interconnects 236c between the memory chips 242 and 244, multiple overlying interconnects 236d over the memory chip 244, multiple TSV interconnects 246, 264 and 268 vertically through the memory chips 240, 242 and 244, multiple TSV interconnects 247, 250 and 266 in the memory chips 238, 240, 242 and 244, the dielectric or insulating layer 36 as mentioned in FIG. 81 between the memory chips 238 and 240, the dielectric or insulating layer 36a as mentioned in FIG. 84 between the memory chips 240 and 242, a dielectric or insulating layer 36b between the memory chips 242 and 244, a dielectric or insulating layer 36c over the memory chip 244, the insulating layer 44 as mentioned in FIG. 82 on the overlying interconnects 236a and the dielectric or insulating layer 36 and under the memory chip 240, an insulating layer 44a on the overlying interconnects 236b and the dielectric or insulating layer 36a and under the memory chip 242, an insulating layer 44b on the overlying interconnects 236c and the dielectric or insulating layer 36b and under the memory chip 244, the insulating layer 45 as mentioned in FIG. 85 on the overlying interconnects 236d and the dielectric or insulating layer 36c, and multiple metal pillars or bumps 248, 252 and 254 over the memory chip 244 and on the insulating layer 45.

The multichip package 990 can be mounted over the above-mentioned circuit substrate by joining the metal pillars or bumps 248, 252 and 254 with a solder preformed on the circuit substrate, for example. The multichip package 990 can be connected to the circuit substrate through the metal pillars or bumps 248, 252 and 254.

The specifications of the dielectric or insulating layer 36b shown in FIG. 87 can be referred to as the specifications of the dielectric or insulating layer 36a as illustrated in FIG. 84. The specifications of the dielectric or insulating layer 36c shown in FIG. 87 can be referred to as the specifications of the dielectric or insulating layer 36a as illustrated in FIG. 84. The specifications of the insulating layer 44a shown in FIG. 87 can be referred to as the specifications of the insulating layer 44 as illustrated in FIG. 82. The specifications of the insulating layer 44b shown in FIG. 87 can be referred to as the specifications of the insulating layer 44 as illustrated in FIG. 82.

The multichip package 990 may further include the adhesive layer 30 (not shown in FIG. 87), as mentioned in FIG. 78, between the substrate 212a and the passivation layer 20 of the memory chip 238, the dielectric layer 34 (not shown in FIG. 87), as mentioned in FIG. 81, between the overlying interconnects 236a and the backside of the semiconductor substrate 2 of the memory chip 238 and between the dielectric layer 36 and the backside of the semiconductor substrate 2 of the memory chip 238, the dielectric layer 34a (not shown in FIG. 87), as mentioned in FIG. 84, between the overlying interconnects 236b and the backside of the semiconductor substrate 2 of the memory chip 240 and between the dielectric layer 36a and the backside of the semiconductor substrate 2 of the memory chip 240, a dielectric layer (not shown in FIG. 87), which can be referred to the dielectric layer 34a mentioned in FIG. 84, between the overlying interconnects 236c and the backside of the semiconductor substrate 2 of the memory chip 242 and between the dielectric layer 36b and the backside of the semiconductor substrate 2 of the memory chip 242, and a dielectric layer (not shown in FIG. 87), which can be referred to the dielectric layer 34a mentioned in FIG. 84, between the overlying interconnects 236d and the backside of the semiconductor substrate 2 of the memory chip 244 and between the dielectric layer 36c and the backside of the semiconductor substrate 2 of the memory chip 244.

The steps of forming the multichip package 990 can be referred to as the steps of forming the multichip package as illustrated in FIGS. 75-85. The steps of mounting a semiconductor wafer, finally cut into multiple memory chips 238 (one of them is shown), herein called as a first semiconductor wafer, over the supporting substrate 212 illustrated in FIG. 78, finally cut into multiple substrate 212a (one of them is shown), and forming the TSV interconnects 247, 250 and 266 in the first semiconductor wafer and the overlying interconnects 236a over the first semiconductor wafer and in the dielectric layer 36 can be referred to as the steps of mounting the semiconductor wafer 210 over the supporting substrate 212 and forming the TSV interconnects 214 in the semiconductor wafer 210 and the overlying interconnects 214a over the semiconductor wafer 210 and in the dielectric layer 36 as illustrated in FIGS. 78-81.

The steps of forming the insulating layer 44 on the overlying interconnects 236a and the dielectric layer 36, mounting another semiconductor wafer, finally cut into multiple memory chips 240 (one of them is shown), herein called as a second semiconductor wafer having a same die marking as that of the first semiconductor wafer, over the first semiconductor wafer, and forming the TSV interconnects 246, 250, 264 and 268 in and through the second semiconductor wafer and the overlying interconnects 236b over the second semiconductor wafer and in the dielectric layer 36a can be referred to as the steps of forming the insulating layer 44 on the overlying interconnects 214a and the dielectric layer 36, mounting the semiconductor wafer 211 over the semiconductor wafer 210, and forming the TSV interconnects 216a, 216b and 216c in and through the semiconductor wafer 211 and the overlying interconnects 216d over the semiconductor wafer 211 and in the dielectric layer 36a as illustrated in FIGS. 82-84.

The steps of forming the insulating layer 44a on the overlying interconnects 236b and the dielectric layer 36a, mounting another semiconductor wafer, finally cut into multiple memory chips 242 (one of them is shown), herein called as a third semiconductor wafer having a same die marking as that of the second semiconductor wafer, over the second semiconductor wafer, and forming the TSV interconnects 246, 250, 264 and 268 in and through the third semiconductor wafer and the overlying interconnects 236c over the third semiconductor wafer and in the dielectric layer 36b can be referred to as the steps of forming the insulating layer 44 on the overlying interconnects 214a and the dielectric layer 36, mounting the semiconductor wafer 211 over the semiconductor wafer 210, and forming the TSV interconnects 216a, 216b and 216c in and through the semiconductor wafer 211 and the overlying interconnects 216d over the semiconductor wafer 211 and in the dielectric layer 36a as illustrated in FIGS. 82-84.

The steps of forming the insulating layer 44b on the overlying interconnects 236c and the dielectric layer 36b, mounting another semiconductor wafer, finally cut into multiple memory chips 244 (one of them is shown), herein called as a fourth semiconductor wafer having a same die marking as that of the third semiconductor wafer, over the third semiconductor wafer, and forming the TSV interconnects 246, 250, 264 and 268 in and through the fourth semiconductor wafer and the overlying interconnects 236d over the fourth semiconductor wafer and in the dielectric layer 36c can be referred to as the steps of forming the insulating layer 44 on the overlying interconnects 214a and the dielectric layer 36, mounting the semiconductor wafer 211 over the semiconductor wafer 210, and forming the TSV interconnects 216a, 216b and 216c in and through the semiconductor wafer 211 and the overlying interconnects 216d over the semiconductor wafer 211 and in the dielectric layer 36a as illustrated in FIGS. 82-84.

After forming the TSV interconnects 246, 250, 264 and 268 in and through the fourth semiconductor wafer and the overlying interconnects 236d over the fourth semiconductor wafer, the insulating layer 45 illustrated in FIG. 85 can be formed on the overlying interconnects 236d and the dielectric layer 36c. Multiple openings 45a in the insulating layer 45 are over multiple contact points of the overlying interconnects 236d, and the contact points of the overlying interconnects 236d are at bottoms of the openings 45a. Each of the openings 45a may have a suitable width or diameter, such as between 0.3 and 5 micrometer, 0.5 and 10 micrometers or 10 and 100 micrometers. Next, the metal pillars or bumps 248, 252 and 254 can be formed on the contact points of the overlying interconnects 236d, on the insulating layer 45 and in the openings 45a by using a suitable process. The metal pillars or bumps 248, 252 and 254 can be connected to the contact points of the overlying interconnects 236d through the openings 45a in the insulating layer 45. The specifications of the metal pillars or bumps 248, 252 and 254 shown in FIG. 87 can be referred to as the specifications of the metal pillars or bumps 99 as illustrated in FIG. 85.

After forming the metal pillars or bumps 248, 252 and 254, a singulation process can be performed to cut the first, second, third and fourth semiconductor wafers and the supporting substrate 212 into a plurality of the multichip package 990, shown in FIG. 87, including the chip 238 cut from the first semiconductor wafer, the chip 240 cut from the second semiconductor wafer, the chip 242 cut from the third semiconductor wafer, the chip 244 cut from the fourth semiconductor wafer, and the substrate 212a cut from the supporting substrate 212.

The TSV interconnects 247, 250 and 266 are in TSVs, which can be referred to as the TSVs 77 illustrated in FIG. 81, in the memory chip 238. The specifications of the TSV interconnects 247, 250 and 266 shown in FIG. 87 can be referred to as the specifications of the TSV interconnects 214 as illustrated in FIG. 81. The TSV interconnects 268 are in TSVs, which can be referred to as the TSVs 77a illustrated in FIG. 84, through the memory chips 240, 242 and 244. The specifications of the TSV interconnects 268 shown in FIG. 87 can be referred to as the specifications of the TSV interconnects 216a as illustrated in FIG. 84. The TSV interconnects 246 and 264 are in TSVs, which can be referred to as the TSVs 77b illustrated in FIG. 84, through the memory chips 240, 242 and 244. The specifications of the TSV interconnects 246 and 264 shown in FIG. 87 can be referred to as the specifications of the TSV interconnects 216b as illustrated in FIG. 84. The TSV interconnects 250 are in TSVs, which can be referred to as the TSVs 77c illustrated in FIG. 84, in the memory chips 240, 242 and 244. The specifications of the TSV interconnects 250 shown in FIG. 87 can be referred to as the specifications of the TSV interconnects 216c as illustrated in FIG. 84.

The specifications of the overlying interconnects 236a shown in FIG. 87 can be referred to as the specifications of the overlying interconnects 214a as illustrated in FIG. 81. The specifications of the overlying interconnects 236b shown in FIG. 87 can be referred to as the specifications of the overlying interconnects 216d as illustrated in FIG. 84. The specifications of the overlying interconnects 236c shown in FIG. 87 can be referred to as the specifications of the overlying interconnects 216d as illustrated in FIG. 84. The specifications of the overlying interconnects 236d shown in FIG. 87 can be referred to as the specifications of the overlying interconnects 216d as illustrated in FIG. 84.

Each of the memory chips 238, 240, 242 and 244 shown in FIG. 87 may include the ground or polished semiconductor substrate 2, the STI layer 6 (not shown in FIG. 87), the DTI layer 4 having the isolation enclosures 202 and the alignment marks 206 (not shown in FIG. 87), the IC devices 7 (not shown in FIG. 87), the IC scheme 208 and the passivation layer 20, as mentioned above in FIGS. 75-85. The ground or polished semiconductor substrate 2 may have a suitable thickness, such as between 1 and 100 micrometers, between 1 and 50 micrometers, between 1 and 20 micrometers, between 1 and 10 micrometers, between 1 and 5 micrometers, or between 2 and 5 micrometers, that may be same as the thickness of the DTI layer 4. The ground or polished semiconductor substrate 2 may have the above-mentioned surface 200, and the DTI layer 4 may have the above-mentioned bottom surface 400 substantially coplanar with the surface 200. Each of the TSV interconnects 246, 247, 250, 264, 266 and 268 is enclosed by one of the isolation enclosures 202.

The passivation layer 20 of the memory chip 238 can face the substrate 212a. The passivation layer 20 of the memory chip 240 can face the backside of the semiconductor substrate 2 of the memory chip 238. The passivation layer 20 of the memory chip 242 can face the backside of the semiconductor substrate 2 of the memory chip 240. The passivation layer 20 of the memory chip 244 can face the backside of the semiconductor substrate 2 of the memory chip 242.

The conductive layer 10 of each of the memory chips 238, 240, 242 and 244 may include multiple interconnects 256 (one of them is shown in each of the memory chips 238, 240, 242 and 244 shown in FIG. 87) and multiple interconnects 261 (one of them is shown in each of the memory chips 238, 240, 242 and 244 shown in FIG. 87).

The conductive layer 16 of each of the memory chips 238, 240, 242 and 244 shown in FIG. 87 may include the above-mentioned serial input ports 234 (one of them is shown in each of the memory chips 238, 240, 242 and 244 and can be, for example, the input port D0), the above-mentioned serial output ports 235 (one of them is shown in each of the memory chips 238, 240, 242 and 244 and can be, for example, the output port Q0), and the above-mentioned parallel common input ports 228 (one of them is shown in each of the memory chips 238, 240, 242 and 244 and can be the port CK, RST or CE).

The TSV interconnects 247 in the memory chip 238 may contact the interconnects 261 of the memory chip 238 and may be connected to the parallel common input ports 228 of the memory chip 238 through the interconnects 261 of the memory chip 238. The TSV interconnects 246 passing through the memory chip 240 may contact the parallel common input ports 228 of the memory chip 240 and the overlying interconnects 301c but may not contact the interconnects 261 of the memory chip 240. The TSV interconnects 246 passing through the memory chip 240 may be not vertically over the TSV interconnects 247. Alternatively, the TSV interconnects 246 passing through the memory chip 240 may be horizontally offset from the TSV interconnects 247.

The TSV interconnects 246 passing through the memory chip 242 may contact the parallel common input ports 228 of the memory chip 242 and some of the overlying interconnects 236b, that are, overlying interconnects 302c mentioned as below, connecting to the TSV interconnects 246 in the memory chip 240, but may not contact the interconnects 261 of the memory chip 242. The TSV interconnects 246 passing through the memory chip 242 may be vertically over the TSV interconnects 246 passing through the memory chip 240.

The TSV interconnects 246 passing through the memory chip 244 may contact the parallel common input ports 228 of the memory chip 244 and some of the overlying interconnects 236c, that are, overlying interconnects 303c mentioned as below, connecting to the TSV interconnects 246 in the memory chip 242, but may not contact the interconnects 261 of the memory chip 244. The TSV interconnects 246 passing through the memory chip 244 may be vertically over the TSV interconnects 246 passing through the memory chip 242.

The isolation enclosures 202 enclosing the TSV interconnects 246 in the memory chip 240 can be vertically over and substantially aligned with the isolation enclosures 202 enclosing the TSV interconnects 247 in the memory chip 238. The isolation enclosures 202 enclosing the TSV interconnects 246 in the memory chip 242 can be vertically over and substantially aligned with the isolation enclosures 202 enclosing the TSV interconnects 246 in the memory chip 240. The isolation enclosures 202 enclosing the TSV interconnects 246 in the memory chip 244 can be vertically over and substantially aligned with the isolation enclosures 202 enclosing the TSV interconnects 246 in the memory chip 242. The isolation enclosures 202 enclosing the TSV interconnects 246 in the memory chip 244 can be vertically over and substantially aligned with the isolation enclosures 202 enclosing the TSV interconnects 246 in the memory chip 240.

The parallel common input ports 228 of the memory chip 240 may be vertically over and substantially aligned with the parallel common input ports 228 of the memory chip 238. The parallel common input ports 228 of the memory chip 242 may be vertically over and substantially aligned with the parallel common input ports 228 of the memory chip 240. The parallel common input ports 228 of the memory chip 244 may be vertically over and substantially aligned with the parallel common input ports 228 of the memory chip 242.

The overlying interconnects 236a include multiple metal traces 301a connecting the serial output ports 235 of the memory chip 238 to the serial input ports 234 of the memory chip 240, multiple overlying interconnects 301b connecting the TSV interconnects 268 in the memory chip 240 to the TSV interconnects 266 in the memory chip 238, and multiple overlying interconnects 301c connecting the TSV interconnects 246 in the memory chip 240 to the TSV interconnects 247 in the memory chip 238. The overlying interconnects 301b may include multiple portions used as TSV etch stop for a through-data connection. The overlying interconnects 301c may include multiple portions used as TSV etch stop for the parallel connection 231.

The TSV interconnects 250 in the memory chip 238 can connect the serial output ports 235 of the memory chip 238 to the metal traces 301a. The TSV interconnects 250 in the memory chip 240 can connect the serial output ports 235 of the memory chip 240 to some of the overlying interconnects 236b, that are, metal traces 302a mentioned as below, connecting to the serial input ports 234 of the memory chip 242. The TSV interconnects 250 in the memory chip 242 can connect the serial output ports 235 of the memory chip 242 to some of the overlying interconnects 236c, that are, metal traces 303a mentioned as below, connecting to the serial input ports 234 of the memory chip 244. The TSV interconnects 250 in the memory chip 244 can connect the serial output ports 235 of the memory chip 244 to some of the overlying interconnects 236d, that are, metal traces 304a mentioned as below, connecting to the metal pillars or bumps 252.

The serial output ports 235 of the memory chip 240 may be vertically over and substantially aligned with the serial output ports 235 of the memory chip 238. The serial output ports 235 of the memory chip 242 may be vertically over and substantially aligned with the serial output ports 235 of the memory chip 240. The serial output ports 235 of the memory chip 244 may be vertically over and substantially aligned with the serial output ports 235 of the memory chip 242.

The TSV interconnects 250 in the memory chip 240 may be vertically over the TSV interconnects 250 in the memory chip 238. The TSV interconnects 250 in the memory chip 242 may be vertically over the TSV interconnects 250 in the memory chip 240. The TSV interconnects 250 in the memory chip 244 may be vertically over the TSV interconnects 250 in the memory chip 242.

The isolation enclosures 202 enclosing the TSV interconnects 250 in the memory chip 240 can be vertically over and substantially aligned with the isolation enclosures 202 enclosing the TSV interconnects 250 in the memory chip 238. The isolation enclosures 202 enclosing the TSV interconnects 250 in the memory chip 242 can be vertically over and substantially aligned with the isolation enclosures 202 enclosing the TSV interconnects 250 in the memory chip 240. The isolation enclosures 202 enclosing the TSV interconnects 250 in the memory chip 244 can be vertically over and substantially aligned with the isolation enclosures 202 enclosing the TSV interconnects 250 in the memory chip 242.

The TSV interconnects 264 passing through the memory chip 240 can contact the serial input ports 234 of the memory chip 240 and the metal traces 301a. The TSV interconnects 264 passing through the memory chip 242 can contact the serial input ports 234 of the memory chip 242 and some of the overlying interconnects 236b, that are, metal traces 302a mentioned as below, connecting to the serial output ports 235 of the memory chip 240. The TSV interconnects 264 passing through the memory chip 244 can contact the serial input ports 234 of the memory chip 244 and some of the overlying interconnects 236c, that are, metal traces 303a mentioned as below, connecting to the serial output ports 235 of the memory chip 242. In one example, there may be no TSV interconnects through the isolation enclosures 202 in the memory chip 238 to contact the serial input ports 234 of the memory chip 238.

The serial input ports 234 of the memory chip 240 may be vertically over and substantially aligned with the serial input ports 234 of the memory chip 238. The serial input ports 234 of the memory chip 242 may be vertically over and substantially aligned with the serial input ports 234 of the memory chip 240. The serial input ports 234 of the memory chip 244 may be vertically over and substantially aligned with the serial input ports 234 of the memory chip 242.

The TSV interconnects 264 passing through the memory chip 242 may be not vertically over the TSV interconnects 264 passing through the memory chip 240. The TSV interconnects 264 passing through the memory chip 244 may be vertically over the TSV interconnects 264 passing through the memory chip 240 and may be not vertically over the TSV interconnects 264 passing through the memory chip 242.

There may be the isolation enclosures 202 in the memory chip 238 vertically under and substantially aligned with the isolation enclosures 202 enclosing the TSV interconnects 264 passing through the memory chip 240. The isolation enclosures 202 enclosing the TSV interconnects 264 passing through the memory chip 242 can be vertically over and substantially aligned with the isolation enclosures 202 enclosing the TSV interconnects 264 passing through the memory chip 240. The isolation enclosures 202 enclosing the TSV interconnects 264 passing through the memory chip 244 can be vertically over and substantially aligned with the isolation enclosures 202 enclosing the TSV interconnects 264 passing through the memory chip 242.

The TSV interconnects 266 in the memory chip 238 may contact the interconnects 256 of the memory chip 238 and may connect the interconnects 256 of the memory chip 238 to the overlying interconnects 301b. The TSV interconnects 268 passing through the memory chip 240 may contact the overlying interconnects 301b but may not contact the interconnects 256 of the memory chip 240. The TSV interconnects 268 passing through the memory chip 240 may be not vertically over the TSV interconnects 266.

The TSV interconnects 268 passing through the memory chip 242 may contact some of the overlying interconnects 236b, that are, overlying interconnects 302b mentioned as below, connecting to the TSV interconnects 268 passing through the memory chip 240, but may not contact the interconnects 256 of the memory chip 242. The TSV interconnects 268 passing through the memory chip 242 may be vertically over the TSV interconnects 268 passing through the memory chip 240.

The TSV interconnects 268 passing through the memory chip 244 may contact some of the overlying interconnects 236c, that are, overlying interconnects 303b mentioned as below, connecting to the TSV interconnects 268 passing through the memory chip 242, but may not contact the interconnects 256 of the memory chip 244. The TSV interconnects 268 passing through the memory chip 244 may be vertically over the TSV interconnects 268 passing through the memory chip 242.

The isolation enclosures 202 enclosing the TSV interconnects 268 passing through the memory chip 240 can be vertically over and substantially aligned with the isolation enclosures 202 enclosing the TSV interconnects 266 in the memory chip 238. The isolation enclosures 202 enclosing the TSV interconnects 268 passing through the memory chip 242 can be vertically over and substantially aligned with the isolation enclosures 202 enclosing the TSV interconnects 268 passing through the memory chip 240. The isolation enclosures 202 enclosing the TSV interconnects 268 passing through the memory chip 244 can be vertically over and substantially aligned with the isolation enclosures 202 enclosing the TSV interconnects 268 passing through the memory chip 242.

The interconnects 256 of the memory chip 240 may be vertically over the interconnects 256 of the memory chip 238. The interconnects 256 of the memory chip 242 may be vertically over the interconnects 256 of the memory chip 240. The interconnects 256 of the memory chip 244 may be vertically over the interconnects 256 of the memory chip 242.

The input signals 230a (such as signals CK, RST and CE), illustrated in FIG. 86, can be input from an external circuit of the multichip package 990, such as the memory controller of the data storage device, to the parallel common input ports 228 of the memory chips 238, 240, 242 and 244 through the metal pillars or bumps 248 (one of them is shown in FIG. 87). The input signals 230b (such as signals D0-D15, CSI and DSI), illustrated in FIG. 86, can be input from the external circuit of the multichip package 990, such as the memory controller of the data storage device, to the serial input ports 234 of the memory chip 238 through the metal pillars or bumps 254 (one of them is shown in FIG. 87). The signals 232 (such as signals Q0-Q15, CSO and DSO), illustrated in FIG. 86, can be output from the serial output ports 235 of the memory chip 244 to the external circuit of the multichip package 990, such as the memory controller of the data storage device, through the metal pillars or bumps 252 (one of them is shown in FIG. 87).

The layout design of the isolation enclosures 202 in the memory chip 244 shown in FIG. 87 can be same as that of the isolation enclosures 202 in the memory chip 238 shown in FIG. 87, that of the isolation enclosures 202 in the memory chip 240 shown in FIG. 87, and that of the isolation enclosures 202 in the memory chip 242 shown in FIG. 87. That is, the isolation enclosures 202 in the memory chip 244 shown in FIG. 87 can be vertically over and substantially aligned with the isolation enclosures 202 in the memory chip 238 shown in FIG. 87, the isolation enclosures 202 in the memory chip 240 shown in FIG. 87, and the isolation enclosures 202 in the memory chip 242 shown in FIG. 87.

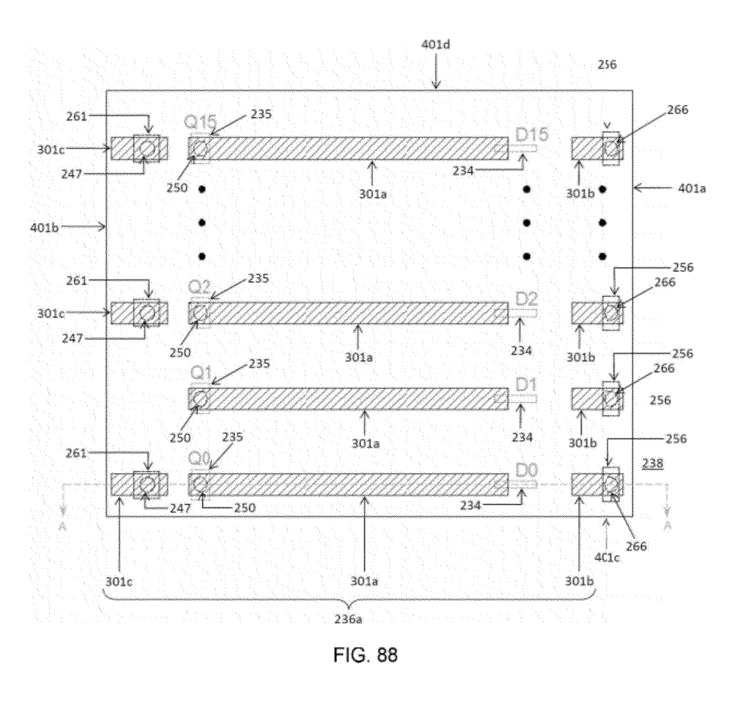

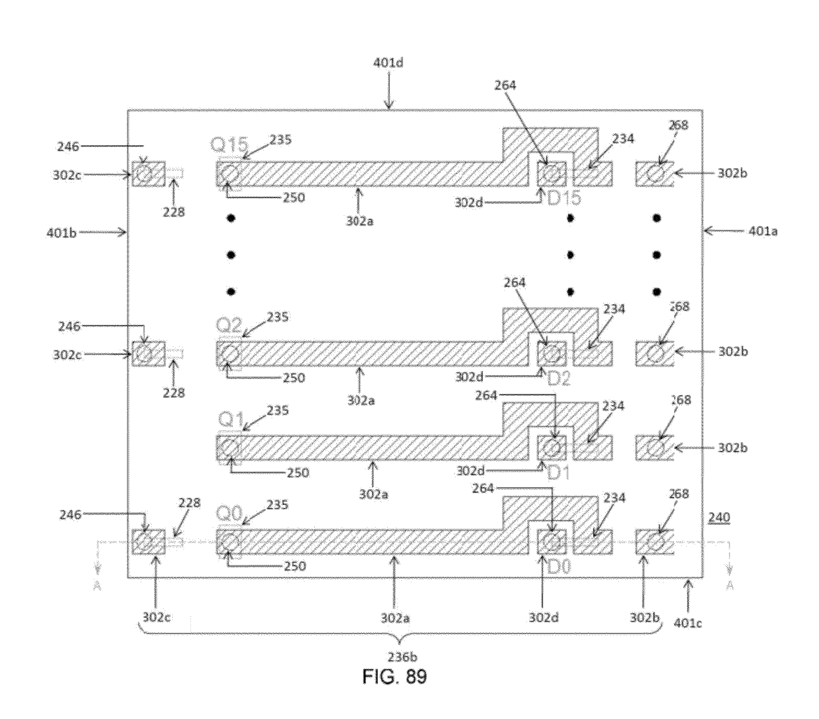

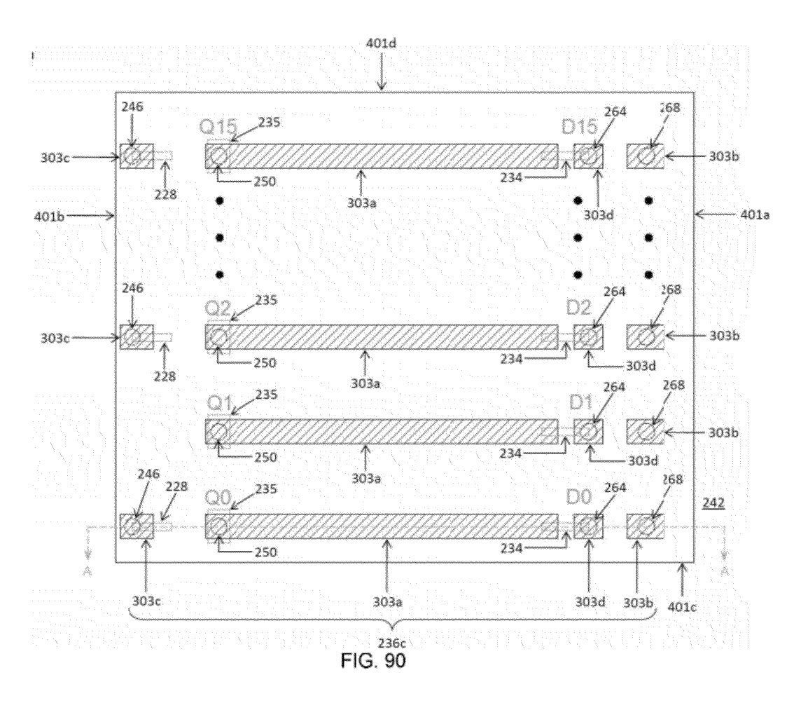

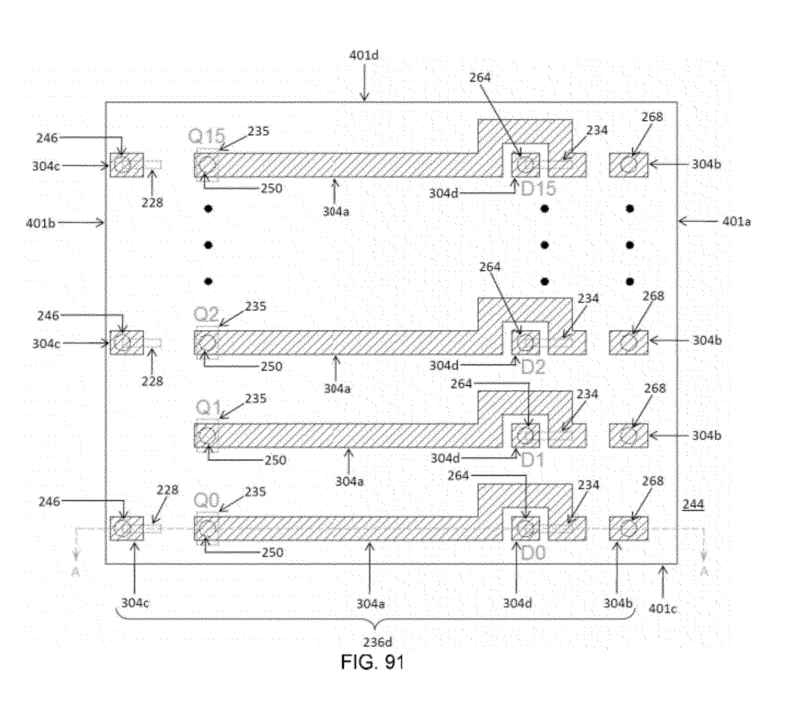

FIG. 87 shows a cross-sectional view illustrating the memory chip 238 and the overlying interconnects 236a cut along the line A-A shown in FIG. 88 showing a top perspective view of the layout of the overlying interconnects 236a, the memory chip 240 and the overlying interconnects 236b cut along the line A-A shown in FIG. 89 showing a top perspective view of the layout of the overlying interconnects 236b, the memory chip 242 and the overlying interconnects 236c cut along the line A-A shown in FIG. 90 showing a top perspective view of the layout of the overlying interconnects 236c, and the memory chip 244 and the overlying interconnects 236d cut along the line A-A shown in FIG. 91 showing a top perspective view of the layout of the overlying interconnects 236d.

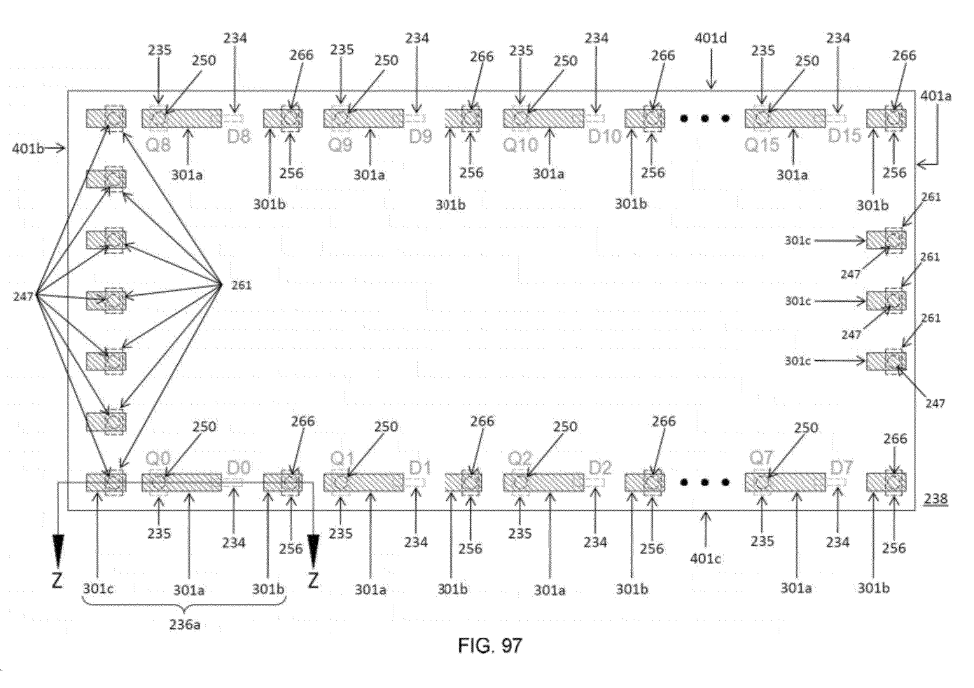

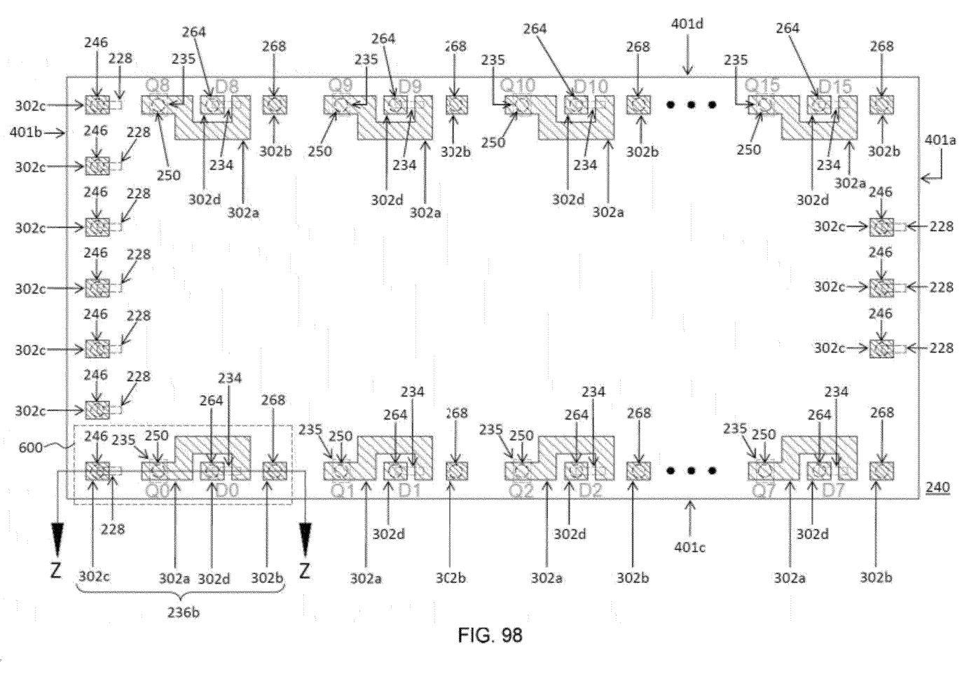

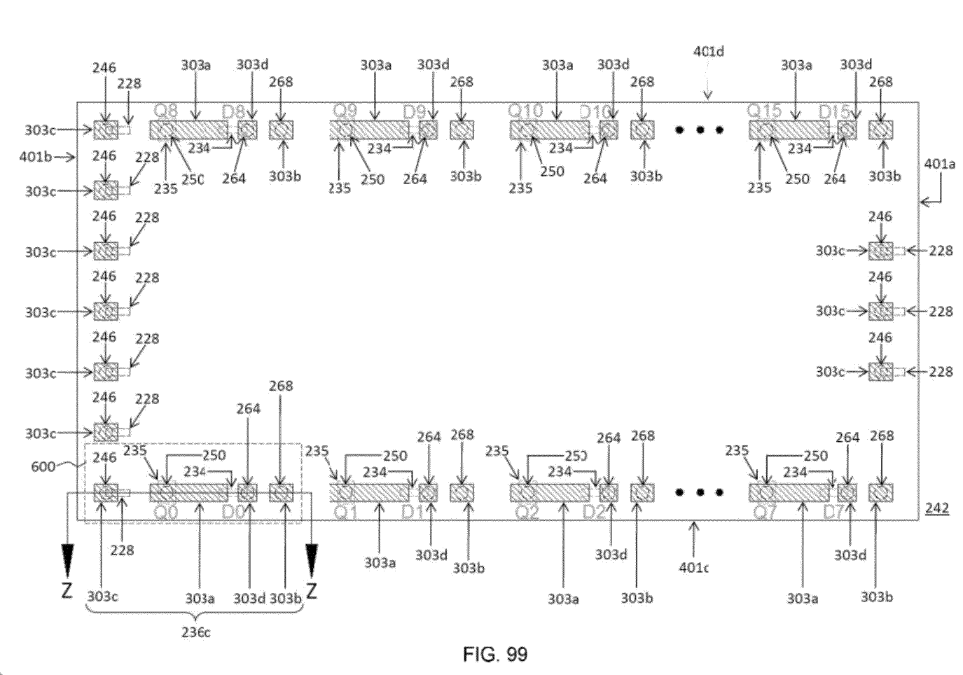

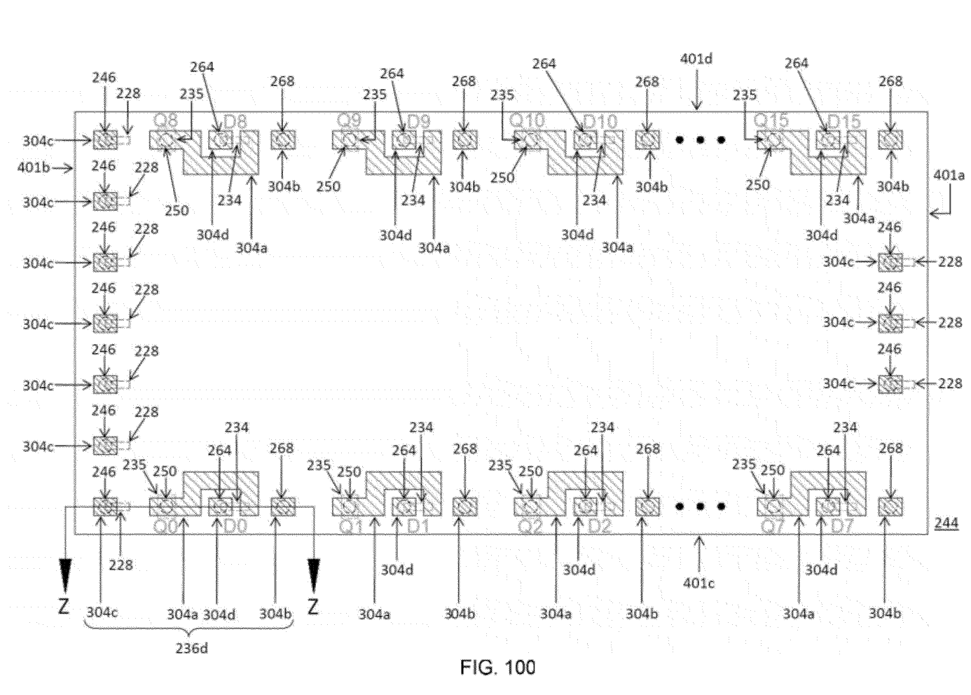

Alternatively, FIG. 87 may show a cross-sectional view illustrating the memory chip 238 and the overlying interconnects 236a cut along the line Z-Z shown in FIG. 97 showing a top perspective view of the layout of the overlying interconnects 236a, the memory chip 240 and the overlying interconnects 236b cut along the line Z-Z shown in FIG. 98 showing a top perspective view of the layout of the overlying interconnects 236b, the memory chip 242 and the overlying interconnects 236c cut along the line Z-Z shown in FIG. 99 showing a top perspective view of the layout of the overlying interconnects 236c, and the memory chip 244 and the overlying interconnects 236d cut along the line Z-Z shown in FIG. 100 showing a top perspective view of the layout of the overlying interconnects 236d.

Referring to FIG. 87, FIGS. 88-91 and FIGS. 97-100, the memory chip 238 may have a top surface with a profile that is substantially same as that of a top surface of the substrate 212a, that of a top surface of the memory chip 240, that of a top surface of the memory chip 242, and that of a top surface of the memory chip 244. The memory chip 238 may have a same length as that of each of the memory chips 240, 242 and 244 and that of the substrate 212a, and/or may have a same width as that of each of the memory chips 240, 242 and 244 and that of the substrate 212a. The memory chips 238, 240, 242 and 244 are same chips having a same die marking and/or having a same layout of the DTI layer 4. Each of the memory chips 238, 240, 242 and 244 has four edges 401a, 401b, 401c and 401d. The edge 401a is opposite to the edge 401b, and the edge 401c is opposite the edge 401d. The edges 401a of the memory chips 238, 240, 242 and 244 shown in FIGS. 88-91 and FIGS. 97-100 can be at a right side of the multichip package 990, and the edges 401b of the memory chips 238, 240, 242 and 244 shown in FIGS. 88-91 and FIGS. 97-100 can be at a left side of the multichip package 990.

The overlying interconnects 236b shown in FIGS. 87, 89 and 98 include multiple metal traces 302a connecting the serial output ports 235 of the memory chip 240 to the serial input ports 234 of the memory chip 242, multiple overlying interconnects 302b connecting the TSV interconnects 268 in the memory chip 242 to the TSV interconnects 268 in the memory chip 240, multiple overlying interconnects 302c connecting the TSV interconnects 246 in the memory chip 242 to the TSV interconnects 246 in the memory chip 240, and multiple overlying interconnects 302d connecting to the TSV interconnects 264 in the memory chip 240. The overlying interconnects 302b may include multiple portions used as TSV etch stop for the through-data connection. The overlying interconnects 302c may include multiple portions used as TSV etch stop for the parallel connection 231.

The overlying interconnects 236c shown in FIGS. 87, 90 and 99 include multiple metal traces 303a connecting the serial output ports 235 of the memory chip 242 to the serial input ports 234 of the memory chip 244, multiple overlying interconnects 303b connecting the TSV interconnects 268 in the memory chip 244 to the TSV interconnects 268 in the memory chip 242, multiple overlying interconnects 303c connecting the TSV interconnects 246 in the memory chip 244 to the TSV interconnects 246 in the memory chip 242, and multiple overlying interconnects 303d connecting to the TSV interconnects 264 in the memory chip 242. The overlying interconnects 303b may include multiple portions used as TSV etch stop for the through-data connection. The overlying interconnects 303c may include multiple portions used as TSV etch stop for the parallel connection 231.

The overlying interconnects 236d shown in FIGS. 87, 91 and 100 include multiple metal traces 304a connecting the serial output ports 235 of the memory chip 244 to the metal pillars or bumps 252, multiple overlying interconnects 304b connecting the TSV interconnects 268 in the memory chip 244 to the metal pillars or bumps 254, multiple overlying interconnects 304c connecting the TSV interconnects 246 in the memory chip 244 to the metal pillars or bumps 248, and multiple overlying interconnects 304d connecting to the TSV interconnects 264 in the memory chip 244.

Referring to FIG. 87, FIGS. 88-91 and FIGS. 97-100, the parallel connection 231 illustrated in FIG. 86 may include the metal pillars or bumps 248, the overlying interconnects 304c, the TSV interconnects 246 passing through the memory chip 244, the overlying interconnects 303c, the TSV interconnects 246 passing through the memory chip 242, the overlying interconnects 302c, the TSV interconnects 246 passing through the memory chip 240, the overlying interconnects 301c, the TSV interconnects 247 in the memory chip 238, and the interconnects 261 of the memory chip 238. The metal pillars or bumps 248 shown in FIG. 87 can be connected to the parallel common input ports 228 of the memory chips 238, 240, 242 and 244 through the parallel connection 231.

The metal pillars or bumps 248 shown in FIG. 87 can be on multiple contact points, exposed by some of the openings 45a in the insulating layer 45, of the overlying interconnects 304c and can be physically and electrically connected to the parallel common input ports 228 of the memory chip 238 through, in sequence, the overlying interconnects 304c, the TSV interconnects 246 passing through the memory chip 244, the overlying interconnects 303c, the TSV interconnects 246 passing through the memory chip 242, the overlying interconnects 302c, the TSV interconnects 246 passing through the memory chip 240, the overlying interconnects 301c, the TSV interconnects 247 in the memory chip 238, and the interconnects 261 of the memory chip 238.

The metal pillars or bumps 248 can be physically and electrically connected to the parallel common input ports 228 of the memory chip 240 through, in sequence, the overlying interconnects 304c, the TSV interconnects 246 passing through the memory chip 244, the overlying interconnects 303c, the TSV interconnects 246 passing through the memory chip 242, the overlying interconnects 302c, and the TSV interconnects 246 passing through the memory chip 240.

The metal pillars or bumps 248 can be physically and electrically connected to the parallel common input ports 228 of the memory chip 242 through, in sequence, the overlying interconnects 304c, the TSV interconnects 246 passing through the memory chip 244, the overlying interconnects 303c, and the TSV interconnects 246 passing through the memory chip 242. The metal pillars or bumps 248 can be physically and electrically connected to the parallel common input ports 228 of the memory chip 244 through, in sequence, the overlying interconnects 304c and the TSV interconnects 246 passing through the memory chip 244.

Referring to FIG. 87, FIGS. 88-91 and FIGS. 97-100, the metal pillars or bumps 254 shown in FIG. 87 can be on multiple contact points, exposed by some of the openings 45a in the insulating layer 45, of the overlying interconnects 304b and can be physically and electrically connected to the interconnects 256 of the memory chip 238 through, in sequence, the overlying interconnects 304b, the TSV interconnects 268 passing through the memory chip 244, the overlying interconnects 303b, the TSV interconnects 268 passing through the memory chip 242, the overlying interconnects 302b, the TSV interconnects 268 passing through the memory chip 240, the overlying interconnects 301b, and the TSV interconnects 266 in the memory chip 238. Referring to FIGS. 87, 91 and 100, the metal pillars or bumps 252 shown in FIG. 87 can be on multiple contact points, exposed by some of the openings 45a in the insulating layer 45, of the metal traces 304a and can be physically and electrically connected to the serial output ports 235 of the memory chip 244 through, in sequence, the metal traces 304a and the TSV interconnects 250 passing through the memory chip 244.

Referring to FIGS. 88 and 97, the memory chip 238 is shown with the serial input ports 234 (such as the input ports D0-D15), the serial output ports 235 (such as the output ports Q0-Q15), and the interconnects 256 and 261. The TSV interconnects 247, 250 and 266 shown in FIGS. 88 and 97 are in the memory chip 238. There is no TSV interconnect, in the memory chip 238, as shown in FIG. 87, vertically between the serial input ports 234 of the memory chip 238 shown in FIGS. 88 and 97 and the metal traces 301a. Referring to FIGS. 89 and 98, the memory chip 240 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 268 shown in FIGS. 89 and 98 are in the memory chip 240. The serial input ports 234 of the memory chip 240 shown in FIGS. 89 and 98 are not connected to the metal traces 302a and the overlying interconnects 302b through the TSV interconnects 264 in the memory chip 240. Referring to FIGS. 90 and 99, the memory chip 242 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 268 shown in FIGS. 90 and 99 are in the memory chip 242. The serial input ports 234 of the memory chip 242 shown in FIGS. 90 and 99 are not connected to the metal traces 303a and the overlying interconnects 303b through the TSV interconnects 264 in the memory chip 242. Referring to FIGS. 91 and 100, the memory chip 244 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 268 shown in FIGS. 91 and 100 are in the memory chip 244. The serial input ports 234 of the memory chip 244 shown in FIGS. 91 and 100 are not connected to the metal traces 304a and the overlying interconnects 304b through the TSV interconnects 264 in the memory chip 244.

Referring to FIGS. 87, 88 and 97, the memory chip 238 includes circuit paths, signal paths, between the interconnects 256 of the memory chip 238 and the serial input ports 234 of the memory chip 238. In one example, the interconnects 256 of the memory chip 238 can be physically and electrically connected to the serial input ports 234 of the memory chip 238. The memory chip 238 further includes the above-mentioned circuit paths, signal or data paths, illustrated in FIG. 86, between the serial input ports 234 of the memory chip 238 and the serial output ports 235 of the memory chip 238. For example, the memory chip 238 includes a circuit path, signal or data path, between the input port D0 of the memory chip 238 and the corresponding output port Q0 of the memory chip 238. The serial output ports 235 of the memory chip 238 can be physically and electrically connected to the serial input ports 234 of the memory chip 240 through, in sequence, the TSV interconnects 250 in the memory chip 238, the metal traces 301a, and the TSV interconnects 264 passing through the memory chip 240. The above-mentioned serial connection 233a, illustrated in FIG. 86, between the serial output ports 235 of the memory chip 238 and the serial input ports 234 of the memory chip 240 may include the TSV interconnects 250 in the memory chip 238, the metal traces 301a, and the TSV interconnects 264 passing through the memory chip 240.

Referring to FIG. 88, each of the metal traces 301a may have a middle portion in a center region of the memory chip 238 enclosed by a peripheral region of the memory chip 238, a right portion, connecting to the input port 234 of the memory chip 240 through the TSV interconnect 264 in the memory chip 240 shown in FIGS. 87 and 89, in the peripheral region of the memory chip 238 closer to the edge 401a than the edge 401b, and a left portion, connecting to the output port 235 of the memory chip 238 through the TSV interconnect 250, in the peripheral region of the memory chip 238 closer to the edge 401b than the edge 401a. The serial input ports 234 of the memory chip 238 may be arranged in a line parallel with the edge 401a and in the peripheral region of the memory chip 238 closer to the edge 401a than the edge 401b. The serial output ports 235 of the memory chip 238 may be arranged in a line parallel with the edge 401b and in the peripheral region of the memory chip 238 closer to the edge 401b than the edge 401a. The TSV interconnects 250 may be arranged in a line parallel with the edge 401b and in the peripheral region of the memory chip 238 closer to the edge 401b than the edge 401a. The interconnects 256 of the memory chip 238 may be arranged in a line parallel with the edge 401a and in the peripheral region of the memory chip 238 closer to the edge 401a than the edge 401b. The TSV interconnects 266 may be arranged in a line parallel with the edge 401a and in the peripheral region of the memory chip 238 closer to the edge 401a than the edge 401b. The interconnects 261 of the memory chip 238 may be arranged in a line parallel with the edge 401b and in the peripheral region of the memory chip 238 closer to the edge 401b than the edge 401a. The TSV interconnects 247 may be arranged in a line parallel with the edge 401b and in the peripheral region of the memory chip 238 closer to the edge 401b than the edge 401a. The parallel common input ports 228 of the memory chip 238 may be arranged in a line parallel with the edge 401b and in the peripheral region of the memory chip 238 closer to the edge 401b than the edge 401a. The overlying interconnects 301b can be in the peripheral region of the memory chip 238 closer to the edge 401a than the edge 401b. The overlying interconnects 301c can be in the peripheral region of the memory chip 238 closer to the edge 401b than the edge 401a. The overlying interconnects 236a may further include multiple power traces or planes and multiple ground traces or planes in the center region and/or peripheral region of the memory chip 238. Alternatively, the interconnects 256 and 261 of the memory chip 238, the parallel common input ports 228 of the memory chip 238, the serial input ports 234 of the memory chip 238, the serial output ports 235 of the memory chip 238, the TSV interconnects 247, 250 and 266, the metal traces 301a, and the overlying interconnects 301b and 301c may be all in the center region of the memory chip 238.

Referring to FIG. 97, each of the metal traces 301a may have a right portion, connecting to the input port 234 of the memory chip 240 through the TSV interconnect 264 in the memory chip 240 shown in FIGS. 87 and 98, in a peripheral region of the memory chip 238, and a left portion, connecting to the output port 235 of the memory chip 238 through the TSV interconnect 250, in the peripheral region of the memory chip 238. Some of the serial input ports 234 of the memory chip 238 can be arranged in a line parallel with the edge 401c and in the peripheral region of the memory chip 238 closer to the edge 401c than the edge 401d, and the others can be arranged in a line parallel with the edge 401d and in the peripheral region of the memory chip 238 closer to the edge 401d than the edge 401c. Some of the serial output ports 235 of the memory chip 238 can be arranged in a line parallel with the edge 401c and in the peripheral region of the memory chip 238 closer to the edge 401c than the edge 401d, and the others can be arranged in a line parallel with the edge 401d and in the peripheral region of the memory chip 238 closer to the edge 401d than the edge 401c. Some of the interconnects 256 of the memory chip 238 can be arranged in a line parallel with the edge 401c and in the peripheral region of the memory chip 238 closer to the edge 401c than the edge 401d, and the others can be arranged in a line parallel with the edge 401d and in the peripheral region of the memory chip 238 closer to the edge 401d than the edge 401c. Some of the TSV interconnects 266 can be arranged in a line parallel with the edge 401c and in the peripheral region of the memory chip 238 closer to the edge 401c than the edge 401d, and the others can be arranged in a line parallel with the edge 401d and in the peripheral region of the memory chip 238 closer to the edge 401d than the edge 401c. Some of the TSV interconnects 250 can be arranged in a line parallel with the edge 401c and in the peripheral region of the memory chip 238 closer to the edge 401c than the edge 401d, and the others can be arranged in a line parallel with the edge 401d and in the peripheral region of the memory chip 238 closer to the edge 401d than the edge 401c. Some of the parallel common input ports 228 of the memory chip 238 can be arranged in a line parallel with the edge 401a and in the peripheral region of the memory chip 238 closer to the edge 401a than the edge 401b, and the others can be arranged in a line parallel with the edge 401b and in the peripheral region of the memory chip 238 closer to the edge 401b than the edge 401a. Some of the interconnects 261 of the memory chip 238 can be arranged in a line parallel with the edge 401a and in the peripheral region of the memory chip 238 closer to the edge 401a than the edge 401b, and the others can be arranged in a line parallel with the edge 401b and in the peripheral region of the memory chip 238 closer to the edge 401b than the edge 401a. Some of the TSV interconnects 247 can be arranged in a line parallel with the edge 401a and in the peripheral region of the memory chip 238 closer to the edge 401a than the edge 401b, and the others can be arranged in a line parallel with the edge 401b and in the peripheral region of the memory chip 238 closer to the edge 401b than the edge 401a. Some of the meal traces 301a can be in the peripheral region of the memory chip 238 closer to the edge 401c than the edge 401d, and the others can be in the peripheral region of the memory chip 238 closer to the edge 401d than the edge 401c. Some of the overlying interconnects 301b can be in the peripheral region of the memory chip 238 closer to the edge 401c than the edge 401d, and the others can be in the peripheral region of the memory chip 238 closer to the edge 401d than the edge 401c. Some of the overlying interconnects 301c can be in the peripheral region of the memory chip 238 closer to the edge 401a than the edge 401b, and the others can be in the peripheral region of the memory chip 238 closer to the edge 401b than the edge 401a. The overlying interconnects 236a may further include multiple power traces or planes and multiple ground traces or planes in a center region of the memory chip 238 enclosed by the peripheral region of the memory chip 238.

Referring to FIGS. 87, 89 and 98, the memory chip 240 includes the above-mentioned circuit paths, signal paths, illustrated in FIG. 86, between the serial input ports 234 of the memory chip 240 and the serial output ports 235 of the memory chip 240. For example, the memory chip 240 includes a circuit path, signal path, between the input port D0 of the memory chip 240 and the corresponding output port Q0 of the memory chip 240. The serial output ports 235 of the memory chip 240 can be physically and electrically connected to the serial input ports 234 of the memory chip 242 through, in sequence, the TSV interconnects 250 in the memory chip 240, the metal traces 302a, and the TSV interconnects 264 passing through the memory chip 242. The overlying interconnects 302d can be spaced apart from the metal traces 302a, and the TSV interconnects 264 in the memory chip 240 cannot be connected to the metal traces 302a through the overlying interconnects 302d. The TSV interconnects 264 passing through the memory chip 240 can connect the serial input ports 234 of the memory chip 240 and the metal traces 301a shown in FIGS. 88 and 97. The above-mentioned serial connection 233b, illustrated in FIG. 86, between the serial output ports 235 of the memory chip 240 and the serial input ports 234 of the memory chip 242 may include the TSV interconnects 250 in the memory chip 240, the metal traces 302a, and the TSV interconnects 264 passing through the memory chip 242.

Referring to FIG. 89, each of the metal traces 302a may have a middle portion in a center region of the memory chip 240 enclosed by a peripheral region of the memory chip 240, a right portion, connecting to the input port 234 of the memory chip 242 through the TSV interconnect 264 in the memory chip 242 shown in FIGS. 87 and 90, in the peripheral region of the memory chip 240 closer to the edge 401a than the edge 401b, and a left portion, connecting to the output port 235 of the memory chip 240 through the TSV interconnect 250, in the peripheral region of the memory chip 240 closer to the edge 401b than the edge 401a. The right portion of each of the metal traces 302a may be between one of the overlying interconnects 302b and one of the overlying interconnects 302d. The serial input ports 234 of the memory chip 240 may be arranged in a line parallel with the edge 401a and in the peripheral region of the memory chip 240 closer to the edge 401a than the edge 401b. The serial output ports 235 of the memory chip 240 may be arranged in a line parallel with the edge 401b and in the peripheral region of the memory chip 240 closer to the edge 401b than the edge 401a. The TSV interconnects 264 may be arranged in a line parallel with the edge 401a and in the peripheral region of the memory chip 240 closer to the edge 401a than the edge 401b. The TSV interconnects 250 may be arranged in a line parallel with the edge 401b and in the peripheral region of the memory chip 240 closer to the edge 401b than the edge 401a. The parallel common input ports 228 of the memory chip 240 may be arranged in a line parallel with the edge 401b and in the peripheral region of the memory chip 240 closer to the edge 401b than the edge 401a. The TSV interconnects 268 may be arranged in a line parallel with the edge 401a and in the peripheral region of the memory chip 240 closer to the edge 401a than the edge 401b. The TSV interconnects 246 may be arranged in a line parallel with the edge 401b and in the peripheral region of the memory chip 240 closer to the edge 401b than the edge 401a. The overlying interconnects 302b and 302d can be in the peripheral region of the memory chip 240 closer to the edge 401a than the edge 401b. The overlying interconnects 302c can be in the peripheral region of the memory chip 240 closer to the edge 401b than the edge 401a. The overlying interconnects 236b may further include multiple power traces or planes and multiple ground traces or planes in the center region and/or peripheral region of the memory chip 240. Alternatively, the metal traces 302a, the overlying interconnects 302b, 302c and 302d, the serial input ports 234 of the memory chip 240, the serial output ports 235 of the memory chip 240, the parallel common input ports 228 of the memory chip 240, and the TSV interconnects 246, 250, 264 and 268 may be all in the center region of the memory chip 240.

Referring to FIG. 98, each of the metal traces 302a may have a right portion, connecting to the input port 234 of the memory chip 242 through the TSV interconnect 264 in the memory chip 242 shown in FIGS. 87 and 99, in a peripheral region of the memory chip 240, and a left portion, connecting to the output port 235 of the memory chip 240 through the TSV interconnect 250, in the peripheral region of the memory chip 240. The right portion of each of the metal traces 302a may be between one of the overlying interconnects 302b and one of the overlying interconnects 302d. Some of the serial input ports 234 of the memory chip 240 can be arranged in a line parallel with the edge 401c and in the peripheral region of the memory chip 240 closer to the edge 401c than the edge 401d, and the others can be arranged in a line parallel with the edge 401d and in the peripheral region of the memory chip 240 closer to the edge 401d than the edge 401c. Some of the serial output ports 235 of the memory chip 240 can be arranged in a line parallel with the edge 401c and in the peripheral region of the memory chip 240 closer to the edge 401c than the edge 401d, and the others can be arranged in a line parallel with the edge 401d and in the peripheral region of the memory chip 240 closer to the edge 401d than the edge 401c. Some of the TSV interconnects 250 can be arranged in a line parallel with the edge 401c and in the peripheral region of the memory chip 240 closer to the edge 401c than the edge 401d, and the others can be arranged in a line parallel with the edge 401d and in the peripheral region of the memory chip 240 closer to the edge 401d than the edge 401c. Some of the TSV interconnects 264 can be arranged in a line parallel with the edge 401c and in the peripheral region of the memory chip 240 closer to the edge 401c than the edge 401d, and the others can be arranged in a line parallel with the edge 401d and in the peripheral region of the memory chip 240 closer to the edge 401d than the edge 401c. Some of the TSV interconnects 268 can be arranged in a line parallel with the edge 401c and in the peripheral region of the memory chip 240 closer to the edge 401c than the edge 401d, and the others can be arranged in a line parallel with the edge 401d and in the peripheral region of the memory chip 240 closer to the edge 401d than the edge 401c. Some of the TSV interconnects 246 can be arranged in a line parallel with the edge 401a and in the peripheral region of the memory chip 240 closer to the edge 401a than the edge 401b, and the others can be arranged in a line parallel with the edge 401b and in the peripheral region of the memory chip 240 closer to the edge 401b than the edge 401a. Some of the parallel common input ports 228 of the memory chip 240 can be arranged in a line parallel with the edge 401a and in the peripheral region of the memory chip 240 closer to the edge 401a than the edge 401b, and the others can be arranged in a line parallel with the edge 401b and in the peripheral region of the memory chip 240 closer to the edge 401b than the edge 401a. Some of the meal traces 302a can be in the peripheral region of the memory chip 240 closer to the edge 401c than the edge 401d, and the others can be in the peripheral region of the memory chip 240 closer to the edge 401d than the edge 401c. Some of the overlying interconnects 302b can be in the peripheral region of the memory chip 240 closer to the edge 401c than the edge 401d, and the others can be in the peripheral region of the memory chip 240 closer to the edge 401d than the edge 401c. Some of the overlying interconnects 302c can be in the peripheral region of the memory chip 240 closer to the edge 401a than the edge 401b, and the others can be in the peripheral region of the memory chip 240 closer to the edge 401b than the edge 401a. Some of the overlying interconnects 302d can be in the peripheral region of the memory chip 240 closer to the edge 401c than the edge 401d, and the others can be in the peripheral region of the memory chip 240 closer to the edge 401d than the edge 401c. The overlying interconnects 236b may further include multiple power traces or planes and multiple ground traces or planes in a center region of the memory chip 240 enclosed by the peripheral region of the memory chip 240.

Referring to FIGS. 87, 90 and 99, the memory chip 242 includes the above-mentioned circuit paths, signal paths, illustrated in FIG. 86, between the serial input ports 234 of the memory chip 242 and the serial output ports 235 of the memory chip 242. For example, the memory chip 242 includes a circuit path, signal path, between the input port D0 of the memory chip 242 and the corresponding output port Q0 of the memory chip 242. The serial output ports 235 of the memory chip 242 can be physically and electrically connected to the serial input ports 234 of the memory chip 244 through, in sequence, the TSV interconnects 250 in the memory chip 242, the metal traces 303a, and the TSV interconnects 264 passing through the memory chip 244. The overlying interconnects 303d can be spaced apart from the metal traces 303a, and the TSV interconnects 264 in the memory chip 242 cannot be connected to the metal traces 303a through the overlying interconnects 303d. The TSV interconnects 264 passing through the memory chip 242 can connect the serial input ports 234 of the memory chip 242 and the metal traces 302a shown in FIGS. 89 and 98. The above-mentioned serial connection 233c, illustrated in FIG. 86, between the serial output ports 235 of the memory chip 242 and the serial input ports 234 of the memory chip 244 may include the TSV interconnects 250 in the memory chip 242, the metal traces 303a, and the TSV interconnects 264 passing through the memory chip 244. From a top perspective view, the isolation enclosures 202 enclosing the TSV interconnects 264 in the memory chip 242 are substantially aligned with the isolation enclosures 202 enclosing the TSV interconnects 264 in the memory chip 240, and the TSV interconnects 264 in the memory chip 242 can be horizontally offset from the TSV interconnects 264 in the memory chip 240.

Referring to FIG. 90, each of the metal traces 303a may have a middle portion in a center region of the memory chip 242 enclosed by a peripheral region of the memory chip 242, a right portion, connecting to the input port 234 of the memory chip 244 through the TSV interconnect 264 in the memory chip 244 shown in FIGS. 87 and 91, in the peripheral region of the memory chip 242 closer to the edge 401a than the edge 401b, and a left portion, connecting to the output port 235 of the memory chip 242 through the TSV interconnect 250, in the peripheral region of the memory chip 242 closer to the edge 401b than the edge 401a. The serial input ports 234 of the memory chip 242 may be arranged in a line parallel with the edge 401a and in the peripheral region of the memory chip 242 closer to the edge 401a than the edge 401b. The serial output ports 235 of the memory chip 242 may be arranged in a line parallel with the edge 401b and in the peripheral region of the memory chip 242 closer to the edge 401b than the edge 401a. The TSV interconnects 264 may be arranged in a line parallel with the edge 401a and in the peripheral region of the memory chip 242 closer to the edge 401a than the edge 401b. The TSV interconnects 250 may be arranged in a line parallel with the edge 401b and in the peripheral region of the memory chip 242 closer to the edge 401b than the edge 401a. The parallel common input ports 228 of the memory chip 242 may be arranged in a line parallel with the edge 401b and in the peripheral region of the memory chip 242 closer to the edge 401b than the edge 401a. The TSV interconnects 268 may be arranged in a line parallel with the edge 401a and in the peripheral region of the memory chip 242 closer to the edge 401a than the edge 401b. The TSV interconnects 246 may be arranged in a line parallel with the edge 401b and in the peripheral region of the memory chip 242 closer to the edge 401b than the edge 401a. The overlying interconnects 303b and 303d can be in the peripheral region of the memory chip 242 closer to the edge 401a than the edge 401b. The overlying interconnects 303c can be in the peripheral region of the memory chip 242 closer to the edge 401b than the edge 401a. The overlying interconnects 236c may further include multiple power traces or planes and multiple ground traces or planes in the center region and/or peripheral region of the memory chip 242. Alternatively, the metal traces 303a, the overlying interconnects 303b, 303c and 303d, the serial input ports 234 of the memory chip 242, the serial output ports 235 of the memory chip 242, the parallel common input ports 228 of the memory chip 242, and the TSV interconnects 246, 250, 264 and 268 may be all in the center region of the memory chip 242.

Referring to FIG. 99, each of the metal traces 303a may have a right portion, connecting to the input port 234 of the memory chip 244 through the TSV interconnect 264 in the memory chip 244 shown in FIGS. 87 and 100, in a peripheral region of the memory chip 242, and a left portion, connecting to the output port 235 of the memory chip 242 through the TSV interconnect 250, in the peripheral region of the memory chip 242. Some of the serial input ports 234 of the memory chip 242 can be arranged in a line parallel with the edge 401c and in the peripheral region of the memory chip 242 closer to the edge 401c than the edge 401d, and the others can be arranged in a line parallel with the edge 401d and in the peripheral region of the memory chip 242 closer to the edge 401d than the edge 401c. Some of the serial output ports 235 of the memory chip 242 can be arranged in a line parallel with the edge 401c and in the peripheral region of the memory chip 242 closer to the edge 401c than the edge 401d, and the others can be arranged in a line parallel with the edge 401d and in the peripheral region of the memory chip 242 closer to the edge 401d than the edge 401c. Some of the TSV interconnects 250 can be arranged in a line parallel with the edge 401c and in the peripheral region of the memory chip 242 closer to the edge 401c than the edge 401d, and the others can be arranged in a line parallel with the edge 401d and in the peripheral region of the memory chip 242 closer to the edge 401d than the edge 401c. Some of the TSV interconnects 264 can be arranged in a line parallel with the edge 401c and in the peripheral region of the memory chip 242 closer to the edge 401c than the edge 401d, and the others can be arranged in a line parallel with the edge 401d and in the peripheral region of the memory chip 242 closer to the edge 401d than the edge 401c. Some of the TSV interconnects 268 can be arranged in a line parallel with the edge 401c and in the peripheral region of the memory chip 242 closer to the edge 401c than the edge 401d, and the others can be arranged in a line parallel with the edge 401d and in the peripheral region of the memory chip 242 closer to the edge 401d than the edge 401c. Some of the TSV interconnects 246 can be arranged in a line parallel with the edge 401a and in the peripheral region of the memory chip 242 closer to the edge 401a than the edge 401b, and the others can be arranged in a line parallel with the edge 401b and in the peripheral region of the memory chip 242 closer to the edge 401b than the edge 401a. Some of the parallel common input ports 228 of the memory chip 242 can be arranged in a line parallel with the edge 401a and in the peripheral region of the memory chip 242 closer to the edge 401a than the edge 401b, and the others can be arranged in a line parallel with the edge 401b and in the peripheral region of the memory chip 242 closer to the edge 401b than the edge 401a. Some of the meal traces 303a can be in the peripheral region of the memory chip 242 closer to the edge 401c than the edge 401d, and the others can be in the peripheral region of the memory chip 242 closer to the edge 401d than the edge 401c. Some of the overlying interconnects 303b can be in the peripheral region of the memory chip 242 closer to the edge 401c than the edge 401d, and the others can be in the peripheral region of the memory chip 242 closer to the edge 401d than the edge 401c. Some of the overlying interconnects 303c can be in the peripheral region of the memory chip 242 closer to the edge 401a than the edge 401b, and the others can be in the peripheral region of the memory chip 242 closer to the edge 401b than the edge 401a. Some of the overlying interconnects 303d can be in the peripheral region of the memory chip 242 closer to the edge 401c than the edge 401d, and the others can be in the peripheral region of the memory chip 242 closer to the edge 401d than the edge 401c. The overlying interconnects 236c may further include multiple power traces or planes and multiple ground traces or planes in a center region of the memory chip 242 enclosed by the peripheral region of the memory chip 242.

Referring to FIGS. 87, 91 and 100, the memory chip 244 includes the above-mentioned circuit paths, signal paths, illustrated in FIG. 86, between the serial input ports 234 of the memory chip 244 and the serial output ports 235 of the memory chip 244. For example, the memory chip 244 includes a circuit path, signal path, between the input port D0 of the memory chip 244 and the corresponding output port Q0 of the memory chip 244. The serial output ports 235 of the memory chip 244 can be physically and electrically connected to the metal pillars or bumps 252 through, in sequence, the TSV interconnects 250 in the memory chip 244, and the metal traces 304a. The overlying interconnects 304d can be spaced apart from the metal traces 304a, and the TSV interconnects 264 in the memory chip 244 cannot be connected to the metal traces 304a through the overlying interconnects 304d. The TSV interconnects 264 passing through the memory chip 244 can connect the serial input ports 234 of the memory chip 244 and the metal traces 303a shown in FIGS. 90 and 99. The overlying interconnects 304b can connect the TSV interconnects 268 in the memory chip 244 to the metal pillars or bumps 254. The overlying interconnects 304c can be connected to the parallel common input ports 228 of the memory chip 244 through the TSV interconnects 246 in the memory chip 244. The metal pillars or bumps 248 may be vertically over the TSV interconnects 246 in the memory chip 244. The metal pillars or bumps 254 may be vertically over the TSV interconnects 268 in the memory chip 244. There are no metal pillars or bumps vertically over the overlying interconnects 304d to connect to the overlying interconnects 304d. From a top perspective view, the isolation enclosures 202 enclosing the TSV interconnects 264 in the memory chip 244 are substantially aligned with the isolation enclosures 202 enclosing the TSV interconnects 264 in the memory chip 242 and with the isolation enclosures 202 enclosing the TSV interconnects 264 in the memory chip 240, and the TSV interconnects 264 in the memory chip 244 can be horizontally offset from the TSV interconnects 264 in the memory chip 242 and can be vertically over the TSV interconnects 264 in the memory chip 240.

Referring to FIG. 91, each of the metal traces 304a may have a middle portion in a center region of the memory chip 244 enclosed by a peripheral region of the memory chip 244, a right portion, between one of the overlying interconnects 304b and one of the overlying interconnects 304d, in the peripheral region of the memory chip 244 closer to the edge 401a than the edge 401b, and a left portion, connecting to the output port 235 of the memory chip 244 through the TSV interconnect 250, in the peripheral region of the memory chip 244 closer to the edge 401b than the edge 401a. The serial input ports 234 of the memory chip 244 may be arranged in a line parallel with the edge 401a and in the peripheral region of the memory chip 244 closer to the edge 401a than the edge 401b. The serial output ports 235 of the memory chip 244 may be arranged in a line parallel with the edge 401b and in the peripheral region of the memory chip 244 closer to the edge 401b than the edge 401a. The TSV interconnects 264 may be arranged in a line parallel with the edge 401a and in the peripheral region of the memory chip 244 closer to the edge 401a than the edge 401b. The TSV interconnects 250 may be arranged in a line parallel with the edge 401b and in the peripheral region of the memory chip 244 closer to the edge 401b than the edge 401a. The parallel common input ports 228 of the memory chip 244 may be arranged in a line parallel with the edge 401b and in the peripheral region of the memory chip 244 closer to the edge 401b than the edge 401a. The TSV interconnects 268 may be arranged in a line parallel with the edge 401a and in the peripheral region of the memory chip 244 closer to the edge 401a than the edge 401b. The TSV interconnects 246 may be arranged in a line parallel with the edge 401b and in the peripheral region of the memory chip 244 closer to the edge 401b than the edge 401a. The overlying interconnects 304b and 304d can be in the peripheral region of the memory chip 244 closer to the edge 401a than the edge 401b. The overlying interconnects 304c can be in the peripheral region of the memory chip 244 closer to the edge 401b than the edge 401a. The overlying interconnects 236d may further include multiple power traces or planes and multiple ground traces or planes in the center region and/or peripheral region of the memory chip 244. Alternatively, the metal traces 304a, the overlying interconnects 304b, 304c and 304d, the serial input ports 234 of the memory chip 244, the serial output ports 235 of the memory chip 244, the parallel common input ports 228 of the memory chip 244, and the TSV interconnects 246, 250, 264 and 268 may be all in the center region of the memory chip 244.

The layout design of the overlying interconnects 236d, including the metal traces 304a and the overlying interconnects 304b, 304c and 304d, shown in FIG. 91 can be same as that of the overlying interconnects 236b, including the metal traces 302a and the overlying interconnects 302b, 302c and 302d, shown in FIG. 89. That is, the metal traces 304a and the overlying interconnects 304b, 304c and 304d shown in FIG. 91 can be vertically over and substantially aligned with the metal traces 302a and the overlying interconnects 302b, 302c and 302d shown in FIG. 89.

Referring to FIG. 100, each of the metal traces 304a may have a right portion, between one of the overlying interconnects 304b and one of the overlying interconnects 304d, in a peripheral region of the memory chip 244, and a left portion, connecting to the output port 235 of the memory chip 244 through the TSV interconnect 250, in the peripheral region of the memory chip 244. Some of the serial input ports 234 of the memory chip 244 can be arranged in a line parallel with the edge 401c and in the peripheral region of the memory chip 244 closer to the edge 401c than the edge 401d, and the others can be arranged in a line parallel with the edge 401d and in the peripheral region of the memory chip 244 closer to the edge 401d than the edge 401c. Some of the serial output ports 235 of the memory chip 244 can be arranged in a line parallel with the edge 401c and in the peripheral region of the memory chip 244 closer to the edge 401c than the edge 401d, and the others can be arranged in a line parallel with the edge 401d and in the peripheral region of the memory chip 244 closer to the edge 401d than the edge 401c. Some of the TSV interconnects 250 can be arranged in a line parallel with the edge 401c and in the peripheral region of the memory chip 244 closer to the edge 401c than the edge 401d, and the others can be arranged in a line parallel with the edge 401d and in the peripheral region of the memory chip 244 closer to the edge 401d than the edge 401c. Some of the TSV interconnects 264 can be arranged in a line parallel with the edge 401c and in the peripheral region of the memory chip 244 closer to the edge 401c than the edge 401d, and the others can be arranged in a line parallel with the edge 401d and in the peripheral region of the memory chip 244 closer to the edge 401d than the edge 401c. Some of the TSV interconnects 268 can be arranged in a line parallel with the edge 401c and in the peripheral region of the memory chip 244 closer to the edge 401c than the edge 401d, and the others can be arranged in a line parallel with the edge 401d and in the peripheral region of the memory chip 244 closer to the edge 401d than the edge 401c. Some of the TSV interconnects 246 can be arranged in a line parallel with the edge 401a and in the peripheral region of the memory chip 244 closer to the edge 401a than the edge 401b, and the others can be arranged in a line parallel with the edge 401b and in the peripheral region of the memory chip 244 closer to the edge 401b than the edge 401a. Some of the parallel common input ports 228 of the memory chip 244 can be arranged in a line parallel with the edge 401a and in the peripheral region of the memory chip 244 closer to the edge 401a than the edge 401b, and the others can be arranged in a line parallel with the edge 401b and in the peripheral region of the memory chip 244 closer to the edge 401b than the edge 401a. Some of the meal traces 304a can be in the peripheral region of the memory chip 244 closer to the edge 401c than the edge 401d, and the others can be in the peripheral region of the memory chip 244 closer to the edge 401d than the edge 401c. Some of the overlying interconnects 304b can be in the peripheral region of the memory chip 244 closer to the edge 401c than the edge 401d, and the others can be in the peripheral region of the memory chip 244 closer to the edge 401d than the edge 401c. Some of the overlying interconnects 304c can be in the peripheral region of the memory chip 244 closer to the edge 401a than the edge 401b, and the others can be in the peripheral region of the memory chip 244 closer to the edge 401b than the edge 401a. Some of the overlying interconnects 304d can be in the peripheral region of the memory chip 244 closer to the edge 401c than the edge 401d, and the others can be in the peripheral region of the memory chip 244 closer to the edge 401d than the edge 401c. The overlying interconnects 236d may further include multiple power traces or planes and multiple ground traces or planes in a center region of the memory chip 244 enclosed by the peripheral region of the memory chip 244.

The layout design of the overlying interconnects 236d, including the metal traces 304a and the overlying interconnects 304b, 304c and 304d, shown in FIG. 100 can be same as that of the overlying interconnects 236b, including the metal traces 302a and the overlying interconnects 302b, 302c and 302d, shown in FIG. 98. That is, the metal traces 304a and the overlying interconnects 304b, 304c and 304d shown in FIG. 100 can be vertically over and substantially aligned with the metal traces 302a and the overlying interconnects 302b, 302c and 302d shown in FIG. 98.

The layout design of the parallel common input ports 228 shown in FIG. 91 or 100 can be same as that of the parallel common input ports 228 shown in FIG. 88 or 97, that of the parallel common input ports 228 shown in FIG. 89 or 98, and that of the parallel common input ports 228 shown in FIG. 90 or 99. That is, the parallel common input ports 228 shown in FIG. 91 or 100 can be vertically over and substantially aligned with the parallel common input ports 228 shown in FIG. 88 or 97, the parallel common input ports 228 shown in FIG. 89 or 98, and the parallel common input ports 228 shown in FIG. 90 or 99.

The layout design of the serial input ports 234 shown in FIG. 91 or 100 can be same as that of the serial input ports 234 shown in FIG. 88 or 97, that of the serial input ports 234 shown in FIG. 89 or 98, and that of the serial input ports 234 shown in FIG. 90 or 99. That is, the serial input ports 234 shown in FIG. 91 or 100 can be vertically over and substantially aligned with the serial input ports 234 shown in FIG. 88 or 97, the serial input ports 234 shown in FIG. 89 or 98, and the serial input ports 234 shown in FIG. 90 or 99.

The layout design of the serial output ports 235 shown in FIG. 91 or 100 can be same as that of the serial output ports 235 shown in FIG. 88 or 97, that of the serial output ports 235 shown in FIG. 89 or 98, and that of the serial output ports 235 shown in FIG. 90 or 99. That is, the serial output ports 235 shown in FIG. 91 or 100 can be vertically over and substantially aligned with the serial output ports 235 shown in FIG. 88 or 97, the serial output ports 235 shown in FIG. 89 or 98, and the serial output ports 235 shown in FIG. 90 or 99.

The layout design of the TSV interconnects 246 shown in FIG. 91 or 100 can be same as that of the TSV interconnects 246 shown in FIG. 89 or 98 and that of the TSV interconnects 246 shown in FIG. 90 or 99. That is, the TSV interconnects 246 shown in FIG. 91 or 100 can be vertically over and substantially aligned with the TSV interconnects 246 shown in FIG. 89 or 98 and the TSV interconnects 246 shown in FIG. 90 or 99.

The layout design of the TSV interconnects 250 shown in FIG. 91 or 100 can be same as that of the TSV interconnects 250 shown in FIG. 88 or 97, that of the TSV interconnects 250 shown in FIG. 89 or 98, and that of the TSV interconnects 250 shown in FIG. 90 or 99. That is, the TSV interconnects 250 shown in FIG. 91 or 100 can be vertically over and substantially aligned with the TSV interconnects 250 shown in FIG. 88 or 97, the TSV interconnects 250 shown in FIG. 89 or 98, and the TSV interconnects 250 shown in FIG. 90 or 99.

The layout design of the TSV interconnects 268 shown in FIG. 91 or 100 can be same as that of the TSV interconnects 268 shown in FIG. 89 or 98 and that of the TSV interconnects 268 shown in FIG. 90 or 99. That is, the TSV interconnects 268 shown in FIG. 91 or 100 can be vertically over and substantially aligned with the TSV interconnects 268 shown in FIG. 89 or 98 and the TSV interconnects 268 shown in FIG. 90 or 99.

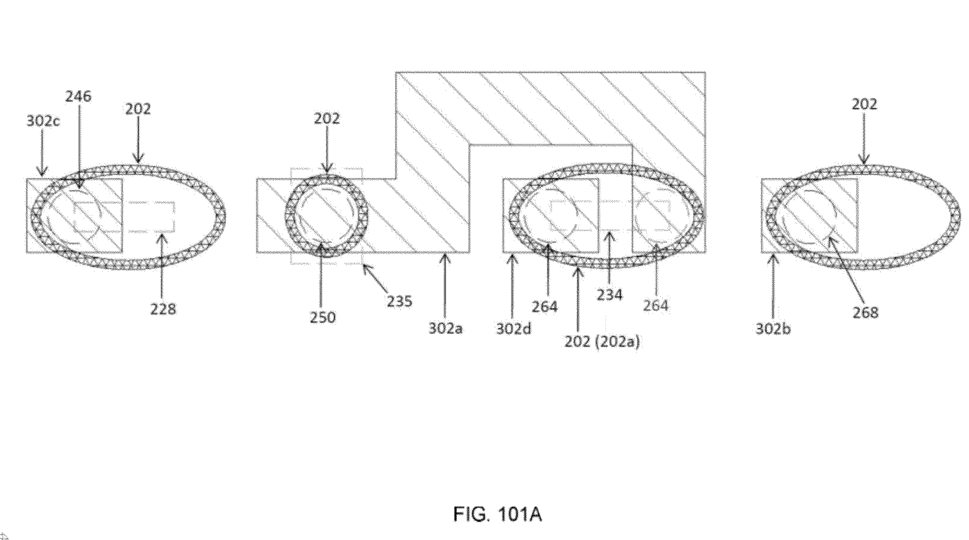

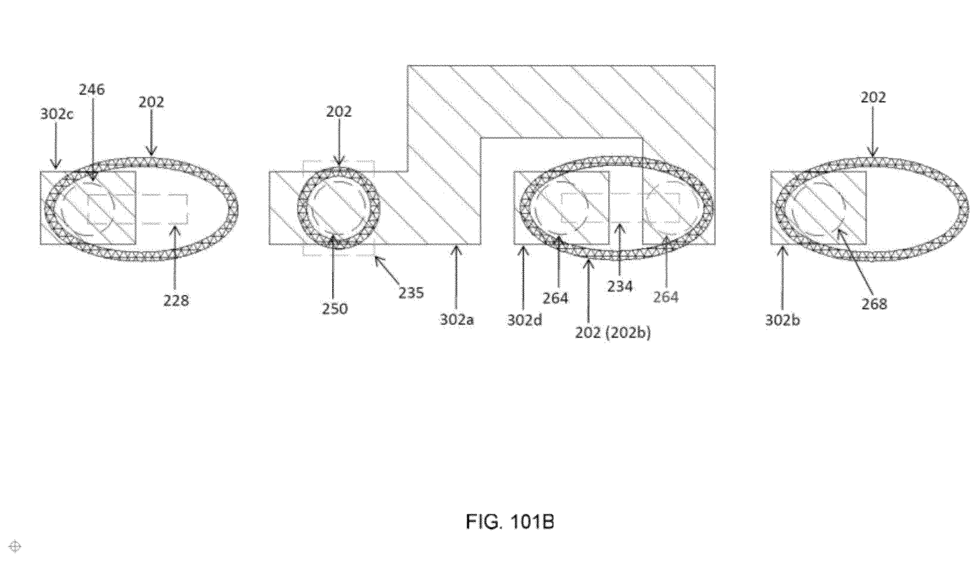

FIGS. 101A and 101B are top perspective views illustrating a region 600 shown in FIGS. 98 and 99. Both of FIGS. 101A and 101B show the metal trace 302a and the overlying interconnects 302b, 302c and 302d are at a same horizontal level of the overlying interconnects 236b between the upper and lower memory chips 242 and 240 shown in FIG. 87. Both of FIGS. 101A and 101B show the left TSV interconnect 264 in the lower memory chip 240 shown in FIG. 87 and the right TSV interconnect 264 in the upper memory chip 242 shown in FIG. 87. FIG. 101B shows the isolation enclosures 202 vertically over and substantially aligned with the isolation enclosures 202 shown in FIG. 101A, respectively. For example, the upper isolation enclosure 202, that is, 202b shown in FIG. 101B, enclosing the right TSV interconnect 264 in the upper memory chip 242 can be vertically over and substantially aligned with the lower isolation enclosure 202, that is, 202a shown in FIG. 101A, enclosing the left TSV interconnect 264 in the lower memory chip 240. The upper TSV interconnects 246, 250 and 268, in the upper memory chip 242, shown in FIG. 101B can be vertically over and substantially aligned with the lower TSV interconnects 246, 250 and 268, in the lower memory chip 240, shown in FIG. 101A. The ports 234, 235 and 228, in the upper memory chip 242, shown in FIG. 101B can be vertically over and substantially aligned with the ports 234, 235 and 228, in the lower memory chip 240, shown in FIG. 101A. The right TSV interconnect 264 in the upper memory chip 242 can be not vertically over the left TSV interconnect 264 in the lower memory chip 240, as shown in FIGS. 87, 101A and 101B. Alternatively, the right TSV interconnect 264 in the upper memory chip 242 may be horizontally offset from the left TSV interconnect 264 in the lower memory chip 240, as shown in FIGS. 87, 101A and 101B.

Referring to FIG. 101A, the left TSV interconnect 264 can pass through a portion of the semiconductor substrate 2 enclosed by one of the isolation enclosures 202, that is, 202a shown in FIG. 101A, of the lower memory chip 240, and the right TSV interconnect 264 in the upper memory chip 242 is vertically over the portion of the semiconductor substrate 2 enclosed by the isolation enclosure 202a of the lower memory chip 240.

Referring to FIG. 101B, the right TSV interconnect 264 in the upper memory chip 242 can contact the metal trace 302a and the serial input port 234 of the memory chip 242. The right TSV interconnect 264 can pass through a portion of the semiconductor substrate 2 enclosed by one of the isolation enclosures 202, that is, 202b shown in FIG. 101B, of the upper memory chip 242, and the left TSV interconnect 264 in the lower memory chip 240 is vertically under the portion of the semiconductor substrate 2 enclosed by the isolation enclosure 202b of the upper memory chip 242.

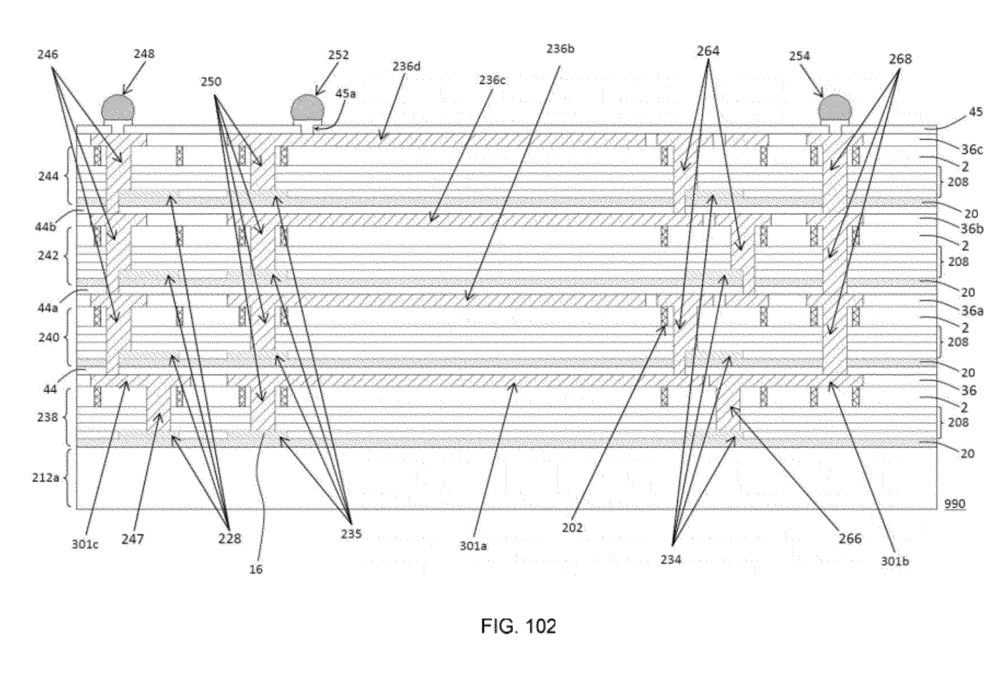

Referring to FIGS. 87 and 102, the multichip package 990 shown in FIG. 102 is similar to the multichip package 990 illustrated in FIG. 87 except that the interconnects 256 and 261 of each of the memory chips 238, 240, 242 and 244 are omitted, the TSV interconnects 266 in the memory chip 238 contact the serial input ports 234 of the memory chip 238 instead of contacting the interconnects 256 of the memory chip 238, the TSV interconnects 247 in the memory chip 238 contact the parallel common input ports 228 of the memory chip 238 instead of contacting the interconnects 261 of the memory chip 238, and the layout design of the overlying interconnects 301b shown in FIG. 102 is different from that of the overlying interconnects 301b shown in FIG. 87. The TSV interconnects 266 shown in FIG. 102 may be through and enclosed by some of the isolation enclosures 202, in the memory chip 238, vertically under and substantially aligned with the isolation enclosures 202 enclosing the TSV interconnects 264 in the memory chip 240. The schematic circuit diagram illustrated in FIG. 86 can be applied to the multichip package 990 shown in FIG. 102.

The multichip package 990 shown in FIG. 87 or 102 includes four-level stacked memory chips 238, 240, 242 and 244, four levels of the TSV interconnects in the four-level memory chips 238, 240, 242 and 244, and four levels of the overlying interconnects at backsides of the four-level memory chips 238, 240, 242 and 244. Alternatively, the multichip package 990 may further include another one or more levels of the memory chips stacked over the memory chip 244, another one or more levels of the TSV interconnects in the another one or more levels of the memory chips, and another one or more levels of the overlying interconnects at backsides of the another one or more levels of the memory chips. The another one or more levels of the memory chips and the memory chips 238, 240, 242 and 244 can be same chips having a same die marking and/or having a same layout of the DTI layer 4.

The layout design of the odd-level TSV interconnects in the odd-level memory chip(s) over the memory chip 244 and the layout design of the odd-level overlying interconnects at backside(s) of the odd-level memory chip(s) over the memory chip 244 can be referred to as the layout design of the TSV interconnects 246, 250, 264 and 268 in the memory chip 242 and the layout design of the overlying interconnects 236c at the backside of the memory chip 242, respectively.

The layout design of the even-level TSV interconnects in the even-level memory chip(s) over the memory chip 244 and the layout design of the even-level overlying interconnects at backside(s) of the even-level memory chip(s) over the memory chip 244 can be referred to as the layout design of the TSV interconnects 246, 250, 264 and 268 in the memory chip 244 and the layout design of the overlying interconnects 236d at the backside of the memory chip 244, respectively.

The insulating layer 45 and the metal pillars or bumps 248, 252 and 254 can be over the topmost one of the stacked memory chips over the memory chip 244, and the metal pillars or bumps 248, 252 and 254 can be connected to the overlying interconnects over the topmost one of the stacked memory chips over the memory chip 244. The layout design of the metal pillars or bumps 248, 252 and 254 can be referred to as that of the metal pillars or bumps 248, 252 and 254 shown in FIG. 87 or 102. Accordingly, the multichip package 990 can include five-level, six-level, eight-level, ten-level, sixteen-level, twenty-level, thirty-two-level or fifty-level stacked memory chips, containing the memory chips 238, 240, 242 and 244, stacked over the substrate 212a.

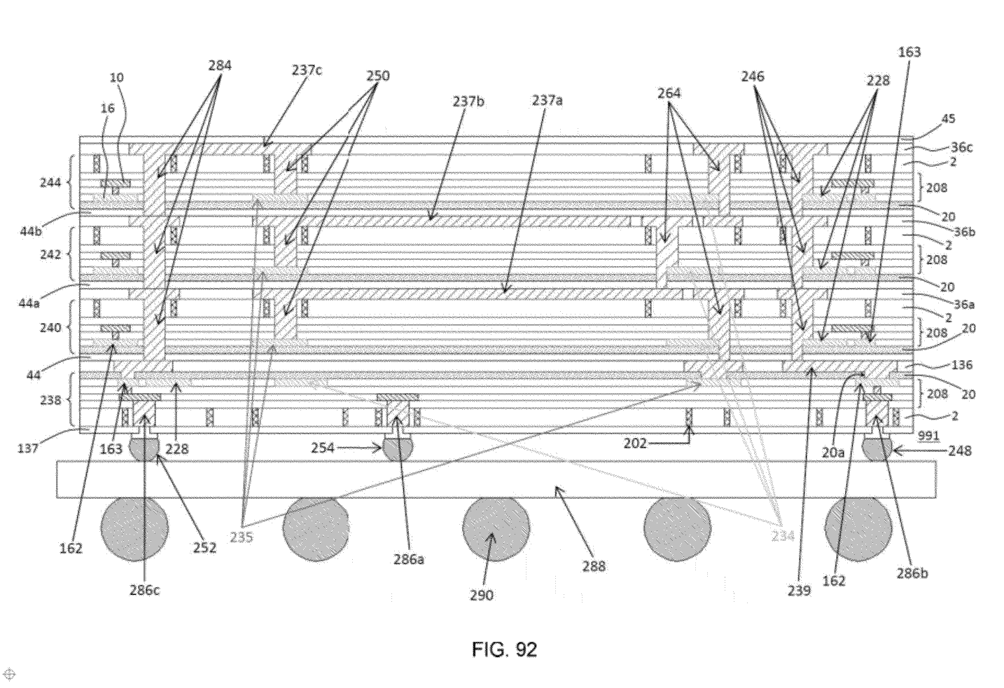

FIG. 92 illustrates a schematic cross-sectional view of a data storage device. Referring to FIG. 92, the data storage device shown in FIG. 92 may include a circuit substrate 288, a multichip package 991 joining and connecting to the circuit substrate 288, a memory controller (not shown) joining the circuit substrate 288 and connecting to the multichip package 991, one or more DRAM chips (not shown) joining the circuit substrate 288, multiple solder balls 290 joining the circuit substrate 288, etc. The circuit substrate 288, for example, may be a printed circuit board (PCB) or a ball-grid-array (BGA) substrate. The solder balls 290 may include one or more of tin, indium, silver, and/or gold. The schematic circuit diagram illustrated in FIG. 86 can be applied to the multichip package 991.

The multichip package 991 includes the memory chips 238, 240, 242 and 244 as mentioned in FIG. 86. In the multichip package 991, the memory chip 238 is faced up, and the memory chips 240, 242 and 244 are faced down. The multichip package 991 further includes multiple metal interconnects 239 between the memory chips 238 and 240, multiple overlying interconnects 237a between the memory chips 240 and 242, multiple overlying interconnects 237b between the memory chips 242 and 244, multiple overlying interconnects 237c over the memory chip 244, multiple TSV interconnects 246, 250, 264 and 284 in the memory chips 240, 242 and 244, multiple TSV interconnects 286a, 286b and 286c in the memory chip 238, a dielectric or insulating layer 136 between the memory chips 238 and 240, the dielectric or insulating layer 36a as mentioned in FIG. 84 between the memory chips 240 and 242, a dielectric or insulating layer 36b between the memory chips 242 and 244, a dielectric or insulating layer 36c over the memory chip 244, the insulating layer 44 as mentioned in FIG. 82 on the metal interconnects 239 and the dielectric or insulating layer 136 and under the memory chip 240, an insulating layer 44a on the overlying interconnects 237a and the dielectric or insulating layer 36a and under the memory chip 242, an insulating layer 44b on the overlying interconnects 237b and the dielectric or insulating layer 36b and under the memory chip 244, the insulating layer 45 as mentioned in FIG. 85 on the overlying interconnects 237c and the dielectric or insulating layer 36c, a dielectric or insulating layer 137 under the memory chip 238, and multiple metal pillars or bumps 248, 252 and 254 under the memory chip 238 and the dielectric or insulating layer 137. There are no openings in the insulating layer 45 shown in FIG. 92 to expose the overlying interconnects 237c.

The multichip package 991 can be mounted over the circuit substrate 288 by joining the metal pillars or bumps 248, 252 and 254 with a solder preformed on the circuit substrate 288, for example. The multichip package 991 can be connected to the circuit substrate 288 through the metal pillars or bumps 248, 252 and 254.

The specifications of the dielectric or insulating layer 36b shown in FIG. 92 can be referred to as the specifications of the dielectric or insulating layer 36a as illustrated in FIG. 84. The specifications of the dielectric or insulating layer 36c shown in FIG. 92 can be referred to as the specifications of the dielectric or insulating layer 36a as illustrated in FIG. 84. The specifications of the insulating layer 44a shown in FIG. 92 can be referred to as the specifications of the insulating layer 44 as illustrated in FIG. 82. The specifications of the insulating layer 44b shown in FIG. 92 can be referred to as the specifications of the insulating layer 44 as illustrated in FIG. 82.

The multichip package 991 may further include the dielectric layer 34a (not shown in FIG. 92), as mentioned in FIG. 84, between the overlying interconnects 237a and the backside of the semiconductor substrate 2 of the memory chip 240 and between the dielectric layer 36a and the backside of the semiconductor substrate 2 of the memory chip 240, a dielectric layer (not shown in FIG. 92), which can be referred to the dielectric layer 34a mentioned in FIG. 84, between the overlying interconnects 237b and the backside of the semiconductor substrate 2 of the memory chip 242 and between the dielectric layer 36b and the backside of the semiconductor substrate 2 of the memory chip 242, and a dielectric layer (not shown in FIG. 92), which can be referred to the dielectric layer 34a mentioned in FIG. 84, between the overlying interconnects 237c and the backside of the semiconductor substrate 2 of the memory chip 244 and between the dielectric layer 36c and the backside of the semiconductor substrate 2 of the memory chip 244.

The TSV interconnects 284 are in TSVs, which can be referred to as the TSVs 77a illustrated in FIG. 84, through the memory chips 240, 242 and 244. The specifications of the TSV interconnects 284 shown in FIG. 92 can be referred to as the specifications of the TSV interconnects 216a as illustrated in FIG. 84. The TSV interconnects 246 and 264 are in TSVs, which can be referred to as the TSVs 77b illustrated in FIG. 84, through the memory chips 240, 242 and 244. The specifications of the TSV interconnects 246 and 264 shown in FIG. 92 can be referred to as the specifications of the TSV interconnects 216b as illustrated in FIG. 84. The TSV interconnects 250 are in TSVs, which can be referred to as the TSVs 77c illustrated in FIG. 84, in the memory chips 240, 242 and 244. The specifications of the TSV interconnects 250 shown in FIG. 92 can be referred to as the specifications of the TSV interconnects 216c as illustrated in FIG. 84. The TSV interconnects 286a, 286b, 286c are in TSVs, which can be referred to as the TSVs 77c illustrated in FIG. 84, in the memory chip 238. The specifications of the TSV interconnects 286a, 286b, 286c shown in FIG. 92 can be referred to as the specifications of the TSV interconnects 216c as illustrated in FIG. 84.

The specifications of the overlying interconnects 237a shown in FIG. 92 can be referred to as the specifications of the overlying interconnects 216d as illustrated in FIG. 84. The specifications of the overlying interconnects 237b shown in FIG. 92 can be referred to as the specifications of the overlying interconnects 216d as illustrated in FIG. 84. The specifications of the overlying interconnects 237c shown in FIG. 92 can be referred to as the specifications of the overlying interconnects 216d as illustrated in FIG. 84.

Each of the memory chips 238, 240, 242 and 244 shown in FIG. 92 may include the ground or polished semiconductor substrate 2, the STI layer 6 (not shown in FIG. 92), the DTI layer 4 having the isolation enclosures 202 and the alignment marks 206 (not shown in FIG. 92), the IC devices 7 (not shown in FIG. 92), the IC scheme 208 and the passivation layer 20, as mentioned above in FIGS. 75-85. The ground or polished semiconductor substrate 2 may have a suitable thickness, such as between 1 and 100 micrometers, between 1 and 50 micrometers, between 1 and 20 micrometers, between 1 and 10 micrometers, between 1 and 5 micrometers, or between 2 and 5 micrometers, that may be same as the thickness of the DTI layer 4. The ground or polished semiconductor substrate 2 may have the above-mentioned surface 200, and the DTI layer 4 may have the above-mentioned bottom surface 400 substantially coplanar with the surface 200. Each of the TSV interconnects 246, 250, 264, 284, 286a, 286b and 286c is enclosed by one of the isolation enclosures 202.

The passivation layer 20 of the memory chip 238 can face the passivation layer 20 of the memory chip 240. The passivation layer 20 of the memory chip 242 can face the backside of the semiconductor substrate 2 of the memory chip 240. The passivation layer 20 of the memory chip 244 can face the backside of the semiconductor substrate 2 of the memory chip 242.

The conductive layer 16 of each of the memory chips 238, 240, 242 and 244 shown in FIG. 92 may include the serial input ports 234 (one of them is shown in each of the memory chips 238, 240, 242 and 244 and can be the input port D0, for example) shown in FIG. 86, the serial output ports 235 (one of them is shown in each of the memory chips 238, 240, 242 and 244 and can be the output port Q0, for example) shown in FIG. 86, the parallel common input ports 228 (one of them is shown in each of the memory chips 238, 240, 242 and 244 and can be the port CK, RST or CE) shown in FIG. 86, and metal interconnects 162 and 163. Multiple openings 20a in the passivation layer 20 of the memory chip 238 shown in FIG. 92 are over multiple contact points of the conductive layer 16 of the memory chip 238, and the contact points are at bottoms of the openings 20a.

The metal interconnects 239, for example, include an adhesion/barrier layer, a seed layer on the adhesion/barrier layer, and a conduction layer on the seed layer. The adhesion/barrier layer can be on a top surface of the passivation layer 20 of the memory chip 238 and on the contact points, under the openings 20a, of the conductive layer 16 of the memory chip 238. The adhesion/barrier layer can be form by a suitable process, such as sputtering process. The adhesion/barrier layer may include or can be a metal layer, such as titanium, a titanium-tungsten alloy, titanium nitride, chromium, tantalum or tantalum nitride, having a suitable thickness, such as smaller than 1 micrometer or between 1 nanometer and 0.5 micrometers. The seed layer may include or can be a metal layer, such as copper, a titanium-copper alloy, nickel or gold, having a suitable thickness, such as smaller than 1 micrometer or between 10 nanometers and 0.8 micrometers, on the adhesion/barrier layer. The seed layer can be formed by a suitable process, such as sputtering process. The conduction layer may include or can be a metal layer, such as copper, gold or nickel, having a suitable thickness, such as greater than 3 micrometers or between 5 and 25 micrometers, on the seed layer. The conduction layer can be formed by a suitable process, such as electroplating process.

Alternatively, the metal interconnects 239 may include an adhesion/barrier layer and an aluminum-containing layer, such as aluminum or an aluminum-copper alloy, on the adhesion/barrier layer. The adhesion/barrier layer can be on the top surface of the passivation layer 20 of the memory chip 238 and on the contact points, under the openings 20a, of the conductive layer 16 of the memory chip 238. The adhesion/barrier layer may include or can be a metal layer, such as titanium, a titanium-tungsten alloy or titanium nitride, having a suitable thickness, such as smaller than 1 micrometer or between 1 nanometer and 0.5 micrometers.

The dielectric or insulating layer 136, for example, can be a polymer layer, such as polyimide, benzocyclobutene (BCB), epoxy, polybenzoxazole (PBO) or Poly(p-phenylene oxide) (PPO), having a thickness greater than that of the passivation layer 20 of the memory chip 238 and between 2 and 30 micrometers on the passivation layer 20 of the memory chip 238. The metal interconnects 239 can be in the dielectric or insulating layer 136, and each of the metal interconnects 239 may have a top surface substantially coplanar with a top surface of the dielectric or insulating layer 136. The insulating layer 44 can be on the top surface of the dielectric or insulating layer 136 and on the top surfaces of the metal interconnects 239.

The dielectric or insulating layer 137, for example, may include or can be a silicon-containing layer, such as silicon oxide, silicon nitride, silicon carbon nitride or silicon oxynitride, having a suitable thickness, such as between 0.1 and 1 micrometers or between 0.3 and 2 micrometers, on the backside of the semiconductor substrate 2 of the memory chip 238. Alternatively, the dielectric or insulating layer 137 may include or can be a polymer layer, such as polyimide, benzocyclobutene (BCB), epoxy, polybenzoxazole (PBO) or Poly(p-phenylene oxide) (PPO) having a suitable thickness, such as between 1 and 5 micrometers or between 2 and 10 micrometers. The metal pillars or bumps 248 can contact the TSV interconnects 286b and the dielectric or insulating layer 137. The metal pillars or bumps 252 can contact the TSV interconnects 286c and the dielectric or insulating layer 137. The metal pillars or bumps 254 can contact the TSV interconnects 286a and the dielectric or insulating layer 137. The specifications of the metal pillars or bumps 248, 252 and 254 shown in FIG. 92 can be referred to as the specifications of the metal pillars or bumps 99 as illustrated in FIG. 85.

The TSV interconnects 246 passing through the memory chip 240 may contact the parallel common input ports 228 of the memory chip 240 and some of the metal interconnects 239, that are, metal traces 239b mentioned as below, connecting to the parallel common input ports 228 of the memory chip 238 and the metal interconnects 162 of the memory chip 238 through the openings 20a in the passivation layer 20 of the memory chip 238, and connecting to the metal pillars or bumps 248 through the TSV interconnects 286b in the memory chip 238. The TSV interconnects 246 passing through the memory chip 240 may be not vertically over the TSV interconnects 286b (one of them is shown in FIG. 92) in the memory chip 238. Alternatively, the TSV interconnects 246 passing through the memory chip 240 may be horizontally offset from the TSV interconnects 238b in the memory chip 238.

The TSV interconnects 246 passing through the memory chip 242 may contact the parallel common input ports 228 of the memory chip 242 and some of the overlying interconnects 237a, that are, overlying interconnects 311b mentioned as below, connecting to the TSV interconnects 246 in the memory chip 240. The TSV interconnects 246 in the memory chip 242 may be vertically over the TSV interconnects 246 in the memory chip 240.

The TSV interconnects 246 passing through the memory chip 244 may contact the parallel common input ports 228 of the memory chip 244 and some of the overlying interconnects 237b, that are, overlying interconnects 312b mentioned as below, connecting to the TSV interconnects 246 in the memory chip 242. The TSV interconnects 246 in the memory chip 244 may be vertically over the TSV interconnects 246 in the memory chip 242.

The isolation enclosures 202 enclosing the TSV interconnects 246 in through the memory chip 242 can be vertically over and substantially aligned with the isolation enclosures 202 enclosing the TSV interconnects 246 in the memory chip 240. The isolation enclosures 202 enclosing the TSV interconnects 246 in the memory chip 244 can be vertically over and substantially aligned with the isolation enclosures 202 enclosing the TSV interconnects 246 in the memory chip 242. The isolation enclosures 202 enclosing the TSV interconnects 246 in the memory chip 244 can be vertically over and substantially aligned with the isolation enclosures 202 enclosing the TSV interconnects 246 in the memory chip 240.

The parallel common input ports 228 of the memory chip 240 may be not vertically over the parallel common input ports 228 of the memory chip 238. The parallel common input ports 228 of the memory chip 242 may be vertically over and substantially aligned with the parallel common input ports 228 of the memory chip 240. The parallel common input ports 228 of the memory chip 244 may be vertically over and substantially aligned with the parallel common input ports 228 of the memory chip 242.

The TSV interconnects 250 in the memory chip 240 can connect the serial output ports 235 of the memory chip 240 to some of the overlying interconnects 237a, that are, metal traces 311a mentioned as below, connecting to the serial input ports 234 of the memory chip 242. The TSV interconnects 250 in the memory chip 242 can connect the serial output ports 235 of the memory chip 242 to some of the overlying interconnects 237b, that are, metal traces 312a mentioned as below, connecting to the serial input ports 234 of the memory chip 244. The TSV interconnects 250 in the memory chip 242 may be vertically over the TSV interconnects 250 in the memory chip 240. The isolation enclosures 202 enclosing the TSV interconnects 250 in the memory chip 242 can be vertically over and substantially aligned with the isolation enclosures 202 enclosing the TSV interconnects 250 in the memory chip 240. The TSV interconnects 250 in the memory chip 244 can connect the serial output ports 235 of the memory chip 244 to some of the overlying interconnects 237c, that are, metal traces 313a mentioned as below, connecting to the TSV interconnects 284 in the memory chip 244. The TSV interconnects 250 in the memory chip 244 may be vertically over the TSV interconnects 250 in the memory chip 242. The isolation enclosures 202 enclosing the TSV interconnects 250 in the memory chip 244 can be vertically over and substantially aligned with the isolation enclosures 202 enclosing the TSV interconnects 250 in the memory chip 242.

The serial output ports 235 of the memory chip 240 may be not vertically over and substantially aligned with the serial output ports 235 of the memory chip 238. The serial output ports 235 of the memory chip 242 may be vertically over and substantially aligned with the serial output ports 235 of the memory chip 240. The serial output ports 235 of the memory chip 244 may be vertically over and substantially aligned with the serial output ports 235 of the memory chip 242.

The TSV interconnects 264 passing through the memory chip 240 can contact the serial input ports 234 of the memory chip 240 and some of the metal interconnects 239, that are, metal interconnects 239a mentioned as below, connecting to the serial output ports 235 of the memory chip 238 through multiple openings 20a in the passivation layer 20 of the memory chip 238. The TSV interconnects 264 passing through the memory chip 242 can contact the serial input ports 234 of the memory chip 242 and some of the overlying interconnects 237a, that are, metal traces 311a mentioned as below, connecting to the serial output ports 235 of the memory chip 240. The TSV interconnects 264 in the memory chip 242 may be not vertically over the TSV interconnects 264 in the memory chip 240. The TSV interconnects 264 passing through the memory chip 244 can contact the serial input ports 234 of the memory chip 244 and some of the overlying interconnects 237b, that are, metal traces 312a mentioned as below, connecting to the serial output ports 235 of the memory chip 242. The TSV interconnects 264 in the memory chip 244 may be vertically over the TSV interconnects 264 in the memory chip 240 and may be not vertically over the TSV interconnects 264 in the memory chip 242.

The isolation enclosures 202 enclosing the TSV interconnects 264 in the memory chip 242 can be vertically over and substantially aligned with the isolation enclosures 202 enclosing the TSV interconnects 264 in the memory chip 240. The isolation enclosures 202 enclosing the TSV interconnects 264 in the memory chip 244 can be vertically over and substantially aligned with the isolation enclosures 202 enclosing the TSV interconnects 264 in the memory chip 242 and can be vertically over and substantially aligned with the isolation enclosures 202 enclosing the TSV interconnects 264 in the memory chip 240.

The serial input ports 234 of the memory chip 240 may be not vertically over and substantially aligned with the serial input ports 234 of the memory chip 238. The serial input ports 234 of the memory chip 242 may be vertically over and substantially aligned with the serial input ports 234 of the memory chip 240. The serial input ports 234 of the memory chip 244 may be vertically over and substantially aligned with the serial input ports 234 of the memory chip 242.

The TSV interconnects 286a (one of them is shown in FIG. 92) in the memory chip 238 may contact multiple first contact points of the conductive layer 10 of the memory chip 238 and may connect the metal pillars or bumps 254 (one of them is shown in FIG. 92) to the serial input ports 234 of the memory chip 238. The TSV interconnects 286b (one of them is shown in FIG. 92) in the memory chip 238 may contact multiple second contact points of the conductive layer 10 of the memory chip 238 and may connect the metal pillars or bumps 248 (one of them is shown in FIG. 92) to the parallel common input ports 228 of the memory chip 238. The TSV interconnects 286c (one of them is shown in FIG. 92) in the memory chip 238 may contact multiple third contact points of the conductive layer 10 of the memory chip 238 and may connect the metal pillars or bumps 252 (one of them is shown in FIG. 92) to some of the metal interconnects 239, that are, metal interconnects 239c mentioned as below.

The TSV interconnects 284 passing through the memory chip 240 may contact some of the metal interconnects 239, that are, metal interconnects 239c mentioned as below, connecting to the TSV interconnects 286c in the memory chip 240 through multiple openings 20a in the passivation layer 20 of the memory chip 238. The TSV interconnects 284 passing through the memory chip 242 may contact some of the overlying interconnects 237a, that are, overlying interconnects 311c mentioned as below, connecting to the TSV interconnects 284 in the memory chip 240. The TSV interconnects 284 passing through the memory chip 242 may be vertically over the TSV interconnects 284 passing through the memory chip 240. The TSV interconnects 284 passing through the memory chip 244 may contact some of the overlying interconnects 237b, that are, overlying interconnects 312c mentioned as below, connecting to the TSV interconnects 284 in the memory chip 242. The TSV interconnects 284 passing through the memory chip 244 may be vertically over the TSV interconnects 284 passing through the memory chip 242. Some of the overlying interconnects 237c, that are, overlying interconnects 313a mentioned as below, can connect the TSV interconnects 250 in the memory chip 244 to the TSV interconnects 284 in the memory chip 244.

The isolation enclosures 202 enclosing the TSV interconnects 284 in the memory chip 242 can be vertically over and substantially aligned with the isolation enclosures 202 enclosing the TSV interconnects 284 in the memory chip 240. The isolation enclosures 202 enclosing the TSV interconnects 284 in the memory chip 244 can be vertically over and substantially aligned with the isolation enclosures 202 enclosing the TSV interconnects 284 in the memory chip 242.

The input signals 230a (such as signals CK, RST and CE), illustrated in FIG. 86, can be input from an external circuit of the multichip package 991, such as the memory controller of the data storage device, to the parallel common input ports 228 of the memory chips 238, 240, 242 and 244 through the metal pillars or bumps 248 (one of them is shown in FIG. 92). The input signals 230b (such as signals D0-D15, CSI and DSI), illustrated in FIG. 86, can be input from the external circuit of the multichip package 991, such as the memory controller of the data storage device, to the serial input ports 234 of the memory chip 238 through the metal pillars or bumps 254 (one of them is shown in FIG. 92). The signals 232 (such as signals Q0-Q15, CSO and DSO), illustrated in FIG. 86, can be output from the serial output ports 235 of the memory chip 244 to the external circuit of the multichip package 991, such as the memory controller of the data storage device, through the metal pillars or bumps 252 (one of them is shown in FIG. 92).

The isolation enclosures 202 in the memory chip 244 shown in FIG. 92 can be vertically over and substantially aligned with the isolation enclosures 202 in the memory chip 240 shown in FIG. 92, and the isolation enclosures 202 in the memory chip 242 shown in FIG. 92.

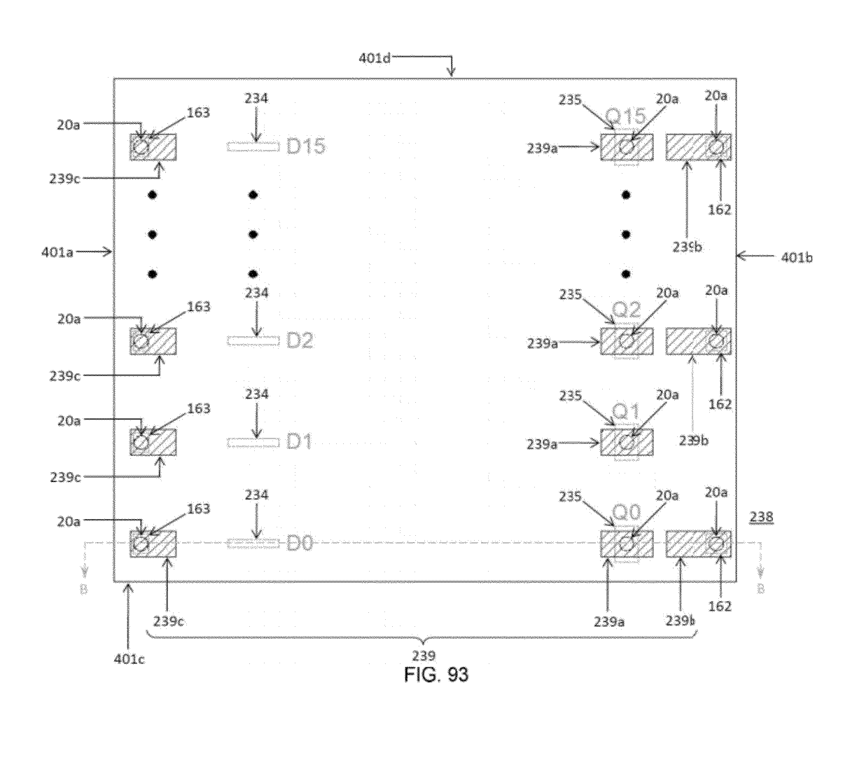

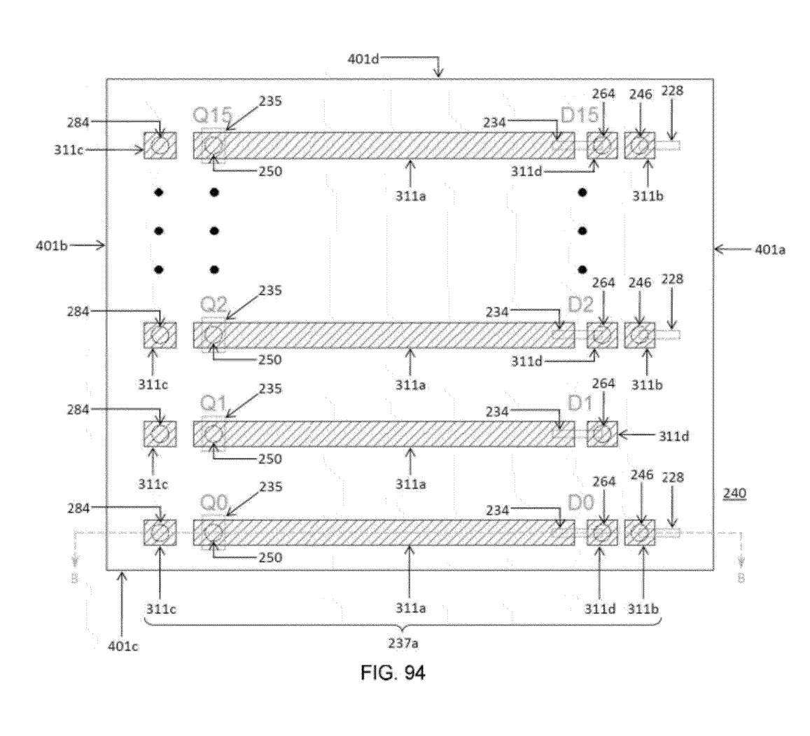

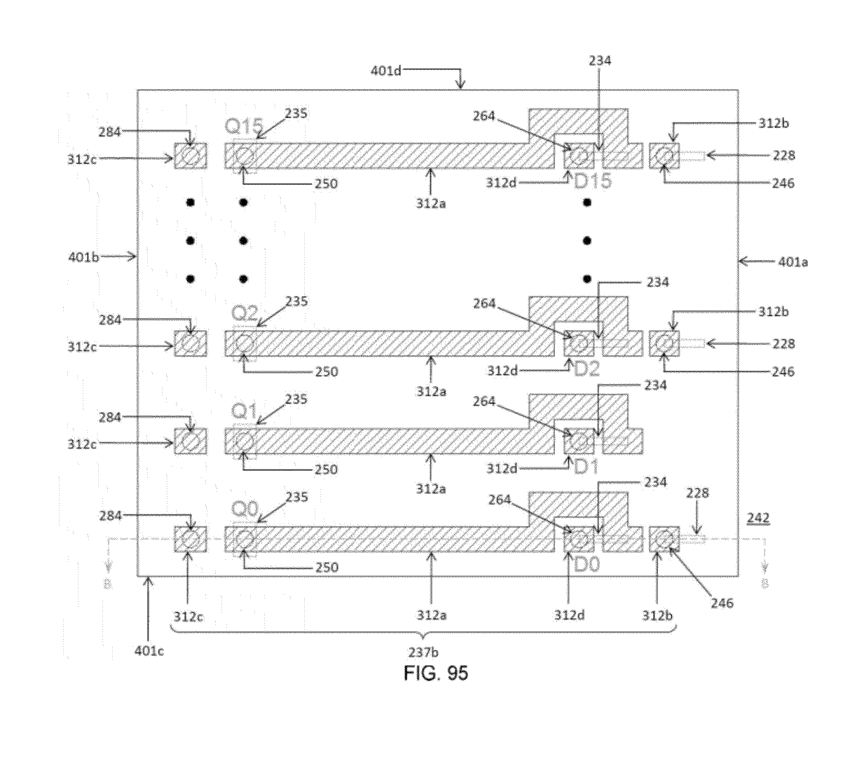

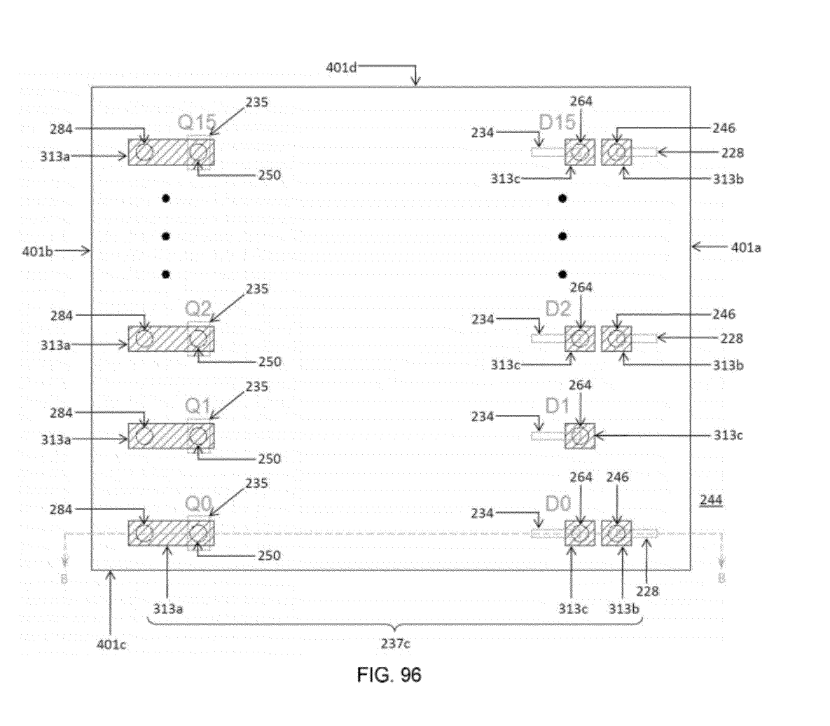

FIG. 92 shows a cross-sectional view illustrating the memory chip 238 and the metal interconnects 239 cut along the line B-B shown in FIG. 93 showing a top perspective view of the layout of the metal interconnects 239, the memory chip 240 and the overlying interconnects 237a cut along the line B-B shown in FIG. 94 showing a top perspective view of the layout of the overlying interconnects 237a, the memory chip 242 and the overlying interconnects 237b cut along the line B-B shown in FIG. 95 showing a top perspective view of the layout of the overlying interconnects 237b, and the memory chip 244 and the overlying interconnects 237c cut along the line B-B shown in FIG. 96 showing a top perspective view of the layout of the overlying interconnects 237c.

Referring to FIGS. 92-96, the memory chip 238 may have a top surface with a profile that is substantially same as that of a top surface of the memory chip 240, that of a top surface of the memory chip 242, and that of a top surface of the memory chip 244. The memory chip 238 may have a same length as that of each of the memory chips 240, 242 and 244, and/or may have a same width as that of each of the memory chips 240, 242 and 244. The memory chips 238, 240, 242 and 244 are same chips having a same die marking and/or having a same layout design of the isolation enclosures 202. Each of the memory chips 238, 240, 242 and 244 has four edges 401a, 401b, 401c and 401d. The edge 401a is opposite to the edge 401b, and the edge 401c is opposite the edge 401d. The edge 401a of the memory chip 238 shown in FIG. 93 can be at a left side of the multichip package 991, and the edge 401b of the memory chip 238 shown in FIG. 93 can be at a right side of the multichip package 991. The edges 401a of the memory chips 240, 242 and 244 shown in FIGS. 94-96 can be at the right side of the multichip package 991, and the edges 401b of the memory chips 240, 242 and 244 shown in FIGS. 94-96 can be at the left side of the multichip package 991.

The metal interconnects 239 shown in FIGS. 92 and 93 include multiple metal interconnects 239a (such as metal traces) connecting the serial output ports 235 of the memory chip 238 to the serial input ports 234 of the memory chip 240, multiple metal traces 239b connecting the TSV interconnects 246 in the memory chip 240 to the parallel common input ports 228 of the memory chip 238 and to the TSV interconnects 286b in the memory chip 238, and multiple metal interconnects 239c (such as metal traces) connecting the TSV interconnects 284 in the memory chip 240 to the TSV interconnects 286c in the memory chip 238. The metal interconnects 239a may have multiple portions used as TSV etch stop. The metal traces 239b may have multiple portions used as TSV etch stop. The metal interconnects 239c may have multiple portions used as TSV etch stop.

Referring to FIGS. 92 and 93, the metal interconnects 239a can be on the top surface of the passivation layer 20 of the memory chip 238 and on multiple contact points, under the openings 20a in the passivation layer 20 of the memory chip 238, of the serial output ports 235 of the memory chip 238, and the contact points of the serial output ports 235 of the memory chip 238 are at the bottoms of the openings 20a in the passivation layer 20 of the memory chip 238. The serial output ports 235 of the memory chip 238 are connected to the metal interconnects 239a through the openings 20a in the passivation layer 20 of the memory chip 238. The metal traces 239b can be on the top surface of the passivation layer 20 of the memory chip 238 and on multiple contact points, under the openings 20a in the passivation layer 20 of the memory chip 238, of the metal interconnects 162 of the memory chip 238, and the contact points of the metal interconnects 162 of the memory chip 238 are at the bottoms of the openings 20a in the passivation layer 20 of the memory chip 238. The metal interconnects 162 of the memory chip 238 are connected to the metal traces 239b through the openings 20a in the passivation layer 20 of the memory chip 238. The metal interconnects 239c can be on the top surface of the passivation layer 20 of the memory chip 238 and on multiple contact points, under the openings 20a in the passivation layer 20 of the memory chip 238, of the metal interconnects 163 of the memory chip 238, and the contact points of the metal interconnects 163 of the memory chip 238 are at the bottoms of the openings 20a in the passivation layer 20 of the memory chip 238. The metal interconnects 163 of the memory chip 238 are connected to the metal interconnects 239c through the openings 20a in the passivation layer 20 of the memory chip 238.

The overlying interconnects 237a shown in FIGS. 92 and 94 include multiple metal traces 311a connecting the serial output ports 235 of the memory chip 240 to the serial input ports 234 of the memory chip 242, multiple overlying interconnects 311b connecting the TSV interconnects 246 in the memory chip 242 to the TSV interconnects 246 in the memory chip 240, multiple overlying interconnects 311c connecting the TSV interconnects 284 in the memory chip 242 to the TSV interconnects 284 in the memory chip 240, and multiple overlying interconnects 311d connecting to the TSV interconnects 264 in the memory chip 240.

The overlying interconnects 237b shown in FIGS. 92 and 95 include multiple metal traces 312a connecting the serial output ports 235 of the memory chip 242 to the serial input ports 234 of the memory chip 244, multiple overlying interconnects 312b connecting the TSV interconnects 246 in the memory chip 244 to the TSV interconnects 246 in the memory chip 242, multiple overlying interconnects 312c connecting the TSV interconnects 284 in the memory chip 244 to the TSV interconnects 284 in the memory chip 242, and multiple overlying interconnects 312d connecting to the TSV interconnects 264 in the memory chip 242.

The overlying interconnects 237c shown in FIGS. 92 and 96 include multiple metal traces 313a connecting the TSV interconnects 250 in the memory chip 244 to the TSV interconnects 284 in the memory chip 244, multiple overlying interconnects 313b connecting to the TSV interconnects 246 in the memory chip 244, and multiple overlying interconnects 313c connecting to the TSV interconnects 264 in the memory chip 244.

Referring to FIG. 92 and FIGS. 93-96, the parallel connection 231 illustrated in FIG. 86 may include the metal pillars or bumps 248, the TSV interconnects 286b in the memory chip 238, multiple metal interconnects composed of the conductive layers 10 and 16 of the memory chip 238, the overlying interconnects 239b, the TSV interconnects 246 passing through the memory chip 240, the overlying interconnects 311b, the TSV interconnects 246 passing through the memory chip 242, the overlying interconnects 312b, and the TSV interconnects 246 passing through the memory chip 244. The metal pillars or bumps 248 shown in FIG. 92 can be connected to the parallel common input ports 228 of the memory chips 238, 240, 242 and 244 through the parallel connection 231.

Referring to FIGS. 92 and 93, the metal pillars or bumps 254 shown in FIG. 92 may be physically and electrically connected to the serial input ports 234 of the memory chip 238 through the TSV interconnects 286a in the memory chip 238. The memory chip 238 may include circuit paths, signal paths, from the TSV interconnects 286a in the memory chip 238 to the serial input ports 234 of the memory chip 238.

Referring to FIG. 92 and FIGS. 93-96, the metal pillars or bumps 252 shown in FIG. 92 can be physically and electrically connected to the serial output ports 235 of the memory chip 244 through, in sequence, the TSV interconnects 286c, multiple metal interconnects composed of the conductive layers 10 and 16 of the memory chip 238, the metal interconnects 239c, the TSV interconnects 284 passing through the memory chip 240, the overlying interconnects 311c, the TSV interconnects 284 passing through the memory chip 242, the overlying interconnects 312c, the TSV interconnects 284 passing through the memory chip 244, the metal traces 313a, and the TSV interconnects 250 in the memory chip 244.

Referring to FIG. 93, the memory chip 238 is shown with the serial input ports 234 (such as the input ports D0-D15), the serial output ports 235 (such as the output ports Q0-Q15), and the metal interconnects 162 and 163. Referring to FIG. 94, the memory chip 240 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 284 shown in FIG. 94 are in the memory chip 240. The serial input ports 234 of the memory chip 240 shown in FIG. 94 are not connected to the metal traces 311a and the overlying interconnects 311b through the TSV interconnects 264 in the memory chip 240.

Referring to FIG. 95, the memory chip 242 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 284 shown in FIG. 95 are in the memory chip 242. The serial input ports 234 of the memory chip 242 shown in FIG. 95 are not connected to the metal traces 312a and the overlying interconnects 312b through the TSV interconnects 264 in the memory chip 242. Referring to FIG. 96, the memory chip 244 is shown with the serial input ports 234 (such as the input ports D0-D15), the serial output ports 235 (such as the output ports Q0-Q15), and the parallel common input ports 228 (such as the ports CK, RST and CE). The TSV interconnects 246, 250, 264 and 284 shown in FIG. 96 are in the memory chip 244. The serial input ports 234 of the memory chip 244 shown in FIG. 96 are not connected to the metal traces 313a and the overlying interconnects 313b through the TSV interconnects 264 in the memory chip 244.

Referring to FIGS. 92 and 93, the memory chip 238 includes the above-mentioned circuit paths, signal or data paths, illustrated in FIG. 86, from the serial input ports 234 of the memory chip 238 to the serial output ports 235 of the memory chip 238. For example, the memory chip 238 includes a circuit path, signal or data path, from the input port D0 of the memory chip 238 to the corresponding output port Q0 of the memory chip 238. The serial output ports 235 of the memory chip 238 can be physically and electrically connected to the serial input ports 234 of the memory chip 240 through, in sequence, the metal interconnects 239a and the TSV interconnects 264 passing through the memory chip 240. The above-mentioned serial connection 233a, illustrated in FIG. 86, between the serial output ports 235 of the memory chip 238 and the serial input ports 234 of the memory chip 240 may include the metal interconnects 239a and the TSV interconnects 264 passing through the memory chip 240.

Referring to FIG. 93, the metal interconnects 239a and the metal traces 239b can be in a peripheral region of the memory chip 238 closer to the edge 401b than the edge 401a, and the metal interconnects 239c can be in the peripheral region of the memory chip 238 closer to the edge 401a than the edge 401b. The serial input ports 234 of the memory chip 238 may be arranged in a line parallel with the edge 401a and in the peripheral region of the memory chip 238 closer to the edge 401a than the edge 401b. The serial output ports 235 of the memory chip 238 may be arranged in a line parallel with the edge 401b and in the peripheral region of the memory chip 238 closer to the edge 401b than the edge 401a. The metal interconnects 162 of the memory chip 238 may be arranged in a line parallel with the edge 401b and in the peripheral region of the memory chip 238 closer to the edge 401b than the edge 401a. The metal interconnects 163 of the memory chip 238 may be arranged in a line parallel with the edge 401a and in the peripheral region of the memory chip 238 closer to the edge 401a than the edge 401b. The parallel common input ports 228 (not shown in FIG. 93 but shown in FIG. 92) of the memory chip 238 may be arranged in a line parallel with the edge 401a and in the peripheral region of the memory chip 238 closer to the edge 401a than the edge 401b. The metal interconnects 239 may further include multiple power traces or planes and multiple ground traces or planes in the peripheral region of the memory chip 238 and/or in a center region of the memory chip 238 enclosed by the peripheral region of the memory chip 238. Alternatively, the metal interconnects 162 and 163 of the memory chip 238, the parallel common input ports 228 of the memory chip 238, the serial input ports 234 of the memory chip 238, the serial output ports 235 of the memory chip 238, the metal interconnects 239a and 239c, and the metal traces 239b may be all in the center region of the memory chip 238.

Referring to FIGS. 92 and 94, the memory chip 240 includes the above-mentioned circuit paths, signal or data paths, illustrated in FIG. 86, from the serial input ports 234 of the memory chip 240 to the serial output ports 235 of the memory chip 240. For example, the memory chip 240 includes a circuit path, signal or data path, from the input port D0 of the memory chip 240 to the corresponding output port Q0 of the memory chip 240. The serial output ports 235 of the memory chip 240 can be physically and electrically connected to the serial input ports 234 of the memory chip 242 through, in sequence, the TSV interconnects 250 in the memory chip 240, the metal traces 311a, and the TSV interconnects 264 passing through the memory chip 242. The overlying interconnects 311d can be spaced apart from the metal traces 311a and from the overlying interconnects 311b, and the TSV interconnects 264 in the memory chip 240 cannot be connected to the metal traces 311a and the overlying interconnects 311b through the overlying interconnects 311d. The TSV interconnects 264 in the memory chip 240 can connect the serial input ports 234 of the memory chip 240 to the metal interconnects 239a shown in FIG. 93. The above-mentioned serial connection 233b, illustrated in FIG. 86, between the serial output ports 235 of the memory chip 240 and the serial input ports 234 of the memory chip 242 may include the TSV interconnects 250 in the memory chip 240, the metal traces 311a, and the TSV interconnects 264 in the memory chip 242.

Referring to FIG. 94, each of the metal traces 311a may have a middle portion in a center region of the memory chip 240 enclosed by a peripheral region of the memory chip 240, a right portion, connecting to the input port 234 of the memory chip 242 through the TSV interconnect 264 in the memory chip 242 shown in FIGS. 92 and 95, in the peripheral region of the memory chip 240 closer to the edge 401a than the edge 401b, and a left portion, connecting to the output port 235 of the memory chip 240 through the TSV interconnect 250, in the peripheral region of the memory chip 240 closer to the edge 401b than the edge 401a. The serial input ports 234 of the memory chip 240 may be arranged in a line parallel with the edge 401a and in the peripheral region of the memory chip 240 closer to the edge 401a than the edge 401b. The serial output ports 235 of the memory chip 240 may be arranged in a line parallel with the edge 401b and in the peripheral region of the memory chip 240 closer to the edge 401b than the edge 401a. The TSV interconnects 264 may be arranged in a line parallel with the edge 401a and in the peripheral region of the memory chip 240 closer to the edge 401a than the edge 401b. The TSV interconnects 250 may be arranged in a line parallel with the edge 401b and in the peripheral region of the memory chip 240 closer to the edge 401b than the edge 401a. The parallel common input ports 228 of the memory chip 240 may be arranged in a line parallel with the edge 401a and in the peripheral region of the memory chip 240 closer to the edge 401a than the edge 401b. The TSV interconnects 284 may be arranged in a line parallel with the edge 401b and in the peripheral region of the memory chip 240 closer to the edge 401b than the edge 401a. The TSV interconnects 246 may be arranged in a line parallel with the edge 401a and in the peripheral region of the memory chip 240 closer to the edge 401a than the edge 401b. The overlying interconnects 311b and 311d can be in the peripheral region of the memory chip 240 closer to the edge 401a than the edge 401b. The overlying interconnects 311c can be in the peripheral region of the memory chip 240 closer to the edge 401b than the edge 401a. The overlying interconnects 237a may further include multiple power traces or planes and multiple ground traces or planes in the center region and/or peripheral region of the memory chip 240. Alternatively, the metal traces 311a, the overlying interconnects 311b, 311c and 311d, the serial input ports 234 of the memory chip 240, the serial output ports 235 of the memory chip 240, the parallel common input ports 228 of the memory chip 240, and the TSV interconnects 246, 250, 264 and 284 may be all in the center region of the memory chip 240.

Referring to FIGS. 92 and 95, the memory chip 242 includes the above-mentioned circuit paths, signal or data paths, illustrated in FIG. 86, from the serial input ports 234 of the memory chip 242 to the serial output ports 235 of the memory chip 242. For example, the memory chip 242 includes a circuit path, signal or data path, from the input port D0 of the memory chip 242 to the corresponding output port Q0 of the memory chip 242. The serial output ports 235 of the memory chip 242 can be physically and electrically connected to the serial input ports 234 of the memory chip 244 through, in sequence, the TSV interconnects 250 in the memory chip 242, the metal traces 312a, and the TSV interconnects 264 passing through the memory chip 244. The overlying interconnects 312d can be spaced apart from the metal traces 312a and from the overlying interconnects 312b, and the TSV interconnects 264 in the memory chip 242 cannot be connected to the metal traces 312a and the overlying interconnects 312b through the overlying interconnects 312d. The TSV interconnects 264 passing through the memory chip 242 can connect the serial input ports 234 of the memory chip 242 to the metal traces 311a shown in FIG. 94. The above-mentioned serial connection 233c, illustrated in FIG. 86, between the serial output ports 235 of the memory chip 242 and the serial input ports 234 of the memory chip 244 may include the TSV interconnects 250 in the memory chip 242, the metal traces 312a, and the TSV interconnects 264 in the memory chip 244. From a top perspective view, the isolation enclosures 202 enclosing the TSV interconnects 264 in the memory chip 242 are substantially aligned with the isolation enclosures 202 enclosing the TSV interconnects 264 in the memory chip 240, and the TSV interconnects 264 in the memory chip 242 can be horizontally offset from or not vertically over the TSV interconnects 264 in the memory chip 240.

Referring to FIG. 95, each of the metal traces 312a may have a middle portion in a center region of the memory chip 242 enclosed by a peripheral region of the memory chip 242, a right portion, connecting to the input port 234 of the memory chip 244 through the TSV interconnect 264 in the memory chip 244 shown in FIGS. 92 and 96, in the peripheral region of the memory chip 242 closer to the edge 401a than the edge 401b, and a left portion, connecting to the output port 235 of the memory chip 242 through the TSV interconnect 250, in the peripheral region of the memory chip 242 closer to the edge 401b than the edge 401a. The serial input ports 234 of the memory chip 242 may be arranged in a line parallel with the edge 401a and in the peripheral region of the memory chip 242 closer to the edge 401a than the edge 401b. The serial output ports 235 of the memory chip 242 may be arranged in a line parallel with the edge 401b and in the peripheral region of the memory chip 242 closer to the edge 401b than the edge 401a. The TSV interconnects 264 may be arranged in a line parallel with the edge 401a and in the peripheral region of the memory chip 242 closer to the edge 401a than the edge 401b. The TSV interconnects 250 may be arranged in a line parallel with the edge 401b and in the peripheral region of the memory chip 242 closer to the edge 401b than the edge 401a. The parallel common input ports 228 of the memory chip 242 may be arranged in a line parallel with the edge 401a and in the peripheral region of the memory chip 242 closer to the edge 401a than the edge 401b. The TSV interconnects 284 may be arranged in a line parallel with the edge 401b and in the peripheral region of the memory chip 242 closer to the edge 401b than the edge 401a. The TSV interconnects 246 may be arranged in a line parallel with the edge 401a and in the peripheral region of the memory chip 242 closer to the edge 401a than the edge 401b. The overlying interconnects 312b and 312d can be in the peripheral region of the memory chip 242 closer to the edge 401a than the edge 401b. The overlying interconnects 312c can be in the peripheral region of the memory chip 242 closer to the edge 401b than the edge 401a. The overlying interconnects 237b may further include multiple power traces or planes and multiple ground traces or planes in the center region and/or peripheral region of the memory chip 242. Alternatively, the metal traces 312a, the overlying interconnects 312b, 312c and 312d, the serial input ports 234 of the memory chip 242, the serial output ports 235 of the memory chip 242, the parallel common input ports 228 of the memory chip 242, and the TSV interconnects 246, 250, 264 and 284 may be all in the center region of the memory chip 242.

Referring to FIGS. 92 and 96, the memory chip 244 includes the above-mentioned circuit paths, signal or data paths, illustrated in FIG. 86, from the serial input ports 234 of the memory chip 244 to the serial output ports 235 of the memory chip 244. For example, the memory chip 244 includes a circuit path, signal or data path, from the input port D0 of the memory chip 244 to the corresponding output port Q0 of the memory chip 244. The serial output ports 235 of the memory chip 244 can be physically and electrically connected to the metal pillars or bumps 252 through, in sequence, the TSV interconnects 250 in the memory chip 244, the metal traces 313a, the TSV interconnects 284 in the memory chip 244, the overlying interconnects 312c, the TSV interconnects 284 in the memory chip 242, the overlying interconnects 311c, the TSV interconnects 284 in the memory chip 240, the metal interconnects 239c, the metal interconnects 163 of the memory chip 238, and the TSV interconnects 286c in the memory chip 238. The overlying interconnects 313c can be spaced apart from the metal traces 313a and from the overlying interconnects 313b, and the TSV interconnects 264 in the memory chip 244 cannot be connected to the metal traces 313a and the overlying interconnects 313b through the overlying interconnects 313c. The TSV interconnects 264 passing through the memory chip 244 can connect the serial input ports 234 of the memory chip 244 to the metal traces 312a shown in FIG. 95. The overlying interconnects 313b can be connected to the TSV interconnects 246 in the memory chip 244. There are no metal pillars or bumps contacting the overlying interconnects 313c. From a top perspective view, the isolation enclosures 202 enclosing the TSV interconnects 264 in the memory chip 244 are substantially aligned with the isolation enclosures 202 enclosing the TSV interconnects 264 in the memory chip 242 and with the isolation enclosures 202 enclosing the TSV interconnects 264 in the memory chip 240, and the TSV interconnects 264 in the memory chip 244 can be horizontally offset from or not vertically over the TSV interconnects 264 in the memory chip 242 and can be vertically over the TSV interconnects 264 in the memory chip 240.

Referring to FIG. 96, the metal traces 313a can be in a peripheral region of the memory chip 244 closer to the edge 401b than the edge 401a. The overlying interconnects 313b and 313c can be in the peripheral region of the memory chip 244 closer to the edge 401a than the edge 401b. The serial input ports 234 of the memory chip 244 may be arranged in a line parallel with the edge 401a and in the peripheral region of the memory chip 244 closer to the edge 401a than the edge 401b. The serial output ports 235 of the memory chip 244 may be arranged in a line parallel with the edge 401b and in the peripheral region of the memory chip 244 closer to the edge 401b than the edge 401a. The TSV interconnects 264 may be arranged in a line parallel with the edge 401a and in the peripheral region of the memory chip 244 closer to the edge 401a than the edge 401b. The TSV interconnects 250 may be arranged in a line parallel with the edge 401b and in the peripheral region of the memory chip 244 closer to the edge 401b than the edge 401a. The parallel common input ports 228 of the memory chip 244 may be arranged in a line parallel with the edge 401a and in the peripheral region of the memory chip 244 closer to the edge 401a than the edge 401b. The TSV interconnects 284 may be arranged in a line parallel with the edge 401b and in the peripheral region of the memory chip 244 closer to the edge 401b than the edge 401a. The TSV interconnects 246 may be arranged in a line parallel with the edge 401a and in the peripheral region of the memory chip 244 closer to the edge 401a than the edge 401b. The overlying interconnects 237c may further include multiple power traces or planes and multiple ground traces or planes in the peripheral region of the memory chip 244 and/or in a center region of the memory chip 238 enclosed by the peripheral region of the memory chip 244. Alternatively, the metal traces 313a, the overlying interconnects 313b and 313c, the serial input ports 234 of the memory chip 244, the serial output ports 235 of the memory chip 244, the parallel common input ports 228 of the memory chip 244, and the TSV interconnects 246, 250, 264 and 284 may be all in the center region of the memory chip 244.

The layout design of the parallel common input ports 228 shown in FIG. 96 can be same as that of the parallel common input ports 228 shown in FIG. 94 and that of the parallel common input ports 228 shown in FIG. 95. That is, the parallel common input ports 228 shown in FIG. 96 can be vertically over and substantially aligned with the parallel common input ports 228 shown in FIG. 94 and the parallel common input ports 228 shown in FIG. 95.

The layout design of the serial input ports 234 shown in FIG. 96 can be same as that of the serial input ports 234 shown in FIG. 94 and that of the serial input ports 234 shown in FIG. 95. That is, the serial input ports 234 shown in FIG. 96 can be vertically over and substantially aligned with the serial input ports 234 shown in FIG. 94 and the serial input ports 234 shown in FIG. 95.

The layout design of the serial output ports 235 shown in FIG. 96 can be same as that of the serial output ports 235 shown in FIG. 94 and that of the serial output ports 235 shown in FIG. 95. That is, the serial output ports 235 shown in FIG. 96 can be vertically over and substantially aligned with the serial output ports 235 shown in FIG. 94 and the serial output ports 235 shown in FIG. 95.

The layout design of the TSV interconnects 246 shown in FIG. 96 can be same as that of the TSV interconnects 246 shown in FIG. 94 and that of the TSV interconnects 246 shown in FIG. 95. That is, the TSV interconnects 246 shown in FIG. 96 can be vertically over and substantially aligned with the TSV interconnects 246 shown in FIG. 94 and the TSV interconnects 246 shown in FIG. 95.

The layout design of the TSV interconnects 250 shown in FIG. 96 can be same as that of the TSV interconnects 250 shown in FIG. 94 and that of the TSV interconnects 250 shown in FIG. 95. That is, the TSV interconnects 250 shown in FIG. 96 can be vertically over and substantially aligned with the TSV interconnects 250 shown in FIG. 94 and the TSV interconnects 250 shown in FIG. 95.

The layout design of the TSV interconnects 284 shown in FIG. 96 can be same as that of the TSV interconnects 284 shown in FIG. 94 and that of the TSV interconnects 284 shown in FIG. 95. That is, the TSV interconnects 284 shown in FIG. 96 can be vertically over and substantially aligned with the TSV interconnects 284 shown in FIG. 94 and the TSV interconnects 284 shown in FIG. 95.

The multichip package 991 shown in FIG. 92 includes four-level stacked memory chips 238, 240, 242 and 244, four levels of the TSV interconnects in the four-level memory chips 238, 240, 242 and 244, one level of the metal interconnects at a topside of the memory chip 238, and three levels of the overlying interconnects at backsides of the three-level memory chips 240, 242 and 244. Alternatively, the multichip package 991 may further include another one or more levels of the memory chips stacked between the memory chip 242 and the memory chip 244, another one or more levels of the TSV interconnects in the another one or more levels of the memory chips, and another one or more levels of the overlying interconnects at backsides of the another one or more levels of the memory chips. The another one or more levels of the memory chips and the memory chips 238, 240, 242 and 244 can be same chips having a same die marking and/or having a same layout of the DTI layer 4. The memory chip 244 shown in FIGS. 92 and 96 is the topmost level of the memory chips in the multichip package 991.

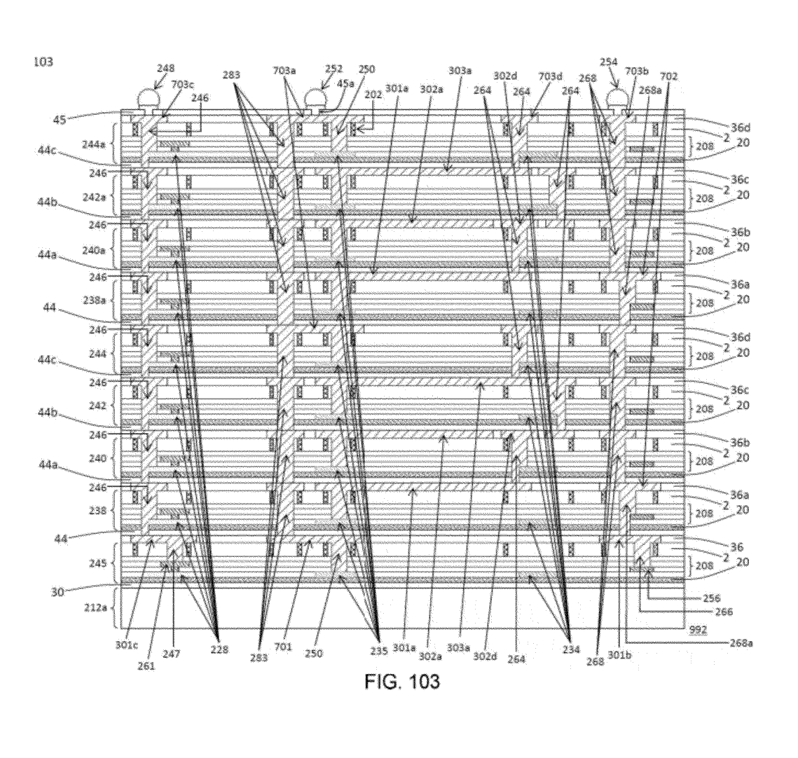

Alternatively, a data storage device, such as SSD, USB device, embedded multi media device or mSATA SSD, may include a circuit substrate, multiple multichip packages 992 as mentioned in FIG. 103 (one of them is shown) mounted over the circuit substrate using the below-mentioned metal pillars or bumps 248, 252 and 254 of each multichip package 992, a controller mounted over the circuit substrate and connected to the multichip packages 992, one or more DRAM chips mounted over the circuit substrate and connected to the controller, etc. The circuit substrate, for example, may be a mother board, a printed circuit board (PCB), a ball-grid-array (BGA) substrate or a glass substrate. FIG. 103 illustrates a schematic cross-sectional view of the multichip package 992. The enclosure-first technology may be applied to the multichip package 992.

The multichip package 992 shown in FIG. 103 includes the substrate 212a as mentioned in FIG. 85, a memory chip 245 over the substrate 212a, the memory chips 238, 240, 242 and 244, as mentioned in FIG. 86, that are stacked over the memory chip 245, and multiple memory chips 238a, 240a, 242a and 244a that are stacked over the memory chip 244. The memory chips 238, 238a, 240, 240a, 242, 242a, 244, 244a and 245 of the multichip package 992 shown in FIG. 103 are all faced down and may be same chips having a same die marking.

Each of the memory chips 238, 238a, 240, 240a, 242, 242a, 244, 244a and 245 shown in FIG. 103 may include the above-mentioned serial input ports 234 (such as the sixteen data input ports D0-D15 and the input ports CSI and DSI), the above-mentioned serial output ports 235 (such as the sixteen data output ports Q0-Q15 and the output ports CSO and DSO), and the above-mentioned parallel common input ports 228 (such as the ports CK, RST and CE). In one example, each of the memory chips 238, 238a, 240, 240a, 242, 242a, 244, 244a and 245 shown in FIG. 103 may have a data width of by-sixteen bits, that is, including the sixteen data input ports D0-D15 and the sixteen data output ports Q0-Q15. Alternatively, each of the memory chips 238, 238a, 240, 240a, 242, 242a, 244, 244a and 245 shown in FIG. 103 may have a data width of by-one bit, that is, including only one data input port D0 and only one data output port Q0, or may have a data width of by-eight bits, that is, including the data input ports D0-D7 and the data output ports Q0-Q7.

In each of the memory chips 238, 238a, 240, 240a, 242, 242a, 244, 244a and 245 shown in FIG. 103, each input port 234 is paired with a corresponding output port 235. For example, each of the memory chips 238, 238a, 240, 240a, 242, 242a, 244, 244a and 245 shown in FIG. 103 may contain the output ports Q0-Q15 and the input ports D0-D15 paired with the corresponding output ports Q0-Q15, respectively. Each of the memory chips 238, 238a, 240, 240a, 242, 242a, 244, 244a and 245 shown in FIG. 103 may further contain the output port CSO, the input port CSI paired with the output port CSO, the output port DSO, and the input port DSI paired with the output port DSO.

Each of the memory chips 238, 238a, 240, 240a, 242, 242a, 244, 244a and 245 shown in FIG. 103 may include circuit paths, signal or data paths, between the input-output pairs 234 and 235, from the serial input ports 234 to the corresponding serial output ports 235, that is, the circuit path between the input-output pair D0 and Q0 can transmit a signal, memory data, from the input port D0 to the output port Q0, for example. Each of the memory chips 238, 238a, 240, 240a, 242, 242a, 244, 244a and 245 includes memory cells to store data, and each of the circuit paths enables access to specific memory cells. Data flows in the memory chips 238, 238a, 240, 240a, 242, 242a, 244, 244a and 245 can be transmitted from the serial input ports 234 of the memory chips 238, 238a, 240, 240a, 242, 242a, 244, 244a and 245 to the corresponding serial output ports 235 of the memory chips 238, 238a, 240, 240a, 242, 242a, 244, 244a and 245, respectively.

The schematic circuit diagram illustrated in FIG. 86 can be applied to a bottom memory module including the stacked memory chips 238, 240, 242 and 244 of the multichip package 992 and to a top memory module including the stacked memory chips 238a, 240a, 242a and 244a of the multichip package 992. With regards to the connection in the top memory module including the stacked memory chips 238a, 240a, 242a and 244a, the memory chips 238a, 240a, 242a and 244a can correspond to the memory chips 238, 240, 242 and 244, respectively.

The memory chips 238, 238a, 240, 240a, 242, 242a, 244, 244a and 245 shown in FIG. 103 can be non-volatile memory chips, such as phase-change memory (PCM) chips, ferroelectric memory chips, magnetoresistive memory chips, racetrack memory chips, electrically-erasable programmable read-only memory (EEPROM) chips, erasable programmable read-only memory (EPROM) chips, or flash memory chips (such as NAND-Flash memory chips or NOR-Flash memory chips).

Each of the memory chips 238, 238a, 240, 240a, 242, 242a, 244, 244a and 245 shown in FIG. 103 may include the ground or polished semiconductor substrate 2, the STI layer 6 (not shown in FIG. 103), the DTI layer 4 having the isolation enclosures 202 and the alignment marks 206 (not shown in FIG. 103), the IC devices 7 (not shown in FIG. 103), the IC scheme 208 and the passivation layer 20, as mentioned above in FIGS. 75-85. The ground or polished semiconductor substrate 2 may have a suitable thickness, such as between 1 and 100 micrometers, between 1 and 50 micrometers, between 1 and 20 micrometers, between 1 and 10 micrometers, between 1 and 5 micrometers, or between 2 and 5 micrometers, that may be same as the thickness of the DTI layer 4. The ground or polished semiconductor substrate 2 may have the above-mentioned surface 200, and the DTI layer 4 may have the above-mentioned bottom surface 400 substantially coplanar with the surface 200.

The conductive layer 10 of each of the memory chips 238, 238a, 240, 240a, 242, 242a, 244, 244a and 245 shown in FIG. 103 may include multiple interconnects 256 (one of them is shown in each of the memory chips 238, 238a, 240, 240a, 242, 242a, 244, 244a and 245) and multiple interconnects 261 (one of them is shown in each of the memory chips 238, 238a, 240, 240a, 242, 242a, 244, 244a and 245).

The conductive layer 16 of each of the memory chips 238, 238a, 240, 240a, 242, 242a, 244, 244a and 245 shown in FIG. 103 may include the serial input ports 234 (one of them is shown in each of the memory chips 238, 238a, 240, 240a, 242, 242a, 244, 244a and 245 and can be, for example, the input port D0), the serial output ports 235 (one of them is shown in each of the memory chips 238, 238a, 240, 240a, 242, 242a, 244, 244a and 245 and can be, for example, the output port Q0), and the parallel common input ports 228 (one of them is shown in each of the memory chips 238, 238a, 240, 240a, 242, 242a, 244, 244a and 245 and can be the port CK, RST or CE).

The multichip package 992 shown in FIG. 103 further includes the adhesive layer 30 as mentioned in FIG. 78 between the substrate 212a and the passivation layer 20 of the memory chip 245, multiple dielectric or insulating layers 36, 36a, 36b, 36c and 36d at backsides of the substrates 2 of the memory chips 238, 238a, 240, 240a, 242, 242a, 244, 244a and 245, nine levels of overlying interconnects (including overlying interconnects 701, 702, 703a, 703b, 703c and 703d, the above-mentioned metal traces 301a, 302a and 303a, and the above-mentioned overlying interconnects 301b, 301c and 302d) at the backsides of the substrates 2 of the memory chips 238, 238a, 240, 240a, 242, 242a, 244, 244a and 245 and in the dielectric or insulating layers 36, 36a, 36b, 36c and 36d, nine levels of TSV interconnects (including the TSV interconnects 246, 247, 250, 264, 266, 268, 268a, and 283) in the memory chips 238, 238a, 240, 240a, 242, 242a, 244, 244a and 245, multiple insulating layers 44, 44a, 44b and 44c on the dielectric or insulating layers 36, 36a, 36b, 36c and 36d and the overlying interconnects, an insulating layer 45 on the overlying interconnects 703a, 703b, 703c and 703d and the dielectric or insulating layer 36 at the backside of the substrate 2 of the memory chip 244a, and the metal pillars or bumps 248, 252 and 254 connecting to the overlying interconnects 703a, 703b and 703c through multiple openings 45a in the insulating layer 45. The steps of forming the TSV interconnects and the overlying interconnects of the multichip package 992 can be referred to as the steps of forming the TSV interconnects 216a, 216b and 216c and the overlying interconnects 216d as illustrated in FIGS. 83 and 84. Each of the TSV interconnects of the multichip package 992 is enclosed by one of the isolation enclosures 202.

The TSV interconnects 247 and 266 are in TSVs, which can be referred to as the TSVs 77 illustrated in FIG. 81, in the memory chip 245 shown in FIG. 103. The specifications of the TSV interconnects 247 and 266 shown in FIG. 103 can be referred to as the specifications of the TSV interconnects 214 as illustrated in FIG. 81. The TSV interconnects 268 are in TSVs, which can be referred to as the TSVs 77a illustrated in FIG. 84, through the memory chips 240, 240a, 242, 242a, 244 and 244a shown in FIG. 103. The TSV interconnects 283 are in TSVs, which can be referred to as the TSVs 77a illustrated in FIG. 84, through the memory chips 238, 238a, 240, 240a, 242, 242a, 244 and 244a shown in FIG. 103. The specifications of the TSV interconnects 268 and 283 shown in FIG. 103 can be referred to as the specifications of the TSV interconnects 216a as illustrated in FIG. 84. The TSV interconnects 246 are in TSVs, which can be referred to as the TSVs 77b illustrated in FIG. 84, through the memory chips 238, 238a, 240, 240a, 242, 242a, 244 and 244a shown in FIG. 103. The TSV interconnects 264 are in TSVs, which can be referred to as the TSVs 77b illustrated in FIG. 84, through the memory chips 240, 240a, 242, 242a, 244 and 244a shown in FIG. 103. The TSV interconnects 268a are in TSVs, which can be referred to as the TSVs 77b illustrated in FIG. 84, through the memory chips 238 and 238a shown in FIG. 103. The specifications of the TSV interconnects 246, 264 and 268a shown in FIG. 103 can be referred to as the specifications of the TSV interconnects 216b as illustrated in FIG. 84. The TSV interconnects 250 are in TSVs, which can be referred to as the TSVs 77c illustrated in FIG. 84, in the memory chips 238, 238a, 240, 240a, 242, 242a, 244, 244a ad 245 shown in FIG. 103. The specifications of the TSV interconnects 250 shown in FIG. 103 can be referred to as the specifications of the TSV interconnects 216c as illustrated in FIG. 84.

The steps of forming each of the insulating layers 44, 44a, 44b and 44c shown in FIG. 103 can be referred to as the steps of forming the insulating layer 44 as illustrated in FIG. 82. The specifications of the insulating layer 45 shown in FIG. 103 can be referred to as the specifications of the insulating layer 45 as illustrated in FIG. 85. The specifications of the metal pillars or bumps 248, 252 and 254 shown in FIG. 103 can be referred to as the specifications of the metal pillars or bumps 99 as illustrated in FIG. 85.s

In one of example, each of the dielectric or insulating layers 36, 36a, 36b, 36c and 36d shown in FIG. 103 can be a silicon-containing layer, such as silicon nitride, silicon oxide, silicon oxynitride or silicon carbon nitride, having a suitable thickness, such as between 0.1 and 1.5 micrometers, between 0.2 and 2 micrometers, between 0.3 and 5 micrometers or between 0.3 and 10 micrometers.

The specifications of the overlying interconnects 701 shown in FIG. 103 can be referred to as the specifications of the overlying interconnects 214a as illustrated in FIG. 81. The specifications of the overlying interconnects 702 shown in FIG. 103 can be referred to as the specifications of the overlying interconnects 216d as illustrated in FIG. 84. The specifications of the overlying interconnects 703a, 703b, 703c and 703d shown in FIG. 103 can be referred to as the specifications of the overlying interconnects 216d as illustrated in FIG. 84.

The metal pillars or bumps 254 (one of them is shown in FIG. 103) of the multichip package 992 can be connected to the interconnects 256 or the serial input ports 234 (one of them is shown in FIG. 103 and can be the input port D0) of the memory chip 238a in the top memory module of the multiple package 992, the interconnects 256 or the serial input ports 234 (one of them is shown in FIG. 103 and can be the input port D0) of the memory chip 238 in the bottom memory module of the multiple package 992, and the interconnects 256 or the serial input ports 234 (one of them is shown in FIG. 103 and can be the input port D0) of the memory chip 245 of the multiple package 992 through the TSV interconnects 268 in the memory chips 240, 240a, 242, 242a, 244 and 244a, the TSV interconnects 268a in the memory chips 238 and 238a, and the TSV interconnects 266 in the memory chip 245. The input signals, such as the signals D0-D15, from an external circuit of the multichip package 992, such as the controller of the data storage device, can be transmitted to the serial input ports 234 of the memory chip 238, 238a or 245 through the metal pillars or bumps 254.

The metal pillars or bumps 252 (one of them is shown in FIG. 103) of the multichip package 992 can be connected to the serial output ports 235 (one of them is shown in FIG. 103 and can be the output port Q0) of the memory chip 244a in the top memory module of the multiple package 992, the serial output ports 235 (one of them is shown in FIG. 103 and can be the output port Q0) of the memory chip 244 in the bottom memory module of the multiple package 992, and the serial output ports 235 (one of them is shown in FIG. 103 and can be the output port Q0) of the memory chip 245 of the multiple package 992 through the TSV interconnects 250 in the memory chips 244, 244a and 245, and the TSV interconnects 283 in the memory chips 238, 238a, 240, 240a, 242, 242a, 244 and 244a. The output signals, such as the signals Q0-Q15, from the serial output ports 235 of the memory chip 244, 244a or 245 can be transmitted to an external circuit of the multichip package 992, such as the controller of the data storage device, through the metal pillars or bumps 252.

The metal pillars or bumps 248 (one of them is shown in FIG. 103) of the multichip package 992 can be connected to the parallel common input ports 228 of the memory chips 238, 238a, 240, 240a, 242, 242a, 244, 244a and 245 through the TSV interconnects 246 in the memory chips 238, 238a, 240, 240a, 242, 242a, 244 and 244a and the TSV interconnects 247 in the memory chip 245. The input signals, such as the signals CK, RST and CE, from an external circuit of the multichip package 992, such as the controller of the data storage device, can be transmitted to the parallel common input ports 228 of one or more of the memory chips 238, 238a, 240, 240a, 242, 242a, 244, 244a and 245 through the metal pillars or bumps 248.

The serial input ports 234 of the memory chip 244a of the multichip package 992 may be vertically over and substantially aligned with the serial input ports 234 of the memory chips 238, 238a, 240, 240a, 242, 242a, 244 and 245 of the multichip package 992. The serial output ports 235 of the memory chip 244a of the multichip package 992 may be vertically over and substantially aligned with the serial output ports 235 of the memory chips 238, 238a, 240, 240a, 242, 242a, 244 and 245 of the multichip package 992. The parallel common input ports 228 of the memory chip 244a of the multichip package 992 may be vertically over and substantially aligned with the parallel common input ports 228 of the memory chips 238, 238a, 240, 240a, 242, 242a, 244 and 245 of the multichip package 992.

The isolation enclosures 202 enclosing the TSV interconnects 246 in the memory chip 238 of the multichip package 992 can be vertically over and substantially aligned with the isolation enclosures 202 enclosing the TSV interconnects 247 in the memory chip 245 of the multichip package 992. The isolation enclosures 202 enclosing the TSV interconnects 268a in the memory chip 238 of the multichip package 992 can be vertically over and substantially aligned with the isolation enclosures 202 enclosing the TSV interconnects 266 in the memory chip 245 of the multichip package 992.

The isolation enclosures 202 enclosing the TSV interconnects 246 in the memory chip 244a of the multichip package 992 can be vertically over and substantially aligned with the isolation enclosures 202 enclosing the TSV interconnects 246 in the memory chips 238, 238a, 240, 240a, 242, 242a and 244 of the multichip package 992. The isolation enclosures 202 enclosing the TSV interconnects 250 in the memory chip 244a of the multichip package 992 can be vertically over and substantially aligned with the isolation enclosures 202 enclosing the TSV interconnects 250 in the memory chips 238, 238a, 240, 240a, 242, 242a, 244 and 245 of the multichip package 992. The isolation enclosures 202 enclosing the TSV interconnects 283 in the memory chip 244a of the multichip package 992 can be vertically over and substantially aligned with the isolation enclosures 202 enclosing the TSV interconnects 283 in the memory chips 238, 238a, 240, 240a, 242, 242a, and 244 of the multichip package 992. The isolation enclosures 202 enclosing the TSV interconnects 264 in the memory chip 244a of the multichip package 992 can be vertically over and substantially aligned with the isolation enclosures 202 enclosing the TSV interconnects 264 in the memory chips 240, 240a, 242, 242a and 244 of the multichip package 992. The isolation enclosures 202 enclosing the TSV interconnects 268 in the memory chip 244a of the multichip package 992 can be vertically over and substantially aligned with the isolation enclosures 202 enclosing the TSV interconnects 268 in the memory chips 240, 240a, 242, 242a and 244 of the multichip package 992 and enclosing the TSV interconnects 268a in the memory chips 238 and 238a of the multichip package 992.

The TSV interconnects 250 in the memory chip 245 can connect the serial output ports 235 of the memory chip 245 to the overlying interconnects 701 at the backside of the substrate 2 of the memory chip 245. The overlying interconnects 701 at the backside of the substrate 2 of the memory chip 245 can connect the TSV interconnects 250 in the memory chip 245 to the TSV interconnects 283 in the memory chip 238.

The TSV interconnects 268 and 268a in the memory chips 238, 238a, 240, 240a, 242, 242a, 244 and 244a shown in FIG. 103 are connected to each other, to the serial input ports 234 of the memory chips 238, 238a and 245, and to the metal pillars or bumps 254. The serial input ports 234, having a same type (such as inputting data of D0), of the memory chips 238, 238a and 245 shown in FIG. 103 can be connected in parallel to each other through the TSV interconnects 268a in the memory chips 238 and 238a, the TSV interconnects 268 in the memory chips 240, 242, and 244, and the TSV interconnects 266 in the memory chip 245.

The interconnects 256 of the memory chip 238 shown in FIG. 103 can be connected to the serial input ports 234 of the memory chip 238. The memory chip 238 shown in FIG. 103 may have circuit paths between the interconnects 256 of the memory chip 238 and the serial input ports 234 of the memory chip 238. The interconnects 256 of the memory chip 238a shown in FIG. 103 can be connected to the serial input ports 234 of the memory chip 238a. The memory chip 238a shown in FIG. 103 may have circuit paths between the interconnects 256 of the memory chip 238a and the serial input ports 234 of the memory chip 238a. The interconnects 256 of the memory chip 245 shown in FIG. 103 can be connected to the serial input ports 234 of the memory chip 245. The memory chip 245 shown in FIG. 103 may have circuit paths between the interconnects 256 of the memory chip 245 and the serial input ports 234 of the memory chip 245.

The TSV interconnects 266 in the memory chip 245 shown in FIG. 103 can contact the interconnects 256 of the memory chip 245. The TSV interconnects 268a in the memory chip 238 shown in FIG. 103 can contact the interconnects 256 of the memory chip 238 and the overlying interconnects 301b at the backside of the substrate 2 of the memory chip 245. The TSV interconnects 268a in the memory chip 238a shown in FIG. 103 can contact the interconnects 256 of the memory chip 238a and the overlying interconnects, connecting to the TSV interconnects 268 in the memory chip 244, at the backside of the substrate 2 of the memory chip 244. The TSV interconnects 268 in the memory chips 240, 240a, 242, 242a, 244 and 244a shown in FIG. 103 may not contact the interconnects 256 of the memory chips 240, 240a, 242, 242a, 244 and 244a.

Alternatively, the interconnects 256 of the memory chips 238, 238a, 240, 240a, 242, 242a, 244, 244a and 245 shown in FIG. 103 can be omitted. In this case, the TSV interconnects 266 in the memory chip 245 can contact the serial input ports 234 of the memory chip 245 instead of contacting the interconnects 256 of the memory chip 245. The TSV interconnects 268a in the memory chip 238 can contact the serial input ports 234 of the memory chip 238 instead of contacting the interconnects 256 of the memory chip 238. The TSV interconnects 268a in the memory chip 238a can contact the serial input ports 234 of the memory chip 238a instead of contacting the interconnects 256 of the memory chip 238a.

The TSV interconnects 268 in the memory chip 240 shown in FIG. 103 are not connected to the serial input ports 234 of the memory chip 240 through any interconnection of the IC scheme 208 of the memory chip 240 and any overlying interconnect at the backside of the substrate 2 of the memory chip 240. The TSV interconnects 268 in the memory chip 242 shown in FIG. 103 are not connected to the serial input ports 234 of the memory chip 242 through any interconnection of the IC scheme 208 of the memory chip 242 and any overlying interconnect at the backside of the substrate 2 of the memory chip 242. The TSV interconnects 268 in the memory chip 244 shown in FIG. 103 are not connected to the serial input ports 234 of the memory chip 244 through any interconnection of the IC scheme 208 of the memory chip 244 and any overlying interconnect at the backside of the substrate 2 of the memory chip 244.

The TSV interconnects 268 in the memory chip 240a shown in FIG. 103 are not connected to the serial input ports 234 of the memory chip 240a through any interconnection of the IC scheme 208 of the memory chip 240a and any overlying interconnect at the backside of the substrate 2 of the memory chip 240a. The TSV interconnects 268 in the memory chip 242a shown in FIG. 103 are not connected to the serial input ports 234 of the memory chip 242a through any interconnection of the IC scheme 208 of the memory chip 242a and any overlying interconnect at the backside of the substrate 2 of the memory chip 242a. The TSV interconnects 268 in the memory chip 244a shown in FIG. 103 are not connected to the serial input ports 234 of the memory chip 244a through any interconnection of the IC scheme 208 of the memory chip 244a and any overlying interconnect at the backside of the substrate 2 of the memory chip 244a.

The TSV interconnects 283 in the memory chips 238, 238a, 240, 240a, 242, 242a, 244 and 244a shown in FIG. 103 are connected to each other, to the serial output ports 235 of the memory chips 244, 244a and 245, and to the metal pillars or bumps 252. The serial output ports 235, having a same type (such as outputting data of Q0), of the memory chips 244, 244a and 245 shown in FIG. 103 can be connected in parallel to each other through the TSV interconnects 283 in the memory chips 238, 238a, 240, 240a, 242, 242a, 244 and 244a.

The serial output ports 235 of the memory chip 245 shown in FIG. 103 can be connected to the TSV interconnects 283 in the memory chips 238, 238a, 240, 240a, 242, 242a, 244 and 244a through the TSV interconnects 250 in the memory chip 245 and the overlying interconnects 701 at the backside of the substrate 2 of the memory chip 245. The serial output ports 235 of the memory chip 244 shown in FIG. 103 can be connected to the TSV interconnects 283 in the memory chips 238, 238a, 240, 240a, 242, 242a, 244 and 244a through the TSV interconnects 250 in the memory chip 244 and the overlying interconnects 703a at the backside of the substrate 2 of the memory chip 244. The serial output ports 235 of the memory chip 244a shown in FIG. 103 can be connected to the TSV interconnects 283 in the memory chips 238, 238a, 240, 240a, 242, 242a, 244a and 244aa through the TSV interconnects 250 in the memory chip 244a and the overlying interconnects 703a at the backside of the substrate 2 of the memory chip 244a.

The TSV interconnects 246 in the memory chips 238, 238a, 240, 240a, 242, 242a, 244 and 244a shown in FIG. 103 are connected to each other, to the parallel common input ports 228 of the memory chips 238, 238a, 240, 240a, 242, 242a, 244, 244a and 245, and to the metal pillars or bumps 248. The parallel common input ports 228, having a same type, of the memory chips 238, 238a, 240, 240a, 242, 242a, 244, 244a and 245 shown in FIG. 103 can be connected in parallel to each other through the TSV interconnects 246 in the memory chips 238, 238a, 240, 240a, 242, 242a, 244 and 244a. For example, the parallel common input ports 228, for inputting the signal (CE), of the memory chips 238, 238a, 240, 240a, 242, 242a, 244, 244a and 245 shown in FIG. 103 can be connected in parallel to each other through the TSV interconnects 246 in the memory chips 238, 238a, 240, 240a, 242, 242a, 244 and 244a.

The layout design of the TSV interconnects 250 in the memory chip 238 and the metal traces 301a at the backside of the substrate 2 of the memory chip 238 as mentioned in FIG. 103 can be referred to as the layout design of the TSV interconnects 250 in the memory chip 238 and the metal traces 301a at the backside of the substrate 2 of the memory chip 238 as illustrated in FIGS. 87, 88 and 97. The layout design of the TSV interconnects 246, 250 and 268 in the memory chip 240, the metal traces 302a at the backside of the substrate 2 of the memory chip 240, and the overlying interconnects 302d at the backside of the substrate 2 of the memory chip 240 as mentioned in FIG. 103 can be referred to as the layout design of the TSV interconnects 246, 250 and 268 in the memory chip 240, the metal traces 302a at the backside of the substrate 2 of the memory chip 240, and the overlying interconnects 302d at the backside of the substrate 2 of the memory chip 240 as illustrated in FIGS. 87, 89 and 98. The layout design of the TSV interconnects 246, 250 and 268 in the memory chip 242 and the metal traces 303a at the backside of the substrate 2 of the memory chip 242 as mentioned in FIG. 103 can be referred to as the layout design of the TSV interconnects 246 250 and 268 in the memory chip 242 and the metal traces 303a at the backside of the substrate 2 of the memory chip 242 as illustrated in FIGS. 87, 90 and 99.

The layout design of the TSV interconnects 250 in the memory chip 238a and the metal traces 301a at the backside of the substrate 2 of the memory chip 238a as mentioned in FIG. 103 can be referred to as the layout design of the TSV interconnects 250 in the memory chip 238 and the metal traces 301a at the backside of the substrate 2 of the memory chip 238 as illustrated in FIGS. 87, 88 and 97. The layout design of the TSV interconnects 246, 250 and 268 in the memory chip 240a, the metal traces 302a at the backside of the substrate 2 of the memory chip 240a, and the overlying interconnects 302d at the backside of the substrate 2 of the memory chip 240a as mentioned in FIG. 103 can be referred to as the layout design of the TSV interconnects 246, 250 and 268 in the memory chip 240, the metal traces 302a at the backside of the substrate 2 of the memory chip 240, and the overlying interconnects 302d at the backside of the substrate 2 of the memory chip 240 as illustrated in FIGS. 87, 89 and 98. The layout design of the TSV interconnects 246, 250 and 268 in the memory chip 242a and the metal traces 303a at the backside of the substrate 2 of the memory chip 242a as mentioned in FIG. 103 can be referred to as the layout design of the TSV interconnects 246 250 and 268 in the memory chip 242 and the metal traces 303a at the backside of the substrate 2 of the memory chip 242 as illustrated in FIGS. 87, 90 and 99.

In one example, the bottom memory module, including the stacked memory chips 238, 240, 242 and 244, of the multichip package 992 may have a circuit path, signal path or data path, between the input port D0, one of the serial input ports 234, of the memory chip 238 and the output port Q0, one of the serial output ports 235, of the memory chip 244, passing through, in sequence, the circuit path from the input port D0 of the memory chip 238 to the corresponding output port Q0 of the memory chip 238, the TSV interconnect 250 in the memory chip 238, the metal trace 301a at the backside of the substrate 2 of the memory chip 238, the TSV interconnect 264 in the memory chip 240, the input port D0 of the memory chip 240, the circuit path from the input port D0 of the memory chip 240 to the corresponding output port Q0 of the memory chip 240, the TSV interconnect 250 in the memory chip 240, the metal trace 302a at the backside of the substrate 2 of the memory chip 240, the TSV interconnect 264 in the memory chip 242, the input port D0 of the memory chip 242, the circuit path from the input port D0 of the memory chip 242 to the corresponding output port Q0 of the memory chip 242, the TSV interconnect 250 in the memory chip 242, the metal trace 303a at the backside of the substrate 2 of the memory chip 242, the TSV interconnect 264 in the memory chip 244, the input port D0 of the memory chip 244, and the circuit path from the input port D0 of the memory chip 244 to the corresponding output port Q0 of the memory chip 244.

The output port Q0 of the memory chip 244 can be connected to one of the metal pillars or bumps 252 through, in sequence, the TSV interconnect 250 in the memory chip 244, the overlying interconnect 703a at the backside of the substrate 2 of the memory chip 244, the TSV interconnect 283 in the memory chip 238a, the TSV interconnect 283 in the memory chip 240a, the TSV interconnect 283 in the memory chip 242a, the TSV interconnect 283 in the memory chip 244a, and the overlying interconnect 703a at the backside of the substrate 2 of the memory chip 244a. The output port Q0 of the memory chip 244, the output port Q0 of the memory chip 244a and the output port Q0 of the memory chip 245 can be connected in parallel to each other through the TSV interconnects 283 in the memory chips 238, 238a, 240, 240a, 242, 242a, 244 and 244a.

One of the metal pillars or bumps 254 can be connected to the input port D0 of the memory chip 238 through, in sequence, the overlying interconnect 703b at the backside of the substrate 2 of the memory chip 244a, the TSV interconnect 268 in the memory chip 244a, the TSV interconnect 268 in the memory chip 242a, the TSV interconnect 268 in the memory chip 240a, the overlying interconnect 702 at the backside of the substrate 2 of the memory chip 238a, the TSV interconnect 268a in the memory chip 238a, the TSV interconnect 268 in the memory chip 244, the TSV interconnect 268 in the memory chip 242, the TSV interconnect 268 in the memory chip 240, the overlying interconnect 702 at the backside of the substrate 2 of the memory chip 238, the TSV interconnect 268a in the memory chip 238, and the interconnect 256 of the memory chip 238. The input port D0 of the memory chip 238, the input port D0 of the memory chip 238a and the input port D0 of the memory chip 245 can be connected in parallel to each other through the TSV interconnects 268 in the memory chips 240, 242 and 244 and the TSV interconnects 268a in the memory chips 238 and 238a.

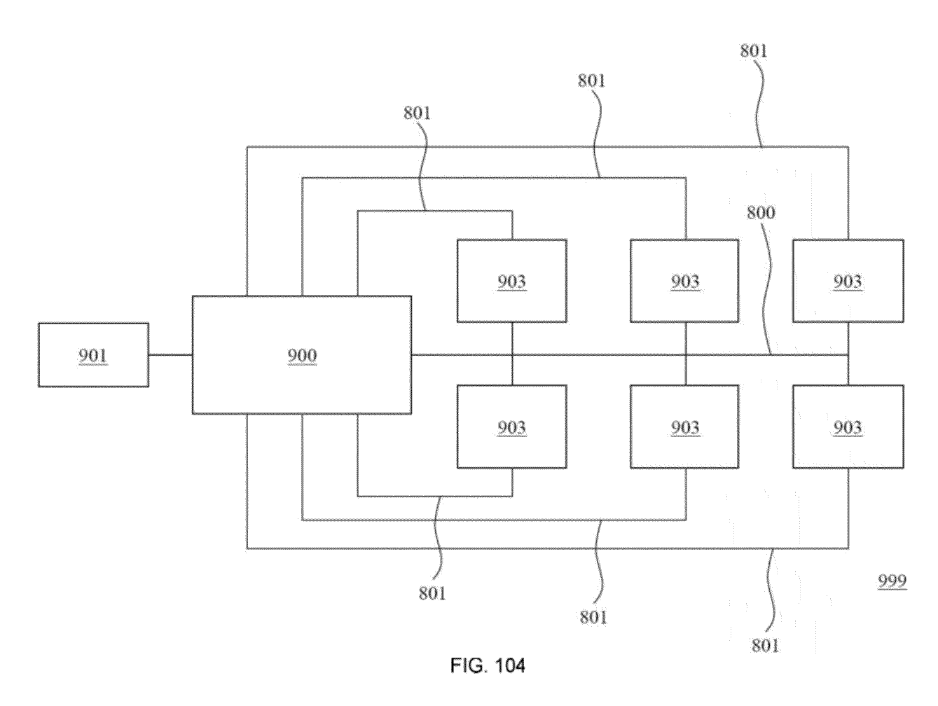

FIG. 104 illustrates a schematic diagram of a data storage device 999 according to an exemplary embodiment of the present disclosure. The data storage device 999 can be a SSD, an USB device, an embedded multi media device or a mSATA SSD. The data storage device 999 may include a circuit substrate (not shown), a controller 900 mounted over the circuit substrate, a DRAM chip 901 mounted over the circuit substrate and connected to the controller 900, and any suitable number of memory devices 903 mounted over the circuit substrate. In this embodiment, the data storage device 999 includes six memory devices 903. Alternatively, the data storage device 999 may include more than six memory devices 903.

Each of the memory devices 903 can be the multichip package 990 illustrated in FIG. 87 or 102, the multichip package 991 illustrated in FIG. 92, or the multichip package 992 illustrated in FIG. 103. That is, each of the memory devices 903 can include some levels of the above-mentioned stacked memory chips 238, 238a, 240, 240a, 242, 242a, 244, 244a and 245 each containing the serial input ports 234, the serial output ports 235 and the parallel common input ports 228, the above-mentioned metal pillars or bumps 248, 252 and 254, some levels of the above-mentioned TSV interconnects, and some levels of the above-mentioned overlying interconnects, which can be referred to FIGS. 87-103.

Each of the memory devices 903 can join the circuit substrate of the data storage device 999 through the metal pillars or bumps 248, 252 and 254. The circuit substrate of the data storage device 999 can be a mother board, a printed circuit board (PCB), a ball-grid-array (BGA) substrate or a glass substrate.

Multiple conductive interconnections 800 and 801 are preformed on the circuit substrate of the data storage device 999 and can be between the controller 900 and the memory devices 903. Each of the conductive interconnections 801 may include multiple conductive traces connecting the controller 900 to the metal pillars or bumps 248 of one of the memory devices 903, respectively.

The conductive interconnection 800 may include multiple first conductive traces for inputting signals or data to the serial input ports 234, and multiple second conductive traces for outputting signals and data from the serial output ports 235. The data storage device 999, for example, may have a data width of by-sixteen bits, that is, including sixteen first conductive traces of the conductive interconnection 800 between the controller 900 and the memory devices 903 and sixteen second conductive traces of the conductive interconnection 800 between the controller 900 and the memory devices 903. Each of the first conductive traces of the conductive interconnection 800 can be connected to the controller 900 and to one of the metal pillars or bumps 254, configured to input a signal or data to one of the serial input ports 234 (such as one of the above-mentioned input ports D0-D15), of each memory device 903. Each of the second conductive traces of the conductive interconnection 800 can be connected to the controller 900 and to one of the metal pillars or bumps 252, configured to output a signal or data from one of the serial output ports 235 (such as one of the above-mentioned output ports Q0-Q15), of each memory device 903.

The metal pillars or bumps 254, configured to input signals or data to the corresponding serial input ports 234 (such as the above-mentioned input ports D0), of the six memory devices 903 are connected in parallel with each other through one of the first conductive traces of the conductive interconnection 800. The metal pillars or bumps 252, configured to output signals or data from the corresponding serial output ports 235 (such as the above-mentioned output ports Q0), of the six memory device 903 are connected in parallel with each other through one of the second conductive traces of the conductive interconnection 800.

Alternatively, the multichip packages shown herein, except the multichip packages illustrated in FIGS. 87, 92, 102 and 103, can be applied to the memory devices 903.

The multichip packages, multichip modules, shown herein can be used in a wide variety of electronic devices, including, but not limited to, e.g., a telephone, a cordless phone, a mobile phone, a smart phone, a netbook computer, a notebook computer, a digital camera, a digital video camera, a digital picture frame, a personal digital assistant (PDA), a pocket personal computer, a portable personal computer, an electronic book, a digital book, a desktop computer, a tablet or slate computer, an automobile electronic product, a mobile internet device (MID), a mobile television, a projector, a mobile projector, a pico projector, a smart projector, a three-dimensional (3D) video display, a 3D television (3D TV), a 3D video game player, a mobile computer device, a mobile compuphone (also called mobile phoneputer or mobile personal computer phone) which is a device or a system combining and providing functions of computers and phones, or a high performance and/or low power computer or server, for example, used for cloud computing.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, benefits and advantages. These also include embodiments in which the components and/or steps are arranged and/or ordered differently.

In reading the present disclosure, one skilled in the art will appreciate that embodiments of the present disclosure, e.g., design of structure and/or control of methods described herein, can be implemented in hardware, software, firmware, or any combinations of such, and over one or more networks. Suitable software can include computer-readable or machine-readable instructions for performing methods and techniques (and portions thereof) of designing and/or controlling the implementation of tailored RF pulse trains. Any suitable software language (machine-dependent or machine-independent) may be utilized. Moreover, embodiments of the present disclosure can be included in or carried by various signals, e.g., as transmitted over a wireless RF or IR communications link or downloaded from the Internet.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A chip package comprising:
a first chip comprising a first semiconductor substrate, a first isolation enclosure in said first semiconductor substrate, a first dielectric layer under said first semiconductor substrate, and a first metal layer under said first semiconductor substrate and said first dielectric layer, wherein said first isolation enclosure is not in contact with said first dielectric layer;
a second chip over said first chip, wherein said second chip comprises a second semiconductor substrate, a second isolation enclosure in said second semiconductor substrate, and a second dielectric layer under said second semiconductor substrate, wherein said second isolation enclosure is not in contact with said second dielectric layer, wherein said second isolation enclosure is aligned with said first isolation enclosure and is separate from said first isolation enclosure; and
a first metal plug in said first and second chips, wherein said first metal plug passes through said first and second isolation enclosures, said first and second dielectric layers, and said second chip, wherein said first metal plug is connected to said first metal layer.

2. The chip package of claim 1, wherein said first chip has a thickness between 1 and 10 micrometers, and said second chip has a thickness between 1 and 10 micrometers.

3. The chip package of claim 1, wherein said first metal plug comprises copper.

4. The chip package of claim 1, wherein said first and second chips are memory chips.

5. The chip package of claim 1, wherein said first and second chips are NAND flash memory chips.

6. The chip package of claim 1, wherein said first isolation enclosure comprises silicon oxide.

7. The chip package of claim 1, wherein said first isolation enclosure comprises silicon nitride.

8. The chip package of claim 1, wherein said first isolation enclosure has a thickness between 1 and 10 micrometers, and said second isolation enclosure has a thickness between 1 and 10 micrometers.

9. The chip package of claim 1 further comprising a second metal plug in said second chip, wherein said second metal plug passes through a third isolation enclosure in said second semiconductor substrate and contacts a second metal layer of said second chip, wherein said third isolation enclosure is not in contact with said second metal layer.

10. The chip package of claim 1 further comprising a wirebonded wire connected to said first metal plug.

11. The chip package of claim 1 further comprising a metal bump connected to said first metal plug.

12. The chip package of claim 11, wherein said metal bump comprises a solder.

13. The chip package of claim 1 further comprising a third dielectric layer between said first and second chips, wherein said first metal plug further passes through said third dielectric layer, wherein said first isolation enclosure is under said third dielectric layer, and said second isolation enclosure is over said third dielectric layer.

14. The chip package of claim 1, wherein said first metal plug is not in contact with said first and second isolation enclosures.

15. The chip package of claim 1, wherein said first metal plug comprises an adhesion layer and a copper plug, wherein said adhesion layer is at a sidewall and a bottom of said copper plug.

16. The chip package of claim 1, wherein said first metal layer comprises a copper layer.

17. The chip package of claim 1, wherein said first metal layer comprises an aluminum layer.

18. The chip package of claim 1, wherein said first chip has a left sidewall substantially coplanar with a left sidewall of said second chip and a right sidewall substantially coplanar with a right sidewall of said second chip.

19. The chip package of claim 1, wherein said second chip further comprises a second metal layer and a passivation layer, wherein said second metal layer is between said passivation layer and said second dielectric layer, wherein said first metal plug contacts said second metal layer and further passes through said passivation layer, wherein said second metal layer is connected to said first metal layer through said first metal plug.

20. The chip package of claim 1, wherein said first metal layer is further under a passivation layer of said first chip.
